(19) United States
(12) Patent Application Publication
(10) Pub. No.: US 2013/0095427 A1
(43) Pub. Date: Apr. 18, 2013

(54) RESIST COMPOSITION FOR EUV OR EB AND METHOD OF FORMING RESIST PATTERN

(71) Applicant: Tokyo Ohka Kogyo Co., Ltd., Kawasaki-shi (JP)

(72) Inventors: Masahito Yahagi, Kawasaki-shi (JP); Jun Iwashita, Kawasaki-shi (JP)

(73) Assignee: TOKYO OHKA KOGYO CO., LTD., Kawasaki-shi (JP)

(21) Appl. No.: 13/650,371

(22) Filed: Oct. 12, 2012

(30) Foreign Application Priority Data
Oct. 14, 2011 (JP) 2011-226917
Oct. 17, 2011 (JP) 2011-228065
Nov. 8, 2011 (JP) 2011-244722
Feb. 8, 2012 (JP) 2012-025595

(51) Int. Cl. G03F 7/004

(52) U.S. Cl. CPC G03F 7/004
USPC 430/285.1; 430/270.1; 430/281.1

(57) ABSTRACT

The present invention relates to a resist composition for EUV or EB containing a base component (A) which generates acid upon exposure and exhibits changed solubility in a developing solution by the action of acid, and a resin component (W) that contains at least one atom selected from a fluorine atom or a silicon atom and contains a polarity conversion group that exhibits increased polarity after decomposition by the action of base, wherein the base component (A) contains a component (A1) which contains a structural unit (a0) having a group represented by general formula (a0-1) or (a0-2) shown below, and the amount of the resin component (W) relative to 100 parts by weight of the base component (A) is 1 to 15 parts by weight. In the formulas, Q¹ and Q² represents a single bond or a divalent linking group; R³ to R⁵ represents an organic group, and —R³—S⁺(R⁴)(R⁵) has one aromatic ring or no aromatic ring in total; V⁻ represents a counteranion; A⁻ represents an organic group containing an anion moiety; and M^{m+} represents a mono- to tri-valent organic cation, provided that M^{m+} has one aromatic ring or no aromatic ring.

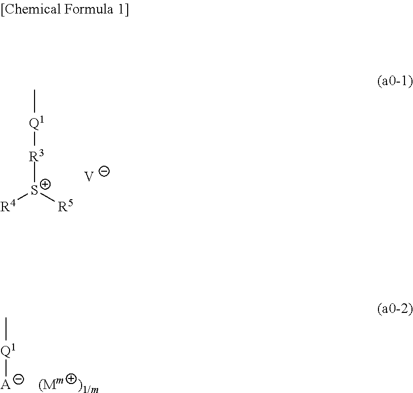

### TECHNICAL FIELD

The present invention relates to a resist composition for EUV or EB, which generates acid upon exposure and exhibits changed solubility in a developing solution by the action of acid and a method of forming a resist pattern using the resist composition.

Priority is claimed on Japanese Patent Application No. 2011-226917, filed Oct. 14, 2011, Japanese Patent Application No. 2011-228065, filed Oct. 17, 2011, Japanese Patent Application No. 2011-244722, filed Nov. 8, 2011, and Japanese Patent Application No. 2012-025595, filed Feb. 8, 2012, the contents of which are incorporated herein by reference.

### BACKGROUND ART

In lithography techniques, for example, a resist film composed of a resist material is formed on a substrate, and the resist film is subjected to selective exposure, followed by development, thereby forming a resist pattern having a predetermined shape on the resist film. A resist material in which the exposed portions of the resist film become soluble in a developing solution is called a positive-type, and a resist material in which the exposed portions of the resist film become insoluble in a developing solution is called a negative-type.

In recent years, in the production of semiconductor elements and liquid crystal display elements, advances in lithography techniques have lead to rapid progress in the field of pattern miniaturization.

Typically, these miniaturization techniques involve shortening the wavelength (increasing the energy) of the exposure light source. Conventionally, ultraviolet radiation typified by g-line and i-line radiation has been used, but nowadays KrF excimer lasers and ArF excimer lasers are starting to be introduced in mass production. Furthermore, research is also being conducted into lithography techniques that use an exposure light source having a wavelength shorter (energy higher) than these excimer lasers, such as electron beam (EB), extreme ultraviolet radiation (EUV), and X ray.

Resist materials for use with these types of exposure light sources require lithography properties such as a high resolution capable of reproducing patterns of minute dimensions, and a high level of sensitivity to these types of exposure light sources.

As a resist material that satisfies these conditions, a chemically amplified composition is used, which includes a base material component that exhibits a changed solubility in a developing solution under the action of acid and an acid-generator component that generates acid upon exposure. For example, in the case where the developing solution is an alkali developing solution (alkali developing process), a chemically amplified positive resist which contains, as a base component (base resin), a resin which exhibits increased solubility in an alkali developing solution under action of acid, and an acid generator is typically used. If the resist film formed using the resist composition is selectively exposed during formation of a resist pattern, then within the exposed portions, acid is generated from the acid-generator component, and the action of this acid causes an increase in the polarity of the base resin (for example, the solubility in an alkali developing solution), making the exposed portions soluble in the alkali developing solution. Thus, by conducting an alkali development, the unexposed portions remain to form a positive resist pattern.

The base resin which exhibits increased polarity by the action of acid is used, thereby exhibiting increased solubility in an alkali developing solution, whereas the solubility in an organic solvent is decreased. Therefore, when such a base resin is applied to a solvent developing process using a developing solution containing an organic solvent (organic developing solution) instead of an alkali developing process, the solubility of the exposed portions in an organic developing solution is decreased. As a result, in the solvent developing process, the unexposed portions of the resist film are dissolved and removed by the organic developing solution, and a negative resist pattern in which the exposed portions are remaining is formed. The solvent developing process to form a negative resist pattern is frequently referred to as “negative tone-developing process” (for example, Patent Document 1).

Currently, resins that contain structural units derived from (meth)acrylate esters within the main chain (acrylic resins) are now widely used as base resins for chemically amplified resist compositions that is used in ArF excimer laser lithography, as they exhibit excellent transparency in the vicinity of 193 nm (for example, see Patent Document 2). Here, the term “(meth)acrylate ester” is a generic term that includes either or both of the acrylate ester having a hydrogen atom bonded to the α-position and the methacrylate ester having a methyl group bonded to the α-position. The term “(meth)acrylate” is a generic term that includes either or both of the acrylate having a hydrogen atom bonded to the α-position and the methacrylate having a methyl group bonded to the α-position. The term “(meth)acrylic acid” is a generic term that includes either or both of acrylic acid having a hydrogen atom bonded to the α-position and methacrylic acid having a methyl group bonded to the α-position.

Recently, as a base resin, a resin which contains an acid-generating group capable of generating acid upon exposure. For example, a resin component which has an acid generating group that generates acid upon exposure and an acid decomposable group that exhibits changed polarity by the action of acid in the structure thereof, has been proposed (for example, Patent Documents 3 to 5). Such a resin component has both the function as an acid generator and the function as a base component, and hence, can compose a chemically amplified resist composition by just one component. Thus, it is indicated that when the resin component is used, in term of acid diffusion control, lithography property such as LWR and the like can be improved (Patent Document 6). That is, when such a resin component is subjected to exposure, acid is generated from the acid-generating group in the structure thereof, and the acid decomposable group is decomposed by the generated acid, thereby forming a polar group such as a carboxy group to exhibit increased polarity. When a resin film (resist film) formed using such a resin component is subjected to selective exposure, the polarity of the exposed portions is increased. Thus, by conducting developing by using an alkali developing solution, the exposed portions are dissolved and removed, thereby forming a positive resist pattern.

Furthermore, as the aforementioned resin component, a resin component containing a structural unit having a lactone ring has been proposed, and it is also indicated that these structural units are conventionally used in order to improve adhesion between the resist composition and the substrate (Patent Documents 4 and 5).

As a technique for further improving the resolution, a lithography method called liquid immersion lithography (hereafter, frequently referred to as “immersion exposure”) is known in which exposure (immersion exposure) is conducted in a state where the region between the lens and the resist layer formed on a wafer is filled with a solvent (a immersion medium) that has a larger refractive index than the refractive index of air. According to this type of immersion exposure, it is considered that higher resolutions equivalent to those obtained using a shorter wavelength light source or a larger NA lens can be obtained using the same exposure light source wavelength, with no lowering of the depth of focus. Furthermore, immersion exposure can be conducted using a conventional exposure apparatus. As a result, immersion exposure is widely used in recent years, because it enables the formation of resist patterns of higher resolution and superior depth of focus at lower costs. Immersion lithography is effective in forming patterns having various shapes. Further, immersion exposure is expected to be capable of being used in combination with super-resolution techniques, such as phase shift method and modified illumination method. Currently, as the immersion exposure technique, technique using an ArF excimer laser as an exposure source is being actively studied. Further, water is mainly used as the immersion medium.

A resist composition for immersion exposure which includes a compound containing a fluorine atom or a silicon atom, has been proposed. For example, Patent Document 7 discloses a resist composition which includes a polymeric compound having a fluorine-containing aromatic cyclic group at the side chain thereof. Patent Document 8 discloses a resist composition including a fluorine-containing compound having a group represented by specific general formula.

### DOCUMENTS OF RELATED ART

### Patent Document

[Patent Document 1] Japanese Unexamined Patent Application, First Publication No. 2009-025723
[Patent Document 2] Japanese Unexamined Patent Application, First Publication No. 2003-241385
[Patent Document 3] Japanese Unexamined Patent Application, First Publication No. Hei 10-221852
[Patent Document 4] Japanese Unexamined Patent Application, First Publication No. 2006-045311
[Patent Document 5] Japanese Unexamined Patent Application, First Publication No. 2010-095643
[Patent Document 6] Japanese Unexamined Patent Application, First Publication No. 2011-158879
[Patent Document 7] Japanese Unexamined Patent Application, First Publication No. 2008-309938
[Patent Document 8] Japanese Unexamined Patent Application, First Publication No. 2009-139909

### SUMMARY OF THE INVENTION

Resist materials for use in EUV lithography or EB lithography require a high level of sensitivity to EUV or EB, and lithography properties such as a high resolution capable of forming a fine resist pattern.

Recently, as the resist materials used in EUV lithography or EB lithography, conventional chemically amplified resist compositions for ArF excimer lasers or KrF excimer lasers are generally used, since these compositions have an excellent sensitivity to EUV or EB and excellent lithography properties such as a high resolution capable of forming a fine resist pattern.

In particular, a chemically amplified resist composition including an acrylic resin as a base resin is superior in these lithography properties.

However, there is a problem that when chemically amplified resist compositions for ArF excimer lasers or KrF excimer lasers are used in EUV lithography or EB lithography, lithography properties of resist patterns to be formed is deteriorated and deterioration of contrast, and thickness loss of a resist pattern at unexposed portions are likely to occur.

For example, in the case of EUV lithography, there is a problem caused by OoB (Out of Band) light which is included in light generated from a light source of EUV exposure apparatus and has a wavelength outside EUV region. At unexposed portions of a resist film, the incidence of OoB light and Flare (stray lights) that is generated with OoB light occur, that is, selectivity of the exposed region during EUV irradiation is lost. As a result, at unexposed portions, an acid generator component is decomposed to generate acid. Therefore, OoB light causes deterioration of contrast of a resist pattern, thickness loss and roughness (surface roughness of the side walls and the top surface of the pattern). In particular, roughness causes defects in the shape of the resist pattern. For example, roughness on the side wall surfaces of a pattern can cause various defects such as non-uniformity of the line width of line and space patterns, or distortions around the holes in hole patterns.

The problem related to deterioration of lithography properties caused by OoB light tends to be significant when a chemically amplified resist composition for a lithography process using light having a wavelength within DUV region such as ArF excimer laser is used. That is, when the chemically amplified composition is irradiated with light having a wavelength within DUV region, in general, acid is generated thereby exhibiting changed solubility in a developing solution. OoB light includes EUV having a wavelength about 13.5 nm, DUV having a wavelength about 150 to 300 nm, and light having a wavelength within the infrared region. An onium salt acid generator, which is conventionally used as an acid-generator, is likely to absorb the light having a wavelength within DUV region to generate acid. As a result, in the case of EUV lithography, portions to be unexposed portions in resist film are exposed with OoB light, and deterioration of contrast, and thickness loss of a resist pattern is likely to occur.

In the case of EB lithography, diffusion (scattering) of electrons at the surface of the resist film may be caused depending on conditions of EB irradiation such as acceleration voltage, and hence, similar problems as those caused by OoB light in EUV lithography as described above may be caused.

Such a deterioration of lithography properties adversely affects the formation of very fine semiconductor elements.

Deterioration of contrast and thickness loss causes degradation of resolution, and therefore, improvement thereof is required.

Therefore, the aforementioned problems related to resist materials for use in EUV lithography or EB lithography need to be solved. Resist materials for use in EUV lithography or EB lithography require a high level of transparency (low sensitivity) to the light having a wavelength within DUV region and a high level of sensitivity to EUV.

Furthermore, in EUV lithography or EB lithography, it is important to reduce roughness (surface roughness of the side walls and the top surface of the pattern) and to improve exposure latitude. For example, roughness on the side wall surfaces of a pattern causes various defects such as non-uniformity of the line width of line and space patterns, or distortions around the holes in hole patterns. Such defects of the resist pattern adversely affect the formation of very fine semiconductor elements, and improvement in these lithography properties becomes more important as the pattern becomes smaller. However, in conventional chemically amplified compositions, these properties were unsatisfactory.

Therefore, as resist materials for use in EUV lithography or EB lithography, resist materials capable of forming a resist pattern with high resolution, reduced roughness and excellent exposure latitude has been required.

The present invention takes the above circumstances into consideration, with an object of providing a resist composition useful for EUV lithography or EB lithography and having excellent lithography properties and resolution, and a method of forming a resist pattern using the resist composition.

The present inventors have found that the aforementioned problems can be solved by using a resist composition containing a resin component as a base component which has a specific structure that generates acid upon exposure. The present invention has been completed based on this finding.

A first aspect of the present invention is a resist composition for EUV or EB containing a base component (A) which generates acid upon exposure and exhibits changed solubility in a developing solution by the action of acid, and a resin component (W) which contains at least one atom selected from a fluorine atom or a silicon atom and a polarity conversion group that exhibits increased polarity after decomposition by the action of base, wherein the base component (A) contains a polymeric compound (A1) which contains a structural unit (a0) having a group represented by general formula (a0-1) or (a0-2) shown below, and the amount of the resin component (W) relative to 100 parts by weight of the base component (A) is 1 to 15 parts by weight.

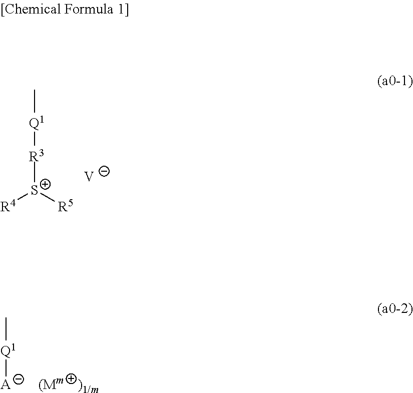

In the formulas, each of Q¹ and Q² independently represent a single bond or a divalent linking group; each of R³, R⁴ and R⁵ independently represents an organic group, provided that R³, R⁴ and R⁵ has one aromatic ring or no aromatic ring in total; R⁴ and R⁵ may be mutually bonded with the sulfur atom to form a ring; V⁻ represents a counteranion; A⁻ represents an organic group containing an anion moiety; M^{m+} represents a m-valent organic cation; and m represents an integer of 1 to 3, provided that M^{m+} has one aromatic ring or no aromatic ring.

A second aspect of the present invention is a resist composition containing a base component (A) which generates acid upon exposure and exhibits changed solubility in a developing solution by the action of acid, wherein the base component (A) contains a resin component (A1b) which contains a structural unit (a0) having a group represented by general formula (a0-1) or (a0-2) shown below, and a structural unit (a5) represented by general formula (a5-1) shown below.

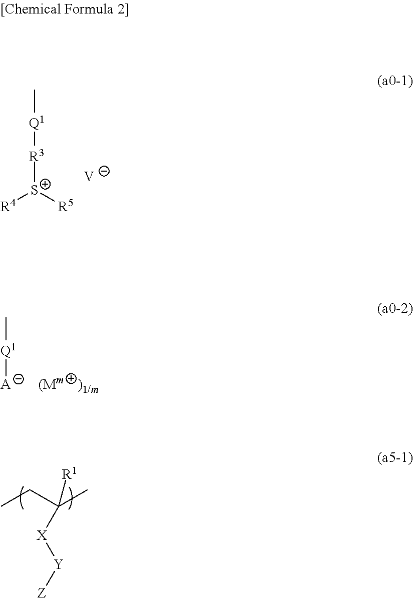

In the formulas, each of Q¹ and Q² independently represent a single bond or a divalent linking group; each of R³, R⁴ and R⁵ independently represents an organic group, R⁴ and R⁵ may be mutually bonded to form a ring with the sulfur atom, provided that —R³—S⁺(R⁴)(R⁵) has one aromatic ring or no aromatic ring in total; A⁻ represents an organic group containing an anion moiety; M^{m+} represents a m-valent organic cation; and m represents an integer of 1 to 3, provided that M^{m+} has one aromatic ring or no aromatic ring; R¹ represents a hydrogen atom, a methyl group or an alkyl group which has a substituent; X represents a divalent linking group; Y represents —O—, —COO—, —CON(R′)—, —OCO—, —CONHCO— or —CONHCS—, R′ represents a hydrogen atom or a methyl group, provided that when Y is —O—, X is a divalent linking group other than C(═O); and Z represents a group containing a lactone ring which may be either monocyclic or polycyclic and may have a substituent.

A third aspect of the present invention is a resist composition for EUV or EB containing a base component (A) which generates acid upon exposure and exhibits changed solubility in a developing solution by the action of acid, and a photoreactive quencher (C), wherein the base component (A) contains a polymeric compound (A1) which contains a structural unit (a0) having a group represented by general formula (a0-1) or (a0-2) shown below.

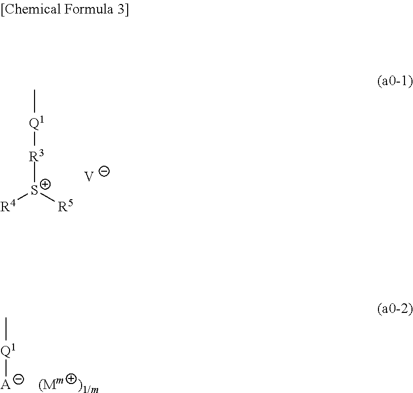

In the formulas, each of Q¹ and Q² independently represent a single bond or a divalent linking group; each of R³, R⁴ and R⁵ independently represents an organic group, R⁴ and R⁵ may be mutually bonded to form a ring with the sulfur atom, provided that —R³—S⁺(R⁴)(R⁵) has one aromatic ring or no aromatic ring in total; V⁻ represents a counteranion; A⁻ represents an organic group containing an anion moiety; M^{m+} represents a m-valent organic cation; and m represents an integer of 1 to 3, provided that M^{m+} has one aromatic ring or no aromatic ring.

As a result of intensive studies of the present inventors, they have found that in the resist composition containing a resin having a specific structure which generates acid upon exposure, when the resin has a cation moiety which absorbs light having a wavelength within DUV region contained in OoB light as a structure which generates acid upon exposure, deterioration of contrast, and thickness loss of a resist pattern at unexposed portions are likely to occur. Therefore, as a countermeasure against the OoB light, a cation moiety which absorbs little light having a wavelength within DUV region can be adopted. Such a countermeasure, a certain level of effects to improve deterioration of contrast, thickness loss and roughness can be achieved, but there is still room for improvement. Further, exposure latitude is not sufficiently improved. As a result of further studies, the present inventors have found that when a resin having a structure which generates acid upon exposure and contains a cation moiety having either one aromatic ring or no aromatic ring in the structure thereof is used in a combination with a photoreactive quencher, deterioration of contrast, thickness loss and roughness can be further suppressed, and exposure latitude can also be improved. The third aspect of the present invention has been completed based on this finding.

A fourth aspect of the present invention is a method of forming a resist pattern, including using a resist composition according to the first aspect or third aspect to form a resist film on a substrate, subjecting the resist film to exposure by EUV or EB, and subjecting the resist film to developing to form a resist pattern.

A fifth aspect of the present invention is a method of forming a resist pattern, including using a resist composition according to the second aspect to form a resist film on a substrate, subjecting the resist film to exposure, and subjecting the resist film to developing to form a resist pattern.

In the present description and claims, the term “for EUV or EB” means that the formation of a resist pattern using the resist composition is conducted with EUV (extreme ultraviolet radiation) or EB (electron beam) as an exposure light source.

The term “exposure” is used as a general concept that includes irradiation with any form of radiation.

The term “aliphatic” is a relative concept used in relation to the term “aromatic”, and defines a group or compound that has no aromaticity.

The term “alkyl group” includes linear, branched or cyclic, monovalent saturated hydrocarbon, unless otherwise specified. The same applies for the alkyl group within an alkoxy group.

The term “alkylene group” includes linear, branched or cyclic, divalent saturated hydrocarbon, unless otherwise specified.

The term “halogenated alkyl group” is a group in which part or all of the hydrogen atoms of the alkyl group has been substituted with halogen atoms. The term “halogenated alkylene group” is a group in which part or all of the hydrogen atoms of the alkylene group has been substituted with halogen atoms. Examples of the halogen atom include a fluorine atom, a chlorine atom, a bromine atom and an iodine atom.

The term “fluorinated alkyl group” is a group in which part or all of the hydrogen atoms of the alkyl group has been substituted with fluorine atoms. The term “fluorinated alkylene group” is a group in which part or all of the hydrogen atoms of the alkylene group has been substituted with fluorine atoms.

The term “structural unit” refers to a monomer unit that contributes to the formation of a resin (polymeric compound, polymer, copolymer).

According to the present invention, there are provided a resist composition useful for EUV or EB and having excellent lithography properties and excellent resolution, and a method of forming the resist pattern.

### DETAILED DESCRIPTION OF THE INVENTION

### <<Resist Composition of First Aspect>>

The resist composition according to a first aspect of the present invention includes a base component (A) which generates acid upon exposure and exhibits changed solubility in a developing solution by the action of acid (hereafter, referred to as “component (A)”), and a resin component (W) which contains at least one atom selected from a fluorine atom or a silicon atom, and a polarity conversion group that exhibits increased polarity after decomposition by the action of base (hereafter, referred to as “component (W)”).

The resist composition according to the first aspect of the present invention contains the component (A), thereby exhibiting changed solubility in a developing solution upon exposure. When a resist film is formed using the resist composition and then subjected to a selective exposure, acid is generated from the component (A) at exposed portions, and the generated acid acts on the component (A) to change the solubility of the component (A) in a developing solution. As a result, at exposed portions, the solubility in a developing solution is changed, whereas at unexposed portions, the solubility in a developing solution is not changed. Therefore, by developing the resist film, the exposed portions are dissolved and removed in the case that the resist composition is a positive resist, thereby enabling formation of a positive resist pattern, whereas the unexposed portions are dissolved and removed in the case that the resist composition is a negative resist, thereby enabling formation of a negative resist pattern.

In the present specification, a resist composition which forms a positive resist pattern by dissolving and removing the exposed portions is called a positive resist composition, and a resist composition which forms a negative resist pattern by dissolving and removing the unexposed portions is called a negative resist composition. The resist composition according to the first aspect of the present invention may be either a positive resist composition or a negative resist composition. Further, in the formation of a resist pattern, the resist composition according to the first aspect of the present invention can be applied to either an alkali developing process using an alkali developing solution in a developing treatment, or a solvent developing process using a developing solution containing an organic solvent (organic developing solution) in a developing treatment. Preferably, a resist composition for forming a positive resist pattern in an alkali developing process, which contains a component that exhibits increased solubility in an alkali developing solution by the action of acid as a component (A), can be used.

### <<Resist Composition of Second Aspect>>

The resist composition according to a second aspect of the present invention includes a base component (A) which generates acid upon exposure and exhibits changed solubility in a developing solution by the action of acid (hereafter, frequently referred to as “component (A)”).

The resist composition according to the second aspect of the present invention contains the component (A), thereby exhibiting changed solubility in a developing solution upon exposure. When a resist film is formed using the resist composition and then subjected to a selective exposure, acid is generated from the component (A) at exposed portions, and the generated acid acts on the component (A) to change the solubility of the component (A) in a developing solution. As a result, at exposed portions, the solubility in a developing solution is changed, whereas at unexposed portions, the solubility in a developing solution is not changed. Therefore, by developing the resist film, the exposed portions are dissolved and removed in the case that the resist composition is a positive resist, thereby enabling formation of a positive resist pattern, whereas the unexposed portions are dissolved and removed in the case that the resist composition is a negative resist, thereby enabling formation of a negative resist pattern.

In the present specification, a resist composition which forms a positive resist pattern by dissolving and removing the exposed portions is called a positive resist composition, and a resist composition which forms a negative resist pattern by dissolving and removing the unexposed portions is called a negative resist composition.

The resist composition according to the second aspect of the present invention may be either a positive resist composition or a negative resist composition. Further, in the formation of a resist pattern, the resist composition according to the second aspect of the present invention can be applied to either an alkali developing process using an alkali developing solution in a developing treatment, or a solvent developing process using a developing solution containing an organic solvent (organic developing solution) in a developing treatment. Preferably, in the case where the resist composition is used for forming a positive resist pattern in an alkali developing process and for forming a negative resist pattern in a solvent developing process, it is preferable to use a component that exhibits increased solubility in an alkali developing solution (decreased solubility in an organic developing solution) by the action of acid as a component (A).

### <<Resist Composition of Third Aspect>>

The resist composition for EUV or EB according the third aspect of the present invention (hereafter, referred to simply as resist composition) contains a base component (A) that generates acid upon exposure and exhibits changed solubility in a developing solution by the action of acid (hereafter, referred to as component (A)).

The resist composition according to the third aspect of the present invention contains the component (A), thereby exhibiting changed solubility in a developing solution upon exposure. When a resist film is formed using the resist composition and then subjected to a selective exposure, acid is generated from the component (A) at exposed portions, and the generated acid acts on the component (A) to change the solubility of the component (A) in a developing solution. As a result, at exposed portions, the solubility in a developing solution is changed, whereas at unexposed portions, the solubility in a developing solution is not changed. Therefore, by developing the resist film, the exposed portions are dissolved and removed in the case that the resist composition is a positive resist, thereby enabling formation of a positive resist pattern, whereas the unexposed portions are dissolved and removed in the case that the resist composition is a negative resist, thereby enabling formation of a negative resist pattern.

In the present specification, a resist composition which forms a positive resist pattern by dissolving and removing the exposed portions is called a positive resist composition, and a resist composition which forms a negative resist pattern by dissolving and removing the unexposed portions is called a negative resist composition. The resist composition according to the third aspect of the present invention may be either a positive resist composition or a negative resist composition. Further, in the formation of a resist pattern, the resist composition of the present invention can be applied to an alkali developing process using an alkali developing solution in the developing treatment, or a solvent developing process using a developing solution containing an organic solvent (organic developing solution) in the developing treatment. Preferably, a resist composition for forming a positive resist pattern in an alkali developing process, which contains a component that exhibits increased solubility in an alkali developing solution by the action of acid as a component (A), can be used.

### <Component (W)>

The component (W) is a resin component which contains at least one atom selected from a fluorine atom or a silicon atom, and a polarity conversion group that exhibits increased polarity after decomposition by the action of base.

In the present description, the term “resin component” refers to an organic compound capable of forming a film and which is a polymer. As a resin component, in terms of ease in forming a resist pattern of nano level, any polymeric compound which has a molecular weight of 500 or more, and preferably 1,000 or more, is generally used. With respect to a resin component, the “molecular weight” is the weight average molecular weight in terms of the polystyrene equivalent value determined by gel permeation chromatography (GPC).

[Polarity Conversion Group that Exhibits Increased Polarity after Decomposition by the Action of Base]

The polarity conversion group that exhibits increased polarity after decomposition by the action of base (hereafter, frequently referred to as base decomposable polarity conversion group) is decomposed (hydrolyzed) by the action of an alkali developing solution (preferably a 2.38 wt % aqueous TMAH solution at 23° C.). As a result, the component (W) which exhibits hydrophobicity prior to exposure is changed to exhibit hydrophilicity after exposure. Therefore, when a resist pattern is formed using a resist composition containing a component (W), the surface of the resist pattern exhibits hydrophobicity prior to exposure is changed to exhibit hydrophilicity after exposure. As a result, a resist pattern with reduced defects, reduced line edge roughness (LER) and excellent shape can be formed.

Examples of base decomposable polarity conversion groups include groups which are decomposed by the action of base to form a polar group. Examples of the polar group include a carboxy group, a hydroxy group and an amino group.

Specific examples of a polarity conversion group include a group in which at least one polar group within a polar group-containing group having at least one polar group has been protected with a base dissociable group can be given. The polar group-containing group may consist of a polar group, or may be a group in which n number of polar groups (wherein n represents an integer of 1 or more) are bonded to a (n+1)-valent linking group.

A “base dissociable group” is a group which exhibits base dissociable properties that at least the bond between the base dissociable group and an atom adjacent to the base dissociable group is cleaved by the action of base. As a base, an alkali developing solution (e.g., a 2.38 wt % aqueous TMAH solution at 23° C.) can be used. It is necessary that the base dissociable group that constitutes the polarity conversion group is a group which exhibits a lower polarity than the polar group generated by dissociation of the base dissociable group. Thus, when the base dissociable group is dissociated by the action of base, a polar group exhibiting a higher polarity than a base dissociable group is generated, thereby increasing the polarity. As a result, the polarity of the entire component (W) is increased. As the base dissociable groups, those which have been variously proposed can be used without particular limitation.

As the base decomposable polarity conversion group, groups represented by general formulas (I-1) to (I-4) shown below are preferable. Among these, a group represented by general formula (I-1) or (I-2) is preferable, and a group represented by general formula (I-2) is particularly desirable.

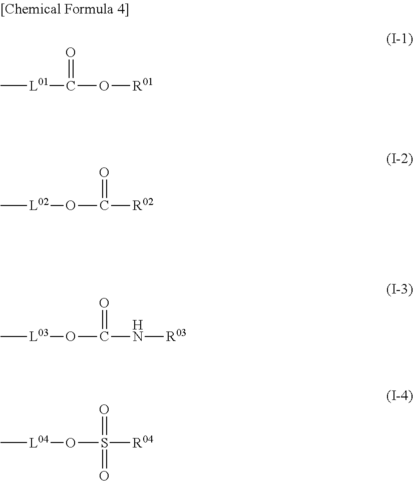

In the formulas, R⁰¹ represents an alkyl group of 1 or 2 carbon atoms or a fluorinated alkyl group of 1 to 10 carbon atoms; L⁰¹ represents a single bond or a divalent linking group; R⁰² represents is an organic group which may have a fluorine atom; L⁰² represents a single bond or a divalent linking group; R⁰³ represents is an organic group which may have a fluorine atom; L⁰³ represents a single bond or a divalent linking group; R⁰⁴ represents is an organic group which may have a fluorine atom; and L⁰⁴ represents a single bond or a divalent linking group.

As the fluorinated alkyl group for R⁰¹ in the formula (I-1), a linear or branched alkyl group is preferable. The fluorination ratio (percentage (%) of the number of fluorine atoms, base on the total number of fluorine atoms and hydrogen atoms in an unsubstituted alkyl group) is preferably at least 30%, and more preferably at least 50%.

The upper limit of the fluorination ratio is not particularly limited, and may be 100%.

As the fluorinated alkyl group, a group represented by —(CH₂)ᵥ—R^{f} [wherein v represents an integer of 0 to 4; and R^{f} represents a fluorinated alkyl group of 1 to 8 carbon atoms] is particularly preferable. v is preferably an integer of 1 to 3. R^{f} preferably has 1 or 2 carbon atoms. When v is an integer of 1 or more, R^{f} is preferably a perfluoroalkyl group.

Specific examples of R⁰¹ include —CH₃, —CH₂—CH₃, —CF₃, —CH₂—CF₃, —CH₂—CF₂—CF₃, —CH(CF₃)₂, —(CH₂)₂—(CF₂)₂—CF₃, —(CH₂)₂—(CF₂)₃—CF₃, —(CH₂)₂—(CF₂)₄—CF₃, —(CH₂)₂—(CF₂)₇—CF₃, —(CH₂)₃—CF₃, —(CH₂)₃—CF₂—CF₃, —(CH₂)₄—CF₃ and —(CH₂)₄—CF₂—CF₃.

In the formula (I-1), the divalent linking group for L⁰¹ is not particularly limited, and preferable examples thereof include a divalent hydrocarbon group which may have a substituent and a divalent linking group containing a hetero atom.

(Divalent Hydrocarbon Group which May have a Substituent)

The hydrocarbon group as a divalent linking group may be either an aliphatic hydrocarbon group or an aromatic hydrocarbon group.

An “aliphatic hydrocarbon group” refers to a hydrocarbon group that has no aromaticity. The aliphatic hydrocarbon group may be saturated or unsaturated. In general, the aliphatic hydrocarbon group is preferably saturated.

As specific examples of the aliphatic hydrocarbon group, a linear or branched aliphatic hydrocarbon group, and an aliphatic hydrocarbon group containing a ring in the structure thereof can be given.

The linear or branched aliphatic hydrocarbon group preferably has 1 to 10 carbon atoms, more preferably 1 to 8, and still more preferably 1 to 5.

As the linear aliphatic hydrocarbon group, a linear alkylene group is preferable, and specific examples include a methylene group [—CH₂—], an ethylene group [—(CH₂)₂—], a trimethylene group [—(CH₂)₃—], a tetramethylene group [—(CH₂)₄—] and a pentamethylene group [—(CH₂)₅—].

As the branched aliphatic hydrocarbon group, a branched alkylene group is preferable, and specific examples include alkylalkylene groups, e.g., alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—.

As the alkyl group within the alkylalkylene group, a linear alkyl group of 1 to 5 carbon atoms is preferable.

The linear or branched aliphatic hydrocarbon group may or may not have a substituent (that is, a group or an atom other than hydrogen atom) which substitutes a hydrogen atom in the linear or branched aliphatic hydrocarbon group. Examples of the substituent include a fluorine atom, a fluorinated alkyl group of 1 to 5 carbon atoms, and an oxo group (═O).

As examples of the aliphatic hydrocarbon group containing a ring in the structure thereof, a cyclic aliphatic hydrocarbon group which may have a substituent containing a hetero atom in the ring structure thereof (a group in which two hydrogen atoms have been removed from an aliphatic hydrocarbon ring) and a group in which the cyclic aliphatic hydrocarbon group has been bonded to the terminal of the linear or branched aliphatic hydrocarbon group or interposed within the aforementioned linear or branched aliphatic hydrocarbon group, can be given. Examples of the linear or branched aliphatic hydrocarbon group include the same groups as described above.

The cyclic aliphatic hydrocarbon group preferably has 3 to 20 carbon atoms, and more preferably 3 to 12 carbon atoms.

The cyclic aliphatic hydrocarbon group may be either a polycyclic group or a monocyclic group. As the monocyclic aliphatic hydrocarbon group, a group in which 2 hydrogen atoms have been removed from a monocycloalkane is preferable. The monocycloalkane preferably has 3 to 6 carbon atoms, and specific examples thereof include cyclopentane and cyclohexane. As the polycyclic aliphatic hydrocarbon group, a group in which two hydrogen atoms have been removed from a polycycloalkane is preferable, and the polycyclic group preferably has 7 to 12 carbon atoms. Examples of the polycycloalkane include adamantane, norbornane, isobornane, tricyclodecane and tetracyclododecane.

The cyclic aliphatic hydrocarbon group may or may not have a substituent (that is, a group or an atom other than hydrogen atom) which substitutes a hydrogen atom in the cyclic aliphatic hydrocarbon group. Examples of substituents include an alkyl group, an alkoxy group, a halogen atom, a halogenated alkyl group, a hydroxyl group and an oxo group (═O).

The alkyl group as a substituent is preferably an alkyl group of 1 to 5 carbon atoms, and a methyl group, an ethyl group, a propyl group, an n-butyl group or a tert-butyl group is most desirable.

The alkoxy group as a substituent is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom as a substituent include a fluorine atom, a chlorine atom, a bromine atom and an iodine atom, and a fluorine atom is preferable.

Examples of the halogenated alkyl group as a substituent include groups in which part or all of the hydrogen atoms within the aforementioned alkyl groups has been substituted with the aforementioned halogen atoms.

Further, part of the carbon atoms constituting the cyclic structure of the cyclic aliphatic hydrocarbon group may be substituted with a hetero atom-containing substituent group. The hetero atom-containing substituent group is preferably —O—, —C(═O)—O—, —S—, —S(═O)₂— or —S(═O)₂—O—.

The aromatic group as a divalent hydrocarbon group is a divalent hydrocarbon group having at least one aromatic ring.

The aromatic ring is not particularly limited as long as it is a cyclic conjugation ring having 4n+2 of π electrons, and may be a monocyclic or a polycyclic. The aromatic ring preferably has 5 to 30 carbon atoms, more preferably 5 to 20, still more preferably 6 to 15, and particularly preferably 6 to 12. Here, the number of carbon atoms within a substituent(s) is not included in the number of carbon atoms of the aromatic ring. Examples of the aromatic ring include aromatic hydrocarbon rings such as benzene, biphenyl, fluorene, naphthalene, anthracene and phenanthrene and aromatic heterocycles in which part of the carbon atoms of the aromatic hydrocarbon ring have been substituted with a hetero atom. Examples of hetero atoms within the aromatic heterocycle include an oxygen atom, a nitrogen atom, and a sulfur atom. Specific examples of aromatic heterocycles include a pyridine ring and a thiophene ring.

Specific examples of the aromatic group as a divalent hydrocarbon group include a group in which two hydrogen atoms have been removed from the aromatic hydrocarbon ring or aromatic heterocycle (arylene group or heteroarylene group); a group in which two hydrogen atoms have been removed from an aromatic compound (for example, biphenyl or tluorene) having two or more aromatic rings; a group in which one of hydrogen atom of the group in which one hydrogen atom has been removed from the aromatic hydrocarbon group or aromatic heterocycle (aryl group or heteroaryl group) is substituted with an alkylene group (for example, a group in which one hydrogen atom is removed from an aryl group of an arylalkyl group such as a benzyl group, a phenethyl group, a 1-naphthylmethyl group, a 2-naphthylmethyl group, a 1-naphthylethyl group, or a 2-naphthylethyl group). The alkylene group bonded to the aryl group or heteroaryl group preferably has 1 to 4 carbon atom, more preferably 1 or 2, and most preferably 1.

The aromatic group may or may not have a substituent. For example, the hydrogen atom bonded to the aromatic ring within the aromatic group may be substituted with a substituent. Examples of substituents include an alkyl group, an alkoxy group, a halogen atom, a halogenated alkyl group, a hydroxyl group and an oxo group (═O).

The alkyl group as a substituent is preferably an alkyl group of 1 to 5 carbon atoms, and a methyl group, an ethyl group, a propyl group, an n-butyl group or a tert-butyl group is most desirable.

The alkoxy group as a substituent is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom as a substituent include a fluorine atom, a chlorine atom, a bromine atom and an iodine atom, and a fluorine atom is preferable.

Examples of the halogenated alkyl group as a substituent include groups in which part or all of the hydrogen atoms within the aforementioned alkyl groups has been substituted with the aforementioned halogen atoms.

### (Divalent Linking Group Containing a Hetero Atom)

With respect to a divalent linking group containing a hetero atom, a hetero atom is an atom other than carbon and hydrogen, and examples thereof include an oxygen atom, a nitrogen atom, a sulfur atom, a halogen atom or a silicon atom.

Specific examples of the divalent linking group containing a hetero atom include non-hydrocarbon linking groups such as —O—, —C(═O)—, —C(═O)—O—, —O—C(═O)—O—, —S—, —S(═O)₂—, —S(═O)₂—O—, —NH—, —NH—C(═O)—, —NH—C(═NH)—, ═N— and —SiH₂—O—; and a combination of any one of these non-hydrocarbon linking groups with a divalent hydrocarbon group. As the divalent hydrocarbon group, the same groups as those described above for the divalent hydrocarbon group which may have a substituent can be given, and a linear or branched aliphatic hydrocarbon group is preferable.

The hydrogen atom of —NH— within —C(═O)—NH—, —NH—, —NH—C(═NH)— and —SiH₂—O— may be substituted with a substituent such as an alkyl group or an acyl group. The substituent preferably has 1 to 10 carbon atoms, more preferably 1 to 8 carbon atoms, and most preferably 1 to 5 carbon atoms.

Examples of the divalent linking group which is a combination of a non-hydrocarbon linking group and a divalent hydrocarbon group include —Y²¹—O—Y²²—, —[Y²¹—C(═O)—O]_{m′}—Y²²—, —Y²¹—O—C(═O)—Y²²— (provided that each of Y²¹ and Y²² independently a divalent hydrocarbon group which may have a substituent; O represents an oxygen atom; and m′ represents an integer of 0 to 3) and —[Y²³—O]_{n′}— (provided that Y²³ represents an alkylene group; O represents an oxygen atom; and n′ represents an integer of 1 or more).

In formulas —Y²¹—O—Y²²—, —[Y²¹—C(═O)—O]_{m′}—Y²²— and —Y²¹—O—C(═O)—Y²²—, —Y²¹ and Y²² each independently represents a divalent linking group which may have a substituent. Examples of the divalent hydrocarbon group include the same groups as those described above for the “divalent hydrocarbon group which may have a substituent”.

As Y²¹, a linear aliphatic hydrocarbon group is preferable, more preferably a linear alkylene group, still more preferably a linear alkylene group of 1 to 5 carbon atoms, and a methylene group or an ethylene group is particularly desirable.

As Y²², a linear or branched aliphatic hydrocarbon group is preferable, and a methylene group, an ethylene group or an alkylmethylene group is more preferable. The alkyl group within the alkylmethylene group is preferably a linear alkyl group of 1 to 5 carbon atoms, more preferably a linear alkyl group of 1 to 3 carbon atoms, and most preferably a methyl group.

In the group —[Y²¹—C(═O)—O]_{m′}—Y²²—, m′ represents an integer of 0 to 3, preferably an integer of 0 or 1, and particularly preferably 1. Namely, it is particularly desirable that the group represented by the formula —[Y²¹—C(═O)—O]_{m′}—Y²²— is a group represented by the formula —Y²¹—C(═O)—O—Y²²—. Among these, a group represented by formula —(CH₂)_{a′}—C(═O)—O—(CH₂)_{b′}— is preferable. In the formula, a′ is an integer of 1 to 10, preferably an integer of 1 to 8, more preferably an integer of 1 to 5, still more preferably 1 or 2, and most preferably 1. b′ is an integer of 1 to 10, preferably an integer of 1 to 8, more preferably an integer of 1 to 5, still more preferably 1 or 2, and most preferably 1.

In the group represented by the formula —[Y²³—O]_{n′}— as the alkylene group for Y²³, an alkylene group of 1 to 4 is preferable.

In the formula (I-1), as the divalent linking group for L⁰¹, a linear or branched alkylene group, a divalent aliphatic cyclic group or a divalent linking group containing a hetero atom is preferable, a linear or branched alkylene group is more preferable, and a linear alkylene group is still more preferable.

In the formula (I-2), as the organic group for R⁰², an organic group which may or may not have a fluorine atom, and an organic group having a fluorine atom is preferable. An “organic group having a fluorine atom” refers to an organic group in which part or all of the hydrogen atoms have been substituted with a fluorine atom. As the organic group, a monovalent hydrocarbon group which may have a substituent is preferable. The hydrocarbon group may be either an aliphatic hydrocarbon group or an aromatic hydrocarbon group.

The aliphatic hydrocarbon group as a monovalent hydrocarbon group may be either saturated or unsaturated. In general, the divalent aliphatic hydrocarbon group is preferably saturated.

As specific examples of the aliphatic hydrocarbon group, a linear or branched aliphatic hydrocarbon group, and an aliphatic hydrocarbon group containing a ring in the structure thereof can be given.

The linear or branched aliphatic hydrocarbon group preferably has 1 to 10 carbon atoms, more preferably 1 to 8, and still more preferably 1 to 5. As the linear or branched aliphatic hydrocarbon group, an alkyl group is preferable.

The linear or branched aliphatic hydrocarbon group may or may not have a substituent (that is, a group or an atom other than hydrogen atom) which substitutes a hydrogen atom in the linear or branched aliphatic hydrocarbon group. Examples of the substituent include a fluorine atom, a fluorinated alkyl group of 1 to 5 carbon atoms, and an oxo group (═O).

As examples of the aliphatic hydrocarbon group containing a ring in the structure thereof, a monovalent cyclic aliphatic hydrocarbon group (a group in which one hydrogen atom has been removed from an aliphatic hydrocarbon ring), and a group in which the monovalent cyclic aliphatic hydrocarbon group is bonded to the terminal of the linear or branched aliphatic hydrocarbon group or interposed within the aforementioned monovalent linear aliphatic hydrocarbon group, can be given. Examples of the monovalent linear or branched aliphatic hydrocarbon group include the same groups as described above.

The cyclic aliphatic hydrocarbon group preferably has 3 to 20 carbon atoms, and more preferably 3 to 12 carbon atoms.

The cyclic aliphatic hydrocarbon group may be either a polycyclic group or a monocyclic group. The cyclic aliphatic hydrocarbon group may be either a polycyclic group or a monocyclic group. The monocycloalkane preferably has 3 to 6 carbon atoms, and specific examples thereof include cyclopentane and cyclohexane. As the polycyclic aliphatic hydrocarbon group, a group in which one or more hydrogen atoms have been removed from a polycycloalkane is preferable, and the polycyclic group preferably has 7 to 12 carbon atoms. Examples of the polycycloalkane include adamantane, norbornane, isobornane, tricyclodecane and tetracyclododecane.

The cyclic aliphatic hydrocarbon group may or may not have a substituent (that is, a group or an atom other than hydrogen atom) which substitutes a hydrogen atom in the cyclic aliphatic hydrocarbon group. Examples of the substituent include an alkyl group of 1 to 5 carbon atoms, a fluorine atom, a fluorinated alkyl group of 1 to 5 carbon atoms, and an oxo group (═O).

Further, part of the carbon atoms constituting the cyclic structure of the cyclic aliphatic hydrocarbon group may be substituted with a hetero atom-containing substituent group. The hetero atom-containing substituent group is preferably —O—, —C(═O)—O—, —S—, —S(═O)₂— or —S(═O)₂—O—.

The aromatic hydrocarbon group as a monovalent hydrocarbon group is a monovalent hydrocarbon group having at least one aromatic ring and may have as a substituent.

The aromatic ring preferably has 5 to 30 carbon atoms, more preferably 5 to 20, still more preferably 6 to 15, and particularly preferably 6 to 12. Here, the number of carbon atoms within a substituent(s) is not included in the number of carbon atoms of the aromatic hydrocarbon group. Examples of the aromatic ring include aromatic hydrocarbon rings such as benzene, biphenyl, fluorene, naphthalene, anthracene and phenanthrene and aromatic heterocycles in which part of the carbon atoms of the aromatic hydrocarbon ring have been substituted with a hetero atom. Examples of hetero atoms within the aromatic heterocycle include an oxygen atom, a nitrogen atom, and a sulfur atom.

Specific examples of the aromatic group as a monovalent hydrocarbon group include a group in which one hydrogen atom has been removed from the aromatic hydrocarbon ring or aromatic heterocycle (aryl group or heteroaryl group); a group in which one hydrogen atom has been removed from an aromatic compound having two or more aromatic rings (for example, biphenyl or fluorene); and a group in which one hydrogen atom of the aromatic hydrocarbon ring or aromatic heterocycle has been substituted with an alkylene group (arylalkyl groups or heteroarylalkyl groups). The alkyl group in the arylalkyl group or heteroarylalkyl group preferably has 1 to 4 carbon atom, more preferably 1 or 2, and most preferably 1. Specific examples of the arylalkyl group and a heteroarylalkyl group include a benzyl group, a phenethyl group, a 1-naphthylmethyl group, a 2-naphthylmethyl group, a 1-naphthylethyl group and a 2-naphthylethyl group.

The aromatic group may or may not have a substituent. For example, the hydrogen atom bonded to the aromatic ring within the aromatic group may be substituted with a substituent. Examples of substituents include an alkyl group, an alkoxy group, a halogen atom, a halogenated alkyl group, a hydroxy group and an oxo group (═O).

The alkyl group as a substituent is preferably an alkyl group of 1 to 5 carbon atoms, and a methyl group, an ethyl group, a propyl group, an n-butyl group or a tert-butyl group is most desirable.

The alkoxy group as a substituent is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom as a substituent include a fluorine atom, a chlorine atom, a bromine atom and an iodine atom, and a fluorine atom is preferable.

Examples of the halogenated alkyl group as a substituent include groups in which part or all of the hydrogen atoms within the aforementioned alkyl groups has been substituted with the aforementioned halogen atoms.

Among these, As R⁰², a fluorinated linear or branched aliphatic hydrocarbon group is preferable, and a linear or branched fluorinated alkyl group is more preferable.

The fluorination ratio (percentage (%) of the number of fluorine atoms, base on the total number of fluorine atoms and hydrogen atoms in an unsubstituted alkyl group) is preferably at least 30%, and more preferably at least 50%. The upper limit of the fluorination ratio is not particularly limited, and may be 100%.

Examples of the divalent linking group for L⁰² in the formula (I-2) include the same divalent linking groups as those described above for L⁰¹ in the formula (I-1).

As L⁰², a linear or branched alkylene group, a divalent aliphatic cyclic group or a divalent linking group containing a hetero atom is preferable, a linear or branched alkylene group is more preferable, and a linear alkylene group is still more preferable.

In the formula (I-3), as R⁰³ and L⁰³, the same groups as those described above for R⁰² and L⁰² in the formula (I-2) can be mentioned.

In the formula (I-4), as R⁰⁴ and L⁰⁴, the same groups as those described above for R⁰² and L⁰² in the formula (I-2) can be mentioned.

With respect to the component (W), at least one atom selected from a fluorine atom or a silicon atom and a polarity conversion group that exhibits increased polarity after decomposition by the action of base may be contained in the same structural unit or different structural unit.

The structural unit constituting the component (W) is not particularly limited, and a structural unit derived from a compound containing an ethylenic double bond is preferred.

Here, the “structural unit derived from a compound containing an ethylenic double bond” refers to a structural unit in which the ethylenic double bond of the compound containing an ethylenic double bond is cleaved to form a single bond.

Examples of the compound containing an ethylenic double bond include an acrylate or ester thereof which may have the hydrogen atom bonded to the carbon atom on the α-position substituted with a substituent, an acrylamide or derivative thereof which may have the hydrogen atom bonded to the carbon atom on the α-position substituted with a substituent, a vinyl aromatic compound which may have the hydrogen atom bonded to the carbon atom on the α-position substituted with a substituent, a cycloolefine or derivative thereof, and a vinyl sulfonate ester and the like.

Among these, an acrylic acid or ester thereof which may have the hydrogen atom bonded to the carbon atom on the α-position substituted with a substituent, an acrylamide or derivative thereof which may have the hydrogen atom bonded to the carbon atom on the α-position substituted with a substituent, and a vinyl aromatic compound which may have the hydrogen atom bonded to the carbon atom on the α-position substituted with a substituent are preferable.

An “acrylate ester” refers to a compound in which the terminal hydrogen atom of the carboxy group of acrylic acid (CH₂═CH—COOH) has been substituted with an organic group.

In the present specification, an acrylic acid and acrylate ester in which the hydrogen atom bonded to the carbon atom on the α-position has been substituted with a substituent are referred to as an “α-substituted acrylic acid” and an “α-substituted acrylate ester”, respectively. Further, acrylic acid and α-substituted acrylic acid are collectively referred to as “(α-substituted) acrylic acid”, and acrylate esters and α-substituted acrylate esters are collectively referred to as “(α-substituted) acrylate ester”.

Examples of the substituent bonded to the carbon atom on the α-position of the α-substituted acrylate or ester thereof include a halogen atom, an alkyl group of 1 to 5 carbon atoms, a halogenated alkyl group of 1 to 5 carbon atoms and a hydroxyalkyl group. With respect to the structural unit derived from an acrylate ester, the α-position (the carbon atom on the α-position) refers to the carbon atom having the carbonyl group bonded thereto, unless specified otherwise.

Examples of the halogen atom as a substituent at the α-position include a fluorine atom, a chlorine atom, a bromine atom and an iodine atom.

Specific examples of the alkyl group of 1 to 5 carbon atoms as a substituent on the α-position include linear or branched alkyl groups such as a methyl group, an ethyl group, a propyl group, an isopropyl group, an n-butyl group, an isobutyl group, a tert-butyl group, a pentyl group, an isopentyl group, and a neopentyl group.

Specific examples of the halogenated alkyl group of 1 to 5 carbon atoms as a substituent on the α-position include groups in which part or all of the hydrogen atoms of the aforementioned alkyl group of 1 to 5 carbon atoms are substituted with halogen atoms. Examples of the halogen atom include a fluorine atom, a chlorine atom, a bromine atom and an iodine atom, and a fluorine atom is particularly preferred.

As the hydroxyalkyl group as a substituent on the α-position, a hydroxyalkyl group of 1 to 5 carbon atoms is preferred. Specific examples include a group in which part or all of the hydrogen atoms of the aforementioned alkyl group of 1 to 5 carbon atoms are substituted with a hydroxy group.

In the present invention, it is preferable that a hydrogen atom, an alkyl group of 1 to 5 carbon atoms or a halogenated alkyl group of 1 to 5 carbon atoms is bonded to the α-position of the (α-substituted) acrylic acid of ester thereof, a hydrogen atom, an alkyl group of 1 to 5 carbon atoms or a fluorinated alkyl group of 1 to 5 carbon atoms is more preferable, and in terms of industrial availability, a hydrogen atom or a methyl group is the most preferred.

The “organic group” refers to a group containing a carbon atom, and may include atoms other than carbon atoms (e.g., a hydrogen atom, an oxygen atom, a nitrogen atom, a sulfur atom, a halogen atom (such as a fluorine atom and a chlorine atom) and the like).

The organic group in (α-substituted) acrylate ester is not particularly limited. Examples thereof include the aforementioned aromatic group, a characteristic group such as an acid decomposable group described later and a polarity conversion group, and a characteristic group-containing group which contain a characteristic group in the structure thereof. Examples of the characteristic group-containing group include a group in which a divalent linking group is bonded to the characteristic group. Examples of the divalent linking group include the same divalent linking groups as those described for L⁰¹ in the aforementioned formula (I-1).

Examples of the “acrylamide and derivative thereof” include an acryl amide which may have the hydrogen atom bonded to the carbon atom on the α-position substituted with a substituent (hereafter, frequently referred to as (α-substituted) acrylamide) and a compound in which one or both of hydrogen atoms at the terminal of the amino group within the (α-substituted) acrylamide have been substituted with a substituent.

As the substituent which may be bonded to the carbon atom on the α-position of an acrylamide or derivatives thereof, the same substituents as those described above for the substituent to be bonded to the carbon atom on the α-position of an α-substituted acrylate ester can be mentioned.

As the substituent with which one or both of hydrogen atoms at the terminal of the amino group within (α-substituted) acrylamide is substituted, an organic group is preferable. The organic group is not particularly limited, and examples thereof include the same groups as described for the organic groups within (α-substituted) acrylate ester.

Examples of the compound in which one or both of hydrogen atom at the terminal of amino group within the (α-substituted) acrylamide have been substituted with a substituent include a compound in which —C(═O)—O— bonded to carbon atom on the α-position of the (α-substituted) acrylate ester is replaced by —C(═O)—N(R^{b})— [in the formula, R^{b} represents a hydrogen atom or an alkyl group of 1 to 5 carbon atoms].

In the formula, the alkyl group for R^{b} is preferably a linear or branched alkyl group.

The “vinyl aromatic compound” is a compound having an aromatic ring and one vinyl group bonded to the aromatic ring, and as the examples thereof, a stylene or derivative thereof and a vinylnaphthalene and derivative thereof can be mentioned.

As the substituent which may be bonded to the carbon atom (that is, the carbon atom of the vinyl group, which is bonded to the aromatic ring) on the α-position of a vinyl aromatic compound, the same substituents as those described above for the substituent to be bonded to the carbon atom on the α-position of an α-substituted acrylate ester can be mentioned.

Hereafter, a vinyl aromatic compound in which the hydrogen atom bonded to the carbon atom on the α-position has been substituted with a substituent is frequently referred to as an (α-substituted) vinyl aromatic compound.

Examples of the “styrene and derivative thereof” include a styrene which may have the hydrogen atom bonded to the carbon atom on the α-position substituted with a substituent and may have the hydrogen atom bonded to the benzene ring substituted with a substituent other than the hydroxy group (hereafter, frequently referred to as (α-substituted)styrene), a hydroxystyrene which may have the hydrogen atom bonded to the carbon atom on the α-position substituted with a substituent and may have a hydrogen atom bonded to the benzene ring substituted with a substituent other than a hydroxy group (hereafter, frequently referred to as (α-substituted)hydroxystyrene), a compound in which a hydrogen atom of hydroxy group of (α-substituted)hydroxystyrene is substituted with an organic group, a vinylbenzoic acid which may have the hydrogen atom bonded to the carbon atom on the α-position substituted with a substituent and may have a hydrogen atom bonded to the benzene ring substituted with a substituent other than a hydroxy group or carboxy group (hereafter, frequently referred to as (α-substituted)vinylbenzoic acid), and a compound in which a hydrogen atom of carboxy group of (α-substituted)vinylbenzoic acid is substituted with an organic group.

A hydroxystyrene is a compound which has one vinyl group and at least one hydroxy group bonded to a benzene ring. The number of hydroxy groups bonded to the benzene ring is preferably 1 to 3, and most preferably 1. The bonding position of the hydroxy group on the benzene ring is not particularly limited. When the number of the hydroxy group is 1, para (4th) position against the bonding position of the vinyl group is preferable. When the number of the hydroxy groups is an integer of 2 or more, an arbitrary combination of the bonding positions can be adopted.

The vinylbenzoic acid is a compound in which one vinyl group is bonded to the benzene ring within the benzoic acid.

The bonding position of the vinyl group on the benzene ring is not particularly limited.

The substituent other than a hydroxy group or carboxy group which may be bonded to the benzene ring of an styrene or derivative thereof is not particularly limited, and examples thereof include a halogen atom, an alkyl group of 1 to 5 carbon atoms and a halogenated alkyl group of 1 to 5 carbon atoms. Examples of the halogen atom include a fluorine atom, a chlorine atom, a bromine atom and an iodine atom, and a fluorine atom is particularly preferred.

The organic group within a compound in which the hydrogen atom of the hydroxy group within the (α-substituted) hydroxystyrene is substituted with an organic group is not particularly limited, and examples thereof include the same groups as described for the organic groups within (α-substituted) acrylate ester.

The organic group within a compound in which the hydrogen atom of the carboxy group within the (α-substituted) vinylbenzoic acid is substituted with an organic group is not particularly limited, and examples thereof include the same organic groups as those described for the organic group within (α-substituted) acrylate ester.

Examples of the “vinylnaphthalene and derivative thereof” include a vinylnaphthalene which may have the hydrogen atom bonded to the carbon atom on the α-position substituted with a substituent and may have the hydrogen atom bonded to the naphthalene ring substituted with a substituent other than the hydroxy group (hereafter, frequently referred to as (α-substituted) vinyl naphthalene), a vinyl (hydroxynaphthalene) which may have the hydrogen atom bonded to the carbon atom on the α-position substituted with a substituent and may have a hydrogen atom bonded to the naphthalene ring substituted with a substituent other than a hydroxy group (hereafter, frequently referred to as (α-substituted) vinyl(hydroxynaphthalene) and a compound in which a hydrogen atom of hydroxy group within (α-substituted) vinyl(hydroxynaphthalene) is substituted with a substituent.

A vinyl(hydroxynaphthalene) is a compound which has one vinyl group and at least one hydroxy group bonded to a naphthalene ring. The vinyl group may be bonded to the 1st or 2nd position of the naphthalene ring. The number of hydroxy groups bonded to the naphthalene ring is preferably 1 to 3, and particularly preferably 1. The bonding position of the hydroxy group on the naphthalene ring is not particularly limited. When the vinyl group is bonded to the 1st or 2nd position of the naphthalene ring, the hydroxy group is preferably bonded to either one of the 5th to 8th position of the naphthalene ring. In particular, when the number of hydroxy group is 1, the hydroxy group is preferably bonded to either one of the 5th to 7th position of the naphthalene ring, and more preferably the 5th or 6th position. When the number of the hydroxy groups is an integer of 2 or more, an arbitrary combination of the bonding positions can be adopted.

As the substituent which may be bonded to the naphthanlene ring of the vinylnaphthalene or derivative thereof, the same substituents as those described above for the substituent which may be bonded to the benzene ring of the (α-substituted) styrene can be mentioned.

The organic group within a compound in which the hydrogen atom of the hydroxy group within the (α-substituted) vinyl(hydroxynaphthalene) is substituted with an organic group is not particularly limited, and examples thereof include the same organic groups as those described for the organic group within (α-substituted) acrylate ester.

Specific examples of the structural unit derived from the (α-substituted) acrylic acid or ester thereof include a structural unit represented by the general formula (U-1) shown below.

Specific examples of the structural unit derived from the (α-substituted) acrylamide or derivative thereof include a structural unit represented by the general formula (U-2) shown below.

With respect to the (α-substituted) vinylaromatic compound, specific examples of the structural unit derived from the (α-substituted) styrene or derivative thereof include a structural unit represented by the general formula (U-3) shown below. Specific examples of the structural unit derived from the (α-substituted) vinylnaphthalene or derivative thereof include a structural unit represented by the general formula (U-4) shown below.

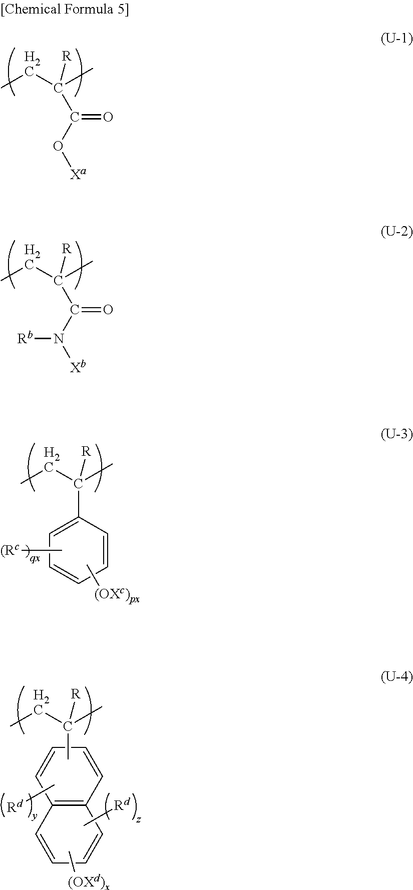

In the formulas, R represents a hydrogen atom, an alkyl group of 1 to 5 carbon atoms or a halogenated alkyl group of 1 to 5 carbon atoms; X^{a} to X^{d} each independently represents a hydrogen atom or an organic group; R^{b} represents a hydrogen atom or an alkyl group of 1 to 5 carbon atoms; R^{c} and R^{d} each independently represents a halogen atom, —COOX^{e} (wherein, X^{e} represents a hydrogen atom or an organic group), an alkyl group of 1 to 5 carbon atoms or a halogenated alkyl group of 1 to 5 carbon atoms; px represents an integer of 0 to 3, and qx represents an integer of 0 to 5, provided that px+qx=0 to 5; and when qx is an integer of 2 or more, the plurality of R^{c} group may be the same or different from each other; and x represents an integer of 0 to 3; y represents an integer of 0 to 3; and z represents an integer of 0 to 4, with the provision that x+y+z=0 to 7, provided that when y+z is an integer of 2 or more, the plurality of R^{d} group may be the same or different from each other.

The component (W) contains a structural unit having at least one atom selected from a fluorine atom or a silicon atom (hereafter, referred to as structural unit (w0)).

The structural unit (w0) is not particularly limited as long as it has a fluorine atom or a silicon atom, a structural unit derived from a compound containing an ethylenic double bond is preferable, and a structural unit represented by general formula (w-0) shown below is preferable.

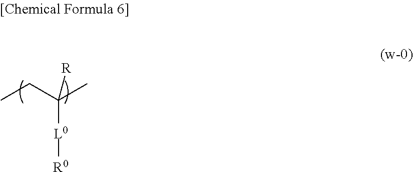

In the formula, R represents a hydrogen atom, an alkyl group of 1 to 5 carbon atoms or a halogenated alkyl group of 1 to 5 carbon atoms; L⁰ represents a single bond or a divalent linking group which may have a fluorine atom or a silicon atom; R⁰ a monovalent organic group which may have a fluorine atom or a silicon atom, provided that at least one of L⁰ and R⁰ has a fluorine atom or a silicon atom.

In the formula (w-0), the alkyl group and the halogenated alkyl group for R are the same as defined for the alkyl group and the halogenated alkyl group for the substituent which may be bonded to the carbon atom on the α-position of the aforementioned substituted acrylic acid or ester thereof.

Examples of the divalent linking group for L⁰ include the same divalent linking groups as those described above for L⁰¹ in the formula (I-1). Among these, —C(═O)—O-L¹⁰, —C(═O)—N(R^{N})-L¹⁰- or R^{ar}-L¹⁰- is preferable.

L¹⁰ represents a single bond or a divalent linking group. Examples of the divalent linking group include the same divalent linking groups as those described above for L⁰¹ in the formula (I-1).

R^{N} is a hydrogen atom or an alkyl group of 1 to 5 carbon atoms. Further, the alkyl group is preferably a linear alkyl group or a branched alkyl group. As R^{N}, a hydrogen atom or a methyl group is particularly preferable.

R^{ar} is a divalent aromatic group which may have a substituent. Examples of the divalent linking group include the same aromatic groups described as divalent hydrocarbon groups in the explanation of the divalent linking groups for L⁰¹ in the formula (I-1). Among these, a phenylene group which may have a substituent or a naphthylene group which may have a substituent is preferable.

The organic groups for R⁰ is not particularly limited, and any of known organic groups containing a characteristic group can be selected depending on the predetermined properties of the component (W). Examples thereof include characteristic groups (e.g., base decomposable polarity conversion group, acid decomposable group, polar group-containing hydrocarbon group) contained in the structural units (w1) to (w6) at the side chain thereof.

As the structural unit constituting the component (W), specific examples include the structural units (w1) to (w5) described below.

Structural unit (w1): a fluorine-containing structural unit having a base decomposable polarity conversion group.

Structural unit (w2): a structural unit having an acid decomposable group that exhibits increased polarity after decomposition by the action of acid.

Structural unit (w3): a structural unit having a polar group.

Structural unit (w4): a fluorine-containing structural unit having a ring structure, and which does not fall under the definition of the structural units (w1) to (w3).

Structural unit (w5): a silicone-containing structural unit having an organic group containing a trialkylsiliy group or a siloxane bond (Si—O—Si).

[Structural Unit (w1)]

The base decomposable polarity conversion group in the structural unit (w1) is the same as those described above.

As the structural unit (w1), a structural unit in which R⁰ in the general formula (w-0) represents a base decomposable polarity conversion group can be mentioned, and as a preferable example, a structural unit represented by general formula (w1-10) or (w1-20) shown below can be mentioned.

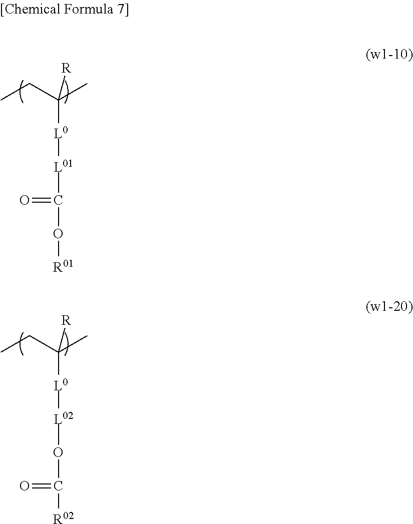

In the formula (w1-10), R, L⁰, L⁰¹ and R⁰¹ are the same as defined above, provided that at least one of L⁰, L⁰¹ and R⁰¹ has a fluorine atom; in the formula (w1-20), R, L⁰, L⁰² and R⁰² are the same as defined above, provided that at least one of L⁰, L⁰² and R⁰² has a fluorine atom.

In the formulas, each of R and L⁰ is the same as defined above for R and L⁰ in the formula (w-0).

Each of L⁰¹ and R⁰¹ is the same as defined above for L⁰¹ and R⁰¹ in the formula

Each of L⁰² and R⁰² is the same as defined above for L⁰² and R⁰² in the formula (I-2).

Preferable examples of the structural units represented by general formula (w1-10) or (w1-20) include structural units represented by general formulas (w1-11) to (w1-15), and (w1-21) to (w1-25) shown below.

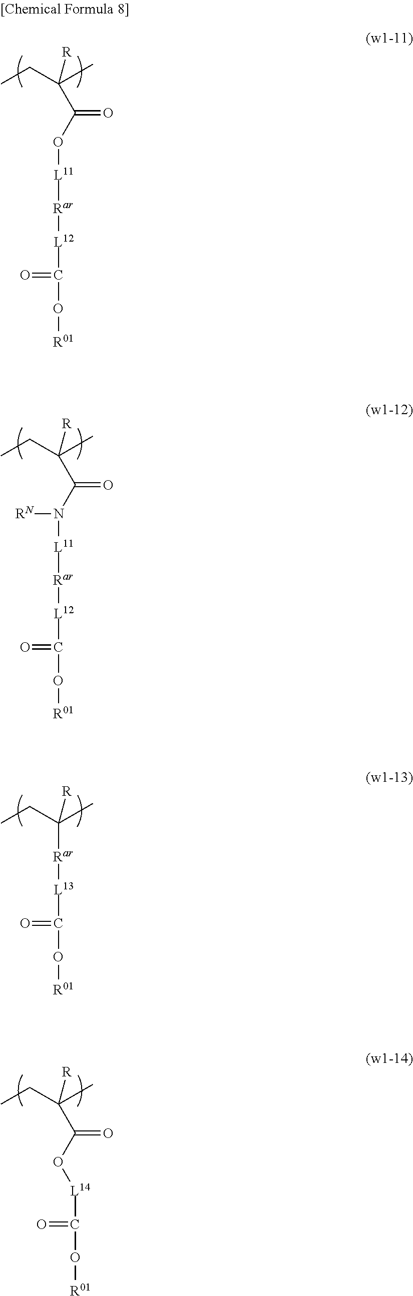

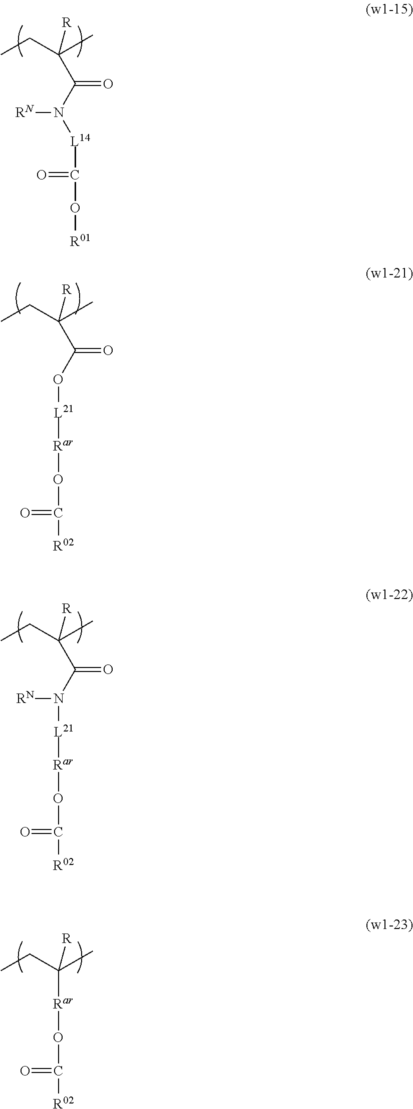

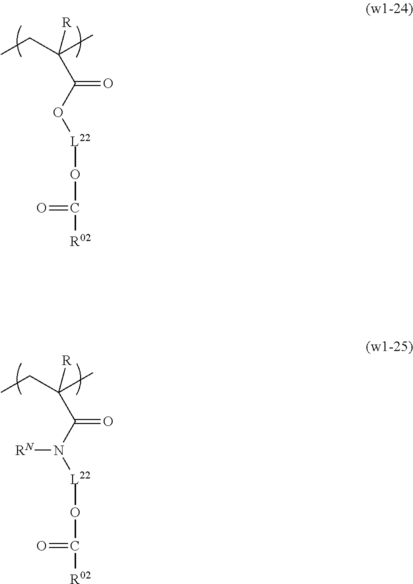

In the formulas (w1-11) and (w1-12), R and R⁰¹ are the same as defined above; L¹¹ is a single bond or a divalent linking group; R^{ar} represents a divalent aromatic group which may have a substituent; L¹² represents a single bond or a divalent linking group; and R^{N} represents a hydrogen atom or an alkyl group of 1 to 5 carbon atoms, provided that at least one of L¹¹, R^{ar}, L¹² and R⁰¹ has a fluorine atom;

in the formula (w1-13), R, R^{ar} and R⁰¹ are the same as defined above; L¹³ represents a single bond or a divalent linking group, provided that at least one of R^{ar}, L¹³ and R⁰¹ has a fluorine atom;

in the formulas (w1-14) and (w1-15), R, R⁰¹ and R^{N} are the same as defined above; L¹⁴ represents a divalent linking group having no aromatic group, provided that at least one of L¹⁴ and R⁰¹ has a fluorine atom;

in the formulas (w1-21) and (w1-22), R, R^{ar}, R⁰² and R^{N} are the same as defined above; L²¹ represents a single bond or a divalent linking group, provided that at least one of L²¹, R^{ar} and R⁰² has a fluorine atom;

in the formula (w1-23), R, R^{ar} and R⁰² are the same as defined above, provided that at least one of R^{ar} and R⁰² has a fluorine atom; and

in the formulas (w1-24) and (w1-25), R, R⁰² and R^{N} are the same as defined above; L²² represents a divalent linking group having no aromatic group, provided that at least one of L²² and R⁰² has a fluorine atom.

In the formulas, R is the same as defined above for R in the formula (w-0).

R⁰¹ is the same as defined above for R⁰¹ in the general formula (I-1) in relation to the base decomposable polarity conversion group, and R⁰² is the same as defined above for R⁰² in the general formula (I-2).

R⁰¹ is the same as defined above for R^{ar} in the group —R^{ar}-L¹⁰- in relation to the divalent linking group for L⁰¹ in the formula (I-1).

R^{N} is the same as defined above for R^{N} in the group —C(═O)—N(R^{N})-L¹⁰- in relation to the divalent linking group for R^{N} in the formula (I-1).

Examples of the divalent linking group for L¹¹ and L²¹ include the same divalent linking groups as those described above for L⁰¹ in the formula (I-1). Among these, a linear or branched alkylene group is preferable, and a linear alkylene group is more preferable. In particular, a methylene group is particularly preferable.

Examples of the divalent linking group for L¹² and L¹³ include the same divalent linking groups as those described above for L⁰¹ in the formula (I-1). Among these, groups containing an ether bond or an ester bond is preferable, —O—(CH₂)ₐ₁, —O—C(═O)—(CH₂)ₐ₁, —(CH₂)ₐ₂—O—(CH₂)ₐ₁— or —(CH₂)ₐ₂—O—C(═O)—(CH₂)ₐ₁— is more preferable, and —O—(CH₂)ₐ₁— is particularly preferable. In the formulas, a1 represents an integer of 1 to 5, and a2 represents an integer of 1 to 5.

Examples of the divalent linking group for L¹⁴ and L²² include the same divalent linking groups (provided that divalent linking group having an aromatic group is excluded) as those described above for L⁰¹ in the formula (I-1). Among these, a linear or branched alkylene group which may have a fluorine atom, a divalent aliphatic cyclic group or a divalent linking group containing a hetero atom is preferable, and a linear or branched alkylene group which may have a fluorine atom is more preferable. In particular, a linear alkylene group or a branched alkylene group in which a fluorine atom or a fluorinated alkyl group has been bonded to the carbon atom adjacent to a carbonyl group is preferable, and —CH₂—, —CH₂—CH₂—, —CH(CH₃)—CF₂—, —CH(CH₂CH₃)—CF₂— or —CH(CH₂CH₃)—CF(CH₃)—is particularly preferable.

Among the aforementioned examples, as the structural unit (w1), a structural unit represented by the general formula (w1-11), (w1-12), (w1-14), (w1-15) or (w1-23) is preferable.

Specific examples of the structural unit are shown below. in the formula, RP represents a hydrogen atom or a methyl group.

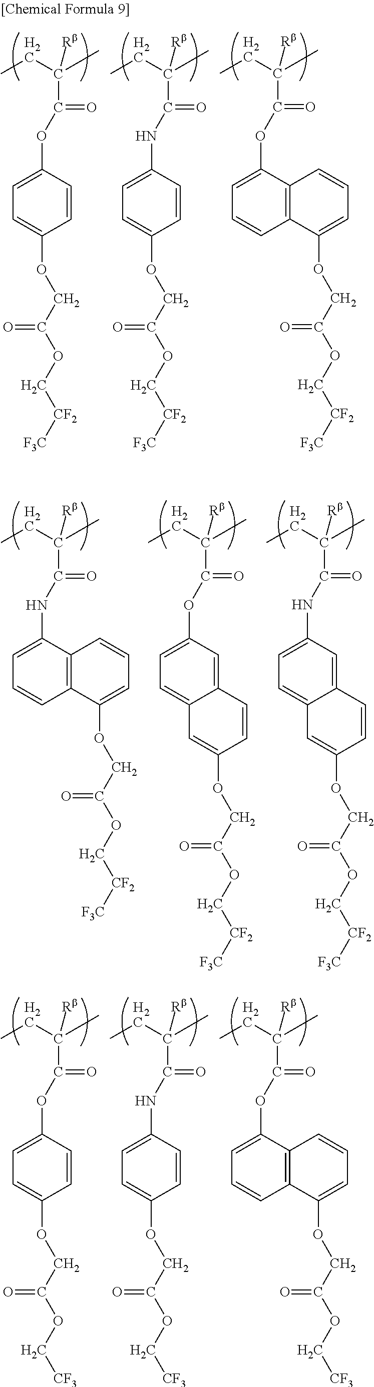

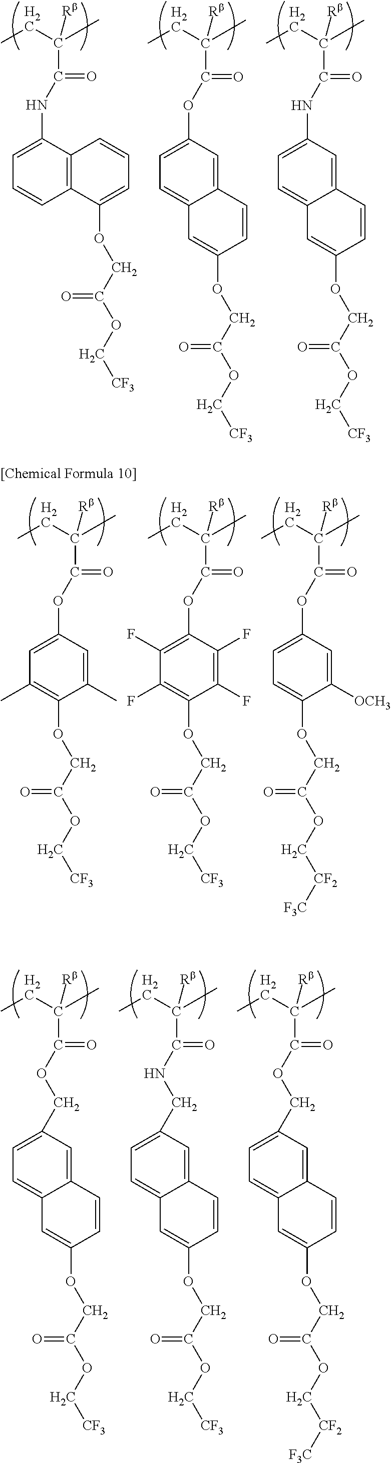

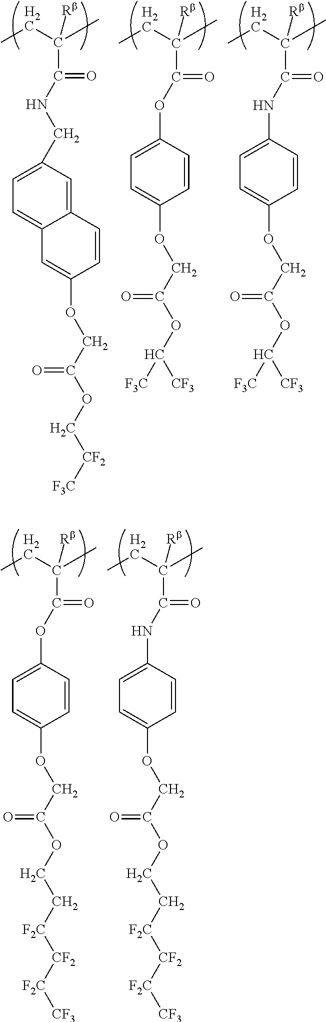

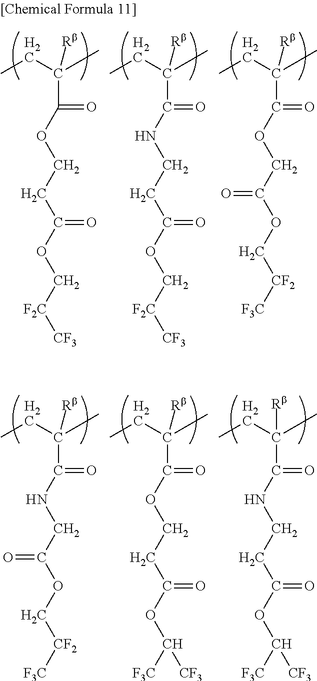

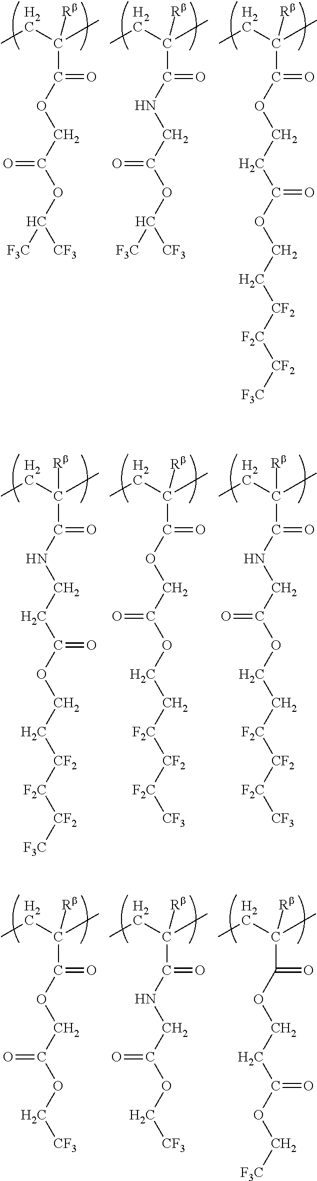

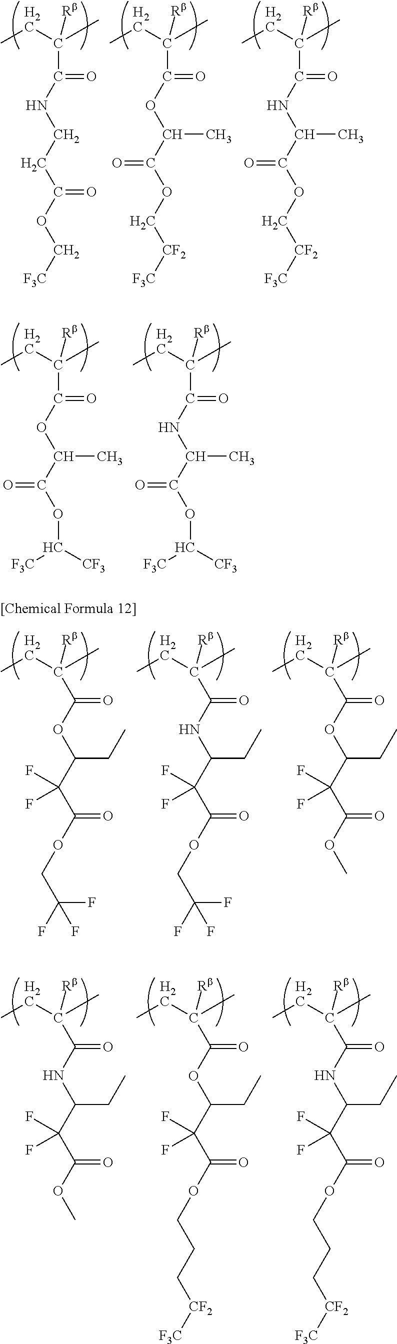

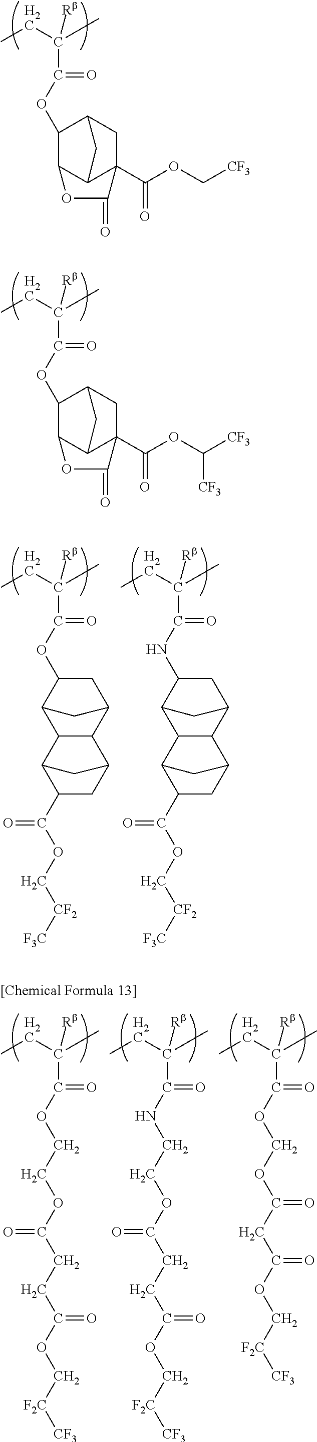

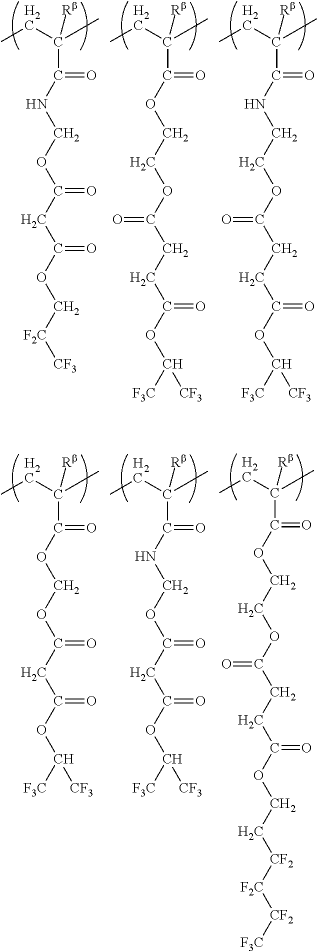

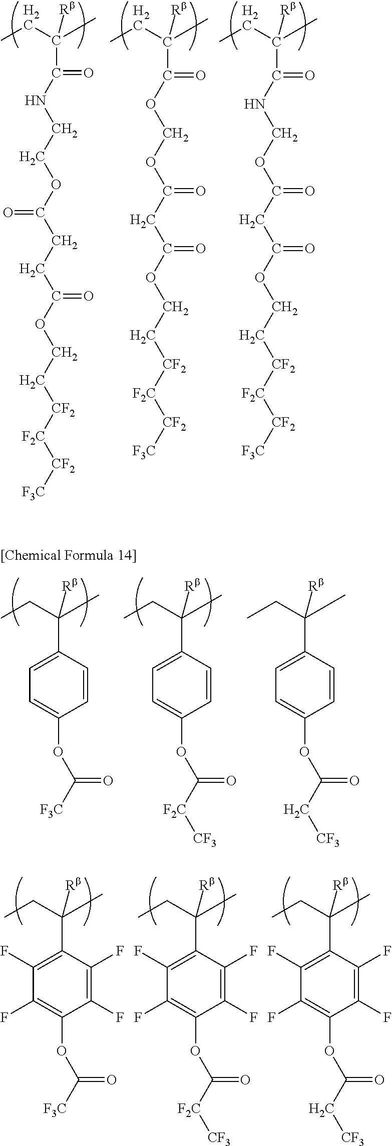

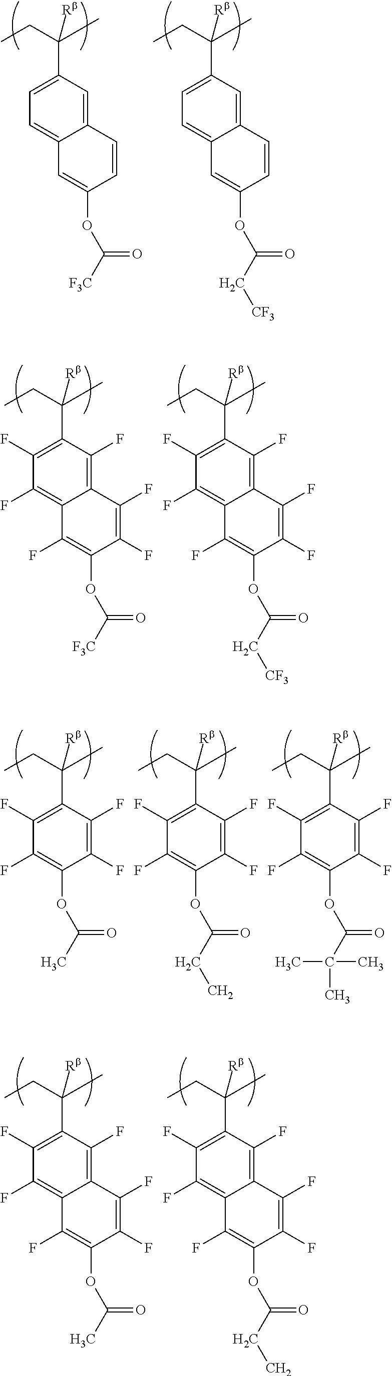

When the component (W) includes the structural unit (w1), as the structural unit (w1) in the component (W), one type of structural unit may be used, or two or more structural units may be used.

In the component (W), the amount of the structural unit (w1) relative to the combined total of all structural units constituting the component (W) is preferably 40 to 90 mol %, more preferably 50 to 85 mol %, and still more preferably 50 to 80 mol %. When the amount of the structural unit (w1) is at least as large as the lower limit of the above-mentioned range, surface segregation effect can be enhanced, solubility in an alkali developing solution can be improved, and lithography properties can be improved. On the other hand, when the amount of the structural unit (w1) is no more than the upper limit of the above-mentioned range, a good balance can be achieved with the other structural units.

[Structural Unit (w2)]

The structural unit (w2) is a structural unit having an acid decomposable group (polarity conversion group having acid decomposability) that exhibits increased polarity after decomposition by the action of acid.

The term “acid decomposable group” refers to a group in which at least a part of the bond within the structure thereof is cleaved by the action of acid generated from the component (A) and the component (B) which is appropriately added upon exposure.

Examples of acid decomposable groups which exhibit increased polarity by the action of an acid include groups which are decomposed by the action of acid to form a polar group.

Examples of the polar group constituting an acid decomposable group include a carboxy group, a hydroxy group, an amino group and a sulfo group (—SO₃H). Among these, a carboxy group and a hydroxy group are preferable, and a carboxy group is particularly desirable.

Specific examples of an acid decomposable group include a group in which the aforementioned polar group has been protected with an acid dissociable group (e.g., a group in which the hydrogen atom of the polar group has been protected with an acid dissociable group) can be given.

An “acid dissociable group” is a group in which at least the bond between the acid dissociable group and the atom adjacent to the acid dissociable group is cleaved by the action of acid generated from the component (A) or the component (B) which is appropriately added upon exposure. It is necessary that the acid dissociable group that constitutes the acid decomposable group is a group which exhibits a lower polarity than the polar group generated by dissociation of the acid dissociable group. Thus, when the acid dissociable group is dissociated by the action of acid, a polar group exhibiting a higher polarity than the acid dissociable group is generated, thereby increasing the polarity of the component (W).

By increasing the polarity of the component (W) during exposure, in the case of applying an alkali developing process, the solubility of exposed portions in an alkali developing solution is increased.

The acid dissociable group is not particularly limited, and any of the groups that have been conventionally proposed as acid dissociable groups for the base resins of chemically amplified resists can be used. Generally, groups that form either a cyclic or chain-like tertiary alkyl ester with the carboxyl group of the (meth)acrylic acid, and acetal-type acid dissociable groups such as alkoxyalkyl groups are widely known.

Here, a tertiary alkyl ester describes a structure in which an ester is formed by substituting the hydrogen atom of a carboxyl group with a chain-like or cyclic tertiary alkyl group, and a tertiary carbon atom within the chain-like or cyclic tertiary alkyl group is bonded to the oxygen atom at the terminal of the carbonyloxy group (—C(═O)—O—). In this tertiary alkyl ester, the action of acid causes cleavage of the bond between the oxygen atom and the tertiary carbon atom, thereby forming a carboxy group.

The chain-like or cyclic alkyl group may have a substituent.

Hereafter, for the sake of simplicity, groups that exhibit acid dissociability as a result of the formation of a tertiary alkyl ester with a carboxyl group are referred to as “tertiary alkyl ester-type acid dissociable groups”.

Examples of tertiary alkyl ester-type acid dissociable groups include aliphatic branched, acid dissociable groups and aliphatic cyclic group-containing acid dissociable groups.

The term “aliphatic branched” refers to a branched structure having no aromaticity. The “aliphatic branched, acid dissociable group” is not limited to be constituted of only carbon atoms and hydrogen atoms (not limited to hydrocarbon groups), but is preferably a hydrocarbon group. Further, the “hydrocarbon group” may be either saturated or unsaturated, but is preferably saturated.

As an example of the aliphatic branched, acid dissociable group, for example, a group represented by the formula —C(R⁷¹)(R⁷²)(R⁷³) can be given. In the formula, each of R⁷¹ to R⁷³ independently represents a linear alkyl group of 1 to 5 carbon atoms. The group represented by the formula —C(R⁷¹)(R⁷²)(R⁷³) preferably has 4 to 8 carbon atoms, and specific examples include a tert-butyl group, a 2-methyl-2-butyl group, a 2-methyl-2-pentyl group and a 3-methyl-3-pentyl group.

Among these, a tert-butyl group is particularly desirable.

An aliphatic branched, acid dissociable group in the structural unit (w2) may have part of the hydrogen atom substituted with a fluorine atom. In such a case, in the group represented by —C(R⁷¹)(R⁷²)(R⁷³), it is preferable that at least one of R⁷¹, R⁷² and R⁷³ represents a fluorinated alkyl group, and the remaining two of them are alkyl groups. As the fluorine alkyl group, a group represented by —(CH₂)_{w}—CF₃ is preferable. w represents an integer of 0 to 3.

The term “aliphatic cyclic group” refers to a monocyclic group or polycyclic group that has no aromaticity.

In the “aliphatic cyclic group-containing acid dissociable group”, the “aliphatic cyclic group” may or may not have a substituent. Examples of the substituent include an alkyl group of 1 to 5 carbon atoms, an alkoxyl group of 1 to 5 carbon atoms, a fluorine atom, a fluorinated alkyl group of 1 to 5 carbon atoms, and an oxygen atom (═O).

The basic ring of the “aliphatic cyclic group” exclusive of substituents is not limited to a structure consisting of a carbon atom and a hydrogen atom (not limited to hydrocarbon groups), but is preferably a hydrocarbon group. Further, the “hydrocarbon group” may be either saturated or unsaturated, but is preferably saturated.

The aliphatic cyclic group may be either a monocyclic group or a polycyclic group.

The aliphatic cyclic group preferably has 3 to 30 carbon atoms, more preferably 5 to 30, still more preferably 5 to 20, particularly preferably 6 to 15, and most preferably 6 to 12. As the monocyclic aliphatic cyclic group, a group in which one or more hydrogen atoms have been removed from a monocycloalkane is preferable. The monocycloalkane preferably has 3 to 6 carbon atoms, and specific examples thereof include cyclobutane, cyclopentane and cyclohexane. As the polycyclic aliphatic cyclic group, a group in which one or more hydrogen atoms have been removed from a polycycloalkane is preferable, and the polycyclic group preferably has 7 to 12 carbon atoms. Examples of the polycycloalkane include adamantane, norbornane, isobornane, tricyclodecane and tetracyclododecane. In these aliphatic cyclic groups, part of the carbon atoms constituting the ring may be replaced with an ethereal oxygen atom (—O—).

Examples of aliphatic cyclic group-containing acid dissociable groups include

(i) a monovalent aliphatic cyclic group in which a substituent (a group or an atom other than hydrogen) is bonded to the carbon atom on the ring skeleton to which an atom adjacent to the acid dissociable group (e.g., “—O—” within “—C(═O)—O— group”) is bonded to form a tertiary carbon atom; and

(ii) a group which has a branched alkylene group containing a tertiary carbon atom, and a monovalent aliphatic cyclic group to which the tertiary carbon atom is bonded.

In the group (i), as the substituent bonded to the carbon atom to which an atom adjacent to the acid dissociable group on the ring skeleton of the aliphatic cyclic group is bonded, an alkyl group can be mentioned. Examples of the alkyl group include the same groups as those represented by R¹⁴ in formulas (1-1) to (1-9) described later.

Specific examples of the group (i) include groups represented by general formulas (1-1) to (1-9) shown below.

Specific examples of the group (ii) include groups represented by general formulas (2-1) to (2-6) shown below.

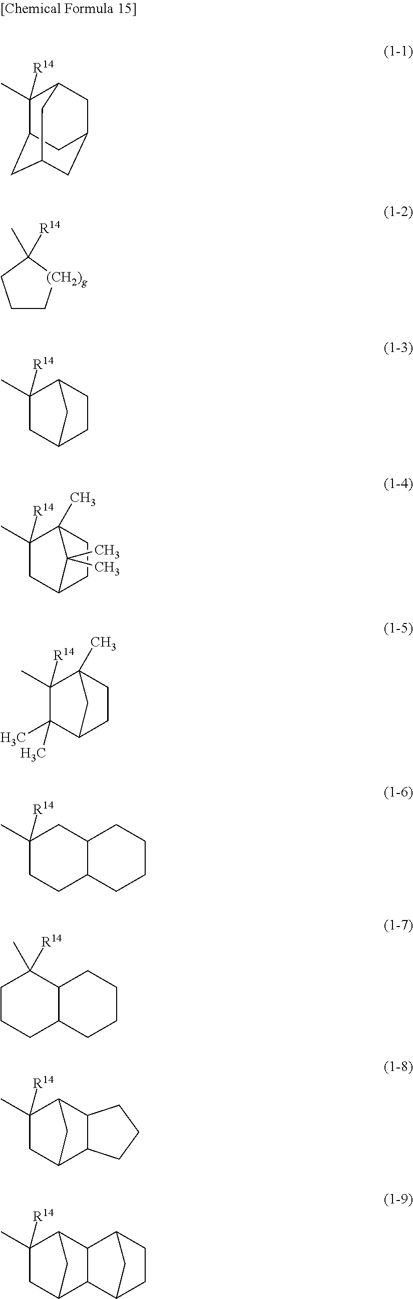

In the formulas above, R¹⁴ represents an alkyl group; and g represents an integer of 0 to 8.

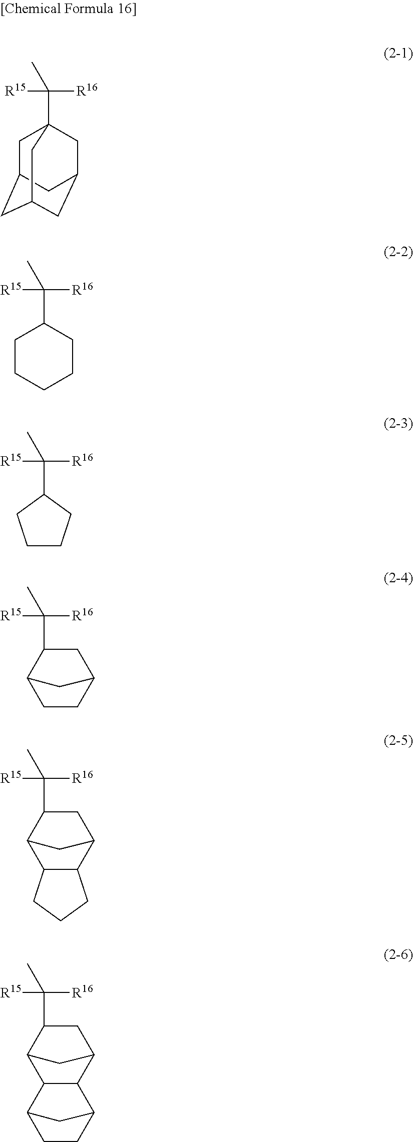

In the formulas above, each of R¹⁵ and R¹⁶ independently represents an alkyl group.

In formulas (1-1) to (1-9), the alkyl group for R¹⁴ may be linear, branched or cyclic, and is preferably linear or branched.

The linear alkyl group preferably has 1 to 5 carbon atoms, more preferably 1 to 4, and still more preferably 1 or 2. Specific examples include a methyl group, an ethyl group, an n-propyl group, an n-butyl group and an n-pentyl group. Among these, a methyl group, an ethyl group or an n-butyl group is preferable, and a methyl group or an ethyl group is more preferable.

The branched alkyl group preferably has 3 to 10 carbon atoms, and more preferably 3 to 5. Specific examples of such branched alkyl groups include an isopropyl group, an isobutyl group, a tert-butyl group, an isopentyl group and a neopentyl group, and an isopropyl group is most desirable.

g is preferably an integer of 0 to 3, more preferably 1 to 3, and still more preferably 1 or 2.

In formulas (2-1) to (2-6), as the alkyl group for R¹⁵ and R¹⁶, the same alkyl groups as those for R¹⁴ can be used.

In formulas (1-1) to (1-9) and (2-1) to (2-6), part of the carbon atoms constituting the ring may be replaced with an ethereal oxygen atom (—O—).

Further, in formulas (1-1) to (1-9) and (2-1) to (2-6), one or more of the hydrogen atoms bonded to the carbon atoms constituting the ring may be substituted with a substituent. Examples of the substituent include an alkyl group of 1 to 5 carbon atoms, a fluorine atom and a fluorinated alkyl group.

An “acetal-type acid dissociable group” generally substitutes a hydrogen atom at the terminal of an OH-containing polar group such as a carboxy group or hydroxy group, so as to be bonded with an oxygen atom. When acid is generated upon exposure, the generated acid acts to break the bond between the acetal-type acid dissociable group and the oxygen atom to which the acetal-type, acid dissociable group is bonded, thereby forming an OH-containing polar group such as a carboxy group or a hydroxy group.

Examples of acetal-type acid dissociable groups include groups represented by general formula (p1) shown below.

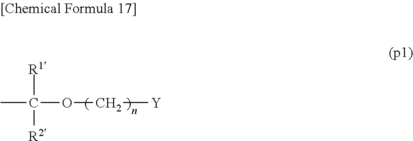

In the formula, R¹′ and R²′ each independently represent a hydrogen atom or an alkyl group of 1 to 5 carbon atoms; n represents an integer of 0 to 3; and Y represents an alkyl group of 1 to 5 carbon atoms or an aliphatic cyclic group.

In general formula (p1), n is preferably an integer of 0 to 2, more preferably 0 or 1, and most preferably 0.

As the alkyl group for R¹′ and R²′, the same alkyl groups as those described above the alkyl groups as the substituent on the α-position of the aforementioned alkylester can be used, although a methyl group or ethyl group is preferable, and a methyl group is particularly desirable.

In the present invention, it is preferable that at least one of R¹′ and R²′ be a hydrogen atom. That is, it is preferable that the acid dissociable group (p1) is a group represented by general formula (p1-1) shown below.

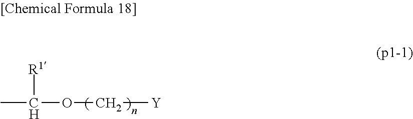

In the formula, R¹′, n and Y are the same as defined above.

As the alkyl group for Y, the same alkyl groups as those described above for the substituent which may be bonded to the carbon atom on the α-position of the aforementioned α-substituted acrylate ester can be mentioned.

As the aliphatic cyclic group for Y, any of the aliphatic monocyclic/polycyclic groups which have been proposed for conventional ArF resists and the like can be appropriately selected for use. For example, the same aliphatic cyclic groups described above in connection with the “acid dissociable group containing an aliphatic cyclic group” can be used.

Further, as the acetal-type, acid dissociable group, groups represented by general formula (p2) shown below can also be used.

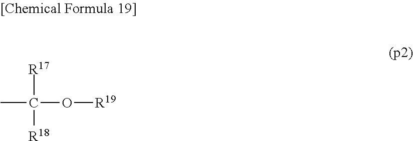

In the formula, R¹⁷ and R¹⁸ each independently represent a linear or branched alkyl group or a hydrogen atom; and R¹⁹ represents a linear, branched or cyclic alkyl group; or R¹⁷ and R¹⁹ each independently represents a linear or branched alkylene group, and the R¹⁷ group may be bonded to the R¹⁹ group to form a ring.

The alkyl group for R¹⁷ and R¹⁸ preferably has 1 to 15 carbon atoms, and may be either linear or branched. As the alkyl group, an ethyl group or a methyl group is preferable, and a methyl group is most preferable.

It is particularly desirable that either one of R¹⁷ and R¹⁸ be a hydrogen atom, and the other be a methyl group.

R¹⁹ represents a linear, branched or cyclic alkyl group which preferably has 1 to 15 carbon atoms, and may be any of linear, branched or cyclic.

When R¹⁹ represents a linear or branched alkyl group, it is preferably an alkyl group of 1 to 5 carbon atoms, more preferably an ethyl group or methyl group, and most preferably an ethyl group.

When R¹⁹ represents a cycloalkyl group, it preferably has 4 to 15 carbon atoms, more preferably 4 to 12 carbon atoms, and most preferably 5 to 10 carbon atoms. As examples of the cycloalkyl group, the same aliphatic cyclic group as those described above, such as groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Among these, a group in which one or more hydrogen atoms have been removed from adamantane is preferable.

In general formula (p2) above, R¹⁷ and R¹⁹ may each independently represent a linear or branched alkylene group (preferably an alkylene group of 1 to 5 carbon atoms), and the R¹⁹ group may be bonded to the R¹⁷ group.

In such a case, a cyclic group is formed by R¹⁷, R¹⁹, the oxygen atom having R¹⁹ bonded thereto, and the carbon atom having the oxygen atom and R¹⁷ bonded thereto. Such a cyclic group is preferably a 4 to 7-membered ring, and more preferably a 4 to 6-membered ring. Specific examples of the cyclic group include tetrahydropyranyl group and tetrahydrofuranyl group.

As the structural unit (w2), the same structural unit as those described later for the structural unit (a1) can be mentioned. The structural unit (w2) may or may not have a fluorine atom or a silicon atom. Examples of the structural unit (w2) having a fluorine atom or a silicon atom include a structural unit represented by formula (w-0) in which R⁰ represents an acid decomposable group, and in particular, a structural unit represented by formula (w-0) in which L⁰¹ represents —C(═O)—O-L¹⁰-, —C(═O)—N(R^{N})-L¹⁰- or —R^{ar}-L₁₀- is preferable.

Specific examples of the structural unit (w2) include structural units represented by general formulas (w2-11) to (w2-15) shown below.

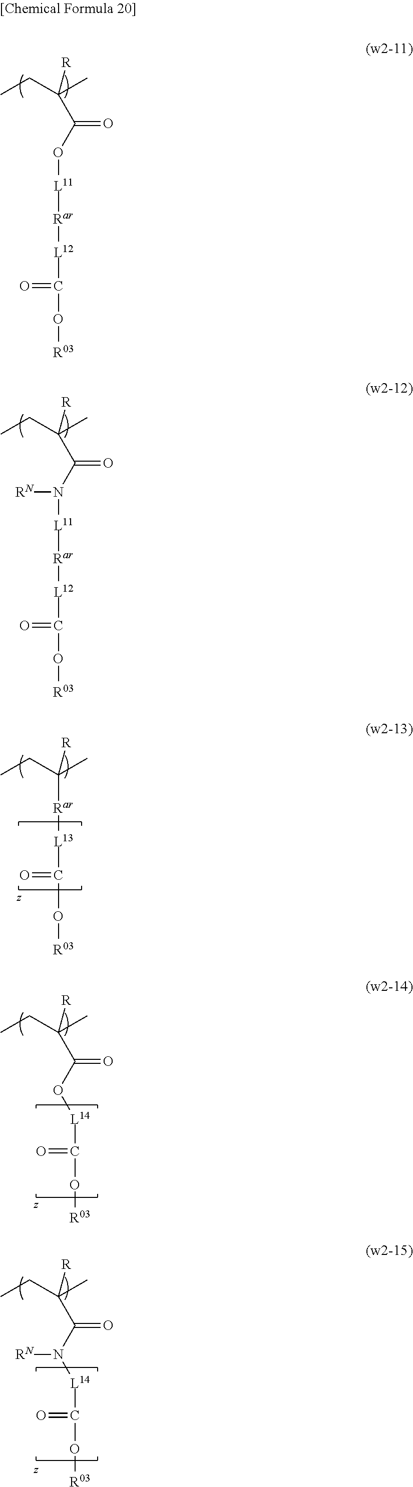

In the formulas (w2-11) and (w2-12), R, L¹¹, R^{ar}, L¹² and R^{N} are the same as defined above; R⁰³ represents an acid dissociable group; in the formula (w2-13), R, L¹³ and R⁰³ are the same as defined above; z represents 0 or 1; and in the formulas (w2-14) and (w2-15), R, L¹⁴, R⁰³, R^{N} and z are the same as defined above.

In the formulas (w2-11) to (w2-15), R, L¹¹ to L¹⁴, R^{ar} and R^{N} are the same as defined for R, L¹¹ to L¹⁴, R^{ar} and R^{N} in the general formulas (w1-11) to (w1-15) in relation to the structural unit (w1). Provided that, the structural units represented by the formula (w2-11) to (w2-15) are not necessarily have a fluorine atom or a silicon atom.

As the acid dissociation group for R⁰³, the same groups as those defined above can be mentioned. Among these, tertiary alkyl ester-type acid dissociable groups are preferable, and aliphatic cyclic group-containing acid dissociable groups are particularly preferable.

When the component (W) includes the structural unit (w2), as the structural unit (w2) in the component (W), one type of structural unit may be used, or two or more structural units may be used.

In the component (W), the amount of the structural unit (w2) based on the combined total of all structural units constituting the component (W) is preferably 0 to 45 mol %, more preferably 5 to 40 mol %, and still more preferably 10 to 40 mol %. When the amount is no more than the upper limit of the above-mentioned range, a good balance can be achieved with the other structural units.

When the amount is at least 5 mol %, in the case of alkali developing process, the solubility in a developing solution at exposed portions can be increased, whereas in the case of solvent developing process, the solubility in a developing solution at unexposed portions can be increased.

[Structural Unit (w3)]

The structural unit (w3) is a structural unit having a polar group. When the component (W) includes the structural unit (w3), the polarity of the component (W) after exposure is enhanced. Increased polarity of the component (W) contributes to reduce defects. In particular, in the case of an alkali developing process, increased polarity of the component (W) contributes to improve resolution.

Examples of the polar group include —OH, —COOH, —CN, —SO₂NH₂— and —CONH₂. The hydroxy group (—OH) may be a phenolic hydroxy group or an alcoholic hydroxy group.

The structural unit (w3) is a structural unit containing a hydrocarbon group in which part of the hydrogen atoms is substituted with a polar group or an organic group having a polar group.

Examples of the organic group having a polar group include a hydroxyalkyl group, hydroxyalkyloxy group, fluorinated alcohol group (a hydroxyalkyl group in which part or all of the hydrogen atoms bonded to carbon atoms have been substituted with fluorine atoms) and a hydroxyaryl group. Among these, a carbon skeleton of a hydroxyalkyl group, a hydroxyalkyloxy group or a fluorinated alcohol group may be linear, branched or cyclic, or a combination thereof. When the carbon sleketon is linear or branched, the linear or branched carbon sleketon preferably has 1 to 12 carbon atoms. When the carbon sleketon is cyclic, the cyclic carbon sleketon preferably has 3 to 30 carbon atoms. Examples of the aryl group of hydroxyaryl group include a group in which one hydrogen atom has been removed from the aromatic ring described above in the explanation of the aromatic group, and a phenyl group or a naphthyl group is preferable.

The hydrocarbon group which has a hydrogen atom substituted with a polar group or an organic group containing a polar group may be either an aliphatic hydrocarbon group or an aromatic hydrocarbon group. Among these, the hydrocarbon group in the structural unit (w3) is preferably an aromatic hydrocarbon group.

Examples of the aliphatic hydrocarbon group or aromatc hydrocarbon group for the hydrocarbon group include the same aliphatic hydrocarbon group or aromatic hydrocarbon group as described above for a divalent hydrocarbon group in relation to the aforementioned divalent linking group for L⁰¹ in the general formula (I-1).

The hydrocarbon group may have a substituent other than a polar group. Examples of the substituent include an alkyl group of 1 to 5 carbon atoms, a fluorine atom, a fluorinated alkyl group of 1 to 5 carbon atoms, and an oxo group (═O).

The structural unit (a3) is preferably a structural unit derived from an (α-substituted) acrylic acid or a structural unit derived from an (α-substituted) acrylate ester which has a polar group. The structural unit derived from an (α-substituted) acrylic acid and the structural unit derived from an (α-substituted) acrylate ester are a structural unit that is formed by the cleavage of the ethylenic double bond of an (α-substituted) acrylic acid to form a single bond or a structural unit that is formed by the cleavage of the ethylenic double bond of an (α-substituted) acrylate ester to form a single bond, respectively.

Examples of the structural unit derived from an (α-substituted) acrylate ester having a polar group include a structural unit (a3-11) described later.

The structural unit (w3) may or may not have a fluorine atom or a silicon atom. Examples of the structural unit (w3) having a fluorine atom or a silicon atom include a structural unit represented by the general formula (w-0) in which R⁰ represents a hydrocarbon group containing a polar group.

The structural unit (w3) preferably has a fluorine atom, as well as a polar group. It is preferable that R⁰ in the general formula (w-0) represents an aromatic cyclic group having a hydroxy group and a fluorine atom bonded thereto or an aliphatic cyclic group having a fluorinated alcohol group bonded thereto.

It is particularly preferable that L⁰¹ in the formula (w0-1) is a single bond, —C(═O)—O-L¹⁰- or —C(═O)—N(R^{N})-L¹⁰-.

Specific examples of preferable structural units (w3) are shown below.

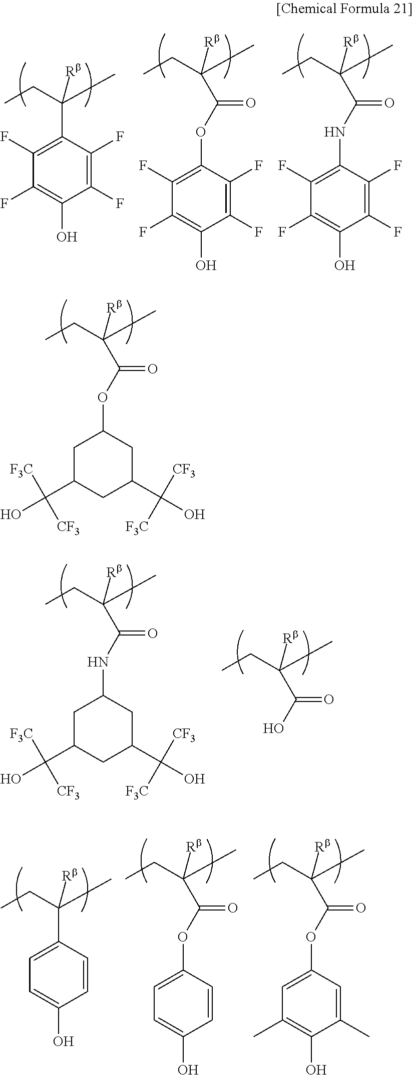

When the component (W) includes the structural unit (w3), as the structural unit (w3) in the component (W), one type of structural unit may be used, or two or more structural units may be used.

In the component (W), the amount of the structural unit (w3) based on the combined total of all structural units constituting the component (W) is preferably 0 to 50 mol %, and more preferably 5 to 45 mol %. When the amount is no more than the upper limit of the above-mentioned range, a good balance can be achieved with the other structural units. When the amount of the structural unit (w3) is at least 5 mol %, the effects of blending the structural unit (w3) can be satisfactorily achieved. When the structural unit (w3) has an aromatic group, the influence of OoB light can be reduced.

[Structural Unit (w4)]

The structural unit (w4) is a fluorine-containing structural unit having a ring structure, and which does not fall under the definition of the structural units (w1) to (w3). When the component (W) includes the structural unit (w4), surface segregation effect can be enhanced.

The cyclic group contained in the structural unit (w4) may be either an aromatic cyclic group or an aliphatic cyclic group.

Examples of the aromatic cyclic group include groups in which one or more hydrogen atoms have been removed from the aromatic ring described above in relation to the aromatic group. When the structural unit (w4) contains an aromatic cyclic group, the influence of OoB light can be reduced.

The aliphatic cyclic group may be saturated or unsaturated. In general, the aliphatic cyclic group is preferably saturated. The aliphatic cyclic group may be either a monocyclic group or a polycyclic group. As the monocyclic aliphatic cyclic group, a group in which one or more hydrogen atoms have been removed from a monocycloalkane is preferable. The monocycloalkane preferably has 3 to 6 carbon atoms, and specific examples thereof include cyclopentane and cyclohexane. As the polycyclic aliphatic hydrocarbon group, a group in which one or more hydrogen atoms have been removed from a polycycloalkane is preferable, and the polycyclic group preferably has 7 to 12 carbon atoms. Examples of the polycycloalkane include adamantane, norbornane, isobornane, tricyclodecane and tetracyclododecane.

The cyclic group may have a substituent. Examples of the substituent include an alkyl group of 1 to 5 carbon atoms, a fluorine atom, a fluorinated alkyl group of 1 to 5 carbon atoms, and an oxo group (═O).

As the alkyl group, alkoxy group, halogen atom and the halogenated alkyl group as a substituent, the same groups as those described above for a substituent which may be bonded to an aromatic ring in relation to the aromatic group can be mentioned.

Examples of the polar group as a substituent include a hydroxy group, a carboxy group, an amino group, a sulfo group, a cyano group, a hydroxyalkyl group, a hydroxyalkyloxy group and a fluorinated alcohol group (i.e., a hydroxyalkyl group in which part or all of the hydrogen atom bonded to a carbon atom have been substituted with a fluorine atom). Among these, a carbon skeleton of a hydroxyalkyl group, hydroxyalkyloxy group or fluorinated alcohol group may be linear, branched or cyclic, or a combination thereof. When the carbon sleketon is linear or branched, the linear or branched carbon sleketon preferably has 1 to 12 carbon atoms. When the carbon sleketon is cyclic, the cyclic carbon sleketon preferably has 3 to 30 carbon atoms.

As the structural unit (w4), it is preferable that R⁰ in the general formula (w-0) is a fluorine-contained cyclic group, and it is particularly preferable that L⁰¹ in the formula (w0-1) is a single bond, —C(═O)—O—O— or —C(═O)—N(R^{N})-L¹⁰-.

Specific examples of preferable structural units (w4) are shown below.

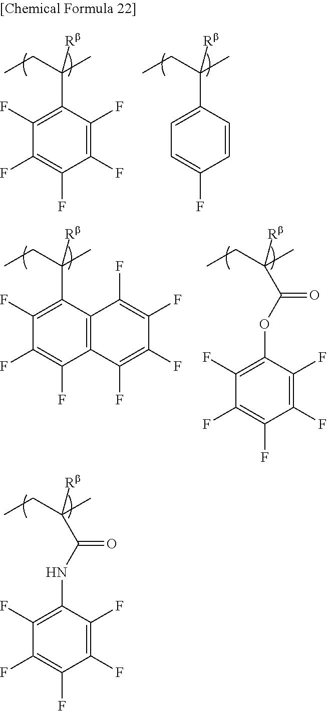

When the component (W) includes the structural unit (w4), as the structural unit (w4) in the component (W), one type of structural unit may be used, or two or more structural units may be used.

In the component (W), the amount of the structural unit (w4) based on the combined total of all structural units constituting the component (W) is preferably 0 to 30 mol %, and more preferably 1 to 20 mol %. When the amount is no more than the upper limit of the above-mentioned range, a good balance can be achieved with the other structural units. When the amount of the structural unit (w4) is at least 1 mol %, the effects of blending the structural unit (w4) can be satisfactorily achieved.

[Structural Unit (w5)]

The structural unit (w5) is a silicone-containing structural unit having an organic group which contains a trialkylsilyl group or a siloxane bond.

Examples of the trialkylsiliyl group include a group represented by formula —Si(R⁷⁴)(R⁷⁵)(R⁷⁶). In the formula, each of R⁷⁴ to R⁷⁶ independently represents a linear or branched alkyl group. The alkyl group preferably has 1 to 10 carbon atoms, more preferably 1 to 8, and still more preferably 1 to 5. As the alkyl group, a methyl group, an ethyl group or an isopropyl group is preferable, and a methyl group is particularly preferable.

Specific examples of the trialkylsiliy group include a trimethylsilyl group, a triethylsilyl group, a triisopropylsilyl group and t-butyldimethylsilyl group.

The organic group containing a trialkylsilyl group may consist of a trialkylsilyl group, or may be a group in which n number of trialkylsilyl groups (wherein n represents an integer of 1 or more) are bonded to a (n+1)-valent linking group. When n is 1 in the (n+1)-valent linking group, as a divalent linking group, the same divalent linking groups as those described above for L⁰¹ in the general formula (I-1) can be mentioned, and a linear or branched alkylene group in which an ether bond or an ester bonded may be interposed, is preferable. When n is 2 or more, as the linking group, groups in which (n−1) number of hydrogen atoms have been removed from the divalent linking group can be mentioned.

Examples of the organic group containing a siloxane bond (Si—O—Si) include a cyclic siloxane in which a hydrocarbon group has been bonded to the silicon atom, a polyhedral oligomeric silsesquioxane in which a hydrocarbon group has been bonded to the silicon atom and a group in which part of the carbon chain in a chain-like or cyclic alkyl group has been substituted with —Si—O—Si—. The hydrocarbon group bonded to the silicon atom within the cyclic siloxane or polyhedral oligomeric silsesquioxane may be either an aliphatic hydrocarbon group or an aromatic group. The hydrocarbon group is preferably an aliphatic group, and more preferably an alkyl group of 1 to 5 carbon atoms.

As the structural unit (w5), a structural unit represented by the general formula (w-0) in which R⁰ is an organic group containing a trialkylsilyl group or a siloxane bond can be mentioned, and it is particularly preferable that L⁰¹ in the formula (w-0) is —C(═O)—O-L¹⁰- or a single bond.

When the component (W) includes the structural unit (w5), as the structural unit (w5) in the component (W), one type of structural unit may be used, or two or more structural units may be used.

In the component (W), the amount of the structural unit (w5) based on the combined total of all structural units constituting the component (W) is preferably 0 to 60 mol %, more preferably 1 to 50 mol %, and still more preferably 5 to 40 mol %. When the amount of the structural unit (w5) is within the above-mentioned range, surface segregation effect and applicability can be enhanced, and a good balance can be achieved with the other structural units.

The component (W) may include a structural unit other than the structural units (w1) to (w5) (hereafter, referred to as structural unit (w6)).

The structural unit (w6) is not particularly limited, as long as it can form a copolymer with the structural units (w1) to (w5). As the structural unit (w6), any of the multitude of conventional structural units used within the resin used in resist compositions for ArF excimer lasers, KrF excimer lasers, EB or EUV can be used. Examples of such structural units include the structural units (a0), (a2) and (a4) described later in relation to the component (A).

As the structural units constituting the component (W), 1 type of structural unit may be used, or 2 or more types may be used.

When the component (W) is constituted by one type of structural unit, as the structural unit, a structural unit which has a fluorine atom or a silicon atom and has a base decomposable polarity conversion group, that is, the aforementioned structural unit (w1) can be used.

In the component (W), the amount of the structural unit having at least one atom selected from a fluorine atom or a silicon atom (preferably a fluorine atom) based on the combined total of all structural units constituting the component (W) is preferably 70 mol % or more, and more preferably 80 mol % or more. The upper limit of the amount of the component (W) is not particularly limited, and may be 100%.

In the component (W), the preferable amount of the structural unit having a polarity conversion group which exhibits increased polarity after decomposition by the action of base is the same as that of the aforementioned structural unit (w1).

The component (W) is preferably a polymer containing the structural units (w1), and more preferably a copolymer containing at least one structural unit selected from the structural unit (w2) and structural unit (w3), as well as the structural unit (w1).

As the structural unit (w1), at least one structural unit selected from the group consisting of formulas (w1-11) to (w1-15) and (w1-21) to (w1-25) is preferable, and at least one structural unit selected from the group consisting of formulas (w1-11), (w1-14) and (w1-23) is more preferable.

As the structural unit (w2), a structural unit (a11) described later is preferable, and a structural unit (a1-0-1) is more preferable, and a structural unit (a1-1-32) is more preferable.

As the structural unit (w3), a structural unit derived from an (α-substituted) acrylic acid, a structural unit having an aromatic cyclic group having a fluorine atom and a hydroxy group bonded thereto, a structural unit having an aromatic cyclic group having a hydroxy group bonded thereto or a structural unit having an aliphatic cyclic group having a fluorinated alcohol group bonded thereto is preferable, and a structural unit having a hydroxyphenyl group which have a hydrogen atom substituted with a fluorine atom or a structural unit containing a cyclohexyl group having a fluorinated alcohol group bonded thereto is more preferable.

The weight average molecular weight (Mw) (the polystyrene equivalent value determined by gel permeation chromatography) of the component (W) is not particularly limited, but is preferably 1,000 to 80,000, more preferably 5,000 to 60,000, and most preferably 10,000 to 50,000. When the weight average molecular weight of the component (W) is no more than the upper limit of the above-mentioned range, the resist composition exhibits a satisfactory solubility in a resist solvent. On the other hand, when the weight average molecular weight is at least as large as the lower limit of the above-mentioned range, the dry etching resistance and the cross-sectional shape of the resist pattern becomes satisfactory.

Further, the dispersity (Mw/Mn) is not particularly limited, but is preferably 1.0 to 5.0, more preferably 1.0 to 3.0, and most preferably 1.2 to 2.5. Here, Mn is the number average molecular weight.

The component (W) can be obtained, for example, by a conventional radical polymerization or the like of the monomers corresponding with each of the structural units to be included in the component (W), using a radical polymerization initiator such as azobisisobutyronitrile (AIBN).

Furthermore, in the component (W), by using a chain transfer agent such as HS—CH₂—CH₂—CH₂—C(CF₃)₂—OH, a —C(CF₃)₂—OH group can be introduced at the terminals of the component (W). Such a copolymer having introduced a hydroxyalkyl group in which some of the hydrogen atoms of the alkyl group are substituted with fluorine atoms is effective in reducing developing defects and LER (line edge roughness: unevenness of the side walls of a line pattern).

These monomers corresponding with each monomer can be synthesized by a conventional method. A monomer corresponding to the structural unit (a0) can be synthesized, for example, by a method disclosed in Japanese Unexamined Patent Application, First Publication No. 2006-045311 and Japanese Unexamined Patent Application, First Publication No. 2010-095643. As conventional monomers, commercially available monomers may be used, As the component (W), one type may be used, or two or more types may be used in combination.

In the resist composition according to the first aspect of the present invention, the amount of the component (W) relative to 100 parts by weight of the component (A) is preferably 1 to 15 parts by weight, more preferably 2 to 14 parts by weight and still more preferably 3 to 12 parts by weight.

When the amount of the component (W) is 1 part by weight or more, pattern shape and critical resolution property of a resist pattern formed by EUV exposure or EB exposure can be improved. When the amount of the component (W) is 15 parts by weight or less, a good balance can be achieved with the component (A), and the lithography properties such as pattern shape and resolution are improved.

### <Component (A) of First Aspect of the Present Invention>

The component (A) used for a resist composition according to the first aspect of the present invention is a base component that generates acid upon exposure and exhibits changed solubility in a developing solution by the action of acid.

The component (A) may be a component that exhibits increased solubility in a developing solution under the action of acid, or may be a component that exhibits decreased solubility in a developing solution under the action of acid.

The component (A) may have a portion that generates acid (acid generating portion) upon exposure at the side chain thereof or at the main chain thereof. When the component (A) has an acid generating portion at the side chain thereof, the component (A) contains a structural unit (a0) described later.

When the resist composition according to the first aspect of the present invention is a resist composition for alkali developing process which forms a negative resist pattern in an alkali developing process, or a resist composition for solvent developing process which forms a positive resist pattern, for example, as the component (A), a base component that generates acid upon exposure and exhibits solubility in an alkali developing solution (hereafter, frequently referred to as component (A-2)) is used, and a cross-linking agent is blended in the resist composition. In the resist composition, when acid is generated from the component (A-2) upon exposure, the action of the generated acid causes cross-linking between the component (A-2) and the cross-linking agent, and the cross-linked portion becomes insoluble in an alkali developing solution (i.e., the cross-linked portion becomes soluble in an organic developing solution). Therefore, in the formation of a resist pattern, by conducting selective exposure to a resist film formed by applying the resist composition onto a substrate, the exposed portions become insoluble in an alkali developing solution (that is, soluble in an organic developing solution), whereas the unexposed portions remain soluble in an alkali developing solution (that is, insoluble in an organic developing solution), and hence, a negative resist pattern can be formed by alkali developing. In addition, when an organic developing solution is used as a developing solution, a positive resist pattern can be formed.

As the component (A-2), a resin component in which an acid generating portion that generates acid upon exposure (e.g., an anion portion that generates acid upon exposure) is introduced into a conventional resin which exhibits solubility in an alkali developing solution (hereafter, referred to as alkali soluble resin) can be mentioned.

Examples of the alkali soluble resin (prior to introducing an acid generating portion) include a resin having a structural unit derived from at least one of α-(hydroxyalkyl)acrylic acid and an alkyl ester of α-(hydroxyalkyl)acrylic acid (preferably an alkyl ester having 1 to 5 carbon atoms), as disclosed in Japanese Unexamined Patent Application, First Publication No. 2000-206694; an acrylic resin which has a sulfonamide group and may have a carbon atom of the α-position having an atom other than a hydrogen atom or a substituent bonded thereto or a polycycloolefin resin having a sulfoneamide group, as disclosed in U.S. Pat. No. 6,949,325; an acrylic resin which may have the carbon atom of the α-position having an atom other than a hydrogen atom or a substituent bonded thereto and which has a fluorinated alcohol, as disclosed in U.S. Pat. No. 6,949,325, Japanese Unexamined Patent Application, First Publication No. 2005-336452 or Japanese Unexamined Patent Application, First Publication No. 2006-317803; and a polycyclolefin resin having a fluorinated alcohol, as disclosed in Japanese Unexamined Patent Application, First Publication No. 2006-259582. These resins are preferable in that a resist pattern can be formed with minimal swelling.

Here, the term “α-(hydroxyalkyl)acrylic acid” refers to one or both of acrylic acid which may has the carbon atom on the α-position having an atom other than a hydrogen atom or a substituent bonded thereto and which has a hydroxy group bonded to a carbon atom on the α-position having the carboxyl group bonded thereto, and α-hydroxyalkylacrylic acid in which a hydroxyalkyl group (preferably a hydroxyalkyl group of 1 to 5 carbon atoms) is bonded to the carbon atom on the α-position.

As the acid generating portion, the same structure as an acid generating portion which a conventional compound used as an acid generator component for a resist composition has, can be used.

The position of the acid generating portion may be at the terminal of the main chain or at the side chain. The acid generating portion can be introduced at the terminal of the main chain by a polymerization reaction using a polymerization initiator having an acid generating portion as a polymerization initiator when producing an alkali soluble resin. The acid generating portion can be introduced at the side chain by a polymerization reaction of a monomer having an alkali soluble group (e.g., a monomer which derives a structural unit (a3) described later having an alkali soluble group such as a hydroxy group and carboxy group as a polar group) or a precursor thereof (e.g., a monomer in which the alkali soluble group has been protected with a protecting group) and a monomer having an acid generating portion (e.g., a monomer which derives a structural unit (a0) described later) when producing an alkali soluble resin.

As the cross-linking agent, typically, an amino-based cross-linking agent such as a glycoluril having a methylol group or alkoxymethyl group, or a melamine-based cross-linking agent is preferable, as it enables formation of a resist pattern with minimal swelling. The amount of the cross-linking agent added is preferably within a range from 1 to 50 parts by weight, relative to 100 parts by weight of the alkali-soluble resin.

In the case where the resist composition of the first aspect of the present invention is a resist composition which forms a positive resist pattern in an alkali developing process and a negative resist pattern in a solvent developing process, it is preferable to use a base component (hereafter, referred to as “component (A-1)”) which exhibits increased polarity by the action of acid as the component (A). Since the polarity of the component (A-1) changes before and after exposure, an excellent development contrast can be obtained not only in an alkali developing process, but also in a solvent developing process.

More specifically, in the case of applying an alkali developing process, the component (A-1) is insoluble in an alkali developing solution prior to exposure, but when acid is generated from the component (A-1) upon exposure, the action of this acid causes an increase in the polarity of the base component, thereby increasing the solubility of the component (A-1) in an alkali developing solution. Therefore, in the formation of a resist pattern, by conducting selective exposure of a resist film formed by applying the resist composition to a substrate, the exposed portions change from an insoluble state to a soluble state in an alkali developing solution, whereas the unexposed portions remain insoluble in an alkali developing solution, and hence, a positive resist pattern can be formed by alkali developing. On the other hand, in the case of a solvent developing process, the component (A-1) exhibits high solubility in an organic developing solution prior to exposure, and when acid is generated from the component (A-1) upon exposure, the polarity of the component (A-1) is increased by the action of the generated acid, thereby decreasing the solubility of the component (A-1) in an organic developing solution. Therefore, in the formation of a resist pattern, by conducting selective exposure of a resist film formed by applying the resist composition to a substrate, the exposed portions changes from an soluble state to an insoluble state in an organic developing solution, whereas the unexposed portions remain soluble in an organic developing solution. As a result, by conducting development using an organic developing solution, a contrast can be made between the exposed portions and unexposed portions, thereby enabling the formation of a negative resist pattern.

In the present invention, as the component (A), a component (A-1) is preferred.

### [Polymeric Compound (A1)]

In the first aspect of the present invention, the component (A) contains a polymeric compound (A1) which contains a structural unit (a0) having a group represented by general formula (a0-1) or (a0-2) shown below (hereafter, referred to as component (A1)).

By virtue of the structural unit (a0) having a group represented by general formula (a0-1) or (a0-2) shown below, the structural unit (a0) generates acid upon exposure.

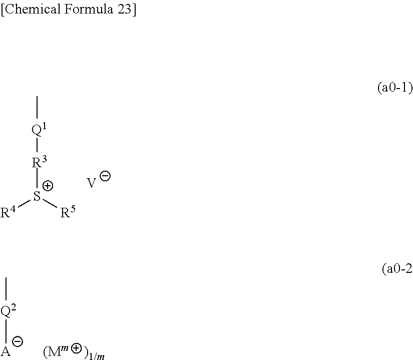

In the formulas, each of Q¹ and Q² independently represent a single bond or a divalent linking group; each of R³, R⁴ and R⁵ independently represents an organic group, R⁴ and R⁵ may be mutually bonded to form a ring with the sulfur atom, provided that —R³—S⁺(R⁴)(R⁵) has one aromatic ring or no aromatic ring in total; V⁻ represents a counteranion; A⁻ represents an organic group containing an anion moiety; M^{m+} represents a m-valent organic cation; and m represents an integer of 1 to 3, provided that M^{m+} has one aromatic ring or no aromatic ring.

### <Component (A) of First Aspect of the Second Invention>

The component (A) used for a resist composition according to the second aspect of the present invention is a base component that generates acid upon exposure and exhibits changed solubility in a developing solution by the action of acid, and contains a resin component (A1b) having a structural unit (a1) and a structural unit (a5) shown below (hereafter, frequently referred to as “component (A1b)”).

Here, the term “base component” refers to an organic compound capable of forming a film, and is preferably an organic compound having a molecular weight of 500 or more. When the organic compound has a molecular weight of 500 or more, the film-forming ability is improved, and a resist pattern of nano level can be easily formed. The “organic compound having a molecular weight of 500 or more” which can be used as a base component is broadly classified into non-polymers and polymers.

In general, as a non-polymer, any of those which have a molecular weight in the range of no less than 500 to less than 4,000 is used. Hereafter, a non-polymer having a molecular weight in the range of no less than 500 to less than 4,000 is referred to as a low molecular weight compound.

As a polymer, any of those which have a molecular weight of 1,000 or more is generally used. Hereafter, a polymer having a molecular weight of 1,000 or more is referred to as a polymeric compound. With respect to a polymeric compound, the “molecular weight” is the weight average molecular weight in terms of the polystyrene equivalent value determined by gel permeation chromatography (GPC). Hereafter, a polymeric compound is frequently referred to simply as a “resin”.

### [Component (A1)]

In the second aspect of the present invention, the component (A) contains a resin component (A1) which contains a structural unit (a0) having a group represented by general formula (a0-1) or (a0-2) shown below (hereafter, referred to as component (A1)).

With respect to the structural unit (a0), by virtue of a structural unit having a group represented by general formula (a0-1) (hereafter, referred to as structural unit (a0-1)) or a structural unit having a group represented by general formula (a0-2) (hereafter, referred to as structural unit (a0-2)) shown below, the structural unit (a0) generates acid upon exposure.

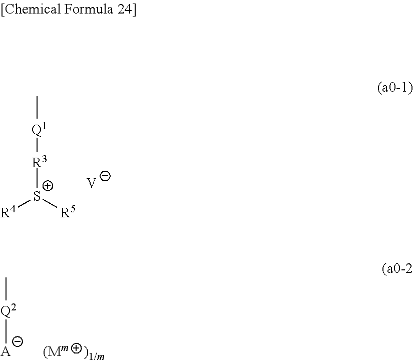

In the formulas, each of Q¹ and Q² independently represent a single bond or a divalent linking group; each of R³, R⁴ and R⁵ independently represents an organic group, R⁴ and R⁵ may be mutually bonded to form a ring with the sulfur atom, provided that —R³—S⁺(R⁴)(R⁵) has one aromatic ring or no aromatic ring in total; A⁻ represents an organic group containing an anion moiety; M^{m+} represents a m-valent organic cation; and m represents an integer of 1 to 3, provided that M^{m+} has one aromatic ring or no aromatic ring.

### <Component (A) of Third Aspect of the Present Invention>

The component (A) in the third aspect of the present invention is a base component that generates acid upon exposure and exhibits changed solubility in a developing solution by the action of acid.

The term “base component” refers to an organic compound capable of forming a film, and is preferably an organic compound having a molecular weight of 500 or more. When the organic compound has a molecular weight of 500 or more, the film-forming ability is improved, and a resist pattern of nano level can be easily formed.

The organic compound which can be used as a base component is broadly classified into non-polymers and polymers.

In general, as a non-polymer, any of those which have a molecular weight in the range of no less than 500 to less than 4,000 is used. Hereafter, a non-polymer having a molecular weight in the range of no less than 500 to less than 4,000 is referred to as a low molecular weight compound.

As a polymer, any of those which have a molecular weight of 1,000 or more is generally used. In the present description and claims, the term “resin” or “polymeric compound” refers to a polymer having a molecular weight of 1,000 or more. With respect to a polymer, the “molecular weight” is the weight average molecular weight in terms of the polystyrene equivalent value determined by gel permeation chromatography (GPC).

The component (A) may be a resin, a low molecular weight compound, or a combination of these materials. The component (A) may have a portion that generates acid (acid generating portion) upon exposure at the side chain thereof or at the main chain thereof. The polymeric compound (A1) containing a structural unit (a0) described later has an acid generating portion on at least side chain thereof.

The component (A) may be a component that exhibits increased solubility in a developing solution under the action of acid, or may be a component that exhibits decreased solubility in a developing solution under the action of acid.

When the resist composition according to the third aspect of the present invention is a resist composition for alkali developing process which forms a negative resist pattern, or a resist composition for solvent developing process which forms a positive resist pattern, for example, as the component (A), a base component that generates acid upon exposure and exhibits solubility in an alkali developing solution (hereafter, frequently referred to as component (A-2)) is used, and a cross-linking agent is blended in the resist composition. In the resist composition, when acid is generated from the component (A-2) upon exposure, the action of the generated acid causes cross-linking between the component (A-2) and the cross-linking agent, and the cross-linked portion becomes insoluble in an alkali developing solution (i.e., the cross-linked portion becomes soluble in an organic developing solution). Therefore, in the formation of a resist pattern, by conducting selective exposure of a resist film formed by applying the resist composition onto a substrate, the exposed portions become insoluble in an alkali developing solution (that is, soluble in an organic developing solution), whereas the unexposed portions remain soluble in an alkali developing solution (that is, insoluble in an organic developing solution), and hence, a negative resist pattern can be formed by alkali developing. In addition, when an organic developing solution is used as a developing solution, a positive resist pattern can be formed.

As the component (A-2), a resin component in which an acid generating portion that generates acid upon exposure is introduced into a conventional resin which exhibits solubility in an alkali developing solution (hereafter, referred to as alkali soluble resin) can be mentioned.

Examples of the alkali soluble resin (prior to introducing an acid generating portion) include a resin having a structural unit derived from at least one of α-(hydroxyalkyl)acrylic acid and an alkyl ester of α-(hydroxyalkyl)acrylic acid (preferably an alkyl ester having 1 to 5 carbon atoms), as disclosed in Japanese Unexamined Patent Application, First Publication No. 2000-206694; an acrylic resin which has a sulfonamide group and may have a carbon atom of the α-position having an atom other than a hydrogen atom or a substituent bonded thereto or a polycycloolefin resin having a sulfoneamide group, as disclosed in U.S. Pat. No. 6,949,325; an acrylic resin which may have the carbon atom of the α-position having an atom other than a hydrogen atom or a substituent bonded thereto and which has a fluorinated alcohol, as disclosed in U.S. Pat. No. 6,949,325, Japanese Unexamined Patent Application, First Publication No. 2005-336452 or Japanese Unexamined Patent Application, First Publication No. 2006-317803; and a polycyclolefin resin having a fluorinated alcohol, as disclosed in Japanese Unexamined Patent Application, First Publication No. 2006-259582. These resins are preferable in that a resist pattern can be formed with minimal swelling.

Here, the term “α-(hydroxyalkyl)acrylic acid” refers to one or both of acrylic acid which may has the carbon atom on the α-position having an atom other than a hydrogen atom or a substituent bonded thereto and which has a hydroxy group bonded to a carbon atom on the α-position having the carboxyl group bonded thereto, and α-hydroxyalkylacrylic acid in which a hydroxyalkyl group (preferably a hydroxyalkyl group of 1 to 5 carbon atoms) is bonded to the carbon atom on the α-position.

As the acid generating portion, the same structure as an acid generating portion which a conventional compound used as an acid generator component for a resist composition has, can be used.

The position of the acid generating portion may be at the terminal of the main chain or at the side chain. The acid generating portion can be introduced at the terminal of the main chain by a polymerization reaction using a polymerization initiator having an acid generating portion as a polymerization initiator when producing an alkali soluble resin. The acid generating portion can be introduced at the side chain by a polymerization reaction of a monomer having an alkali soluble group (e.g., a monomer which derives a structural unit (a3) described later having an alkali soluble group such as a hydroxy group and carboxy group as a polar group) or a precursor thereof (e.g., a monomer in which the alkali soluble group has been protected with a protecting group) and a monomer having an acid generating portion (e.g., a monomer which derives a structural unit (a0) described later) when producing an alkali soluble resin.

As the cross-linking agent, typically, an amino-based cross-linking agent such as a glycoluril having a methylol group or alkoxymethyl group, or a melamine-based cross-linking agent is preferable, as it enables formation of a resist pattern with minimal swelling. The amount of the cross-linking agent added is preferably within a range from 1 to 50 parts by weight, relative to 100 parts by weight of the alkali-soluble resin.

In the case where the resist composition of the third aspect of the present invention is a resist composition which forms a positive resist pattern in an alkali developing process and a negative resist pattern in a solvent developing process, it is preferable to use a base component (hereafter, referred to as “component (A-1)”) which generates acid upon exposure and exhibits increased polarity by the action of acid as the component (A-1).

Since the polarity of the component (A-1) changes before and after exposure, an excellent development contrast can be obtained not only in an alkali developing process, but also in a solvent developing process.

More specifically, in the case of applying an alkali developing process, the component (A-1) is insoluble in an alkali developing solution prior to exposure, but when acid is generated from the component (A-1) upon exposure, the action of this acid causes an increase in the polarity of the base component, thereby increasing the solubility of the component (A-1) in an alkali developing solution. Therefore, in the formation of a resist pattern, by conducting selective exposure of a resist film formed by applying the resist composition to a substrate, the exposed portions change from an insoluble state to a soluble state in an alkali developing solution, whereas the unexposed portions remain insoluble in an alkali developing solution, and hence, a positive resist pattern can be formed by alkali developing. On the other hand, in the case of a solvent developing process, the component (A-1) exhibits high solubility in an organic developing solution prior to exposure, and when acid is generated from the component (A-1) upon exposure, the polarity of the component (A-1) is increased by the action of the generated acid, thereby decreasing the solubility of the component (A-1) in an organic developing solution. Therefore, in the formation of a resist pattern, by conducting selective exposure of a resist film formed by applying the resist composition to a substrate, the exposed portions changes from an soluble state to an insoluble state in an organic developing solution, whereas the unexposed portions remain soluble in an organic developing solution. As a result, by conducting development using an organic developing solution, a contrast can be made between the exposed portions and unexposed portions, thereby enabling the formation of a negative resist pattern.

In the present invention, as the component (A), a component (A-1) is preferred.

### [Polymeric Compound (A1)]

In the third aspect of the present invention, the component (A) contains a polymeric compound (A1) which contains a structural unit (a0) having a group represented by general formula (a0-1) or (a0-2) shown below (hereafter, referred to as component (A1)).

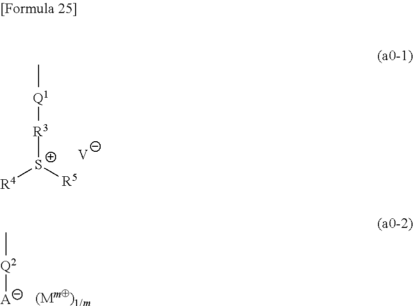

In the formulas, each of Q¹ and Q² independently represent a single bond or a divalent linking group; each of R³, R⁴ and R⁵ independently represents an organic group, R⁴ and R⁵ may be mutually bonded to form a ring with the sulfur atom, provided that —R³—S⁺(R⁴)(R⁵) has one aromatic ring or no aromatic ring in total; R⁴ and R⁵ may be mutually bonded with the sulfur atom to form a ring; V⁻ represents a counteranion; A⁻ represents an organic group containing an anion moiety; M^{m+} represents a m-valent organic cation; and m represents an integer of 1 to 3, provided that M^{m+} has one aromatic ring or no aromatic ring.

(Structural Unit (a0))
(Structural Unit Represented by General Formula (a0-1))

Examples of the structural unit having a group represented by the formula (a0-1) include a structural unit which is derived from an acrylate ester or a structural unit which is derived from a hydroxystyrene or derivatives thereof and which has a group represented by the formula (a0-1). Among these, a structural unit represented by the formula (a0-11′) shown below is preferable.

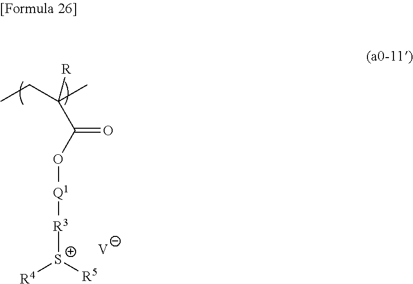

In the formula, R, Q¹, R³ to R⁵ and V⁻ are the same as defined above.

In the formula (a0-1), Q¹ is a single bond or a divalent linking group.

The divalent linking group for Q¹ is not particularly limited, and preferable examples thereof include a divalent hydrocarbon group which may have a substituent and a divalent linking group containing a hetero atom.

(Divalent Hydrocarbon Group which May have a Substituent)

The hydrocarbon group as a divalent linking group may be either an aliphatic hydrocarbon group or an aromatic hydrocarbon group.

An “aliphatic hydrocarbon group” refers to a hydrocarbon group that has no aromaticity. The aliphatic hydrocarbon group may be saturated or unsaturated. In general, the aliphatic hydrocarbon group is preferably saturated.

As specific examples of the aliphatic hydrocarbon group, a linear or branched aliphatic hydrocarbon group, and an aliphatic hydrocarbon group containing a ring in the structure thereof can be given.

The linear or branched aliphatic hydrocarbon group preferably has 1 to 10 carbon atoms, more preferably 1 to 8, and still more preferably 1 to 5.

As the linear aliphatic hydrocarbon group, a linear alkylene group is preferable, and specific examples include a methylene group [—CH₂—], an ethylene group [—(CH₂)₂—], a trimethylene group [—(CH₂)₃—], a tetramethylene group [—(CH₂)₄—] and a pentamethylene group [—(CH₂)₅—].

As the branched aliphatic hydrocarbon group, a branched alkylene group is preferable, and specific examples include alkylalkylene groups, e.g., alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. As the alkyl group within the alkylalkylene group, a linear alkyl group of 1 to 5 carbon atoms is preferable.

The linear or branched aliphatic hydrocarbon group may or may not have a substituent (that is, a group or an atom other than hydrogen atom) which substitutes a hydrogen atom in the cyclic aliphatic hydrocarbon group. Examples of the substituent include a fluorine atom, a fluorinated alkyl group of 1 to 5 carbon atoms, and an oxo group (═O).

As examples of the aliphatic hydrocarbon group containing a ring in the structure thereof, a cyclic aliphatic hydrocarbon group which may have a substituent containing a hetero atom in the ring structure thereof (a group in which two hydrogen atoms have been removed from an aliphatic hydrocarbon ring) and a group in which the cyclic aliphatic hydrocarbon group has been bonded to the terminal of the linear or branched aliphatic hydrocarbon group or interposed within the aforementioned linear or branched aliphatic hydrocarbon group, can be given. Examples of the linear or branched aliphatic hydrocarbon group include the same groups as described above.

The cyclic aliphatic hydrocarbon group preferably has 3 to 20 carbon atoms, and more preferably 3 to 12 carbon atoms.

The cyclic aliphatic hydrocarbon group may be either a polycyclic group or a monocyclic group. As the monocyclic aliphatic hydrocarbon group, a group in which 2 hydrogen atoms have been removed from a monocycloalkane is preferable. The monocycloalkane preferably has 3 to 6 carbon atoms, and specific examples thereof include cyclopentane and cyclohexane. As the polycyclic aliphatic hydrocarbon group, a group in which two hydrogen atoms have been removed from a polycycloalkane is preferable, and the polycyclic group preferably has 7 to 12 carbon atoms. Examples of the polycycloalkane include adamantane, norbornane, isobornane, tricyclodecane and tetracyclododecane.

The cyclic aliphatic hydrocarbon group may or may not have a substituent (that is, a group or an atom other than hydrogen atom) which substitutes a hydrogen atom in the cyclic aliphatic hydrocarbon group. Examples of substituents include an alkyl group, an alkoxy group, a halogen atom, a halogenated alkyl group, a hydroxyl group and an oxo group (═O).

The alkyl group as a substituent is preferably an alkyl group of 1 to 5 carbon atoms, and a methyl group, an ethyl group, a propyl group, an n-butyl group or a tert-butyl group is most desirable.

The alkoxy group as a substituent is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom as a substituent include a fluorine atom, a chlorine atom, a bromine atom and an iodine atom, and a fluorine atom is preferable.

Examples of the halogenated alkyl group as a substituent include groups in which part or all of the hydrogen atoms within the aforementioned alkyl groups has been substituted with the aforementioned halogen atoms.

Further, part of the carbon atoms constituting the cyclic structure of the cyclic aliphatic hydrocarbon group may be substituted with a hetero atom-containing substituent group. The hetero atom-containing substituent group is preferably —O—, —C(═O)—O—, —S—, —S(═O)₂— or —S(═O)₂—O—.

The aromatic group as a divalent hydrocarbon group is a divalent hydrocarbon group having at least one aromatic ring.

The aromatic ring is not particularly limited as long as it is a cyclic conjugation ring having 4n+2 of π electrons, and may be a monocyclic or a polyciclic. The aromatic ring preferably has 5 to 30 carbon atoms, more preferably 5 to 20, still more preferably 6 to 15, and particularly preferably 6 to 12. Here, the number of carbon atoms within a substituent(s) is not included in the number of carbon atoms of the aromatic hydrocarbon group. Examples of the aromatic ring include aromatic hydrocarbon rings such as benzene, biphenyl, fluorene, naphthalene, anthracene and phenanthrene and aromatic heterocycles in which part of the carbon atoms of the aromatic hydrocarbon ring have been substituted with a hetero atom. Examples of hetero atoms within the aromatic heterocycle include an oxygen atom, a nitrogen atom, and a sulfur atom. Specific examples of aromatic heterocycles include a pyridine ring and a thiophene ring.

Specific examples of the aromatic group include a group in which two hydrogen atoms have been removed from the aromatic hydrocarbon ring or aromatic heterocycle (arylene group or heteroarylene group); a group in which two hydrogen atoms have been removed from an aromatic compound having two or more aromatic rings (for example, biphenyl or fluorene); a group in which one hydrogen atom has been removed from the aromatic hydrocarbon group or aromatic heterocycle (aryl group or heteroaryl group) and another one hydrogen atom has been substituted with an alkylene group (for example, a group in which one hydrogen atom has been removed from an aryl group of an arylalkyl group such as a benzyl group, a phenethyl group, a 1-naphthylmethyl group, a 2-naphthylmethyl group, a 1-naphthylethyl group, or a 2-naphthylethyl group). The alkylene group bonded to the aryl group or heteroaryl group preferably has 1 to 4 carbon atom, more preferably 1 or 2, and most preferably 1.

The aromatic group may or may not have a substituent. For example, the hydrogen atom bonded to the aromatic ring within the aromatic group may be substituted with a substituent. Examples of substituents include an alkyl group, an alkoxy group, a halogen atom, a halogenated alkyl group, a hydroxyl group and an oxo group (═O).

The alkyl group as a substituent is preferably an alkyl group of 1 to 5 carbon atoms, and a methyl group, an ethyl group, a propyl group, an n-butyl group or a tert-butyl group is most desirable.

The alkoxy group as the substituent is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom as the substituent include a fluorine atom, a chlorine atom, a bromine atom and an iodine atom, and a fluorine atom is preferable.

Examples of the halogenated alkyl group for the substituent include groups in which part or all of the hydrogen atoms within the aforementioned alkyl groups has been substituted with the aforementioned halogen atoms.

When Q¹ has an aromatic ring, Q¹ preferably has only one aromatic ring in total. Further, when Q¹ has an aromatic ring, R³, R⁴ and R⁵ preferably have no aromatic ring.

### (Divalent Linking Group Containing a Hetero Atom)

With respect to a divalent linking group containing a hetero atom, a hetero atom is an atom other than carbon and hydrogen, and examples thereof include an oxygen atom, a nitrogen atom, a sulfur atom, a halogen atom or a silicon atom.

Specific examples of the divalent linking group containing a hetero atom include non-hydrocarbon linking groups such as —O—, —C(═O)—, —C(═O)—O—, —S—, —S(═O)₂—, —S(═O)₂—O—, —NH—, —NH—C(═O)—, —NH—C(═NH)—, ═N— and —SiH₂—O—; and a combination of any one of these non-hydrocarbon linking groups with a divalent hydrocarbon group. As examples of the divalent hydrocarbon group, the same groups as those described above for the divalent hydrocarbon group which may have a substituent can be given, and a linear or branched aliphatic hydrocarbon group is preferable.

The hydrogen atom included in —NH— within —C(═O)—NH—, —NH—, —NH—C(═NH)— and —SiH₂—O— may be substituted with a substituent such as an alkyl group or an acyl group. The substituent preferably has 1 to 10 carbon atoms, more preferably 1 to 8 carbon atoms, and most preferably 1 to 5 carbon atoms.

In formulas —Y²¹—O—Y²²—, —[Y²¹—C(═OP)—O]_{m′}—Y²²— and —Y²¹—O—C(═O)—Y²²—, Y²¹ and Y²² each independently represents a divalent linking group which may have a substituent. Examples of the divalent hydrocarbon group include the same groups as those described above for the “divalent hydrocarbon group which may have a substituent”.

As Y²¹, a linear aliphatic hydrocarbon group is preferable, more preferably a linear alkylene group, still more preferably a linear alkylene group of 1 to 5 carbon atoms, and a methylene group or an ethylene group is particularly desirable.

As Y²², a linear or branched aliphatic hydrocarbon group is preferable, and a methylene group, an ethylene group or an alkylmethylene group is more preferable. The alkyl group within the alkylmethylene group is preferably a linear alkyl group of 1 to 5 carbon atoms, more preferably a linear alkyl group of 1 to 3 carbon atoms, and most preferably a methyl group.

In the group —[Y²¹—C(═O)—O]_{m′}—Y²²—, m′ represents an integer of 0 to 3, preferably an integer of 0 or 2, more preferably an integer of 0 to 2, and particularly preferably 1.

Namely, it is particularly desirable that the group represented by the formula —[Y²¹—C(═O)—O]_{m′}—Y²²— is a group represented by the formula —Y²¹—C(═O)—O—Y²²—. Among these, —(CH₂)_{a′}—C(═O)—O—(CH₂)_{b′}— is preferable. In the formula, a′ is an integer of 1 to 10, preferably an integer of 1 to 8, more preferably an integer of 1 to 5, still more preferably 1 or 2, and most preferably 1. b′ is an integer of 1 to 10, preferably an integer of 1 to 8, more preferably an integer of 1 to 5, still more preferably 1 or 2, and most preferably 1.

In the group represented by the formula —[Y²³—O]_{n′}—, as the alkylene group for Y²³, an alkylene group of 1 to 4 is preferable.

In the second aspect of the present invention, as Q¹, a single bond or a divalent linking group containing a hetero atom is preferable, and a single bond, a group represented by formula —Y²¹—O—Y²²—, a group represented by formula —[Y²¹—C(═O)—O]_{m′}—Y²²—, a group represented by formula —C(═O)—O—Y²²— or a group represented by formula (═O)—Y²²— is more preferable, and a group represented by formula —C(═O)—O—Y²²— is particularly preferable.

In the formula (a0-1) Q¹ is a single bond or a divalent linking group.

Examples of the divalent linking group for Q¹ include the same divalent linking groups as those described above for L⁰¹ in the formula (I-1). Among these, a linear or branched alkylene group, a divalent aliphatic cyclic group or a divalent linking group containing a hetero atom is preferable, a linear or branched alkylene group is more preferable, and a linear alkylene group is still more preferable.

In the present invention, Q¹ preferably represents an ester bond [—C(═O)—O—], an ether bond (—O—), an alkylene group, a combination of these, or a single bond.

When Q¹ has an aromatic ring, Q¹ preferably has one aromatic ring in total. When Q¹ has an aromatic ring, R³, R⁴ and R⁵ preferably have no aromatic ring.

In the third aspect of the present invention, Q¹ represents a single bond, —C(═O)—O-Q¹¹- or —C(═O)—N(R^{b})-Q¹¹- is preferable. Q¹¹ represents a single bond or a divalent linking group, and R^{b} represents a hydrogen atom or an alkyl group of 1 to 5 carbon atoms.

As the divalent linking group for Q¹¹, the same as described above can be mentioned. Among these, a linear or branched alkylene group, a divalent aliphatic cyclic group or a divalent linking group containing a hetero atom is more preferable.

As the divalent linking group containing a hetero atom for Q¹¹, a combination of at least one of non-hydrocarbon linking group and a divalent hydrocarbon group is preferable. For example, —Y²¹—O—Y²²—, —[Y²¹—C(═O)—O]_{m′}—Y²²— and —Y²¹—O—C(═O)—Y²²— (provided that Y²¹ and Y²² each independently represents a divalent hydrocarbon group which may have a substituent; O represents an oxygen atom; and m′ represents an integer of 0 to 3) can be mentioned.

In the formula (a0-1), each of R³, R⁴ and R⁵ independently represents an organic group, and R⁴ and R⁵ may be mutually bonded to form a ring with the sulfur atom. Among these, it is preferable that R³ represents a divalent organic group and each of R⁴ and R⁵ independently represents a monovalent organic group.

The organic group for R³, R⁴ and R⁵ refers to a group containing a carbon atom, and may include atoms other than carbon atoms (e.g., a hydrogen atom, an oxygen atom, a nitrogen atom, a sulfur atom, a halogen atom (such as a fluorine atom and a chlorine atom) and the like).

As the organic groups, hydrocarbon groups in which a linking group may be interposed between carbon atoms, and which may have part or all of the hydrogen atoms substituted with a substituent. As examples of the divalent linking group, the same divalent linking group as described above can be mentioned. The organic group may or may not have an aromatic ring.

Provided that —R³—S⁺(R⁴)(R⁵) has one aromatic ring or no aromatic ring in total. When R⁴ and R⁵ are not mutually bonded to form a ring with the sulfur atom, any one of R³, R⁴ and R⁵ is an organic group having one aromatic ring or R³, R⁴ and R⁵ are organic groups having no aromatic ring in total. When R⁴ and R⁵ are mutually bonded to form a ring with the sulfur atom, R³ represents an organic group having no aromatic ring.

When R⁴ and R⁵ are mutually bonded to form a ring with the sulfur atom and the ring is an aliphatic ring (i.e., a ring having no aromaticity), R³ is an organic group having one aromatic ring or an organic group having no aromatic ring. When the ring formed by R⁴ and R⁵ bonded with the sulfur atom contains two or more aromatic ring, the structural unit is not regarded as a structural unit (a0-1).

When EUV is used as an exposure light source, an aromatic ring absorbs OoB light having a wavelength within DUV region. When the total number of the aromatic ring in —R³—S⁺(R⁴)(R⁵) constituted by S⁺ and R³, R⁴ and R⁵ bonded to S⁺ is one or less, the influence of OoB light can be suppressed.

The aromatic ring is not particularly limited as long as it is a cyclic conjugated ring having 4n+2 of π electrons, and the same aromatic ring as those described above in the explanation of the divalent hydrocarbon group. Examples of the aromatic ring include aromatic hydrocarbon rings such as benzene, biphenyl, fluorene, naphthalene, anthracene and phenanthrene and aromatic heterocycles in which part of the carbon atoms of the aromatic hydrocarbon ring have been substituted with a hetero atom. Examples of hetero atoms within the aromatic heterocycle include an oxygen atom, a nitrogen atom, and a sulfur atom. Specific examples of aromatic heterocycles include a pyridine ring and a thiophene ring.

The aromatic ring may have a substituent. Examples of substituents include the same groups as those described above for substituents which the aforementioned aromatic hydrocarbon group may have in the explanation of the divalent hydrocarbon group.

Specific examples of the organic group for R³ include an alkylene group which may have a substituent and an arylene group which may have a substituent. Among these, an alkylene group which may have a substituent is preferable.

Example of the alkylene group which may have a substituent for R³ include an unsubstituted alkylene group and a substituted alkylene group in which part or all of hydrogen atoms of the unsubstituted alkylene group have been substituted with a substituent.

The unsubstituted alkylene group may be any of linear, branched or cyclic. In terms of achieving excellent resolution, an alkylene group of 1 to 10 carbon atoms is preferable, and an alkylene group of 1 to 5 carbon atoms. Specific examples include a methylene group, an ethylene group, an n-propylene group, an isopropylene group, an n-butylene group, an isobutylene group, an n-pentylene group, a cyclopentylene group, a hexylene group, a cyclohexylene group, a nonylene group and a decylene group.

Examples of the substituent of the substituted alkylene group include a halogen atom, an oxo group (═O), a cyano group, an alkyl group, an alkoxyalkyloxy group, an alkoxycarbonylalkyloxy group, —C(═O)—O—R⁷″, —O—C(═O)—R⁸″, —O—R⁹″ and an aryl group. R⁷″, R⁸″ and R⁹″ each independently represents a hydrogen atom or a hydrocarbon group.

Examples of the halogen atom as a substituent include a fluorine atom, a chlorine atom, a bromine atom and an iodine atom, and a fluorine atom is preferable.

The alkyl group as a substituent for unsubstituted alkylene group may be any of linear, branched or cyclic. The number of carbon atoms thereof is preferably 1 to 30.

The linear alkyl group preferably has 1 to 20 carbon atoms, more preferably 13 to 15, and most preferably 1 to 10. Specific examples include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group and a docosyl group.

The branched alkyl group preferably has 3 to 20 carbon atoms, more preferably 3 to 15, and most preferably 3 to 10. Specific examples include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

The cyclic alkyl group may be either a polycyclic group or a monocyclic group. The aliphatic cyclic group preferably has 3 to 30 carbon atoms, more preferably 5 to 30, still more preferably 5 to 20, particularly preferably 6 to 15, and most preferably 6 to 12. As the aliphatic cyclic group, a group in which one or more hydrogen atoms have been removed from a monocycloalkane or a polycycloalkane such as a bicycloalkane, tricycloalkane or tetracycloalkane can be used. Specific examples include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

As the cyclic alkyl group, a polycyclic group is preferable, a group in which one or more hydrogen atoms have been removed from a polycycloalkane is more preferable, and most preferably a group in which one or more hydrogen atoms have been removed from adamantane.

The alkyl group as a substituent is preferably an alkyl group of 1 to 5 carbon atoms, and a methyl group, an ethyl group, a propyl group, an n-butyl group or a tert-butyl group is most desirable.

Examples of the alkoxyalkyloxy group as a substituent for the substituted alkylene group includes: a group represented by general formula —O—C(R⁴⁷)(R⁴⁸)—O—R⁴⁹ [in the formula, each of R⁴⁷ and R⁴⁸ independently represents a hydrogen atom or a linear or branched alkyl group; and R⁴⁹ represents an alkyl group].

The alkyl group for R⁴⁷ and R⁴⁸ preferably has 1 to 5 carbon atoms, and may be either linear or branched, and is preferably an ethyl group or a methyl group, and most preferably a methyl group.

It is preferable that at least one of R⁴⁷ and R⁴⁸ be a hydrogen atom. It is particularly desirable that at least one of R⁴⁷ and R⁴⁸ be a hydrogen atom, and the other be a hydrogen atom or a methyl group.

The alkyl group for R⁴⁹ preferably has 1 to 15 carbon atoms, and may be linear, branched or cyclic.

The linear or branched alkyl group for R⁴⁹ preferably has 1 to 5 carbon atoms. Examples thereof include a methyl group, an ethyl group, a propyl group, an n-butyl group and a tert-butyl group.

The cyclic alkyl group for R⁴⁹ preferably has 4 to 15 carbon atoms, more preferably 4 to 12, and most preferably 5 to 10. Specific examples thereof include groups in which one or more hydrogen atoms have been removed from a monocycloalkane or a polycycloalkane such as a bicycloalkane, tricycloalkane or tetracycloalkane, and which may or may not be substituted with an alkyl group of 1 to 5 carbon atoms, a fluorine atom or a fluorinated alkyl group. Examples of the monocycloalkane include cyclopentane and cyclohexane. Examples of polycycloalkanes include adamantane, norbornane, isobornane, tricyclodecane and tetracyclododecane. Among these, a group in which one or more hydrogen atoms have been removed from adamantane is preferable.

Examples of the alkoxycarbonylalkyloxy group as a substituent for the substituted alkylene group includes: a group represented by general formula —O—R⁵⁰—C(═O)—O—R⁵⁶ [in the formula, R⁵⁰ represents a linear or branched alkylene group; and R⁵⁶ represents a tert-alkyl group].

The linear or branched alkylene group for R⁵⁰ preferably has 1 to 5 carbon atoms, and examples thereof include a methylene group, an ethylene group, a trimethylene group, a tetramethylene group and a 1,1-dimethylethylene group.

The alkyl group for R⁵⁶ is a tertiary alkyl group, and examples thereof include a 2-methyl-2-adamantyl group, a 2-ethyl-2-adamantyl group, a 1-methyl-1-cyclopentyl group, a 1-ethyl-1-cyclopentyl group, a 1-methyl-1-cyclohexyl group, a 1-ethyl-1-cyclohexyl group, a 1-(1-adamantyl)-1-methylethyl group, a 1-(1-adamantyl)-1-methylpropyl group, a 1-(1-adamantyl)-1-methylbutyl group, a 1-(1-adamantyl)-1-methylpentyl group, a 1-(1-cyclopentyl)-1-methylethyl group, a 1-(1-cyclopentyl)-1-methylpropyl group, a 1-(1-cyclopentyl)-1-methylbutyl group, a 1-(1-cyclopentyl)-1-methylpentyl group, a 1-(1-cyclohexyl)-1-methylethyl group, a 1-(1-cyclohexyl)-1-methylpropyl group, a 1-(1-cyclohexyl)-1-methylbutyl group, a 1-(1-cyclohexyl)-1-methylpentyl group, a tert-butyl group, a tert-pentyl group and a tert-hexyl group.

Further, a group in which R⁵⁶ in the group represented by the aforementioned general formula: —O—R⁵⁰—C(═O)—O—R⁵⁶ has been substituted with R⁵⁶′ can also be mentioned. R⁵⁶′ represents a hydrogen atom, an alkyl group, a fluorinated alkyl group or an aliphatic cyclic group which may contain a hetero atom.

The alkyl group for R⁵⁶′ is the same as defined for the alkyl group for the aforementioned R⁴⁹.

Examples of the fluorinated alkyl group for R⁵⁶′ include groups in which part or all of the hydrogen atoms within the alkyl group for R⁴⁹ has been substituted with a fluorine atom.

Examples of the aliphatic cyclic group for R⁵⁶′ which may contain a hetero atom include an aliphatic cyclic group which does not contain a hetero atom, an aliphatic cyclic group containing a hetero atom in the ring structure, and an aliphatic cyclic group in which a hydrogen atom has been substituted with a hetero atom.

As an aliphatic cyclic group for R⁵⁶′ which does not contain a hetero atom, a group in which one or more hydrogen atoms have been removed from a monocycloalkane or a polycycloalkane such as a bicycloalkane, a tricycloalkane or a tetracycloalkane can be mentioned. Examples of the monocycloalkane include cyclopentane and cyclohexane. Examples of polycycloalkanes include adamantane, norbornane, isobornane, tricyclodecane and tetracyclododecane. Among these, a group in which one or more hydrogen atoms have been removed from adamantane is preferable.

Specific examples of the aliphatic cyclic group for R⁵⁶′ containing a hetero atom in the ring structure include groups represented by formulas (L1) to (L5) and (S1) to (S4) described later.

As the aliphatic cyclic group for R⁵⁶′ in which a hydrogen atom has been substituted with a hetero atom, an aliphatic cyclic group in which a hydrogen atom has been substituted with an oxo group (═O) can be mentioned.

As the aliphatic cyclic group for R⁵⁶′ in which a hydrogen atom has been substituted with a hetero atom, an aliphatic cyclic group in which a hydrogen atom has been substituted with an oxo group (═O) can be mentioned.

R⁷″ in —C(═O)—O—R⁷″ represents a hydrogen atom or a hydrocarbon group.

The hydrocarbon group for R⁷″ may be either an aliphatic hydrocarbon group, or an aromatic hydrocarbon group. The aliphatic hydrocarbon group may be either a saturated hydrocarbon group or an aliphatic unsaturated, hydrocarbon group.

Further, the aliphatic group for R⁷″ may be linear, branched or cyclic, or a combination thereof.

The linear or branched aliphatic hydrocarbon group preferably has 1 to 25 carbon atoms, more preferably 1 to 15 carbon atoms, and still more preferably 4 to 10.

Examples of the linear, saturated hydrocarbon group include a methyl group, an ethyl group, a propyl group, a butyl group, a pentyl group, a hexyl group, a heptyl group, an octyl group, a nonyl group and a decyl group.

Examples of branched, saturated hydrocarbon groups include the same tert-alkyl group as described above for R⁵⁶. Examples of the branched, saturated hydrocarbon group other than tert-alkyl group include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

The linear or branched, saturated hydrocarbon group may have a substituent. Examples of the substituent include an alkoxy group, a halogen atom, a halogenated alkyl group, a hydroxyl group, an oxo group (═O), a cyano group and a carboxy group.

The alkoxy group as a substituent for the linear or branched, saturated hydrocarbon group is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom as a substituent for the linear or branched, saturated alkyl group include a fluorine atom, a chlorine atom, a bromine atom and an iodine atom, and a fluorine atom is preferable.

Example of the halogenated alkyl group as a substituent for the linear or branched, saturated hydrocarbon group includes a group in which part or all of the hydrogen atoms within the aforementioned linear or branched, saturated hydrocarbon group have been substituted with the aforementioned halogen atoms.

The cyclic, saturated hydrocarbon group for R⁷″ preferably has 3 to 20 carbon atoms. The cyclic saturated, hydrocarbon group may be either a polycyclic group or a monocyclic group, and examples thereof include groups in which one hydrogen atom has been removed from a monocycloalkane, and groups in which one hydrogen atom has been removed from a polycycloalkane (e.g., a bicycloalkane, a tricycloalkane or a tetracycloalkane). More specific examples include groups in which one hydrogen atom has been removed from a monocycloalkane such as cyclopentane, cyclohexane, cycloheptane or cyclooctane; and groups in which one or more hydrogen atoms have been removed from a polycycloalkane such as adamantane, norbornane, isobornane, tricyclodecane or tetracyclododecane.

The cyclic, saturated hydrocarbon group may have a substituent. For example, part of the carbon atoms constituting the ring within the cyclic alkyl group may be substituted with a hetero atom, or a hydrogen atom bonded to the ring within the cyclic alkyl group may be substituted with a substituent.

In the former example, a heterocycloalkane in which part of the carbon atoms constituting the ring within the aforementioned monocycloalkane or polycycloalkane has been substituted with a hetero atom such as an oxygen atom, a sulfur atom or a nitrogen atom, and one hydrogen atom has been removed therefrom, can be used. Further, the ring may contain an ester bond (—C(═O)—O—) in the ring structure thereof. More specific examples include a lactone-containing monocyclic group, such as a group in which one hydrogen atom has been removed from γ-butyrolactone; and a lactone-containing polycyclic group, such as a group in which one hydrogen atom has been removed from a bicycloalkane, tricycloalkane or tetracycloalkane containing a lactone ring.

In the latter example, as the substituent, the same substituent groups as those for the aforementioned linear or branched alkyl group, or an alkyl group of 1 to 5 carbon atoms can be used.

The aliphatic hydrocarbon group for R⁷″ may be a combination of a linear or branched, saturated alkyl group with a cyclic, saturated alkyl group.

Examples of the combination of a linear or branched, saturated hydrocarbon group with a cyclic, saturated hydrocarbon group include groups in which a cyclic, saturated hydrocarbon group as a substituent is bonded to a linear or branched, saturated hydrocarbon group (e.g., 1-(1-adamantyl)methyl group), and groups in which a linear or branched, saturated hydrocarbon group as a substituent is bonded to a cyclic, saturated hydrocarbon group.

The aliphatic unsubstituted hydrocarbon group for R⁷″ is preferably a linear or branched. Examples of linear, aliphatic unsaturated hydrocarbon groups include a vinyl group, a propenyl group (an allyl group) and a butynyl group. Examples of branched, aliphatic unsaturated hydrocarbon groups include a 1-methylpropenyl group and a 2-methylpropenyl group. The aforementioned linear or branched, aliphatic unsaturated hydrocarbon group may have a substituent. Examples of substituents include the same substituents as those which the aforementioned linear or branched alkyl group may have.

The aromatic hydrocarbon group for R⁷″ is a monovalent hydrocarbon group having at least one aromatic ring, and may have a substituent.

The aromatic ring is not particularly limited as long as it is a cyclic conjugation ring having 4n+2 of π electrons, and may be a monocyclic or a polyciclic. The aromatic ring preferably has 5 to 30 carbon atoms, more preferably 5 to 20, still more preferably 6 to 15, and particularly preferably 6 to 12. Here, the number of carbon atoms within a substituent(s) is not included in the number of carbon atoms of the aromatic hydrocarbon group. Examples of the aromatic ring include aromatic hydrocarbon rings such as benzene, biphenyl, fluorene, naphthalene, anthracene and phenanthrene and aromatic heterocycles in which part of the carbon atoms of the aromatic hydrocarbon ring have been substituted with a hetero atom. Examples of hetero atoms within the aromatic heterocycle include an oxygen atom, a nitrogen atom, and a sulfur atom. Specific examples of aromatic heterocycles include a pyridine ring and a thiophene ring.

Specific examples of the aromatic hydrocarbon group include a group in which one hydrogen atoms have been removed from the aromatic hydrocarbon ring or aromatic heterocycle (aryl group or heteroaryl group); a group in which one hydrogen atom of the aromatic hydrocarbon ring or aromatic heterocycle has been substituted with an alkylene group (arylalkyl groups such as a benzyl group, a phenethyl group, a 1-naphthylmethyl group, a 2-naphthylmethyl group, a 1-naphthylethyl group and a 2-naphthylethyl group and heteroarylalkyl groups). The alkylene group with which a hydrogen atom of the aromatic hydrocarbon ring or aromatic heterocycles has been substituted, preferably has 1 to 4 carbon atom, more preferably 1 or 2, and most preferably 1.

The aromatic hydrocarbon group may or may not have a substituent. In the present invention, the number of the aromatic ring in R³, R⁴ and R⁵ in total is one or less. When the substituent of the substituted alkylene group is —C(═O)—O—R⁷″ in which R⁷″ is an aromatic hydrocarbon group, the substituent for substituting the aromatic hydrocarbon group is a non-aromatic substituent. The term “non-aromatic” means having no aromaticity. As the substituent for substituting non-aromatic group is a group which has no aromatic group (e.g., aromatic hydrocarbon group) in the structure thereof, and examples thereof include an alkyl group, an alkoxy group, a halogen atom, a halogenated alkyl group, a hydroxyl group and an oxo group (═O).

The alkyl group as a substituent is preferably an alkyl group of 1 to 5 carbon atoms, and a methyl group, an ethyl group, a propyl group, an n-butyl group or a tert-butyl group is most desirable.

The alkoxy group as a substituent is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom as a substituent include a fluorine atom, a chlorine atom, a bromine atom and an iodine atom, and a fluorine atom is preferable.

Examples of the halogenated alkyl group as a substituent include groups in which part or all of the hydrogen atoms within the aforementioned alkyl groups has been substituted with the aforementioned halogen atoms.

As R⁷″, in terms of improvement in lithography properties and shape of the resist pattern, a hydrogen atom, an aliphatic hydrocarbon group or an aliphatic unsaturated hydrocarbon group is preferable, and a hydrogen atom, a linear or branched, saturated hydrocarbon group of 1 to 15 carbon atom or a cyclic, saturated hydrocarbon group of 3 to 20 carbon atoms is preferable.

R⁸″ in —O—C(═O)—R⁸″ represents a hydrogen atom or a hydrocarbon group.

As R⁸″, the same groups as those described above for R⁷″ can be used. Among these, in terms of improvement in lithography properties and shape of the resist pattern, a hydrogen atom, an aliphatic hydrocarbon group or an aliphatic unsaturated hydrocarbon group is preferable, and a hydrogen atom, a linear or branched, saturated hydrocarbon group of 1 to 15 carbon atom or a cyclic, saturated hydrocarbon group of 3 to 20 carbon atoms is preferable.

R⁹″ in —O—R⁹″ represents a hydrogen atom or a hydrocarbon group.

As R⁹″, the same groups as those described above for R⁷″ can be used. Among these, in terms of improvement in lithography properties and shape of the resist pattern, a hydrogen atom, an aliphatic hydrocarbon group or an aliphatic unsaturated hydrocarbon group is preferable, and a hydrogen atom, a linear or branched, saturated hydrocarbon group of 1 to 15 carbon atom or a cyclic, saturated hydrocarbon group of 3 to 20 carbon atoms is preferable.

The group represented by the formula —O—R⁹″ as a substituent for substituting the non-aromatic group is preferably a hydroxy group or an alkoxy group having 1 to 5 carbon atoms, and a methoxy group, an ethoxy group, an n-propoxy group, an iso-propoxy group, an n-butoxy group or a tert-butoxy group is most desirable.

The aryl group as a substituent for substituting the substituted alkylene group is preferably an aryl group having 6 to 10 carbon atoms because it can be synthesized at a low cost. Specific examples thereof include a phenyl group and a naphthyl group. In the present invention, the number of the aromatic ring in R³, R⁴ and R⁵ in total is one or less. When R³ is a substituted alkylene group and the substituted alkylene group has an aryl group as a substituent, the number of aryl group as a substituent is one.

The aryl group as a substituent may have a substituent. In the present invention, since the total number of the aromatic ring in R³, R⁴ and R⁵ in total is one or less, the substituent which the aryl group has is a non-aromatic group. The non-aromatic substituent is a group which does not have an aromatic group (e.g., aromatic hydrocarbon group) in the structure thereof, for example, the same groups as those described above for non-aromatic substituents which the aromatic hydrocarbon group for R⁷″may have.

In the formula (a0-1), examples of the arylene group which may have a substituent for R³ include an unsubstituted arylene group of 6 to 20 carbon atoms, a substituted arylene group in which part or all of hydrogen atoms of the unsubstituted arylene group have been substituted with a substituent.

The unsubstituted arylene group is preferably an arylene group of 6 to 10 carbon atoms because it can be synthesized at a low cost. Specific examples thereof include a phenylene group and a naphthylene group.

As the substituent for the substituted arylene group, the same groups as those described above for substituent for the substituted alkylene group can be mentioned. In the present invention, since the total number of the aromatic ring in R³, R⁴ and R⁵ is one or less, when R³ is a substituted arylene group, the substituent which the arylene group has is a non-aromatic group. As the non-aromatic substituent, groups having no aromatic group (e.g., aromatic hydrocarbon group) in the structure thereof can be used. Specific examples of the substituent include a halogen atom, an oxo group (═O), a cyano group, an alkyl group, an alkoxyalkyloxy group, an alkoxycarbonylalkyloxy group, —C(═O)—O—R⁷″, —O—C(═O)—R⁸″, —O—R⁹″ (provided that R⁷″, R⁸″ and R⁹″ each independently represents a hydrogen atom, a saturated hydrocarbon group or an aliphatic unsaturated, hydrocarbon group) as described above for the substituent of substituted alkylene group.

In the formula (a0-1), the organic group for R⁴ and R⁵ is not particularly limited, and examples thereof include an aryl group which may have a substituent, an alkyl group which may have a substituent and an alkenyl group which may have a substituent. Among these, an alkyl group which may have a substituent is preferable.

Examples of the aryl group which may have a substituent for R⁴ and R⁵ include an unsubstituted aryl group of 6 to 20 carbon atoms and a substituted aryl group in which part or all of hydrogen atoms of the unsubstituted alkyl group have been substituted with a substituent.

The unsubstituted aryl group is preferably an aryl group having 6 to 10 carbon atoms because it can be synthesized at a low cost. Specific examples thereof include a phenyl group and a naphthyl group.

As the substituent of the substituted aryl group, non-aromatic substituent can be used. Examples of the non-aromatic substituents include the same groups as those described above for non-aromatic substituents which the substituted arylene group may have.

Examples of the alkyl group for R⁴ and R⁵ include an unsubstituted alkyl group and a substituted alkyl group in which part or all of hydrogen atoms of the unsubstituted alkyl group have been substituted with a substituent.

The unsubstituted alkyl group may be any of linear, branched or cyclic. In terms of achieving excellent resolution, an alkyl group of 1 to 10 carbon atoms is preferable, and an alkyl group of 1 to 5 carbon atoms. Specific examples include a methyl group, an ethyl group, an n-propyl group, an isopropyl group, an n-butyl group, an isobutyl group, an n-pentyl group, a cyclopentyl group, a hexyl group, a cyclohexyl group, a nonyl group and a decyl group.

Examples of the substituent for the substituted alkyl group include the same groups as those described above as the substituent which the substituted alkylene group represented by R³ may have.

Examples of the alkenyl group which may have a substituent for substituting R⁴ and R⁵ include an unsubstituted alkenyl group and a substituted alkenyl group in which part or all of hydrogen atoms of the unsubstituted alkenyl group have been substituted with a substituent.

The unsubstituted alkenyl group is preferably linear or branched. Further, the unsubstituted alkenyl group preferably has 2 to 10 carbon atoms, more preferably 2 to 5, and still more preferably 2 to 4. Specific examples thereof include a vinyl group, a propenyl group (an allyl group), a butynyl group, a 1-methylpropenyl group and a 2-methylpropenyl group.

Examples of the substituent for the substituted alkenyl group include the same groups as those described above as the substituent which the substituted alkylene group represented by R³ may have.

In formula (a0-1), R⁴ and R⁵ may be mutually bonded to form a ring with the sulfur atom. The ring may be saturated or unsaturated. Further, the ring may be monocyclic or polycyclic. For example, when either one or both of the two of R⁴″ to R⁵″ represent a cyclic group (a cyclic alkyl group or an aryl group), a polycyclic ring (fused ring) is formed when the two groups are bonded.

As the ring to be formed, the ring containing the sulfur atom in the skeleton thereof is preferably a 3 to 10-membered ring, and most preferably a 5 to 7-membered ring.

The ring may have a hetero as an atom constituting the ring skeleton other than the sulfur atom having R⁴ and R⁵ bonded thereto. Examples of hetero atoms include an oxygen atom, a nitrogen atom, and a sulfur atom.

Specific examples of the rings to be formed include a thiophene ring, a thiazole ring, a benzothiophene ring, a tetrahydrothiophenium ring and tetrahydrothiopyranium ring.

In the present invention, —R³—S⁺(R⁴)(R⁵) has one aromatic ring or no aromatic ring in total. Among these, all of R³, R⁴ and R⁵ have no aromatic ring or only R³ has one aromatic ring is preferable. When —R³—S⁺(R⁴)(R⁵) has no aromatic ring or has one aromatic ring in total, the acid-generating group having a low level of sensitivity to DUV which is included in OoB light, and having a high level of sensitivity to EUV and EB can be obtained.

When the number of aromatic ring is small, the acid generating group having an excellent transparency and a high sensitivity to ArF.

In formula (a0-1), V⁻ represents a counteranion.

As the counteranion for V⁻, there is no particular limitation, and any of those conventionally known as anion moiety for an onium salt acid generator can be appropriately selected for use.

Examples of V⁻ include an anion moiety represented by general formula “R⁴″SO₃⁻” (wherein R⁴″ represents a linear, branched or cyclic alkyl group, a halogenated alkyl group, an aryl group or an alkenyl group which may have a substituent).

In the general formula “R⁴″SO₃⁻”, R⁴″ represents a linear, branched or cyclic alkyl group, a halogenated alkyl group, an aryl group or an alkenyl group which may have a substituent.

The linear or branched alkyl group for R⁴″ preferably has 1 to 10 carbon atoms, more preferably 1 to 8 carbon atoms, and most preferably 1 to 4 carbon atoms.

The cyclic alkyl group for R⁴″ preferably has 4 to 15 carbon atoms, more preferably 4 to 10, and most preferably 6 to 10.

When R⁴″ represents an alkyl group, examples of “R⁴″SO₃⁻” includes alkylsulfonates such as methanesulfonate, n-propanesulfonate, n-butanesulfonate, n-octanesulfonate, 1-adamantanesulfonate, 2-norbornanesulfonate, and d-camphor-10-sulfonate.

The halogenated alkyl group for R⁴″ is a group in which part of all of the hydrogen atoms in the alkyl group have been substituted with a halogen atom. As the alkyl group, an alkyl group of 1 to 5 carbon atoms is preferred. Among these, a linear or branched alkyl group is preferred, and more preferably a methyl group, an ethyl group, a propyl group, an isopropyl group, an n-butyl group, a tert-butyl group, a tert-pentyl group or an isopentyl group. Examples of the halogen atom which substitutes the hydrogen atoms include a fluorine atom, a chlorine atom, an iodine atom and a bromine atom.

With respect to the halogenated alkyl group, 50 to 100% of the hydrogen atoms in the alkyl group (alkyl group before halogenation) are preferably substituted with the halogen atoms, and all of the hydrogen atoms are more preferably substituted with the halogen atoms.

As the halogenated alkyl group, a fluorinated alkyl group is desirable. The fluorinated alkyl group preferably has 1 to 10 carbon atoms, more preferably 1 to 8 carbon atoms, and most preferably 1 to 4 carbon atoms.

Further, the fluorination ratio of the fluorinated alkyl group is preferably from 10 to 100%, more preferably from 50 to 100%, and it is most preferable that all hydrogen atoms are substituted with fluorine atoms because the acid strength increases.

Specific examples of the fluorinated alkyl group include a trifluoromethyl group, a heptafluoro-n-propyl group and a nonafluoro-n-butyl group.

The aryl group for R⁴″ is preferably an aryl group of 6 to 20 carbon atoms.

The alkenyl group for R⁴″ is preferably an alkenyl group of 2 to 10 carbon atoms.

With respect to R⁴″, the expression “may have a substituent” means that part of or all of the hydrogen atoms within the aforementioned linear, branched or cyclic alkyl group, halogenated alkyl group, aryl group or alkenyl group may be substituted with substituents (atoms other than hydrogen atoms, or groups).

R⁴″ may have one substituent, or two or more substituents.

Examples of the substituent include a halogen atom, a hetero atom, an alkyl group, and a group represented by the formula X³-Q′- (in the formula, Q′ represents a divalent linking group containing an oxygen atom; and X³ represents a hydrocarbon group of 3 to 30 carbon atoms which may have a substituent).

Examples of halogen atoms and alkyl groups include the same halogen atoms and alkyl groups as those described above with respect to the halogenated alkyl group for R⁴″.

Examples of hetero atoms include an oxygen atom, a nitrogen atom, and a sulfur atom.

In the group represented by formula X³-Q′-, Q′ represents a divalent linking group containing an oxygen atom.

Q′ may contain an atom other than an oxygen atom. Examples of atoms other than oxygen include a carbon atom, a hydrogen atom, a sulfur atom and a nitrogen atom.

Examples of divalent linkage groups containing an oxygen atom include non-hydrocarbon, oxygen atom-containing linkage groups such as an oxygen atom (an ether bond; —O—), an ester bond (—C(═O)—O—), an amido bond (—C(═O)—NH—), a carbonyl group (—C(═O)—) and a carbonate group (—O—C(═O)—O—); and a combination of any of the aforementioned non-hydrocarbon, oxygen atom-containing linkage groups with an alkylene group. To the combination, a sulfonyl group (—SO₂—) may further be linked.

Specific examples of the combinations of the aforementioned non-hydrocarbon, oxygen atom-containing linkage groups with anlkylene groups include —R⁹¹—O—, —R⁹²—O—C(═O)—, —C(═O)—O—R⁹³—O—C(═O)—, —SO₂—O—R⁹⁴—O—C(═O)— and —R⁹⁵—SO₂—O—R⁹⁴—O—C(═O)— (in the formulas, R⁹¹ to R⁹⁵ each independently represent an alkylene group.)

The alkylene group for R⁹¹ to R⁹⁵ is preferably a linear or branched alkylene group, and preferably has 1 to 12 carbon atoms, more preferably 1 to 5, and most preferably 1 to 3.

Specific examples of the alkylene group include a methylene group [—CH₂—]; alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—; an ethylene group [—CH₂CH₂—]; alkylethylene groups such as —CH(CH₃)CH₂—, —CH(CH₃)CH(CH₃)—, —C(CH₃)₂CH₂— and —CH(CH₂CH₃)CH₂—; a trimethylene group (n-propylene group) [—CH₂CH₂CH₂—]; alkyltrimethylene groups such as —CH(CH₃)CH₂CH₂— and —CH₂CH(CH₃)CH₂—; a tetramethylene group [—CH₂CH₂CH₂CH₂—]; alkyltetramethylene groups such as —CH(CH₃)CH₂CH₂CH₂— and —CH₂CH(CH₃)CH₂CH₂—; and a pentamethylene group [—CH₂CH₂CH₂CH₂CH₂—].

Q′ is preferably a divalent linking group containing an ester linkage or ether linkage, and more preferably a group of —R⁹¹—O—, —R⁹²—O—C(═O)— or —C(═O)—O—R⁹³—O—C(═O)—.

In the group represented by the formula X³-Q′-, the hydrocarbon group for X³ may be either an aromatic hydrocarbon group or an aliphatic hydrocarbon group.

The aromatic hydrocarbon group is a hydrocarbon group having at least one aromatic ring. The aromatic ring is not particularly limited as long as it is a cyclic conjugation ring having 4n+2 of π electrons, and may be a monocyclic or a polyciclic.

The aromatic hydrocarbon group preferably has 5 to 30, more preferably 5 to 20, particularly preferably 6 to 15, and most preferably 6 to 12. Here, the number of carbon atoms within a substituent(s) is not included in the number of carbon atoms of the aromatic hydrocarbon group. Specific examples of aromatic hydrocarbon groups include an aryl group which is an aromatic hydrocarbon ring having one hydrogen atom removed therefrom, such as a phenyl group, a biphenyl group, a fluorenyl group, a naphthyl group, an anthryl group or a phenanthryl group; and an alkylaryl group such as a benzyl group, a phenethyl group, a 1-naphthylmethyl group, a 2-naphthylmethyl group, a 1-naphthylethyl group, or a 2-naphthylethyl group. The alkyl chain within the arylalkyl group preferably has 1 to 4 carbon atom, more preferably 1 or 2, and particularly preferably 1.

In the aromatic hydrocarbon group, part of the carbon atom constituting the aromatic ring may be substituted with a hetero atom to form an aromatic heterocycle.

Examples of hetero atoms within the aromatic heterocycle include an oxygen atom, a nitrogen atom, and a sulfur atom.

Specific examples of aromatic heterocycles include a pyridine ring and a thiophene ring.

The aromatic hydrocarbon group may have a substituent. For example, part of the carbon atoms constituting the aromatic ring within the aromatic hydrocarbon group may be substituted with a hetero atom, or a hydrogen atom bonded to the aromatic ring within the aromatic hydrocarbon group may be substituted with a substituent.

In the former example, a heteroaryl group in which part of the carbon atoms constituting the ring within the aforementioned aryl group has been substituted with a hetero atom such as an oxygen atom, a sulfur atom or a nitrogen atom, and a heteroarylalkyl group in which part of the carbon atoms constituting the aromatic hydrocarbon ring within the aforementioned arylalkyl group has been substituted with the aforementioned heteroatom can be used.

In the latter example, as the substituent for the aromatic hydrocarbon group, an alkyl group, an alkoxy group, a halogen atom, a halogenated alkyl group, a hydroxy group, an oxygen atom (═O) or the like can be used.

The alkyl group as a substituent for the aromatic hydrocarbon group is preferably an alkyl group of 1 to 5 carbon atoms, and a methyl group, an ethyl group, a propyl group, an n-butyl group or a tert-butyl group is most desirable.

The alkoxy group as a substituent for the aromatic hydrocarbon group is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom as a substituent for the aromatic hydrocarbon group include a fluorine atom, a chlorine atom, a bromine atom and an iodine atom, and a fluorine atom is preferable.

Example of the halogenated alkyl group as a substituent for the aromatic hydrocarbon group includes a group in which part or all of the hydrogen atoms within the aforementioned alkyl group have been substituted with the aforementioned halogen atoms.

When X³ has an aromatic ring, X³ preferably has one aromatic ring in total. Further, when X³ has an aromatic ring, R³, R⁴ and R⁵ preferably have no aromatic ring.

The aliphatic hydrocarbon group for X³ may be either a saturated aliphatic hydrocarbon group, or an unsaturated aliphatic hydrocarbon group. Further, the aliphatic hydrocarbon group may be linear, branched or cyclic.

In the aliphatic hydrocarbon group for X³, part of the carbon atoms constituting the aliphatic hydrocarbon group may be substituted with a substituent group containing a hetero atom, or part or all of the hydrogen atoms constituting the aliphatic hydrocarbon group may be substituted with a substituent group containing a hetero atom.

As the “hetero atom” for X³, there is no particular limitation as long as it is an atom other than carbon and hydrogen. Examples of hetero atoms include a halogen atom, an oxygen atom, a sulfur atom and a nitrogen atom.

Examples of the halogen atom include a fluorine atom, a chlorine atom, an iodine atom and a bromine atom.

The substituent group containing a hetero atom may be a group consisting of a hetero atom, or may be a group containing a group or atom other than a hetero atom.

Specific examples of the substituent group for substituting a part of the carbon atoms include —O—, —C(═O)—O—, —C(═O)—, —O—C(═O)—O—, —C(═O)—NH—, —NH— (wherein the H may be substituted with a substituent such as an alkyl group or an acyl group), —S—, —S(═O)₂— and —S(═O)₂—O—. When the aliphatic hydrocarbon group is cyclic, the aliphatic hydrocarbon group may contain any of these substituent groups in the ring structure.

Examples of the substituent group for substituting part or all of the hydrogen atoms include an alkoxy group, a halogen atom, a halogenated alkyl group, a hydroxy group, an oxygen atom (═O) and a cyano group.

The aforementioned alkoxy group is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the aforementioned halogen atom include a fluorine atom, a chlorine atom, a bromine atom and an iodine atom, and a fluorine atom is preferable.

Example of the aforementioned halogenated alkyl group includes a group in which a part or all of the hydrogen atoms within an alkyl group of 1 to 5 carbon atoms (e.g., a methyl group, an ethyl group, a propyl group, an n-butyl group or a tert-butyl group) have been substituted with the aforementioned halogen atoms.

As the aliphatic hydrocarbon group, a linear or branched saturated hydrocarbon group, a linear or branched monovalent unsaturated hydrocarbon group, or a cyclic aliphatic hydrocarbon group (aliphatic cyclic group) is preferable.

The linear saturated hydrocarbon group (alkyl group) preferably has 1 to 20 carbon atoms, more preferably 1 to 15, and most preferably 1 to 10. Specific examples include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group and a docosyl group.

The branched saturated hydrocarbon group (alkyl group) preferably has 3 to 20 carbon atoms, more preferably 3 to 15, and most preferably 3 to 10. Specific examples include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

The unsaturated hydrocarbon group preferably has 2 to 10 carbon atoms, more preferably 2 to 5, still more preferably 2 to 4, and particularly preferably 3. Examples of linear monovalent unsaturated hydrocarbon groups include a vinyl group, a propenyl group (an allyl group) and a butynyl group. Examples of branched monovalent unsaturated hydrocarbon groups include a 1-methylpropenyl group and a 2-methylpropenyl group.

Among the above-mentioned examples, as the unsaturated hydrocarbon group, a propenyl group is particularly desirable.

The aliphatic cyclic group may be either a monocyclic group or a polycyclic group. The aliphatic cyclic group preferably has 3 to 30 carbon atoms, more preferably 5 to 30, still more preferably 5 to 20, particularly preferably 6 to 15, and most preferably 6 to 12.

As the aliphatic cyclic group, a group in which one or more hydrogen atoms have been removed from a monocycloalkane or a polycycloalkane such as a bicycloalkane, tricycloalkane or tetracycloalkane can be used. Specific examples include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

When the aliphatic cyclic group does not contain a hetero atom-containing substituent group in the ring structure thereof, the aliphatic cyclic group is preferably a polycyclic group, more preferably a group in which one or more hydrogen atoms have been removed from a polycycloalkane, and a group in which one or more hydrogen atoms have been removed from adamantane is particularly desirable.

When the aliphatic cyclic group contains a hetero atom-containing substituent group in the ring structure thereof, the hetero atom-containing substituent group is preferably —O—, —C(═O)—O—, —S—, —S(═O)₂— or —S(═O)₂—O—. Specific examples of such aliphatic cyclic groups include groups represented by formulas (L1) to (L6) and (S1) to (S4) shown below.

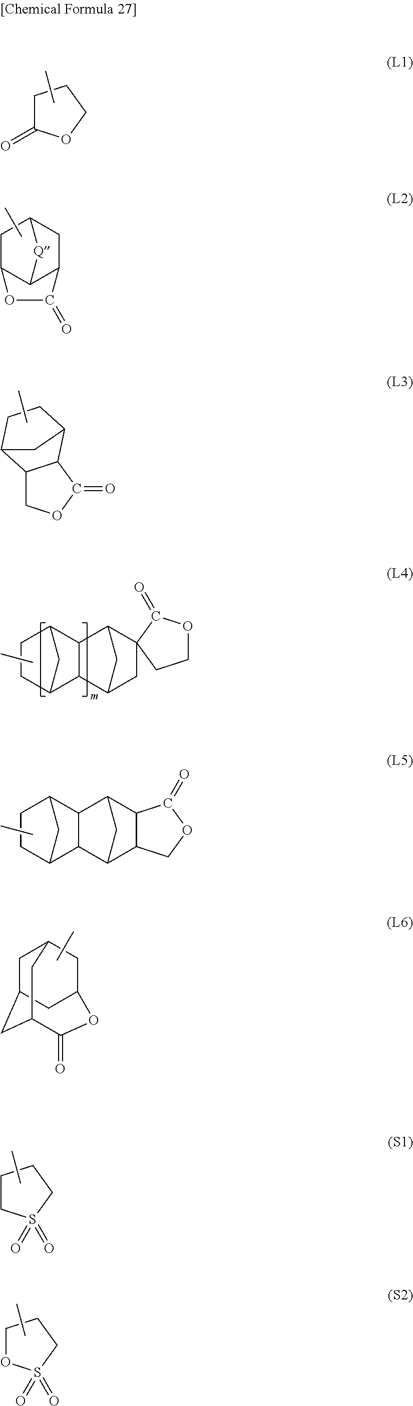

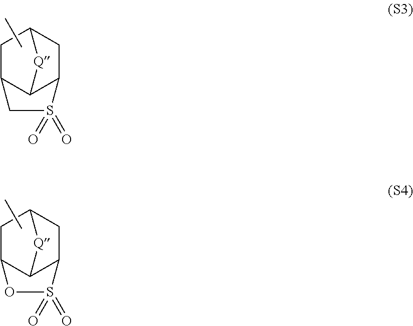

In the formulas, Q″ represents an alkylene group of 1 to 5 carbon atoms, —O—, —S—, —O—R⁹⁴′— or —S—R⁹⁵′—, and R⁹⁴′ and R⁹⁵′ each independently represent an alkylene group of 1 to 5 carbon atoms; and m represents an integer of 0 or 1.

As the alkylene group for Q″, R⁹⁴′ and R⁹⁵′, the same alkylene groups as those described above for R⁹¹ to R⁹⁵ can be used.

In these aliphatic cyclic groups, part of the hydrogen atoms bonded to the carbon atoms constituting the ring structure may be substituted with a substituent. Examples of substituents include an alkyl group, an alkoxy group, a halogen atom, a halogenated alkyl group, a hydroxy group and an oxygen atom (═O).

As the alkyl group, an alkyl group of 1 to 5 carbon atoms is preferable, and a methyl group, an ethyl group, a propyl group, an n-butyl group or a tert-butyl group is particularly desirable.

As the alkoxy group and the halogen atom, the same groups as the substituent groups for substituting part or all of the hydrogen atoms can be used.

In the present invention, as X³, a cyclic group which may have a substituent is preferable. The cyclic group may be either an aromatic hydrocarbon group which may have a substituent, or an aliphatic cyclic group which may have a substituent, and an aliphatic cyclic group which may have a substituent is preferable.

As the aromatic hydrocarbon group, a naphthyl group which may have a substituent, or a phenyl group which may have a substituent is preferable.

As the aliphatic cyclic group which may have a substituent, an aliphatic polycyclic group which may have a substituent is preferable. As the aliphatic polycyclic group, the aforementioned group in which one or more hydrogen atoms have been removed from a polycycloalkane, and groups represented by the formulas (L2) to (L6), (S3) and (S4) are preferable.

Among the above, as R⁴″, a halogenated alkyl group or a group having X³-Q′- as a substituent is preferable.

When the R⁴″ group has X³-Q′- as a substituent, as R⁴″, a group represented by the formula: X³-Q′-Y³— (in the formula, Q′ and X³ are the same as defined above, and Y³ represents an alkylene group of 1 to 4 carbon atoms which may have a substituent or a fluorinated alkylene group of 1 to 4 carbon atoms which may have a substituent is preferable.

In the group represented by the formula X³-Q′-Y³—, as the alkylene group for Y³, the same alkylene group as those described above for Q′ in which the number of carbon atoms is 1 to 4 can be used.

As the fluorinated alkylene group, the aforementioned alkylene group in which part or all of the hydrogen atoms has been substituted with fluorine atoms can be used.

Specific examples of Y³ include —CF₂—, —CF₂CF₂—, —CF₂CF₂CF₂—, —CF(CF₃)CF₂—, —CF(CF₂CF₃)—, —C(CF₃)₂—, —CF₂CF₂CF₂CF₂—, —CF(CF₃)CF₂CF₂—, —CF₂CF(CF₃)CF₂—, —CF(CF₃)CF(CF₃)—, —C(CF₃)₂CF₂—, —CF(CF₂CF₃)CF₂—, —CF(CF₂CF₂CF₃)—, —C(CF₃)(CF₂CF₃)—, —CHF—, —CH₂CF₂—, —CH₂CH₂CF₂—, —CH₂CF₂CF₂—, —CH(CF₃)CH₂—, —CH(CF₂CF₃)—, —C(CH₃)(CF₃)—, —CH₂CH₂CH₂CF₂—, —CH₂CH₂CF₂CF₂—, —CH(CF₃)CH₂CH₂—, —CH₂CH(CF₃)CH₂—, —CH(CF₃)CH(CF₃)—, —C(CF₃)₂CH₂—, —CH₂—, —CH₂CH₂—, —CH₂CH₂CH₂—, —CH(CH₃)CH₂—, —CH(CH₂CH₃)—, —C(CH₃)₂—, —CH₂CH₂CH₂CH₂—, —CH(CH₃)CH₂CH₂—, —CH₂CH(CH₃)CH₂—, —CH(CH₃)CH(CH₃)—, —C(CH₃)₂CH₂—, —CH(CH₂CH₃)CH₂—, —CH(CH₂CH₂CH₃)— and —C(CH₃)(CH₂CH₃)—.

As Y³, a fluorinated alkylene group is preferable, and a fluorinated alkylene group in which the carbon atom bonded to the adjacent sulfur atom is fluorinated is particularly desirable. Examples of such fluorinated alkylene groups include —CF₂—, —CF₂CF₂—, —CF₂CF₂CF₂—, —CF(CF₃)CF₂—, —CF₂CF₂CF₂CF₂—, —CF(CF₃)CF₂CF₂—, —CF₂CF(CF₃)CF₂—, —CF(CF₃)CF(CF₃)—, —C(CF₃)₂CF₂—, —CF(CF₂CF₃)CF₂—, —CH₂CF₂—, —CH₂CH₂CF₂—, —CH₂CF₂CF₂—, —CH₂CH₂CH₂CF₂—, —CH₂CH₂CF₂CF₂— and —CH₂CF₂CF₂CF₂—.

Of these, —CF₂—, —CF₂CF₂—, —CF₂CF₂CF₂— or CH₂CF₂CF₂— is preferable, —CF₂—, —CF₂CF₂— or —CF₂CF₂CF₂— is more preferable, and —CF₂— is particularly desirable.

The alkylene group or fluorinated alkylene group may have a substituent. The alkylene group or fluorinated alkylene group “has a substituent” means that part or all of the hydrogen atoms or fluorine atoms in the alkylene group or fluorinated alkylene group has been substituted with groups or atoms other than hydrogen atoms and fluorine atoms.

Examples of substituents which the alkylene group or fluorinated alkylene group may have include an alkyl group of 1 to 4 carbon atoms, an alkoxy group of 1 to 4 carbon atoms, and a hydroxy group.

Specific examples of groups represented by formula R⁴″SO₃⁻ in which R⁴″ represents X³-Q′-Y³— include anions represented by the following formulae (b1) to (b9).

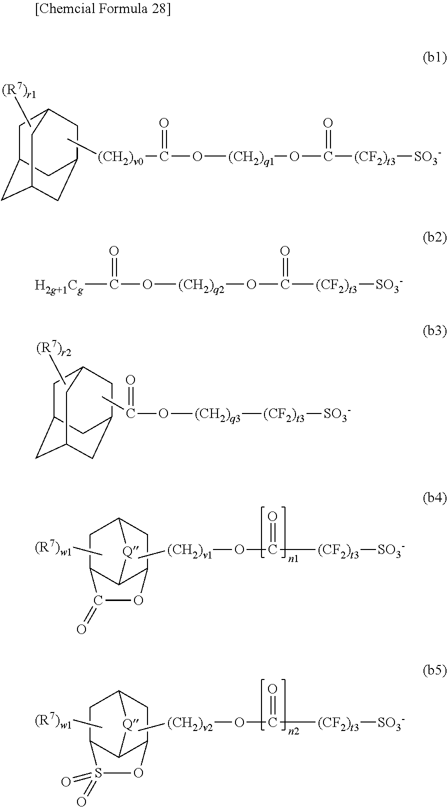

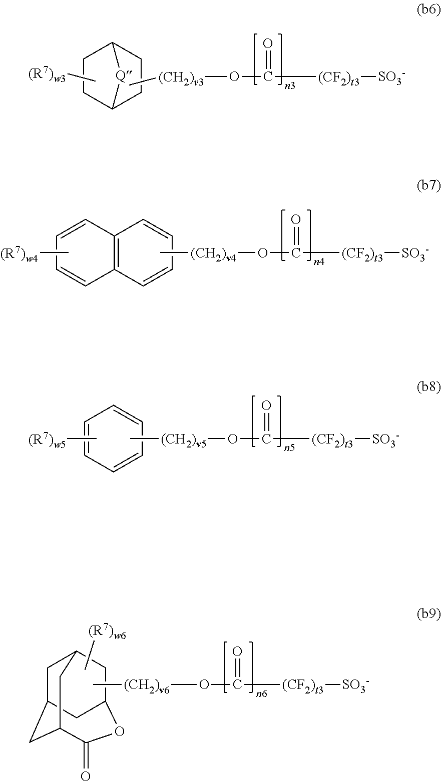

In the formulas, each of q1 and q2 independently represents an integer of 1 to 5; q3 represents an integer of 1 to 12; t3 represents an integer of 1 to 3; each of r1 and r2 independently represents an integer of 0 to 3; g represents an integer of 1 to 20; R⁷ represents a substituent; each of n1 to n6 independently represents 0 or 1; each of v0 to v6 independently represents an integer of 0 to 3; each of w1 to w6 independently represents an integer of 0 to 3; and Q″ is the same as defined above.

Examples of the substituent for substituting R⁷ include the same substituents as those described above for the substituent in the explanation of X³, which may substitute a part of the hydrogen atom bonded to the carbon atom constituting the ring structure within the aliphatic cyclic group, and the substituent which may substitute the hydrogen atom bonded to the aromatic ring within the aromatic hydrocarbon group.

If there are two or more of the R⁷ group, as indicated by the values r1, r2, and w1 to w6 then the two or more of the R⁷ groups may be the same or different from each other.

Moreover, as V⁻ in the formula (a0-1), an anion represented by general formula (b-3) or (b-4), or an anion represented by general formula (b-4) is also preferable.

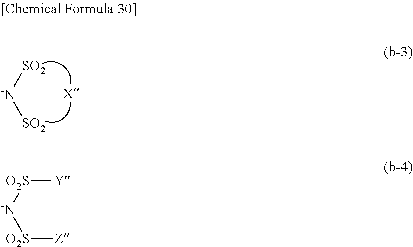

In the formulas, X″ represents an alkylene group of 2 to 6 carbon atoms in which at least one hydrogen atom has been substituted with a fluorine atom; and Y″ and Z″ each independently represents an alkyl group of 1 to 10 carbon atoms in which at least one hydrogen atom has been substituted with a fluorine atom.

In the formula (b-3), X″ represents a linear or branched alkylene group in which at least one hydrogen atom has been substituted with a fluorine atom, and the alkylene group has 2 to 6 carbon atoms, preferably 3 to 5 carbon atoms, and most preferably 3 carbon atoms.

In the formula (b-4), each of Y″ and Z″ independently represents a linear or branched alkyl group in which at least one hydrogen atom has been substituted with a fluorine atom, and the alkyl group has 1 to 10 carbon atoms, preferably 1 to 7 carbon atoms, and most preferably 1 to 3 carbon atoms.

The smaller the number of carbon atoms of the alkylene group for X″ or alkyl group for Y″ and Z″ within the above-mentioned range of the number of carbon atoms is, the more the solubility in a resist solvent is improved.

Further, in the alkylene group for X″ or the alkyl group for Y″ and Z″, the more the number of hydrogen atoms substituted with fluorine atoms is, the more the acid strength is increased, and the transparency to high energy radiation of 200 nm or less or electron beam is improved.

The amount of fluorine atoms within the alkylene group or alkyl group, i.e., fluorination ratio, is preferably from 70 to 100%, more preferably from 90 to 100%, and it is particularly desirable that the alkylene group or alkyl group be a perfluoroalkylene or perfluoroalkyl group in which all hydrogen atoms are substituted with fluorine atoms.

As V⁻ in the formula (a0-1), an anion represented by general formula “R⁴″SO₃⁻” is preferable (in particular, an anion represented by the formulas (b1) to (b9) in which R⁴″ is represented by X³-Q′-Y³—.

A structural unit containing a group represented by the formula (a0-1) (hereafter, referred to as “structural unit (a0-1)”) is not particularly limited as long as it contains a group represented by the general formula (a0-1) in the structure thereof, and a structural unit derived from a compound containing an ethylenic double bond is preferable.

Here, the “structural unit derived from a compound containing an ethylenic double bond” refers to a structural unit in which the ethylenic double bond of the compound containing an ethylenic double bond is cleaved to form a single bond.

Examples of the compound containing an ethylenic double bond include an acrylate or ester thereof which may have the hydrogen atom bonded to the carbon atom on the α-position substituted with a substituent, an acrylamide or derivative thereof which may have the hydrogen atom bonded to the carbon atom on the α-position substituted with a substituent, a vinyl aromatic compound or derivative thereof which may have the hydrogen atom bonded to the carbon atom on the α-position substituted with a substituent, a cycloolefine or derivative thereof, and a vinyl sulfonate ester and the like.

Among these, an acrylic acid or ester thereof which may have the hydrogen atom bonded to the carbon atom on the α-position substituted with a substituent, an acrylamide or derivative thereof which may have the hydrogen atom bonded to the carbon atom on the α-position substituted with a substituent, and a vinyl aromatic compound or derivative thereof which may have the hydrogen atom bonded to the carbon atom on the α-position substituted with a substituent are preferable.

An “acrylate ester” refers to a compound in which the terminal hydrogen atom of the carboxy group of acrylic acid (CH₂═CH—COOH) has been substituted with an organic group.

In the present specification, an acrylic acid and acrylate ester in which the hydrogen atom bonded to the carbon atom on the α position has been substituted with a substituent are referred to as an “α-substituted acrylic acid” and an “α-substituted acrylate ester”, respectively. Further, acrylic acid and α-substituted acrylic acid are collectively referred to as “(α-substituted) acrylic acid”, and acrylate esters and α-substituted acrylate esters are collectively referred to as “(α-substituted) acrylate ester”.

Examples of the substituent bonded to the carbon atom on the α-position of the α-substituted acrylate or ester thereof include an alkyl group of 1 to 5 carbon atoms, a halogenated alkyl group of 1 to 5 carbon atoms and a hydroxyalkyl group. With respect to the structural unit derived from an acrylate ester, the α-position (the carbon atom on the α-position) refers to the carbon atom having the carbonyl group bonded thereto, unless specified otherwise.

Examples of the halogen atom as a substituent at the α-position include a fluorine atom, a chlorine atom, a bromine atom and an iodine atom.

Specific examples of the alkyl group of 1 to 5 carbon atoms as a substituent on the α-position include linear or branched alkyl groups such as a methyl group, an ethyl group, a propyl group, an isopropyl group, an n-butyl group, an isobutyl group, a tert-butyl group, a pentyl group, an isopentyl group, and a neopentyl group.

Specific examples of the halogenated alkyl group of 1 to 5 carbon atoms as a substituent on the α-position include groups in which part or all of the hydrogen atoms of the aforementioned alkyl group of 1 to 5 carbon atoms are substituted with halogen atoms. Examples of the halogen atom include a fluorine atom, a chlorine atom, a bromine atom and an iodine atom, and a fluorine atom is particularly preferred.

As the hydroxyalkyl group as a substituent on the α-position, a hydroxyalkyl group of 1 to 5 carbon atoms is preferred. Specific examples include a group in which part or all of the hydrogen atoms of the aforementioned alkyl group of 1 to 5 carbon atoms are substituted with a hydroxy group.

In the present invention, it is preferable that a hydrogen atom, an alkyl group of 1 to 5 carbon atoms or a halogenated alkyl group of 1 to 5 carbon atoms is bonded to the α-position of the (α-substituted) acrylic acid of ester thereof, a hydrogen atom, an alkyl group of 1 to 5 carbon atoms or a fluorinated alkyl group of 1 to 5 carbon atoms is more preferable, and in terms of industrial availability, a hydrogen atom or a methyl group is the most preferred.

The “organic group” refers to a group containing a carbon atom, and may include atoms other than carbon atoms (e.g., a hydrogen atom, an oxygen atom, a nitrogen atom, a sulfur atom, a halogen atom (such as a fluorine atom and a chlorine atom) and the like).

The organic group in (α-substituted) acrylate ester is not particularly limited. Examples thereof include the aforementioned aromatic group, a characteristic group such as a polarity conversion group and an acid decomposable group, and a characteristic group-containing group which contain the characteristic group in the structure thereof. Examples of the characteristic group-containing group include a group in which a divalent linking group is bonded to the characteristic group. Examples of the divalent linking group include the same divalent linking groups as those described for Q¹ in the general formula (a0-1).

Examples of the “acrylamide and derivative thereof” include an acryl amide which may have the hydrogen atom bonded to the carbon atom on the α-position substituted with a substituent (hereafter, frequently referred to as (α-substituted) acrylamide) and a compound in which one or both of hydrogen atoms at the terminal of the amino group within the (α-substituted) acrylamide have been substituted with a substituent.

As the substituent which may be bonded to the carbon atom on the α-position of an acrylamide or derivatives thereof, the same substituents as those described above for the substituent to be bonded to the carbon atom on the α-position of an α-substituted acrylate ester can be mentioned.

As the substituent with which one or both of hydrogen atoms at the terminal of the amino group within (α-substituted) acrylamide is substituted, an organic group is preferable. The organic group is not particularly limited, and examples thereof include the same groups as described for the organic groups within (α-substituted) acrylate ester.

Examples of the compound in which one or both of hydrogen atom at the terminal of amino group within the (α-substituted) acrylamide have been substituted with a substituent include a compound in which —C(═O)—O— bonded to carbon atom on the α-position of the (α-substituted) acrylate ester is replaced by —C(═O)—N(R^{b})— [in the formula, R^{b} represents a hydrogen atom or an alkyl group of 1 to 5 carbon atoms].

In the formula, the alkyl group for R^{b} is preferably a linear or branched alkyl group.

The “vinyl aromatic compound” is a compound having an aromatic ring and one vinyl group bonded to the aromatic ring, or as the examples thereof, a stylene or derivative thereof and a vinylnaphthalene and derivative thereof can be mentioned.

As the substituent which may be bonded to the carbon atom on the α-position of a vinyl aromatic compound (that is, the carbon atom of the vinyl group, which is bonded to the aromatic ring), the same substituents as those described above for the substituent to be bonded to the carbon atom on the α-position of an α-substituted acrylate ester can be mentioned.

Hereafter, a vinyl aromatic compound in which the hydrogen atom bonded to the carbon atom on the α-position has been substituted with a substituent is frequently referred to as an (α-substituted) vinyl aromatic compound.

Examples of the “styrene and derivative thereof” include a styrene which may have the hydrogen atom bonded to the carbon atom on the α-position substituted with a substituent and may have the hydrogen atom bonded to the benzene ring substituted with a substituent other than the hydroxy group (hereafter, frequently referred to as (α-substituted)styrene), a hydroxystyrene which may have the hydrogen atom bonded to the carbon atom on the α-position substituted with a substituent and may have a hydrogen atom bonded to the benzene ring substituted with a substituent other than a hydroxy group (hereafter, frequently referred to as (α-substituted)hydroxystyrene), a compound in which a hydrogen atom of hydroxy group of (α-substituted)hydroxystyrene is substituted with an organic group, a vinylbenzoic acid which may have the hydrogen atom bonded to the carbon atom on the α-position substituted with a substituent and may have a hydrogen atom bonded to the benzene ring substituted with a substituent other than a hydroxy group and carboxy group (hereafter, frequently referred to as (α-substituted)vinylbenzoic acid), and a compound in which a hydrogen atom of carboxy group of (α-substituted)vinylbenzoic acid is substituted with an organic group.

A hydroxystyrene is a compound which has one vinyl group and at least one hydroxy group bonded to a benzene ring. The number of hydroxy groups bonded to the benzene ring is preferably 1 to 3, and most preferably 1. The bonding position of the hydroxy group on the benzene ring is not particularly limited. When the number of the hydroxy group is 1, para (4th) position against the bonding position of the vinyl group is preferable. When the number of the hydroxy groups is an integer of 2 or more, an arbitrary combination of the bonding positions can be adopted.

The vinylbenzoic acid is a compound in which one vinyl group is bonded to the benzene ring within the benzoic acid.

The bonding position of the vinyl group on the benzene ring is not particularly limited.

The substituent other than a hydroxy group or carboxy group which may be bonded to the benzene ring of an styrene or derivative thereof is not particularly limited, and examples thereof include a halogen atom, an alkyl group of 1 to 5 carbon atoms and a halogenated alkyl group of 1 to 5 carbon atoms. Examples of the halogen atom include a fluorine atom, a chlorine atom, a bromine atom and an iodine atom, and a fluorine atom is particularly preferred.

The organic group within a compound in which the hydrogen atom of the hydroxy group within the (α-substituted) hydroxystyrene is substituted with an organic group is not particularly limited, and examples thereof include the same groups as described for the organic groups within (α-substituted) acrylate ester.

The organic group within a compound in which the hydrogen atom of the carboxy group within the (α-substituted) vinylbenzoic acid is substituted with an organic group is not particularly limited, and examples thereof include the same organic groups as those described for the organic group within (α-substituted) acrylate ester.

Examples of the “vinylnaphthalene and derivative thereof” include a vinylnaphthalene which may have the hydrogen atom bonded to the carbon atom on the α-position substituted with a substituent and may have the hydrogen atom bonded to the naphthalene ring substituted with a substituent other than the hydroxy group (hereafter, frequently referred to as (α-substituted) vinyl naphthalene), a vinyl (hydroxynaphthalene) which may have the hydrogen atom bonded to the carbon atom on the α-position substituted with a substituent and may have a hydrogen atom bonded to the naphthalene ring substituted with a substituent other than a hydroxy group (hereafter, frequently referred to as (α-substituted) vinyl(hydroxynaphthalene) and a compound in which a hydrogen atom of hydroxy group within (α-substituted) vinyl(hydroxynaphthalene) is substituted with a substituent.

A vinyl(hydroxynaphthalene) is a compound which has one vinyl group and at least one hydroxy group bonded to a naphthalene ring. The vinyl group may be bonded to the 1st or 2nd position of the naphthalene ring. The number of hydroxy groups bonded to the naphthalene ring is preferably 1 to 3, and particularly preferably 1. The bonding position of the hydroxy group on the naphthalene ring is not particularly limited. When the vinyl group is bonded to the 1st or 2nd position of the naphthalene ring, the hydroxy group is preferably bonded to either one of the 5th to 8th position of the naphthalene ring. In particular, when the number of hydroxy group is 1, the hydroxy group is preferably bonded to either one of the 5th to 7th position of the naphthalene ring, and more preferably the 5th or 6th position. When the number of the hydroxy groups is an integer of 2 or more, an arbitrary combination of the bonding positions can be adopted.

As the substituent which may be bonded to the naphthanlene ring of the vinylnaphthalene or derivative thereof, the same substituents as those described above for the substituent which may be bonded to the benzene ring of the (α-substituted) styrene can be mentioned.

The organic group within a compound in which the hydrogen atom of the hydroxy group within the (α-substituted) vinyl(hydroxystyrene) is substituted with an organic group is not particularly limited, and examples thereof include the same organic groups as those described for the organic group within (α-substituted) acrylate ester.

Specific examples of the structural unit derived from the (α-substituted) acrylic acid or ester thereof include a structural unit represented by the general formula (U-1) shown below.

Specific examples of the structural unit derived from the (α-substituted) acrylamide or derivative thereof include a structural unit represented by the general formula (U-2) shown below.

Specific examples of the structural unit derived from the (α-substituted) styrene or derivative thereof in the (α-substituted) vinyl aromatic compound include a structural unit represented by the general formula (U-3) shown below. Specific examples of the structural unit derived from the (α-substituted) vinylnaphthalene or derivative thereof include a structural unit represented by the general formula (U-4) shown below.

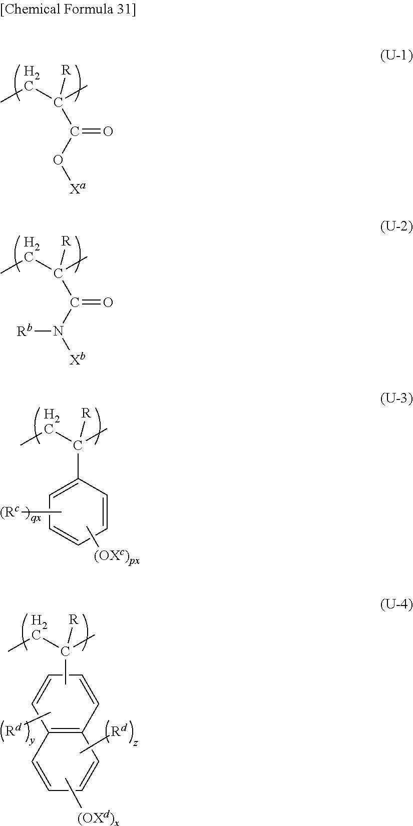

In the formulas, R represents a hydrogen atom, an alkyl group of 1 to 5 carbon atoms or a halogenated alkyl group of 1 to 5 carbon atoms; X^{a} to X^{d} each independently represents a hydrogen atom or an organic group; R^{b} represents a hydrogen atom or an alkyl group of 1 to 5 carbon atoms; R^{c} and R^{d} each independently represents a halogen atom, —COOX^{c} (wherein, X^{c} represents a hydrogen atm or an organic group), an alkyl group of 1 to 5 carbon atoms or a halogenated alkyl group of 1 to 5 carbon atoms; px represents an integer of 0 to 3, and qx represents an integer of 0 to 5, provided that px+qx=0 to 5; and when qx is an integer of 2 or more, the plurality of R^{c} group may be the same or different from each other; and x represents an integer of 0 to 3; y represents an integer of 0 to 3; and z represents an integer of 0 to 4, with the provision that x+y+z=0 to 7, provided that when y+z is an integer of 2 or more, the plurality of R^{d} group may be the same or different from each other.

Specific examples of groups represented by general formula (a0-1) are shown below. In the formulas, V⁻ is the same as defined above.

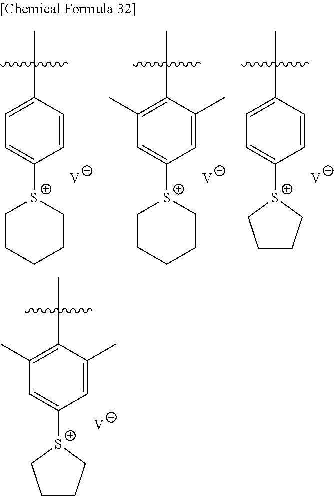

As a structural unit represented by the formula (a0-1) (hereafter, referred to as “structural unit (a0-1)”), a structural unit represented by formula (a0-11) shown below is preferable.

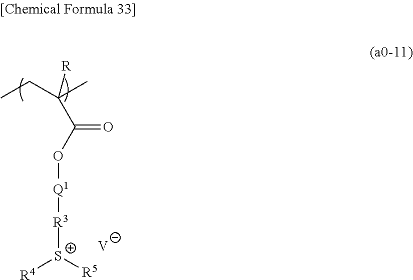

In the formula, R represents a hydrogen atom, an alkyl group of 1 to 5 carbon atoms or a halogenated alkyl group of 1 to 5 carbon atoms; Q¹, R³ to R⁵ and V⁻ are the same as those defined above.

As the alkyl group for R in the formula (a0-11), a linear or branched alkyl group is preferable, and specific examples include a methyl group, an ethyl group, a propyl group, an isopropyl group, an n-butyl group, an isobutyl group, a tert-butyl group, a pentyl group, an isopentyl group and a neopentyl group.

Examples of the halogenated alkyl group for R include groups in which part or all of the hydrogen atoms within the aforementioned alkyl groups for R. Examples of the halogen atom include a fluorine atom, a chlorine atom, a bromine atom and an iodine atom, and a fluorine atom is particularly preferred.

As R, a hydrogen atom, an alkyl group of 1 to 5 carbon atoms or a fluorinated alkyl group of 1 to 5 carbon atoms is preferable, and a hydrogen atom or a methyl group is particularly desirable.

In the formula (a0-11), Q¹, R³ to R^{D} and V⁻ are the same as defined above.

(Structural Unit Represented by General Formula (a0-2))

In the formula (a0-2), Q² is a single bond or a divalent linking group. Examples of the divalent linking group for Q² include the same divalent linking groups as those described above for L⁰¹ in the formula (I-1).

In the third aspect of the present invention, Q² may or may not have an aromatic ring. Provided that, in the formula (a0-2), it is preferable that M^{m+} has one aromatic ring or no aromatic ring, and Q² has one aromatic ring or no aromatic ring. When Q² has one aromatic ring, M^{m+} preferably have no aromatic ring.

In the present invention, Q² preferably represents a single bond, a linear or branched alkylene group, an ester bond [—C(═O)—O—] or a combination of these.

In formula (a0-2), A⁻ represents an organic group containing an anion part.

The A⁻ is not particularly limited as long as it generates acid upon exposure and contains a part which converts into an acid anion. As for A⁻, groups which can generate a sulfonate anion, a carbanion, a carboxylate anion, a sulfonylimide anion, a bis(alkylsulfonyl)imide anion or tris(alkylsulfonyl)methide anion are preferred.

Among these, as A⁻, groups represented by formulas (a0-2-an1) to (a0-2-an4) shown below are preferred.

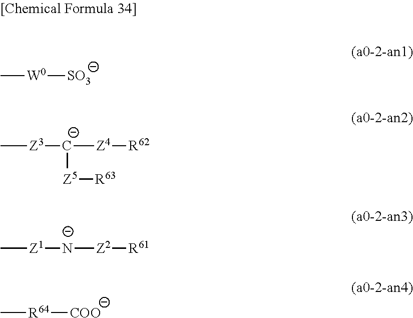

In the formulas, W⁰ is a hydrocarbon group of 1 to 30 carbon atoms which may have a substituent; Z³ represents —C(═O)—O—, —SO₂— or a hydrocarbon group which may have a substituent; and each of Z⁴ and Z⁵ independently represents —C(═O)— or —SO₂—; each of R⁶² and R⁶³ independently represents a hydrocarbon group which may have a fluorine atom; Z¹ represents —C(═O)—, —SO₂—, —C(═O)—O— or a single bond; Z² represents —C(═O)— or —SO₂—; R⁶¹ represents a hydrocarbon group which may have a fluorine atom; and R⁶⁴ represents a hydrocarbon group which may have a fluorine atom.

In the formula (a0-2-an1), W⁰ represents a hydrocarbon group of 1 to 30 carbon atoms which may have a substituent.

The hydrocarbon group of 1 to 30 carbon atoms for W⁰ which may have a substituent may be either an aliphatic hydrocarbon group or an aromatic hydrocarbon group, and the same aliphatic hydrocarbon groups and aromatic hydrocarbon groups as aliphatic hydrocarbon groups and aromatic hydrocarbon groups defined as a divalent linking group for L⁰¹ in the formula (I-1) can be used.

Among these, a group represented by formula (a0-2-an1-1) shown below is preferable.

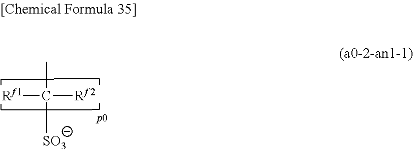

In the formula, each of R^{f1} and R^{f2} independently represents a hydrogen atom, an alkyl group, a fluorine atom or a fluorinated alkyl group, at least one of R^{f1} and R^{f2} represents a fluorine atom or a fluorinated alkyl group; and p0 represents an integer of 1 to 8.

Each of R^{f1} and R^{f2} independently represents a hydrogen atom, an alkyl group, a fluorine atom or a fluorinated alkyl group, and at least one of R^{f1} and R^{f2} represents a fluorine atom or a fluorinated alkyl group.

The alkyl group for R^{f1} and R^{f2} is preferably an alkyl group of 1 to 5 carbon atoms, and specific examples thereof include a methyl group, an ethyl group, a propyl group, an isopropyl group, an n-butyl group, an isobutyl group, a tert-butyl group, a pentyl group, an isopentyl group and a neopentyl group.

The fluorinated alkyl group for R^{f1} and R^{f2} is preferably a group in which part or all of the hydrogen atoms within the aforementioned alkyl group for R^{f1} and R^{f2} have been substituted with a fluorine atom.

Each of R^{f1} and R^{f2} is preferably a fluorine atom or a fluorinated alkyl group.

In formula (0-2-an1-1), p0 represents an integer of 1 to 8, preferably an integer of 1 to 4, and more preferably 1 or 2.

As preferable examples of the hydrocarbon group which may have a substituent for W⁰ exclusive of the group represented by (a0-2-an1-1), an aliphatic cyclic group or an aromatic hydrocarbon group which may have a substituent is preferable, and a group in which two or more hydrogen atoms have been removed from adamantane, norbornane, isobornane, tricyclodecane, tetracyclododecane, camphor or benzene (which may have a substituent) is more preferable.

In formula (a0-2-an2), Z³ represents —C(═O)—O—, —SO₂— or a hydrocarbon group which may have a substituent. As the hydrocarbon group which may have a substituent for Z³, examples thereof include the same divalent hydrocarbon groups which may have a substituent as described in the divalent linking group for L⁰¹ in the formula (I-1). Among these, as Z³, —SO₂— is preferable.

In the formula (a0-2-an2), each of Z⁴ and Z⁵ independently represents —C(═O)— or —SO₂—, at least one of them preferably represents —SO₂—, and both of them more preferably represents —SO₂—.

Each of R⁶² and R⁶³ independently represents a hydrocarbon group which may have a fluorine atom, and the same hydrocarbon group which may have a fluorine atom as those described later for R⁶¹ can be mentioned.

In formula (a0-2-an3), Z¹ represents —C(═O)—, —SO₂—, —C(═O)—O— or a single bond. When Z¹ represents a single bond, it is preferable that N⁻ does not directly bond to —C(═O)— at the other side of the side to which Z² is bonded (that is, at the left terminal of the formula).

In the formula (a0-2-an3), Z² represents —C(═O)— or —SO₂—, and preferably —SO₂—.

R⁶¹ represents a hydrocarbon group which may have a fluorine atom. As the hydrocarbon group for R⁶¹, an alkyl group, a monovalent aliphatic hydrocarbon group, an aryl group and an aralkyl group can be mentioned.

The alkyl group for R⁶¹ preferably has 1 to 8 carbon atoms, more preferably 1 to 6 carbon atoms, and still more preferably 1 to 4 carbon atoms, and may be either linear or branched. Specific examples include a methyl group, an ethyl group, a propyl group, a butyl group, a hexyl group and an octyl group.

The monovalent alicyclic hydrocarbon group for R⁶¹ preferably has 3 to 20 carbon atoms, more preferably 3 to 12 carbon atoms, and may be polycyclic or monocyclic. As the monocyclic alicyclic hydrocarbon group, a group in which one or more hydrogen atoms have been removed from a monocycloalkane is preferable. The monocycloalkane preferably has 3 to 6 carbon atoms, and specific examples thereof include cyclobutane, cyclopentane and cyclohexane. As the polycyclic group, a group in which one or more hydrogen atoms have been removed from a polycycloalkane is preferable, and the polycyclic group preferably has 7 to 12 carbon atoms. Examples of the polycycloalkane include adamantane, norbornane, isobornane, tricyclodecane and tetracyclododecane.

The aryl group for R⁶¹ preferably has 6 to 18 carbon atoms, more preferably 6 to 10 carbon atoms, and a phenyl group is particularly preferable.

As the aralkyl group for R⁶¹, a group in which an alkylene group of 1 to 8 carbon atoms and an aryl group for R⁶¹ are bonded. The aralkyl group in which an alkylene group of 1 to 6 carbon atoms and an aryl group for R⁶¹ are bonded is more preferable, and aralkyl group in which an alkylene group of 1 to 4 carbon atoms and an aryl group for R⁶¹ are bonded is particularly preferable.

The hydrocarbon group for R⁶¹ is preferably a group in which part or all of the hydrogen atoms of the hydrocarbon group is substituted with a fluorine atom, and more preferably a group in which 30 to 100% of the hydrogen atoms of the hydrocarbon group is substituted with a fluorine atom. Among these, a perfluoroalkyl group in which all of the hydrogen atom of the alkyl group are substituted with a fluorine atom is particularly desirable.

In the formula (a0-2-an4), R⁶⁴ represents a hydrocarbon group which may have a fluorine atom. As the hydrocarbon group for R⁶⁴, an alkylene group, a divalent alicyclic hydrocarbon group, a group in which one or more hydrogen atoms have been removed from an aryl group and a group in which one or more hydrogen atom have been removed from an aralkyl group.

Specific examples of the hydrocarbon group for R⁶⁴ include a group in which one or more hydrogen atom have been removed from the same groups as described above for the hydrocarbon groups for R⁶¹ (an alkyl group, a monovalent alicyclic hydrocarbon group, an aryl group and an aralkyl group)

The hydrocarbon group for R⁶⁴ is preferably a group in which part or all of the hydrogen atoms of the hydrocarbon group is substituted with a fluorine atom, and more preferably a group in which 30 to 100% of the hydrogen atoms of the hydrocarbon group is substituted with a fluorine atom.

Among these, in the case where A⁻ is a group represented by the formula (a0-2-an1) and which has a fluorine atom (in particular, a group represented by the formula (a0-2-an1-1)), a group represented by the formula (a0-2-an2) or a group represented by the formula (a0-2-an3) in which Z¹ and Z² represent —SO₂—, the structural unit (a0) generates a relatively strong acid such as a fluorinated alkylsulfonate anion, a carbanion and a sulfonylimide anion upon exposure.

On the other hand, in the case where A⁻ is a group represented by the formula (a0-2-an1) and which does not have a fluorine atom, a group represented by the formula (a0-2-an4) or a group represented by the formula (a0-2-an3) in which Z¹ and Z² represents —C(═O)—, the structural unit (a0) generates a relatively weak acid such as a alkylsulfonate anion, an arylsulfonate anion, a carboxylate anion and an imide anion upon exposure.

As described above, the structural unit (a0) generates acid having a desired acid strength. Therefore, when the polymer containing the structural unit (a0) is used in a resist composition, the function of the acid generated from the structural unit (a0) in the resist composition can be suitably controlled, and A⁻ can also be selected according to the desired function.

For example, when the structural unit (a0) has the same role as an acid generator usually used in a resist composition, it is preferable to select A⁻ which generates a strong acid.

Also, for example, when the structural unit (a0) has the same role as a quencher (quencher to trap a strong acid by salt-exchange reaction with the strong acid which is generated from an acid generator) usually used in a resist composition, it is preferable to select A⁻ which generates a weak acid.

Here, strong acids and weak acids are determined in view of a relationship with the activation energy of the acid decomposable group which is decomposed by the action of acid and which is included in the structural unit (a1) described below and a relationship with the acid strength of the acid generator used in combination with the base component. Therefore, the aforementioned “relatively weak acid” cannot always be used as a quencher.

In the formula (a0-2), M^{m+} represents a countercation, m represents an integer of 1 to 3. Provided that, the organic cation (M^{m+}) has one aromatic ring or no aromatic ring.

As the countercation for M^{m+}, an organic cation is preferable. The organic cation is not particularly limited, and an organic cation conventionally known as the cation moiety of a photo-decomposable base (in the present description, frequently referred to as “photoreactive quencher”) used as a quencher for a resist composition or known as the cation moiety of an onium salt acid generator for a resist composition, which has one aromatic ring or no aromatic ring, can be used. Examples of the organic cation, a cation moiety represented by general formula (m-1) or (m-2) shown below can be used.

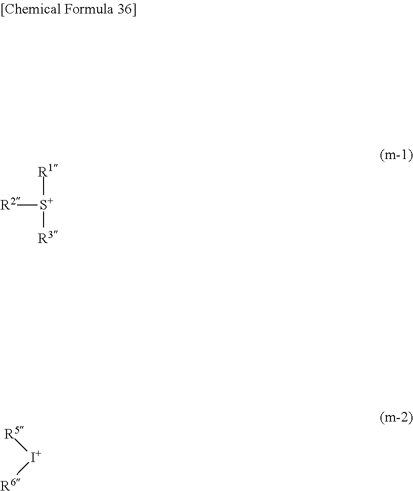

In the formulas, each of R¹″ to R³″ independently represents an aryl group, alkyl group or alkenyl group which may have a substituent; provided that R¹″ to R³″ have one aromatic ring or no aromatic ring in total; two of R¹″ to R³″ may be bonded to each other to form a ring with the sulfur atom; and R⁵″ to R⁶″ each independently represents an aryl group, alkyl group or alkenyl group which may have a substituent, provided that R⁵″ to R⁶″ have one aromatic ring or no aromatic ring in total;

As the aryl group which may have a substituent, alkyl group which may have a substituent or alkenyl group which may have a substituent for R¹″ to R³″ in the formula (m-1), the same aryl group, alkyl group or alkenyl group as those described above for R⁴″ and R⁵″ in the general formula (a0-1) can be mentioned.

Examples of the ring formed by two of R¹″ to R³″ mutually bonded with the sulfur atom in the formula (m-1) include the same ring as those described above for a ring formed by R⁴ to R⁵ mutually bonded with the sulfur atom in the formula (a0-1).

In the formula (m-2), as the aryl group, alkyl group and alkenyl group for R⁵″ and R⁶″, the same aryl groups, alkyl groups and alkenyl groups as those described above for R¹″ to R³″ can be used.

In the formula (m-1), R¹″ to R³″ have one aromatic ring or no aromatic ring in total, and in the formula (m-2), R⁵″ and R⁶″ have one aromatic ring or no aromatic ring in total. When R¹″ to R³″ have no aromatic ring or one aromatic ring, the acid-generating group having a low level of sensitivity to DUV within OoB light, and having a high level of sensitivity to EUV can be obtained.

Among these, as the cation moiety of the formula (a0-2), a cation moiety represented by the formula (m-1) is preferable. As preferable examples of the cation moiety for the compound represented by the formula (m-1), those represented by formulas (m1-1-1) and (m1-1-2) shown below can be given.

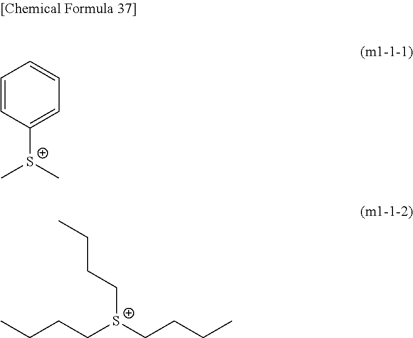

Furthermore, in the cation moiety of the compound represented by the aforementioned formula (m-1), preferable examples of the cation moiety in which two of R¹″ to R³″ are mutually bonded to form a ring with the sulfur atom include cation moieties represented by formulas (m1-3) shown below.

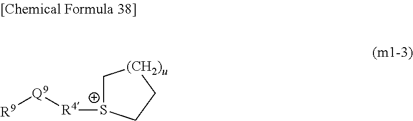

In the formula, R⁹ represents a phenyl group which may have a substituent, a naphthyl group which may have a substituent, an alkyl group of 1 to 5 carbon atoms which may have a substituent, an alkoxy group or a hydroxy group; Q⁹ represents a single bond, —C(═O)—O— or —C(═O)—; R⁴′ represents a single bond or an alkylene group of 1 to 5 carbon atoms; and u represents an integer of 1 to 3.

In the formula (m1-3), R⁹ represents a phenyl group which may have a substituent, a naphthyl group which may have a substituent, an alkyl group of 1 to 5 carbon atoms which may have a substituent, an alkoxy group or a hydroxy group. Examples of the substituent are the same as the substituents described above in relation to the aryl group for R¹″ to R³″ (i.e., an alkyl group, an alkoxy group, an alkoxyalkyloxy group, an alkoxycarbonylalkyloxy group, a halogen atom, a hydroxy group, an oxo group (═O), an aryl group, —C(═O)—O—R⁶″, —O—C(═O)—R⁷″, —O—R⁸″, a group in which R⁵⁶ in the aforementioned general formula —O—R⁵⁰—C(═O)—O—R⁵⁶ has been substituted with R⁵⁶′).

R⁴′ represents an alkylene group of 1 to 5 carbon atoms.

u is an integer of 1 to 3, and most preferably 1 or 2.

As M^{m+}, a cation moiety represented by the general formula (m-1) is preferable, and a cation moiety represented by general formula (m-11), (m-12), (m-13) or (m-14) is more preferable.

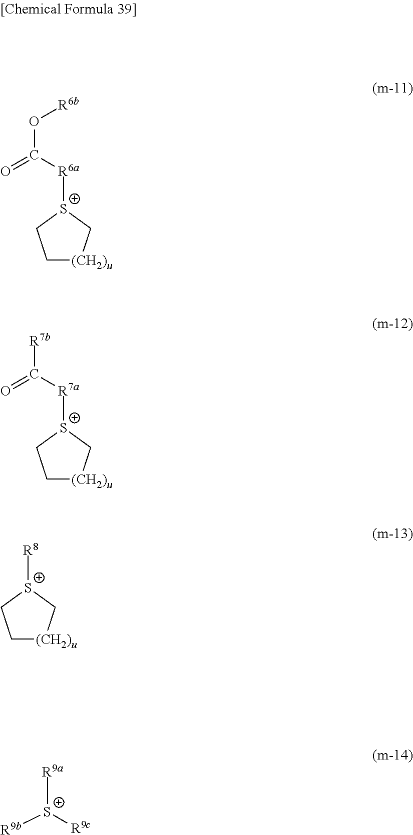

In the formulas, u represents an integer of 1 to 3; R^{6a} represents an alkylene group which may have a substituent; R^{6b} represents a hydrogen atom, an alkyl group which may have a substituent, a phenyl group or a naphthyl group which may have a non-aromatic substituent, provided that R^{6a} and R^{6b} have one aromatic ring or no aromatic ring in total; R^{7a} represents an alkylene group which may have a substituent; R^{7b} represents an alkyl group which may have a non-aromatic substituent, a phenyl group or a naphthyl group which may have a substituent; provided that R^{7a} and R^{7b} have one aromatic ring or no aromatic ring in total; R⁸ represents an alkyl group which may have a substituent, a phenyl group or a naphthyl group which may have a non-aromatic substituent, provided that R⁸ have one aromatic ring or no aromatic ring; and R^{9a} to R^{9c} each independently represents an alkyl group which may have a substituent, a phenyl group or a naphthyl group which may have a non-aromatic substituent, provided that R^{9a} to R^{9c} have one aromatic ring or no aromatic ring in total.

In the formulas, u is an integer of 1 to 3, and most preferably 1 or 2.

As the alkylene group for R^{6a} and R^{7a}, a linear or branched alkylene group is preferable. The alkylene group preferably has 1 to 12 carbon atoms, more preferably 1 to 5 carbon atoms, and most preferably 1 to 3 carbon atoms.

Examples of the substituent which the alkylene group may have include the same groups as those described above for substituents in substituted alkylene group for R³ (e.g., a halogen atom, an oxo group (═O), a cyano group, an alkyl group, an alkoxyalkyloxy group, an alkoxycarbonylalkyloxy group, —C(═O)—O—R⁷″, —O—C(═O)—R⁸″, —O—R⁹″ and an aryl group).

As the alkyl group which may have a substituent for substituting R^{6b}, R^{7b}, R⁸ and R^{9a} to R^{9c}, the same alkyl group as those described above for R⁴ and R⁵ in the general formula (a0-1) can be mentioned.

As the non-aromatic substituent which a phenyl group or a naphthyl group for R^{6b}, R^{7b}, R⁸ and R^{9a} to R^{9c} may have, the same groups as those described above for substituent which the substituted aryl group for R⁴ and R⁵ in the general formula (a0-1) may have can be mentioned.

Preferable examples of the cation represented by the general formulas (m-1) and (m1-3) are shown below.

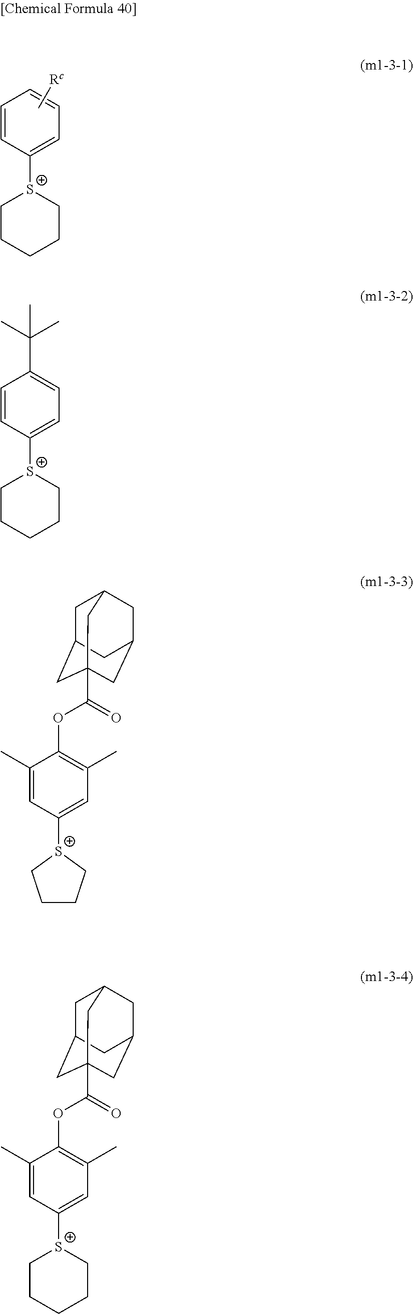

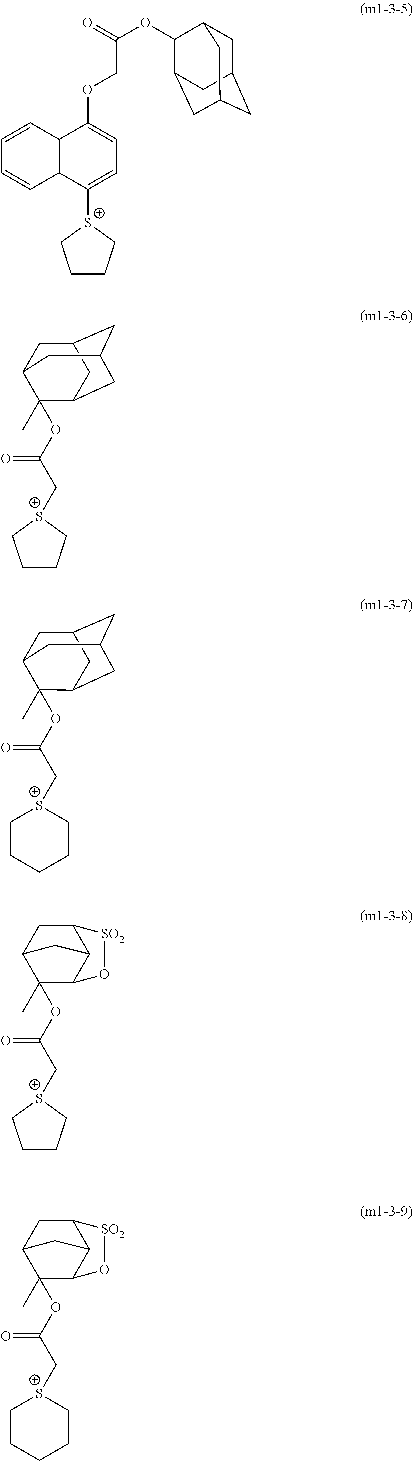

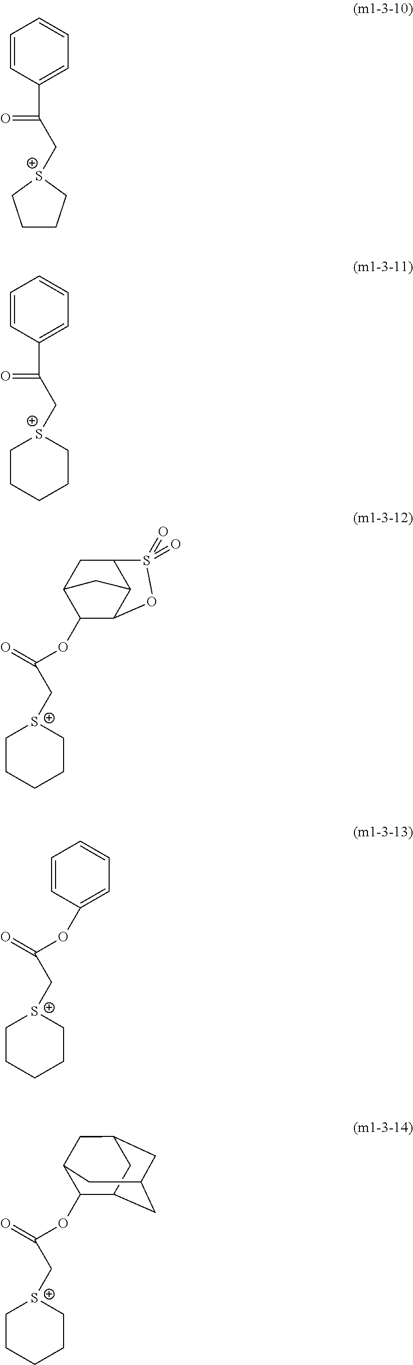

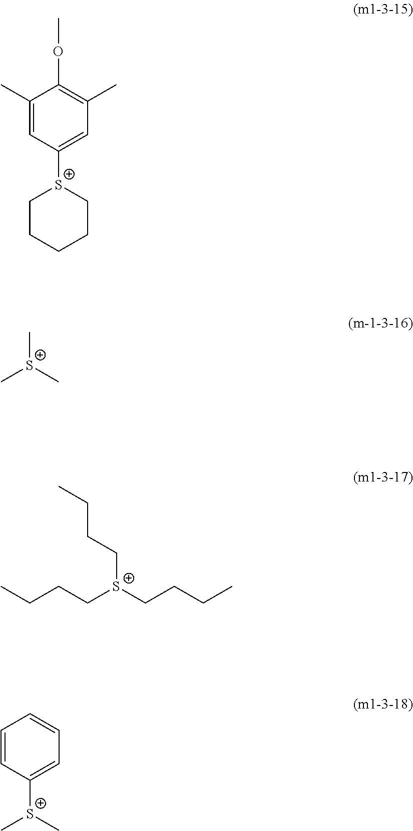

In formula (m1-3-1), R^{C} represents a substituent. Examples of the substituent include the same substituents as those described above in relation to the substituted aryl group (i.e., an alkyl group, an alkoxy group, an alkoxyalkyloxy group, an alkoxycarbonylalkyloxy group, a halogen atom, a hydroxy group, an oxo group (═O), an aryl group, —C(═O)—O—R⁶″, —O—C(═O)—R⁷″ and —O—R⁸″).

In the first aspect of the present invention, as the structural unit containing a group represented by the formula (a0-2) (hereafter, referred to as “structural unit (a0-2)”), at least one structural unit selected from the group consisting of structural units represented by formulas (a0-2-11) to (a0-2-14), (a0-2-21) to (a0-2-25), (a0-2-31) to (a0-2-32) and (a0-2-41) to (a0-2-44) shown below is desirable.

Among these, as the structural units represented by the formulas (a0-2-11) to (a0-2-14) shown below, structural units represented by formulas (a0-2-11-1) to (a0-2-13-1) shown below are preferable.

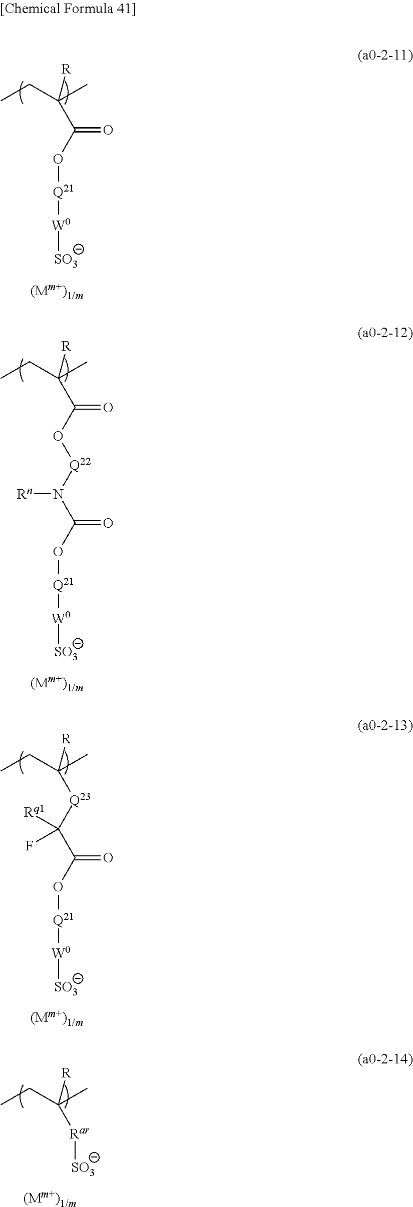

In the formulas, R, Q²¹, to Q²³, W⁰, R^{q1} and (M^{m+})_{l/m} are the same as defined above; R^{ar} represents a divalent aromatic group which may have a substituent, which is the same groups as those described above for R^{ar} in relation to the component (W); and Rⁿ represents a hydrogen atom or an alkyl group of 1 to 5 carbon atoms.

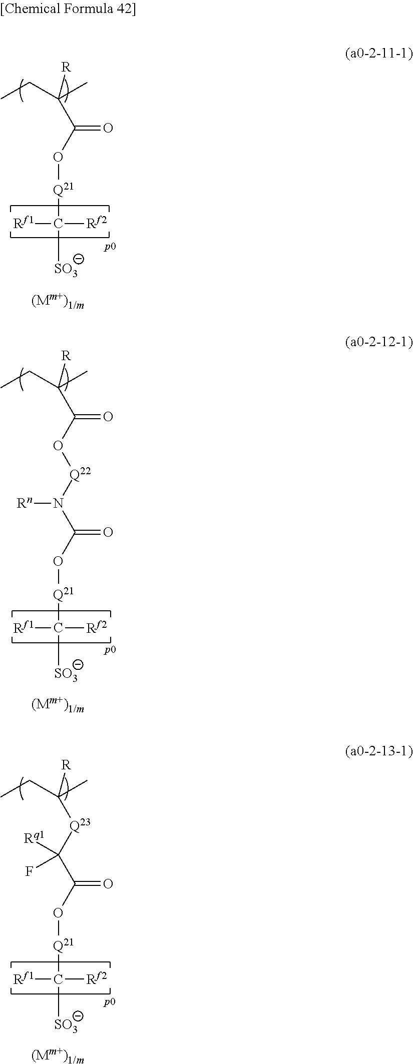

In the formulas, R, R^{f1}, R^{f2}, p0, Rⁿ and (M^{m+})_{l/m} are the same as defined above; Q²¹ each independently a single bond or a divalent linking group; Q²² represents a divalent linking group; Q²³ represents —O—, —CH₂—O— or a group containing —C(═O)—O—; and R^{q1} represents fluorine atom or a fluorinated alkyl group.

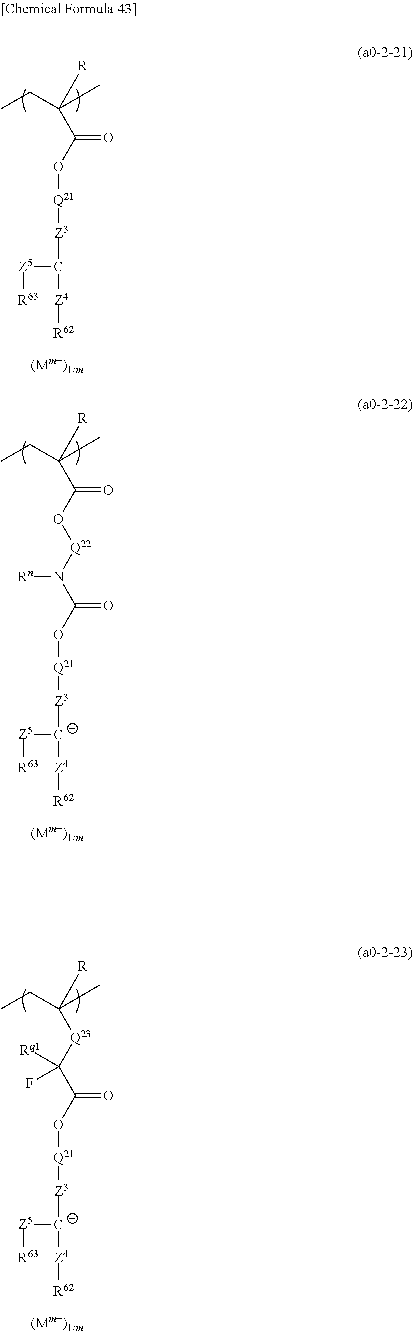

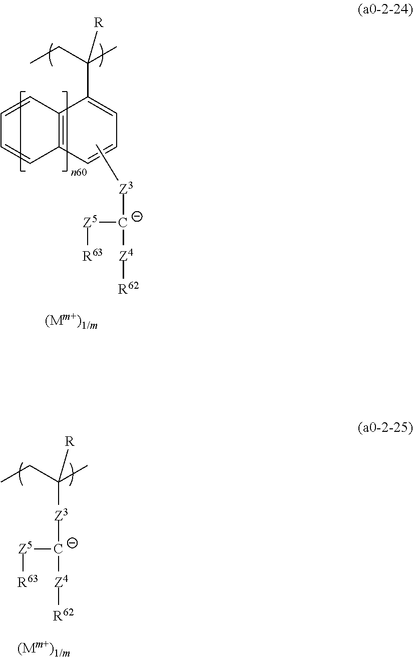

In the formulas, R, Q²¹ to Q²³, Z³ to Z⁵, R⁶² to R⁶³, Rⁿ, R^{q1} and (M^{m+})_{l/m} are the same as defined above; and n60 represents an integer of 0 to 3.

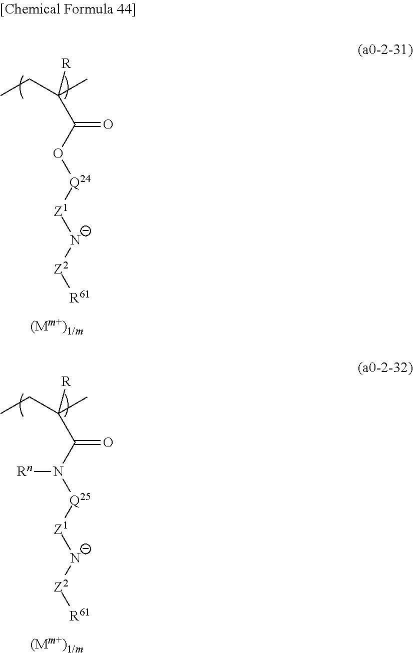

In the formulas, R, Z¹ to Z², Wand (M^{m+})_{l/m} are the same as defined above; and Q²⁴ and Q²⁵ each independently represents a single bond or a divalent linking group.

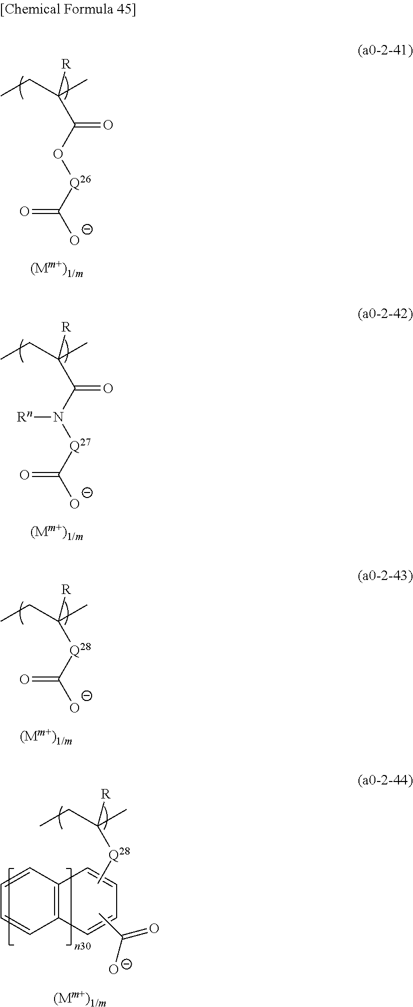

In the formulas, R, Rⁿ and (M^{m+})_{l/m} are the same as defined above; Q²⁶ to Q²⁸ each independently represents a single bond or a divalent linking group; and n30 represents an integer of 0 to 3.

In the formulas (a0-2-11) to (a0-2-14), R, W⁰, R^{q1} and R^{ar}(M^{m+})_{l/m} are the same as defined above.

Q²¹ represents a single bond or a divalent linking group. Examples of the divalent linking group for Q²¹ include the same divalent linking groups as those described above for L⁰¹ in the formula (I-1). In particular, as Q²¹, the same linear or branched alkylene group, a cyclic aliphatic hydrocarbon group, aromatic hydrocarbon group or divalent linking group containing a hetero atom is preferable; a linear or branched alkylene group, a combination of a linear or branched alkylene group with a divalent linking group containing a hetero atom, a combination of a cyclic aliphatic hydrocarbon group with a divalent linking group containing a hetero atom or a combination of an aromatic hydrocarbon group with a divalent linking group containing a hetero atom is more preferable; a linear or branched alkylene group, a combination of a linear or branched alkylene group with an ester bond [—C(═O)—O—] or a combination of a divalent alicyclic hydrocarbon group with an ester bond [—C(═O)—O—] is particularly preferable; and a linear or branched alkylene group, or a combination of a linear or branched alkylene group with an ester bond [—C(═O)—O—] is most preferable.

In formula (a0-2-12), Q²² represents a divalent linking group, and examples thereof include the same divalent linking groups as those described above for L⁰¹ in the aforementioned formula (I-1). Among these, a linear or branched alkylene group, a cyclic aliphatic hydrocarbon group or a divalent aromatic hydrocarbon group for W is preferable, a linear alkylene group is more preferable, and a methylene group or ethylene group is most preferable.

In the formula (a0-2-12), Rⁿ represents a hydrogen atom or an alkyl group of 1 to 5 carbon atoms. As the alkyl group of 1 to 5 carbon atoms, the same alkyl groups of 1 to 5 carbon atoms as those described above for R can be used. As Rⁿ, a hydrogen atom or a methyl group is preferable.

In the formula (a0-2-13), Q²³ represents a group containing —O—, —CH₂—O— or —C(═O)—O—.

Specific examples of Q²³ include a group consisting of —O—, —CH₂—O— or —C(═O)—O—; and a group consisting of a divalent hydrocarbon group which may have a substituent and any one of —O—, —CH₂—O— or —C(═O)—O—.

As the divalent hydrocarbon group which may have a substituent, examples thereof include the same divalent hydrocarbon groups which may have a substituent as described above in relation to the divalent linking group for L⁰¹ in the formula (I-1). Among these examples, as the “divalent hydrocarbon group” for Q¹, an aliphatic hydrocarbon group is preferable, and a linear or branched alkylene group is more preferable.

Q²³ is preferably a group consisting of —C(═O)—O— and a divalent hydrocarbon group which may have a substituent, more preferably a group consisting of —C(═O)—O— and an aliphatic hydrocarbon group, and most preferably a group consisting of —C(═O)—O— and a linear or branched alkylene group.

As a specific example of a preferable group for Q²³, a group represented by general formula (Q²³-1) shown below can be given.

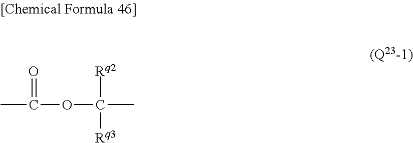

In general formula (Q²³-1), each of R^{q2} and R^{q3} independently represents a hydrogen atom, an alkyl group or a fluorinated alkyl group, wherein R^{q2} and R^{q3} may be mutually bonded to form a ring.

In the formula (Q²³-1), the alkyl group for R^{q2} and R^{q3} may be linear, branched or cyclic, and is preferably linear or branched.

The linear or branched alkyl group is preferably a linear or branched alkyl group of 1 to 5 carbon atoms, more preferably a methyl group or an ethyl group, and most preferably an ethyl group.

The cyclic alkyl group preferably has 4 to 15 carbon atoms, more preferably 4 to 12, and most preferably 5 to 10. Specific examples include groups in which one or more hydrogen atoms have been removed from a monocycloalkane or a polycycloalkane such as a bicycloalkane, tricycloalkane or tetracycloalkane. Specific examples include groups in which one or more hydrogen atoms have been removed from a monocycloalkane such as cyclopentane and cyclohexane; and groups in which one or more hydrogen atoms have been removed from a polycycloalkane such as adamantane, norbornane, isobornane, dicyclodecane, tricyclodecane or tetracyclododecane. Among these examples, a group in which one or more hydrogen atoms have been removed from adamantane is preferable.

The fluorinated alkyl group for R^{q2} and R^{q3} is an alkyl group in which part or all of the hydrogen atoms have been substituted with a fluorine atom.

In the fluorinated alkyl group, the alkyl group prior to being substituted with a fluorine atom may be linear, branched or cyclic, and examples thereof include the same groups as those described above for the alkyl group represented by R^{q2} and R^{q3}.

R^{q2} and R^{q3} may be mutually bonded to form a ring. Such a ring constituted of R^{q2} and R^{q3} and the carbon atom having R^{q2} and R^{q3} bonded thereto can be mentioned as a group in which two hydrogen atoms have been removed from a monocycloalkane or a polycycloalkane described above for the aforementioned cyclic alkyl group, preferably a 4- to 10-membered ring, and more preferably a 5- to 7-membered ring.

Among these examples, R^{q2} and R^{q3} preferably represent a hydrogen atom or an alkyl group.

In the formula (a0-2-13), R^{q1} represents a fluorine atom or a fluorinated alkyl group.

With respect to the fluorinated alkyl group for R^{q1}, the alkyl group prior to being fluorinated may be linear, branched or cyclic.

The linear or branched alkyl group preferably has 1 to 5 carbon atoms, more preferably 1 to 3 carbon atoms, and most preferably 1 or 2 carbon atoms.

The cyclic alkyl group preferably has 4 to 15 carbon atoms, more preferably 4 to 12, and still more preferably 5 to 10. Specific examples include groups in which one or more hydrogen atoms have been removed from a monocycloalkane or a polycycloalkane such as a bicycloalkane, tricycloalkane or tetracycloalkane. Specific examples include groups in which one or more hydrogen atoms have been removed from a monocycloalkane such as cyclopentane and cyclohexane; and groups in which one or more hydrogen atoms have been removed from a polycycloalkane such as adamantane, norbornane, isobornane, dicyclodecane, tricyclodecane or tetracyclododecane.

In the fluorinated alkyl group, the percentage of the number of fluorine atoms based on the total number of hydrogen atoms and fluorine atoms (fluorination ratio (%)) is preferably 30 to 100%, and more preferably 50 to 100%. The higher the fluorination ratio is, the higher the hydrophobicity of the resist film becomes.

Among these, as R^{q1}, a fluorine atom is preferable.

In the formulas (a0-2-11-1) to (a0-2-13-1), R, Q²¹ to Q²³, R^{f1}, R^{f2}, p0, Rⁿ and (M^{m+})_{l/m}) are the same as defined above.

In the formulas (a0-2-21) to (a0-2-25), R, Q²¹ to Q²³, Z³ to Z⁵, R⁶² and R⁶³, Rⁿ, R^{q1} and (M^{m+})_{l/m} are the same as defined above.

In general formula (a0-2-24), n60 represents an integer of 0 to 3, preferably 0 or 1.

In the formulas (a0-2-31) and (a0-2-32), R, Z¹, Z², Rⁿ and (M^{m+})_{l/m} are the same as defined above; Q²⁴ and Q²⁵ each independently represents a single bond or a divalent linking group.

Examples of the divalent linking group for Q²⁴ and Q²⁵ include the same divalent linking groups as those described above for L⁰¹ in the formula (I-1). As described above, when Z¹ represents a single bond, the terminal of Q²⁴ and Q²⁵ bonded to Z¹ is not preferably —C(═O)—. As the divalent linking group for Q²⁴ and Q²⁵, a linear or branched alkylene group, a cyclic aliphatic hydrocarbon group or a divalent linking group containing a hetero atom is particularly desirable. Among these, a linear or branched alkylene group and a cyclic aliphatic hydrocarbon group are preferable, and a linear alkylene group and a cyclic aliphatic hydrocarbon group are more preferable.

In the formulas (a0-2-41) to (a0-2-44) R, R″ and (M^{m+})_{l/m} are the same as defined above, and Q²⁶ to Q²⁸ each independently represents a single bond or a divalent linking group. Q²⁶ to Q²⁸ are the same as Q²⁴ and Q²⁵.

In general formula (a0-2-44), n30 represents an integer of 0 to 3, preferably 0 or 1.

In the second aspect of the present invention, as the structural unit containing a group represented by the formula (a0-2), a structural unit represented by the formula (a0-21′) shown below is preferable.

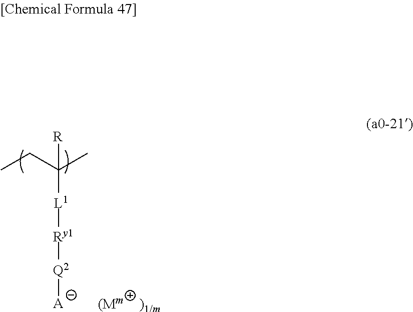

In the formula, R, Q², M^{m+} and m are the same as defined above; L¹ represents —O—, —C(═O)—O—, —C(═O)—NH— or a single bond; R^{y1} is a single bond or a divalent aromatic group which may have a substituent. The divalent hydrocarbon group which may have a substituent is the same groups as those described above for Q¹, and an alkylene group, a cycloalkylene group, a fluorinated alkylene group, a phenylene group, a naphthylene group or a combination thereof is preferable.

Q² is the same as defined above.

In the formula (a0-21′), A⁻ represents an organic group containing an anion moiety.

The A⁻ is not particularly limited as long as it contains a part which converts into an acid anion upon exposure. As for A⁻, groups which can generate a sulfonate anion, a carbanion, a carboxylate anion, an imide anion or a sulfonylmethide anion are preferred.

Among these, as A⁻, groups represented by formulas (a0-22-an1) to (a0-22-an4) shown below are preferred.

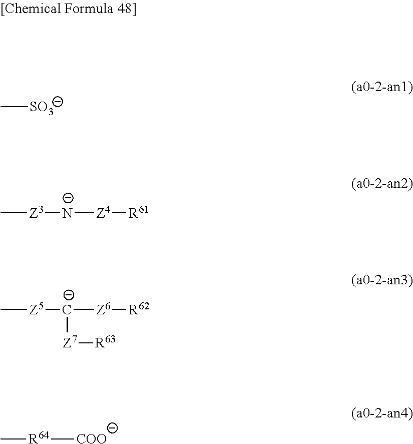

Z³, Z⁴, Z⁶ and Z⁷ each independently represents —C(═O)— or —SO₂—; Z⁵ represents —C(═O)—, —SO₂— or a single bond; R⁶¹ represents a hydrocarbon group which may have a fluorine atom; and R⁶², R⁶³ and R⁶⁴ each independently represents a hydrocarbon group which may have a fluorine atom.

In the formula (a0-22-an2) R⁶¹ represents a hydrocarbon group which may have a fluorine atom. As the hydrocarbon group for R⁶¹, an alkyl group, a monovalent alicyclic hydrocarbon group, an aryl group and an aralkyl group can be mentioned.

The alkyl group for R⁶¹ preferably has 1 to 8 carbon atoms, more preferably 1 to 6 carbon atoms, and still more preferably 1 to 4 carbon atoms, and may be either linear or branched. Specific examples include a methyl group, an ethyl group, a propyl group, a butyl group, a hexyl group and an octyl group.

The monovalent alicyclic hydrocarbon group for R⁶¹ preferably has 3 to 20 carbon atoms, more preferably 3 to 12 carbon atoms, and may be polycyclic or, monocyclic. As the monocyclic alicyclic hydrocarbon group, a group in which one or more hydrogen atoms have been removed from a monocycloalkane is preferable. The monocycloalkane preferably has 3 to 6 carbon atoms, and specific examples thereof include cyclobutane, cyclopentane and cyclohexane. As the polycyclic group, a group in which one or more hydrogen atoms have been removed from a polycycloalkane is preferable, and the polycyclic group preferably has 7 to 12 carbon atoms. Examples of the polycycloalkane include adamantane, norbornane, isobornane, tricyclodecane and tetracyclododecane.

The aryl group for R⁶¹ preferably has 6 to 18 carbon atoms, more preferably 6 to 10 carbon atoms, and a phenyl group is particularly preferable.

As the aralkyl group for R⁶¹, a group in which an alkylene group of 1 to 8 carbon atoms and an aryl group for R⁶¹ are bonded can be mentioned. An aralkyl group in which an alkylene group of 1 to 6 carbon atoms and an aryl group for R⁶¹ are bonded is more preferable, and aralkyl group in which an alkylene group of 1 to 4 carbon atoms and an aryl group for R⁶¹ are bonded is particularly preferable.

The hydrocarbon group for R⁶¹ is preferably a group in which part or all of the hydrogen atoms of the hydrocarbon group is substituted with a fluorine atom, and more preferably a group in which 30 to 100% of the hydrogen atoms of the hydrocarbon group is substituted with a fluorine atom. Among these, a perfluoroalkyl group in which all of the hydrogen atom of the alkyl group are substituted with a fluorine atom is particularly desirable.

In the formula (a0-22-an3), R⁶² and R⁶³ each independently represents a hydrocarbon group which may have a fluorine atom, and examples thereof include the same hydrocarbon group which may have a fluorine atom as those described above for R⁶¹.

In the formula (a0-2), M^{m+} represents a countercation, m represents an integer of 1 to 3.

As the countercation for M^{m+}, an organic cation is preferable. The organic cation is not particularly limited, and an organic cation conventionally known as the cation moiety of a photo-decomposable base used as a quencher for a resist composition or the cation moiety of an onium salt acid generator for a resist composition can be used. Examples of the organic cation, a cation moiety represented by the general formula (m-1) or (m-2) can be used.

In the third aspect of the present invention, a structural unit containing a group represented by the formula (a0-2) (hereafter, referred to as “structural unit (a0-2)”) is not particularly limited as long as it contains a group represented by the general formula (a0-2) in the structure thereof, and a structural unit which is derived from a compound containing an ethylenic double bond and which contains a group represented by the formula (a0-2) is preferable, and a structural unit represented by general formula (a0-21) shown below is particularly preferable.

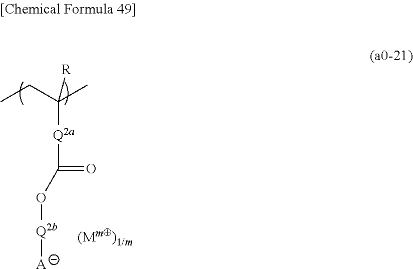

In the formula, R represents a hydrogen atom, an alkyl group of 1 to 5 carbon atoms or a halogenated alkyl group of 1 to 5 carbon atoms; Q^{2a} represents a single bond or a divalent linking group; Q^{2b} represents a single bond or a divalent linking group; A⁻ represents an organic group containing an anion moiety; M^{m+} represents a m-valent organic cation; and m represents an integer of 1 to 3, provided that M^{m+} has one aromatic ring or no aromatic ring.

In general formula (a0-21), R is the same as defined for R in general formula (a0-11).

A− and (M^{m+})_{l/m} are the same as defined above for A⁻ and (M^{m+})_{l/m} in the formula (a0-2).

Examples of the divalent linking group for Q^{2a} include the same divalent linking groups as those described for Q¹ in the general formula (a0-1).

Among these, as Q^{2a}, a single bond, —C(═O)-Q²²-N(Rⁿ)— or -Q²³-CF(R^{q1})— is preferable.

In the group represented by formula —C(═O)-Q²²-N(Rⁿ), Q²² represents a divalent linking group, Rⁿ represents a hydrogen atom or an alkyl group of 1 to 5 carbon atoms.

In the group represented by formula -Q²³-CF(R^{q1})—, Q²³ represents a group containing —O—, —CH₂—O— or —C(═O)—O—, R^{q1} represents a fluorine atom or a fluorinated alkyl group.

In the group represented by formula —C(═O)-Q²²-N(Rⁿ)—, as the divalent linking group for Q²², the same divalent linking group as described above for Q¹ in the formula (a0-1) can be mentioned. Among these, a linear or branched alkylene group, a cyclic aliphatic hydrocarbon group or a divalent aromatic hydrocarbon group is preferable, a linear alkylene group is more preferable, and a methylene group or ethylene group is most preferable.

As the alkyl group of 1 to 5 carbon atoms for Rⁿ, the same alkyl groups of 1 to 5 carbon atoms as those described above for R can be used. As Rⁿ, a hydrogen atom or a methyl group is preferable.

In the group represented by formula -Q²³-CF(R^{q1})—, specific examples of Q²³ include a group consisting of —O—, —CH₂—O— or —C(═O)—O—; and a group consisting of any one of —O—, —CH₂—O— or —C(═O)—O— and a divalent hydrocarbon group which may have a substituent.

As the divalent hydrocarbon group which may have a substituent, examples thereof include the same divalent hydrocarbon groups which may have a substituent as described above in relation to the divalent linking group for Q¹ in the formula (a0-1). Among these examples, as the “divalent hydrocarbon group” for Q²³, an aliphatic hydrocarbon group is preferable, and a linear or branched alkylene group is more preferable.

Q²³ is preferably a group consisting of —C(═O)—O— and a divalent hydrocarbon group which may have a substituent, more preferably a group consisting of —C(═O)—O— and an aliphatic hydrocarbon group, and most preferably a group consisting of —C(═O)—O— and a linear or branched alkylene group.

As a specific example of a preferable group for Q²³, a group represented by general formula (Q²³-1) shown below can be given.

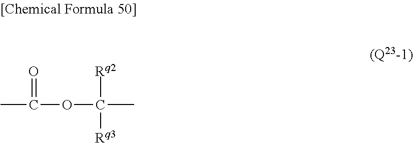

In general formula (Q²³-1), each of R^{q2} and R^{q3} independently represents a hydrogen atom, an alkyl group or a fluorinated alkyl group, wherein R^{q2} and R^{q3} may be mutually bonded to form a ring.

In the formula (Q²³-1), the alkyl group for R^{q2} and R^{q3} may be linear, branched or cyclic, and is preferably linear or branched.

The linear or branched alkyl group is preferably a linear or branched alkyl group of 1 to 5 carbon atoms, more preferably a methyl group or an ethyl group, and most preferably an ethyl group.

The cyclic alkyl group preferably has 4 to 15 carbon atoms, more preferably 4 to 12, and most preferably 5 to 10. Specific examples include groups in which one or more hydrogen atoms have been removed from a monocycloalkane or a polycycloalkane such as a bicycloalkane, tricycloalkane or tetracycloalkane. Specific examples include groups in which one or more hydrogen atoms have been removed from a monocycloalkane such as cyclopentane and cyclohexane; and groups in which one or more hydrogen atoms have been removed from a polycycloalkane such as adamantane, norbornane, isobornane, dicyclodecane, tricyclodecane or tetracyclododecane. Among these examples, a group in which one or more hydrogen atoms have been removed from adamantane is preferable.

The fluorinated alkyl group for R^{q2} and R^{q3} is an alkyl group in which part or all of the hydrogen atoms have been substituted with a fluorine atom.

In the fluorinated alkyl group, the alkyl group prior to being substituted with a fluorine atom may be linear, branched or cyclic, and examples thereof include the same groups as those described above for the alkyl group represented by R^{q2} and R^{q3}.

R^{q2} and R^{q3} may be mutually bonded to form a ring. Such a ring constituted of R^{q2}, R^{q3} and the carbon atom having R^{q2} and R^{q3} bonded thereto can be mentioned as a group in which two hydrogen atoms have been removed from a monocycloalkane or a polycycloalkane described above for the aforementioned cyclic alkyl group, preferably a 4- to 10-membered ring, and more preferably a 5- to 7-membered ring.

Among these examples, R^{q2} and R^{q3} preferably represent a hydrogen atom or an alkyl group.

In the group represented by formula -Q²³-CF(R^{q1})—, with respect to the fluorinated alkyl group for R^{q1}, the alkyl group prior to being fluorinated may be linear, branched or cyclic.

The linear or branched alkyl group preferably has 1 to 5 carbon atoms, more preferably 1 to 3 carbon atoms, and most preferably 1 or 2 carbon atoms.

The cyclic alkyl group preferably has 4 to 15 carbon atoms, more preferably 4 to 12, and still more preferably 5 to 10. Specific examples include groups in which one or more hydrogen atoms have been removed from a monocycloalkane or a polycycloalkane such as a bicycloalkane, tricycloalkane or tetracycloalkane. Specific examples include groups in which one or more hydrogen atoms have been removed from a monocycloalkane such as cyclopentane and cyclohexane; and groups in which one or more hydrogen atoms have been removed from a polycycloalkane such as adamantane, norbornane, isobornane, dicyclodecane, tricyclodecane or tetracyclododecane.

In the fluorinated alkyl group, the percentage of the number of fluorine atoms based on the total number of hydrogen atoms and fluorine atoms (fluorination ratio (%)) is preferably 30 to 100%, and more preferably 50 to 100%. The higher the fluorination ratio is, the higher the hydrophobicity of the resist film becomes.

Among these, as R^{q1}, a fluorine atom is preferable.

In the formula (a0-21), examples of the divalent linking group for Q^{2b} include the same divalent linking group as those described above for Q¹ in the formula (a0-1). In particular, as Q^{2b}, the same linear or branched alkylene group, cyclic aliphatic hydrocarbon group, aromatic hydrocarbon group or divalent linking group containing a hetero atom is preferable; a linear or branched alkylene group, a combination of a linear or branched alkylene group with a divalent linking group containing a hetero atom, a combination of a cyclic aliphatic hydrocarbon group with a divalent linking group containing a hetero atom or a combination of an aromatic hydrocarbon group with a divalent linking group containing a hetero atom is more preferable; a linear or branched alkylene group, a combination of a linear or branched alkylene group with an ester bond [—C(═O)—O—] or a combination of a divalent alicyclic hydrocarbon group with an ester bond [—C(═O)—O—] is particularly preferable; and a linear or branched alkylene group, or a combination of a linear or branched alkylene group with an ester bond [—C(═O)—O—] is most preferable.

In the third aspect of the present invention, as the structural unit (a0-2), at least one structural unit selected from the group consisting of structural units represented by the formulas (a0-2-11) to (a0-2-13), (a0-2-21) to (a0-2-25), (a0-2-31) to (a0-2-32) and (a0-2-41) to (a0-2-44) is preferable.

Among these, as the structural units represented by the formulas (a0-2-11) to (a0-2-13), structural units represented by the formulas (a0-2-11-1) to (a0-2-13-1) are preferable.

Specific examples of groups represented by general formulas (a0-2) and (a0-21′) are shown below. In the formulas shown below, R^{α} represents a hydrogen atom, a methyl group or a trifluoromethyl group, and (M^{m+})_{l/m} is the same as defined above.

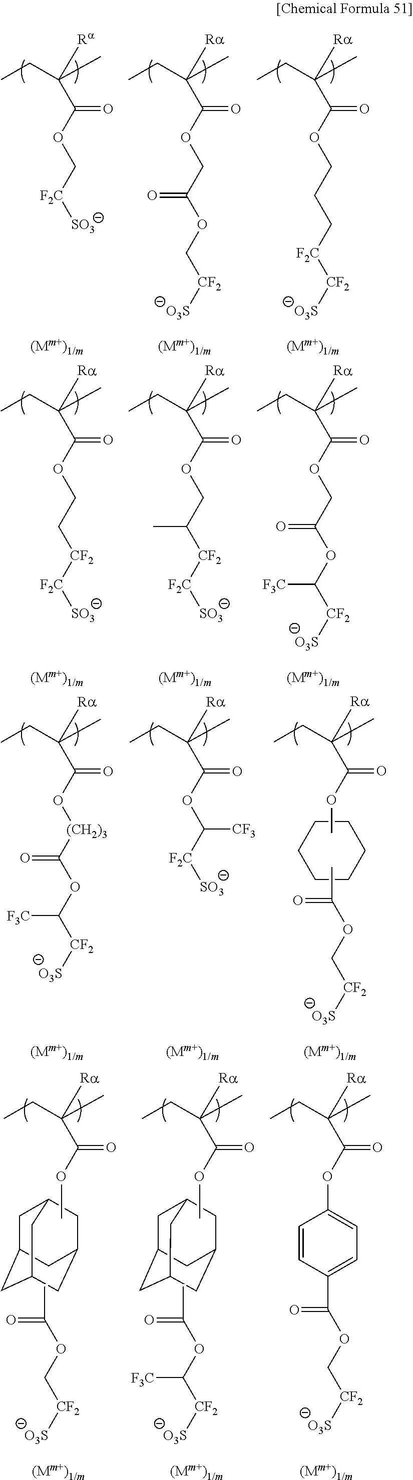

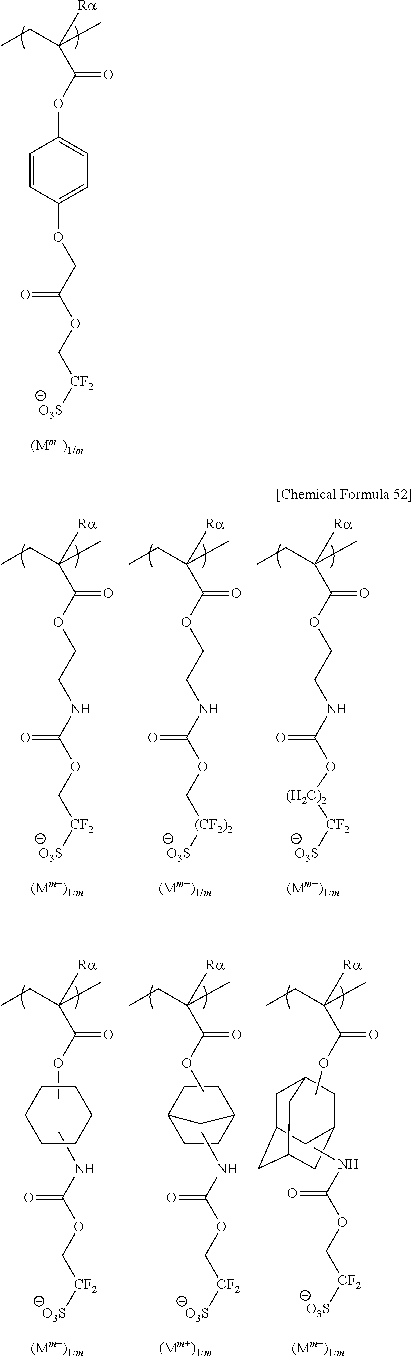

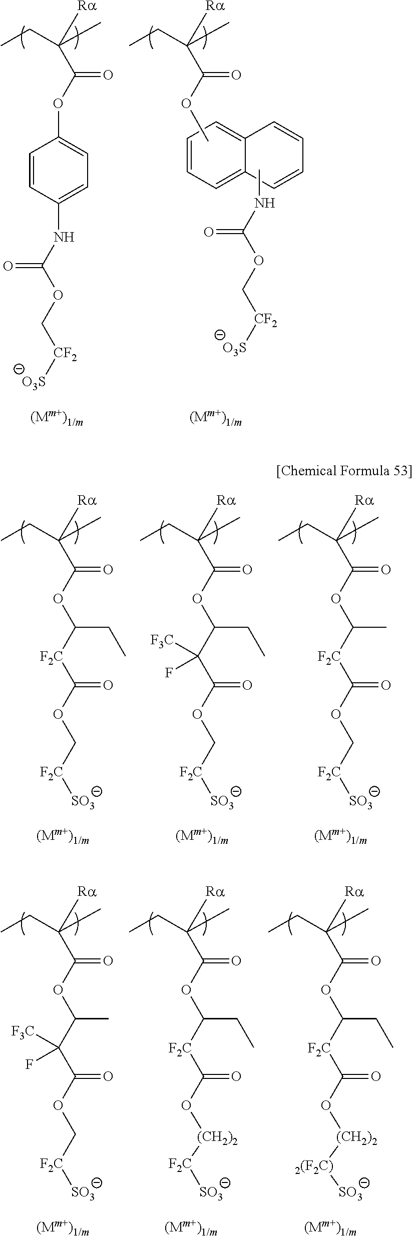

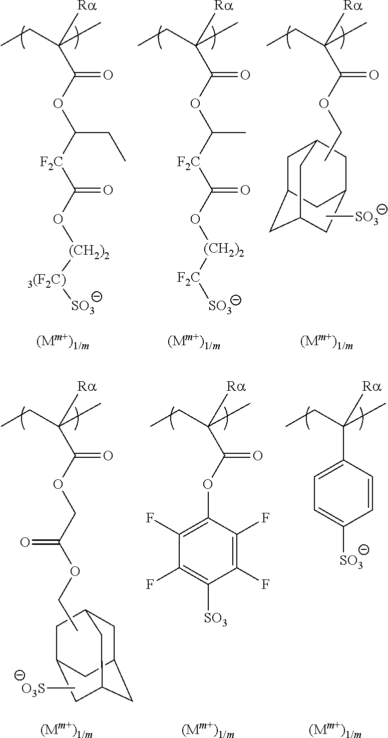

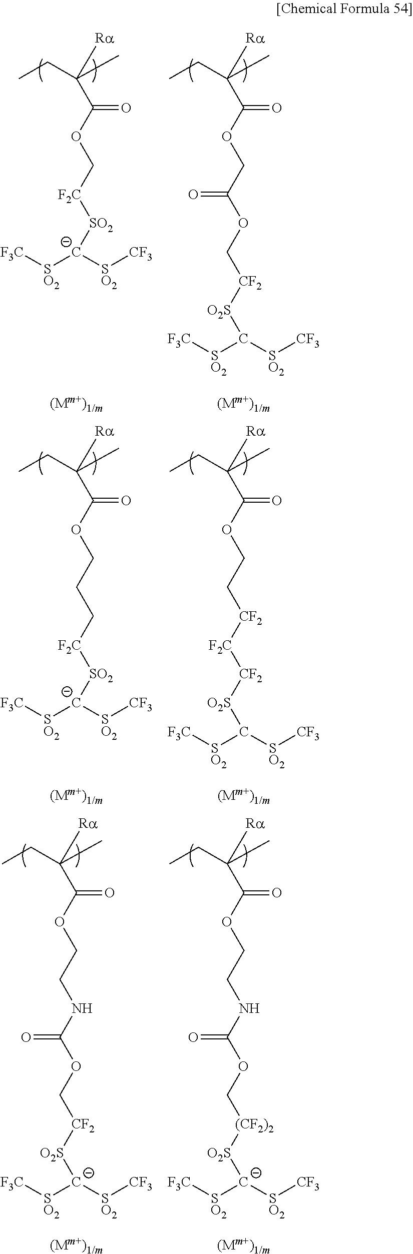

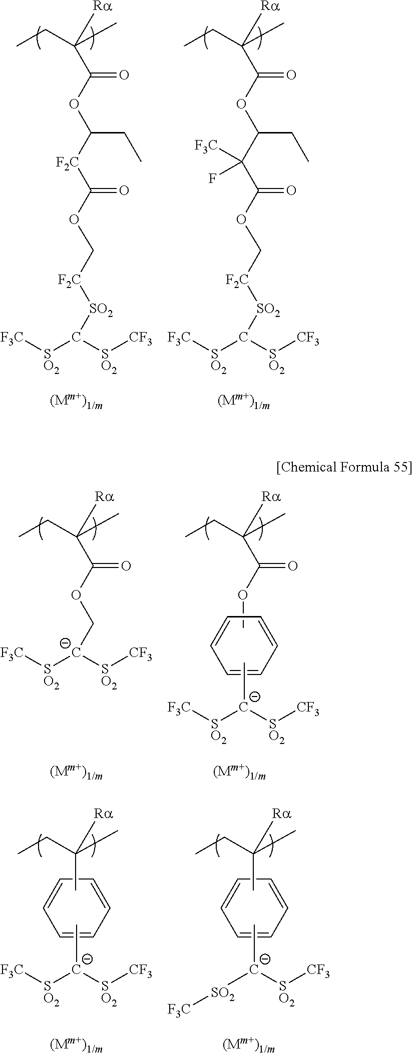

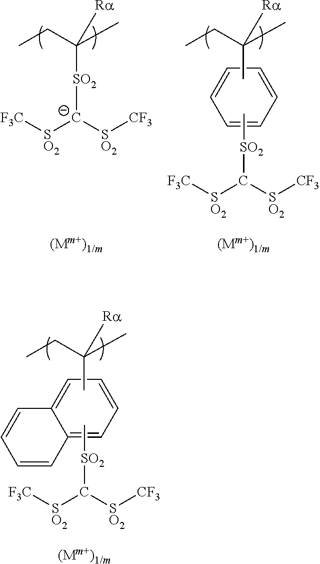

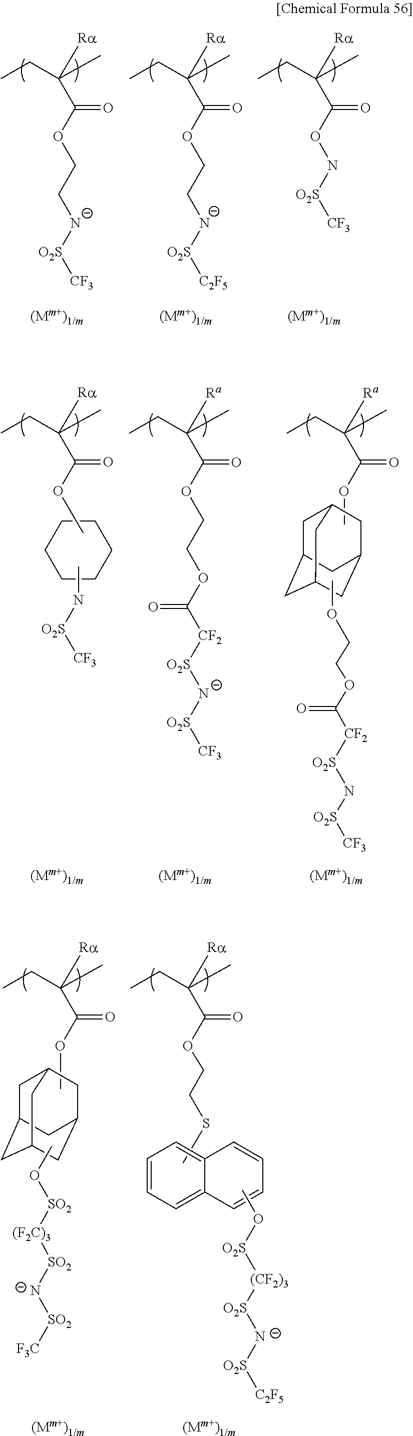

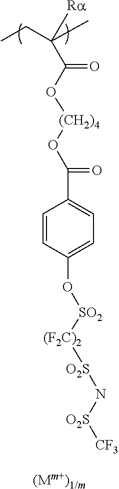

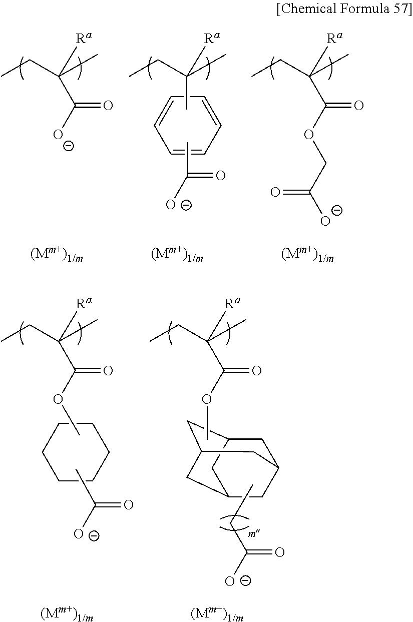

As the structural unit (a0) contained in the component (A1), 1 type of structural unit may be used, or 2 or more types may be used.

In the component (A1), the amount of the structural unit (a0) based on the combined total of all structural units constituting the component (A1) is preferably 1 to 50 mol %, more preferably 1 to 45 mol %, still more preferably 3 to 40 mol %, and particularly preferably 5 to 35 mol %. When the amount of the structural unit (a0) is 1 mol % or more, lithography properties such as sensitivity or resolution can be satisfactorily improved. On the other hand, when the amount of the structural unit (a0) is no more than the upper limit of the above-mentioned range, a good balance can be achieved with the other structural units. Furthermore, solubility in a resist solvent (i.e., component (S) described later) can be satisfactorily achieved.

As the structural unit (a0) contained in the component (A1b), 1 type of structural unit may be used, or 2 or more types may be used.

In the component (A1b), the amount of the structural unit (a0) based on the combined total of all structural units constituting the component (A1b) is preferably 1 to 50 mol %, more preferably 1 to 45 mol %, still more preferably 3 to 40 mol %, and particularly preferably 5 to 35 mol %. When the amount of the structural unit (a0) is 1 mol % or more, lithography properties such as sensitivity or resolution can be satisfactorily improved. On the other hand, when the amount of the structural unit (a0) is no more than the upper limit of the above-mentioned range, a good balance can be achieved with the other structural units.

The component (A1) may include a structural unit other than the structural unit (a0). As the other structural units, any of the multitude of conventional structural units used within the resin of resist compositions for ArF excimer lasers or KrF excimer lasers (and particularly for ArF excimer lasers) can be used. Examples thereof include:

a structural unit (a0) that generates acid upon exposure;

a structural unit (a1) containing an acid decomposable group that exhibits increased polarity by the action of acid;

a structural unit (a2) containing a —SO₂— containing cyclic group or a lactone-containing cyclic group;

a structural unit (a3) containing a polar group; and

a structural unit (a4) containing an acid non-dissociable cyclic group.

In the third aspect of the present invention, when the component (A1) is a component (A-2) (i.e., a resin component that generates acid upon exposure and exhibit solubility in an alkali developing solution), the component (A1) preferably contains a polar group.

Examples of the polar group include the same polar groups as those exemplified in relation to a structural unit (a3) described later.

When the structural unit (a0) contains a polar group, the component (A1) may either consist of the structural unit (a0) or further contains the structural unit (a3) as well as the structural unit (a0).

When the component (a0) does not contain a polar group, the component (A1) preferably contains the structural unit (a3) as well as the structural unit (a0).

When the component (A) is a component (A-1) (i.e., a base component that generates acid upon exposure and exhibit increased polarity by the action of acid), the component (A1) preferably has an acid decomposable group that exhibits increased polarity by the action of acid.

As described in relation to the structural unit (w1), the term “acid decomposable group” refers to a group in which at least a part of the bond within the structure thereof is cleaved by the action of acid generated from the structural unit (a0) or the component (B) as an optional component upon exposure.

When the structural unit (a0) contains an acid decomposable group, the component (A1) may either consist of the structural unit (a0) or further contains the structural unit (a1) having an acid decomposable group that exhibits increased polarity by the action of acid, as well as the structural unit (a0).

When the component (a0) does not contain an acid decomposable group, the component (A1) preferably contains the structural unit (a1) as well as the structural unit (a0).

In the present invention, as the component (A), a component (A-1) is preferred. That is, the component (A1) is preferably a resin component that generates acid upon exposure and exhibits increased polarity by the action of acid, and the resist composition of the present invention is preferably a chemically amplified resist composition which becomes a positive type in the case of an alkali developing process, and a negative type in the case of a solvent developing process.

(Structural Unit (a1))

The structural unit (a1) is a structural unit containing an acid decomposable group which exhibits increased polarity by the action of acid.

As the acid decomposable group, the same acid decomposable groups as those described above in reaction to the structural unit (w2) can be mentioned.

The structure of the structural unit (a1) is not particularly limited as long as it contains an acid decomposable group. Examples of the structural unit (a1) include: a structural unit (a11) derived from an acrylate ester which may have the hydrogen atom bonded to the carbon atom on the α-position substituted with a substituent and contains an acid decomposable group; a structural unit (a12) derived from a hydroxystyrene which may have the hydrogen atom bonded to the carbon atom on the α-position substituted with a substituent and may have the hydrogen atom bonded to the benzene ring substituted with a substituent other than a hydroxy group, and which has the hydrogen atom of the hydroxy group substituted with an acid dissociable group or a substituent having an acid dissociable group; and a structural unit (a13) selected from a structural unit derived from a vinyl(hydroxynaphthalene) which may have the hydrogen atom bonded to the carbon atom on the α-position substituted with a substituent and may have the hydrogen atom bonded to the naphthalene ring substituted with a substituent other than a hydroxy group, and which has the hydrogen atom of the hydroxy group substituted with an acid dissociable group or a substituent having an acid dissociable group; or a structural unit derived from a vinylbenzoic acid which may have the hydrogen atom bonded to the carbon atom on the α-position substituted with a substituent and may have the hydrogen atom bonded to the benzene ring substituted with a substituent other than a hydroxy group, and which has the hydrogen atom of the carboxyl group (—C(═O)—OH) substituted with an acid dissociable group or a substituent having an acid dissociable group. In terms of line edge roughness, the structural unit (a11) is preferable, and in terms of absorption of light having a wavelength within EUV region and in terms of reducing the influence of OoB light to an acid generating component, the structural units (a12) and (a13) are preferable.

[Structural Unit (a11)]

The structural unit (a11) is a structural unit derived from an acrylate ester which may have the hydrogen atom bonded to the carbon atom on the α-position substituted with a substituent and contains an acid decomposable group.

Examples of the structural unit (a11) include a structural unit represented by general formula (a1-0-1) shown below and a structural unit represented by general formula (a1-0-2) shown below.

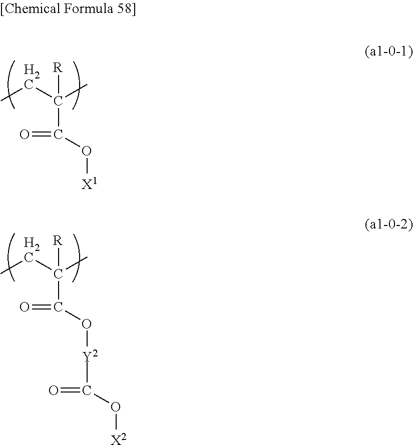

In the formulas, R represents a hydrogen atom, an alkyl group of 1 to 5 carbon atoms or a halogenated alkyl group of 1 to 5 carbon atoms; X¹ represents an acid dissociable group; Y² represents a divalent linking group; and X² represents an acid dissociable group.

In general formula (a1-0-1), the alkyl group and the halogenated alkyl group for R are respectively the same as defined for the alkyl group and the halogenated alkyl group for the substituent on the α-position of the aforementioned α-substituted acrylate ester. R is preferably a hydrogen atom, an alkyl group of 1 to 5 carbon atoms or a fluorinated alkyl group of 1 to 5 carbon atoms, and most preferably a hydrogen atom or a methyl group.

X¹ is not particularly limited as long as it is an acid dissociable group. Examples thereof include the aforementioned tertiary alkyl ester-type acid dissociable groups and acetal-type acid dissociable groups, and tertiary alkyl ester-type acid dissociable groups are preferable.

In general formula (a1-0-2), R is the same as defined above.

X² is the same as defined above for X¹ in general formula (a1-0-1).

The divalent linking group for Y² is not particularly limited, and preferable examples thereof include a divalent hydrocarbon group which may have a substituent and a divalent linking group containing a hetero atom. As the divalent linking group which may have a substituent and the divalent linking group containing a hetero atom are the same divalent linking groups as those described above for L⁰¹ in the formula (I-1) in relation to the component (W).

As Y², a linear or branched alkylene group, a divalent alicyclic hydrocarbon group or a divalent linking group containing a hetero atom is particularly desirable.

When Y² represents a linear or branched alkylene group, it preferably has 1 to 10 carbon atoms, more preferably 1 to 6, still more preferably 1 to 4, and most preferably 1 to 3. Specific examples include the same linear alkylene groups and branched alkylene groups as those described above for the aliphatic hydrocarbon group represented by

When Y² represents a divalent alicyclic hydrocarbon group, as the alicyclic hydrocarbon group, the same alicyclic hydrocarbon groups as those described above for the “aliphatic hydrocarbon group containing a ring in the structure thereof” explained above in relation to a divalent linking group for R⁰¹ can be used.

As the alicyclic hydrocarbon group, a group in which two or more hydrogen atoms have been removed from cyclopentane, cyclohexane, norbornane, isobornane, adamantane, tricyclodecane or tetracyclododecane, is particularly desirable.

When Y² is a divalent linking group containing a hetero atom, preferable examples of the linking group include —O—, —C(═O)—O—, —C(═O)—, —C(═O)—NH— and —NH— (H may be replaced with a substituent such as an alkyl group, an acyl group or the like), —S—, —S(═O)₂—, —S(═O)₂—O— and groups represented by general formulas —Y²¹—O—Y²²—, —[Y²¹—C(═O)—O]_{m′}—Y²²— and —Y²¹—O—C(═O)—Y²²— [wherein each of Y²¹ and Y²² independently represents a divalent linking group, O represents an oxygen atom; and m′ represents an integer of 0 to 3].

When Y² represents —NH—, H may be substituted with a substituent such as an alkyl group, an aryl group (an aromatic group) or the like. The substituent (an alkyl group, an aryl group or the like) preferably has 1 to 10 carbon atoms, more preferably 1 to 8, and particularly preferably 1 to 5.

In the formulas, —Y²¹—O—Y²²—, —[Y²¹—C(═O)—O]_{m′}—Y²²— or —Y²¹—O—C(═O)—Y²²—, each of Y²¹ and Y²² independently represents a divalent hydrocarbon group which may have a substituent. As the divalent hydrocarbon group, the same groups as those described above for the “divalent hydrocarbon group which may have a substituent” for Y² can be mentioned.

As Y²¹, a linear aliphatic hydrocarbon group is preferable, more preferably a linear alkylene group, still more preferably a linear alkylene group of 1 to 5 carbon atoms, and a methylene group or an ethylene group is particularly desirable.

As Y²², a linear or branched aliphatic hydrocarbon group is preferable, and a methylene group, an ethylene group or an alkylmethylene group is more preferable. The alkyl group within the alkylmethylene group is preferably a linear alkyl group of 1 to 5 carbon atoms, more preferably a linear alkyl group of 1 to 3 carbon atoms, and most preferably a methyl group.

In the group represented by the formula —[Y²¹—C(═O)—O]_{m′}—Y²²—, m′ represents an integer of 0 to 3, preferably an integer of 0 to 2, more preferably 0 or 1, and particularly preferably 1. Namely, it is particularly desirable that the group represented by the formula —[Y²¹—C(═O)—O]_{m′}—Y²²— is a group represented by the formula —Y²¹—C(═O)—O—Y²²—. Among these, a group represented by the formula —(CH₂)_{a′}—C(═O)—O—(CH₂)_{b′}— is preferable. In the formula, a′ is an integer of 1 to 10, preferably an integer of 1 to 8, more preferably an integer of 1 to 5, still more preferably 1 or 2, and most preferably 1. b′ is an integer of 1 to 10, preferably an integer of 1 to 8, more preferably an integer of 1 to 5, still more preferably 1 or 2, and most preferably 1.

As the divalent linking group containing a hetero atom for Y², an organic group which consists of a combination of at least one of non-hydrocarbon groups and a divalent hydrocarbon group can be mentioned. In particular, as the divalent linking group containing a hetero atom, a linear group containing an oxygen atom as the hetero atom e.g., a group containing an ether bond or an ester bond is preferable, and a group represented by the aforementioned formula —Y²¹—O—Y²²—, —[Y²¹—C(═O)—O]_{m′}—Y²²— or —Y²¹—O—C(═O)—Y²²— is more preferable, and —[Y²¹—C(═O)—O]_{m′}—Y²²— or —Y²¹—O—C(═O)—Y²²— is still more preferable.

Among these, as for Y², a linear or branched alkylene group or a divalent linking group containing a hetero atom is preferable, and a linear or branched alkylene group, a group represented by the formula —Y²¹—O—Y²²—, a group represented by the formula —[Y²¹—C(═O)—O]_{m′}—Y²²—, or a group represented by the formula —Y²¹—O—C(═O)—Y²²— is more preferable.

Specific examples of the structural unit (a11) include structural units represented by general formulas (a1-1) to (a1-4) shown below.

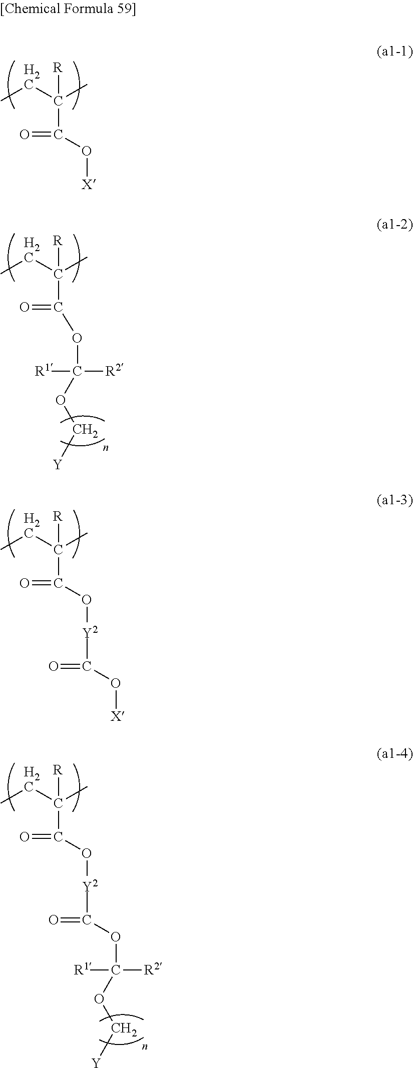

In the formulas, R, R¹′, R²′, n, Y and Y² are the same as defined above; and X′ represents a tertiary alkyl ester-type acid dissociable group.

In the formulas, the tertiary alkyl ester-type acid dissociable group for X′ include the same tertiary alkyl ester-type acid dissociable groups as those described above.

As R¹′, R²′, n and Y are respectively the same as defined for R¹′, R²′, n and Y in the general formula (p1) described above in connection with the “acetal-type acid dissociable group”.

Y² is the same as defined for Y² in general formula (a1-2).

Specific examples of structural units represented by general formulas (a1-1) to (a1-4) are shown below.

In the formulas shown below, R^{α} represents a hydrogen atom, a methyl group or a trifluoromethyl group.

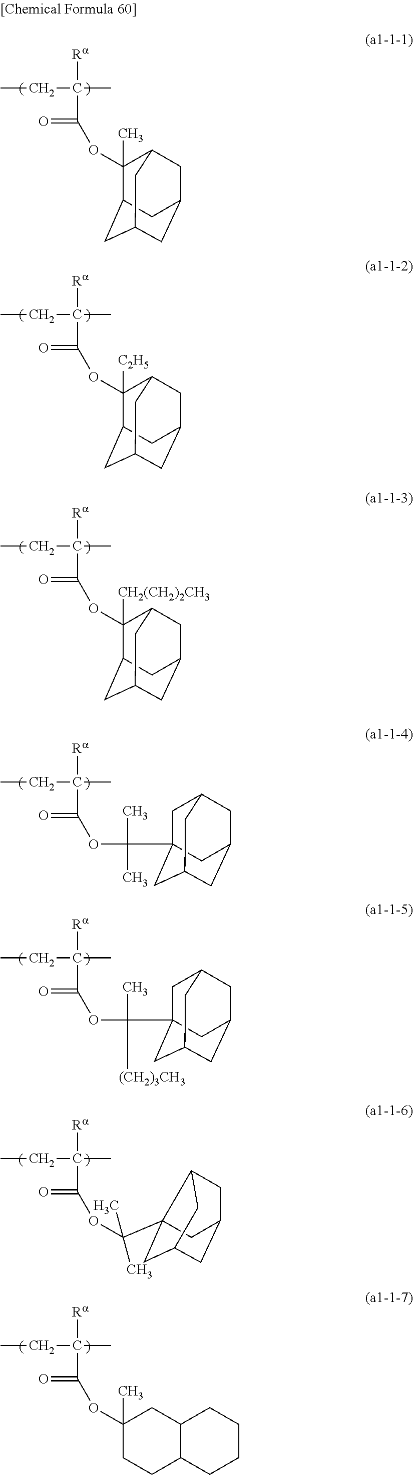

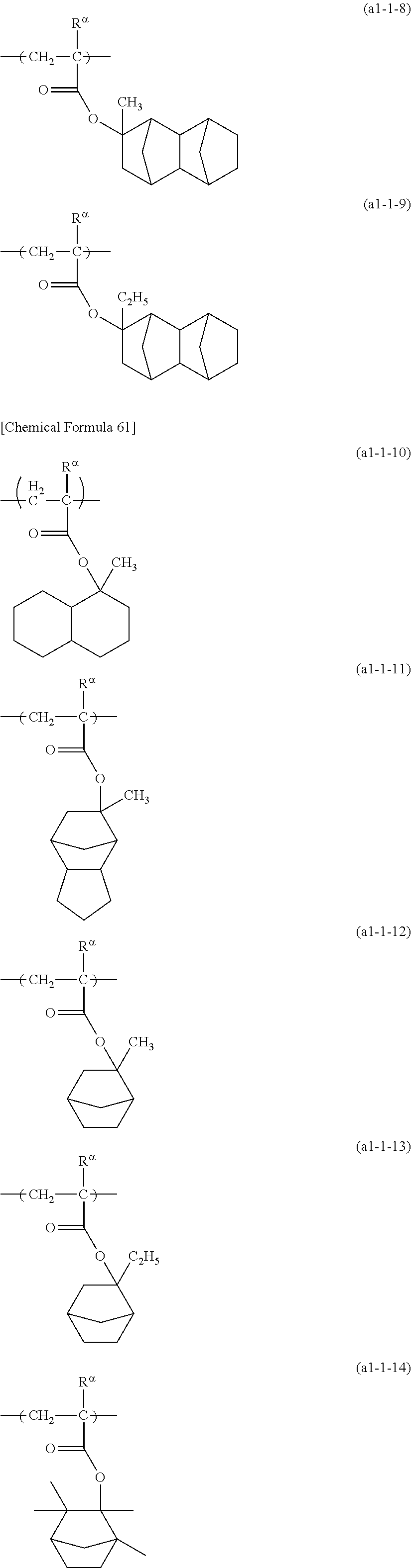

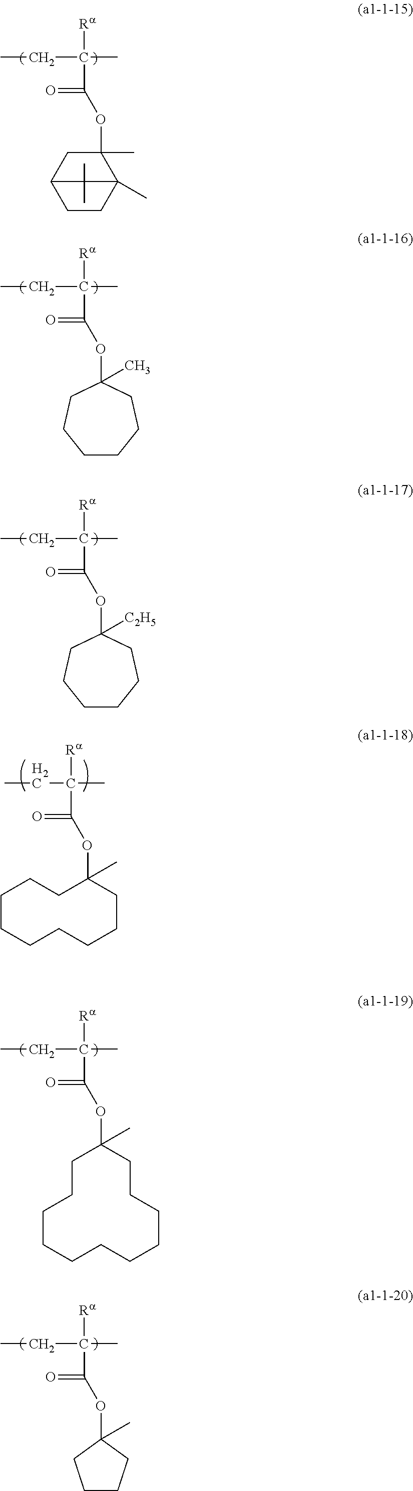

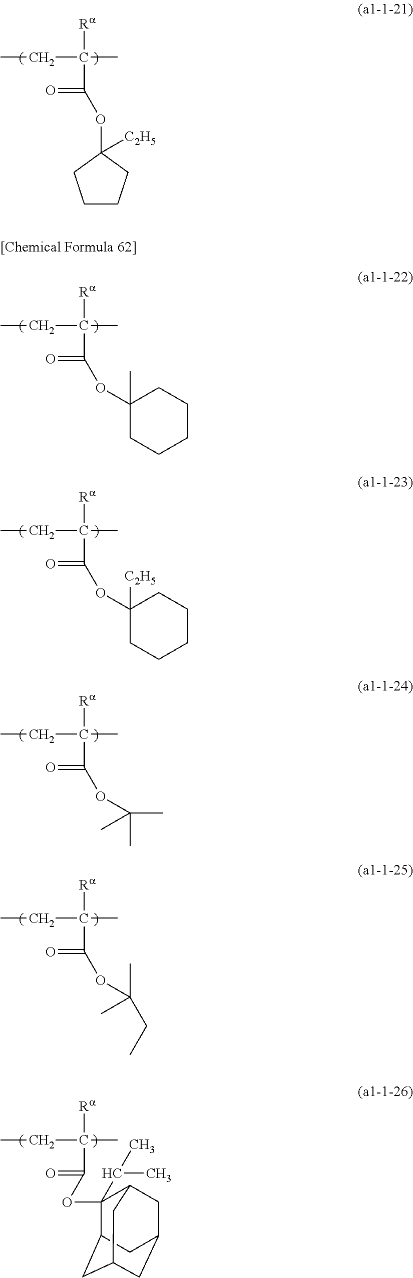

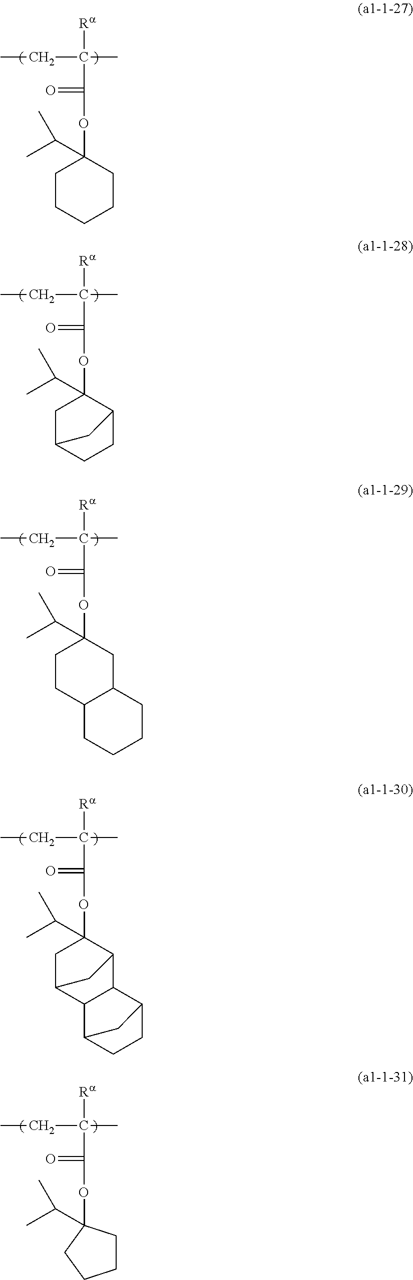

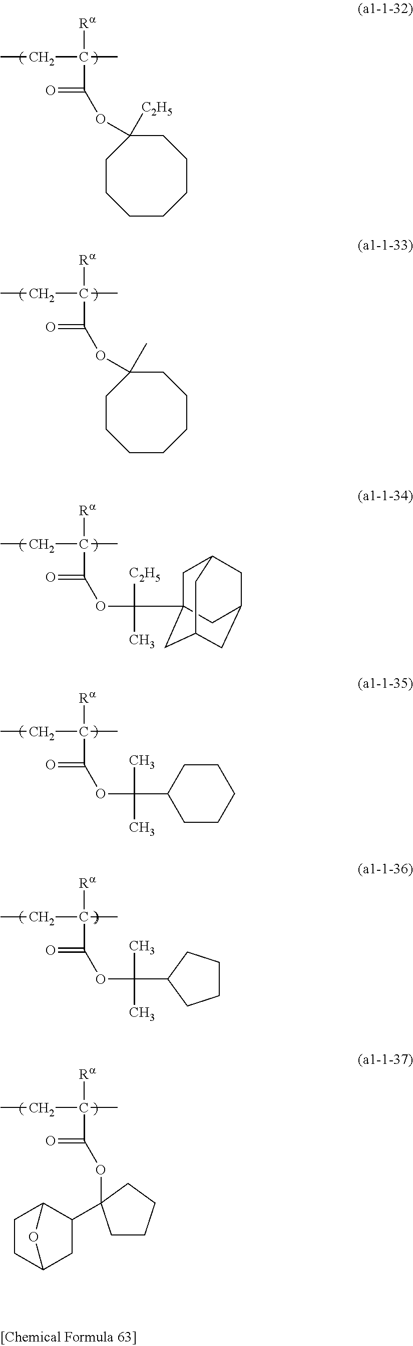

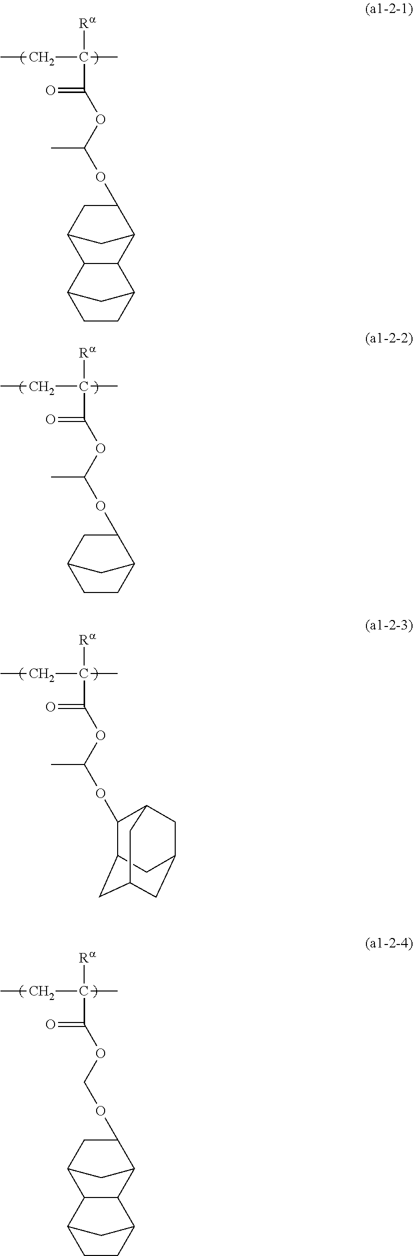

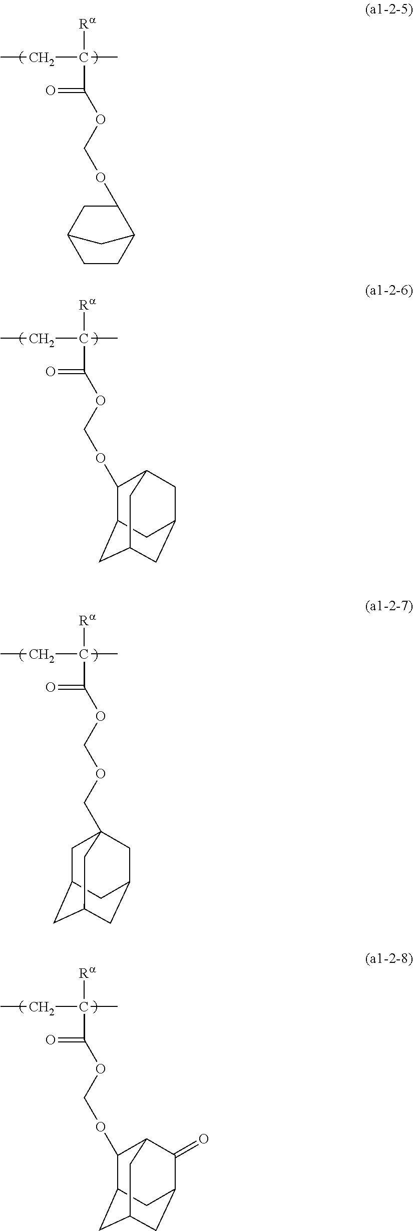

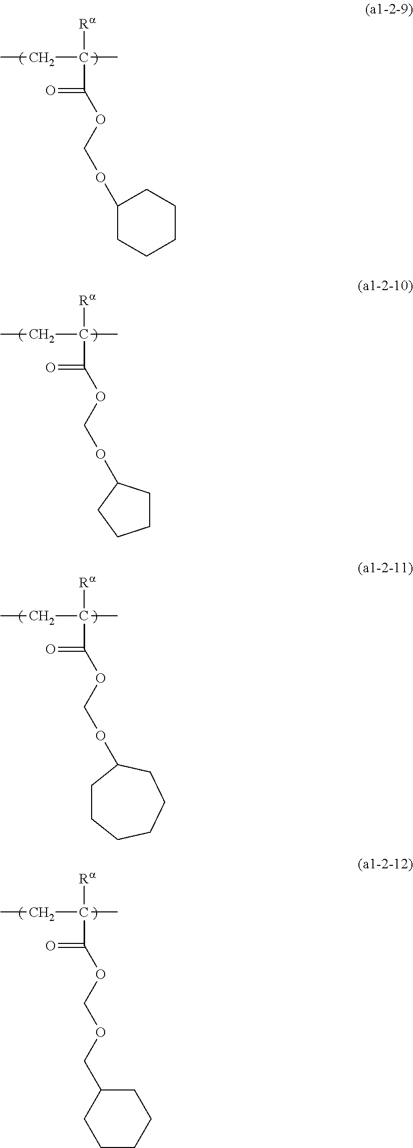

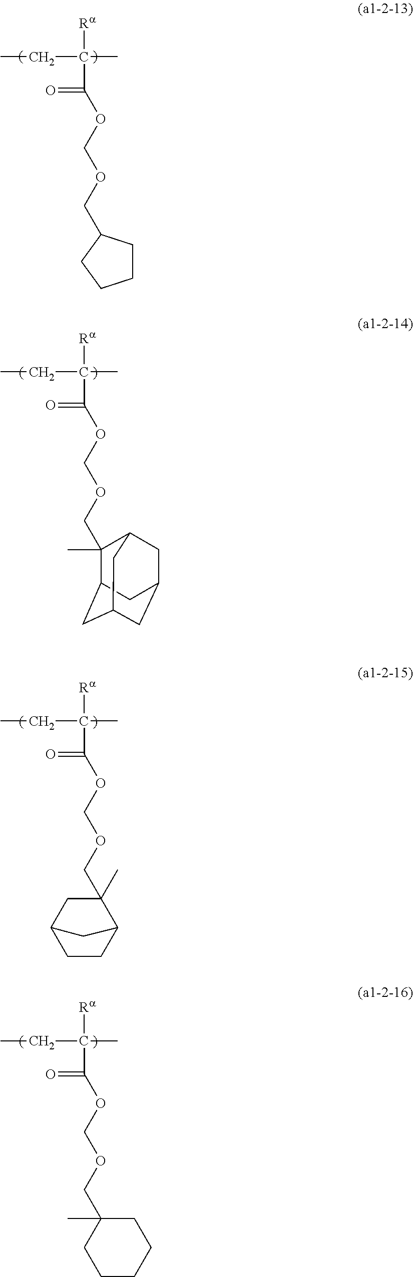

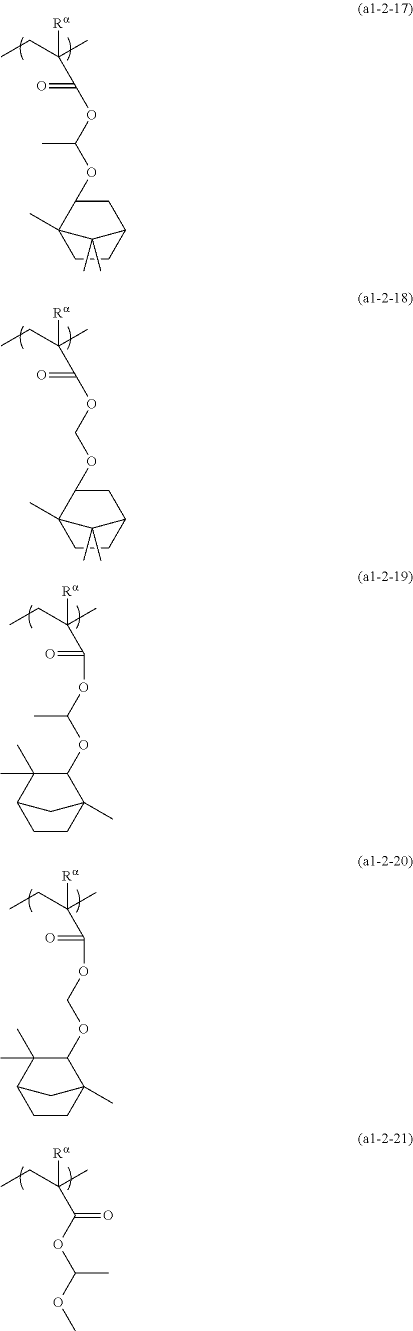

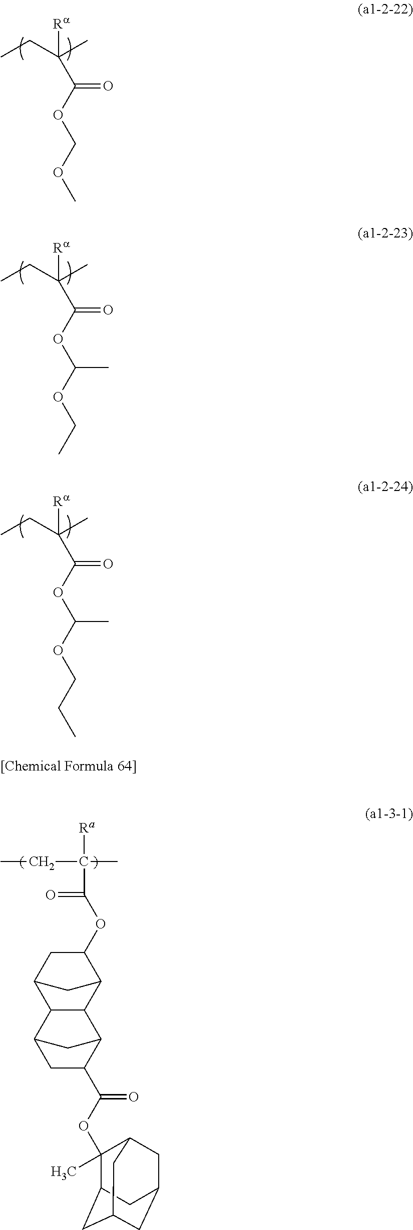

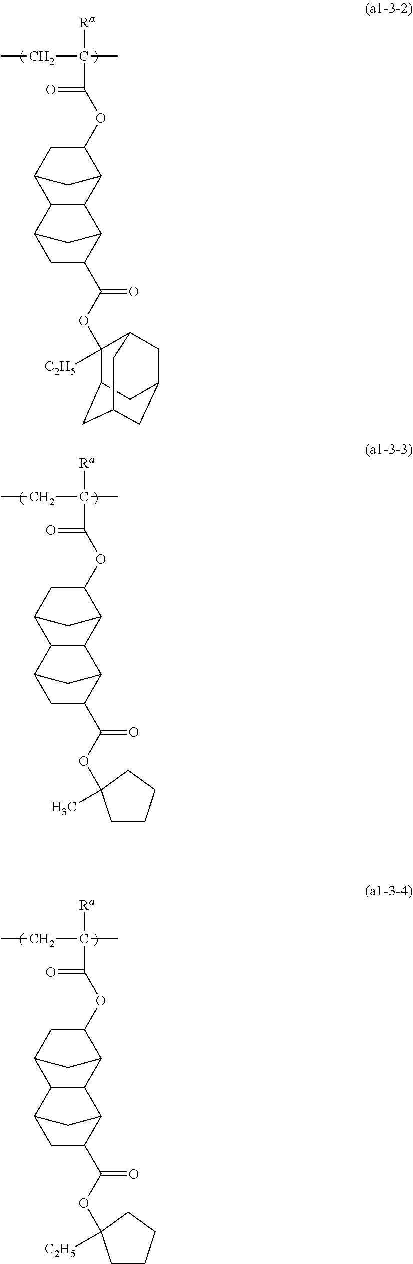

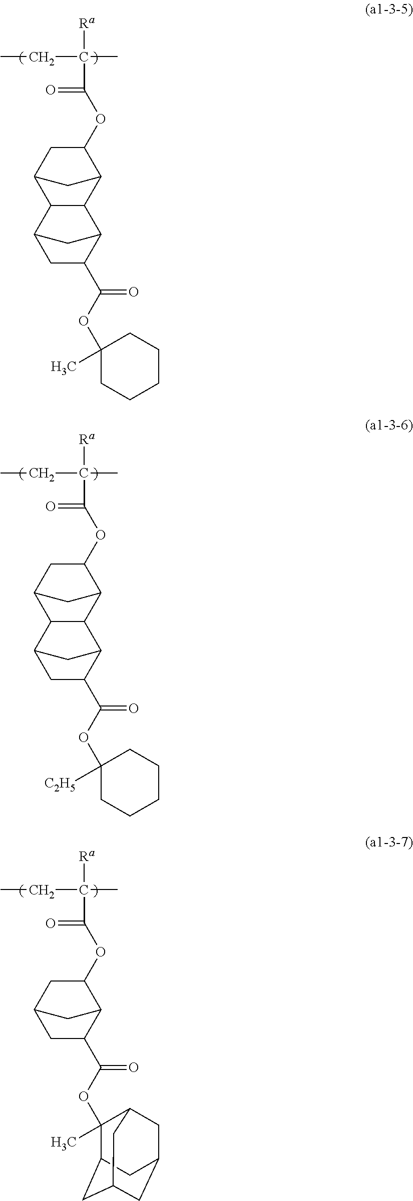

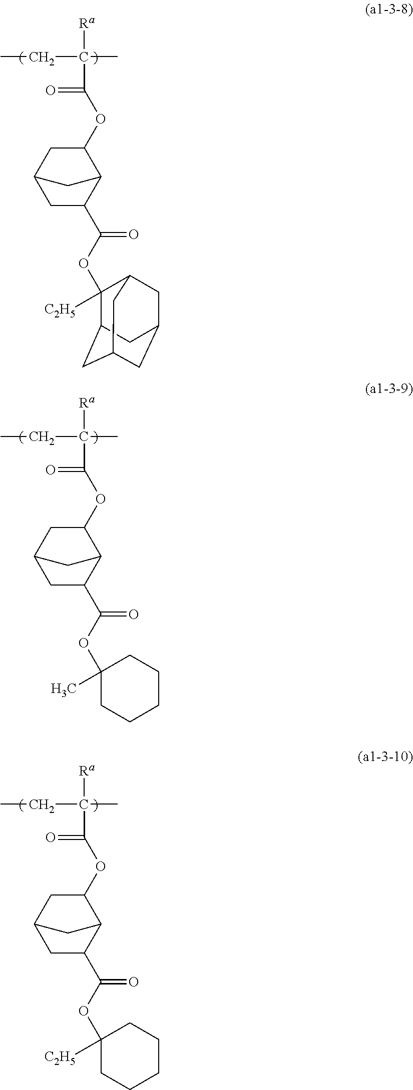

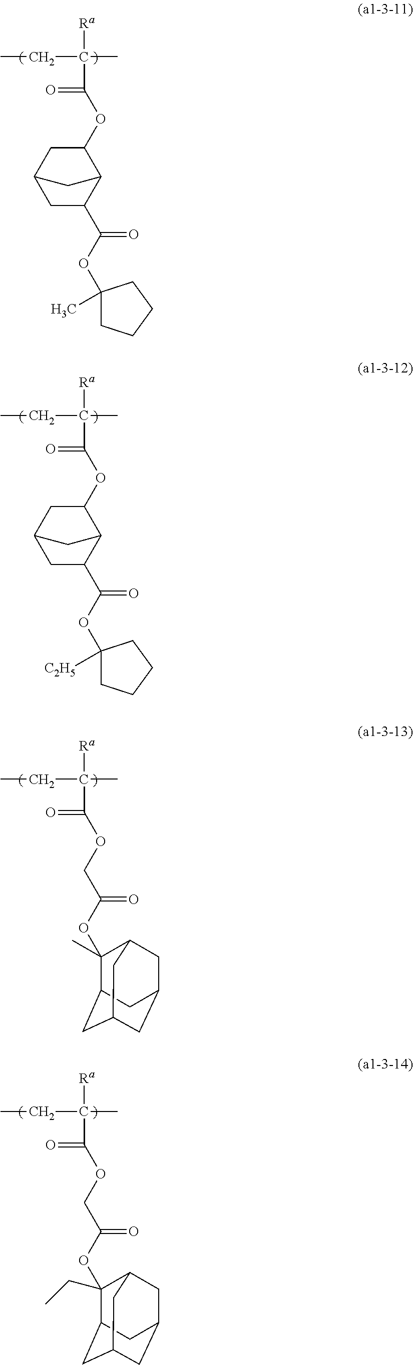

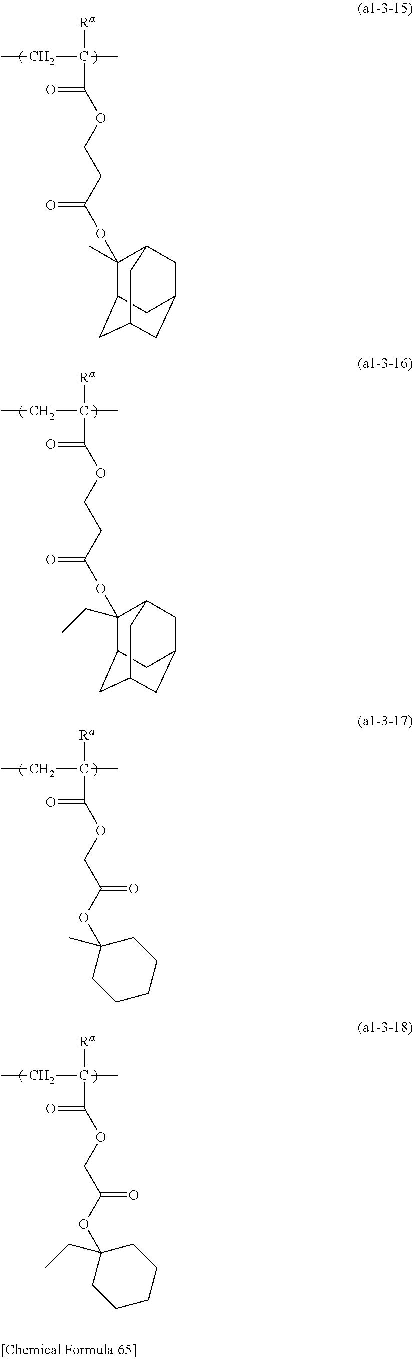

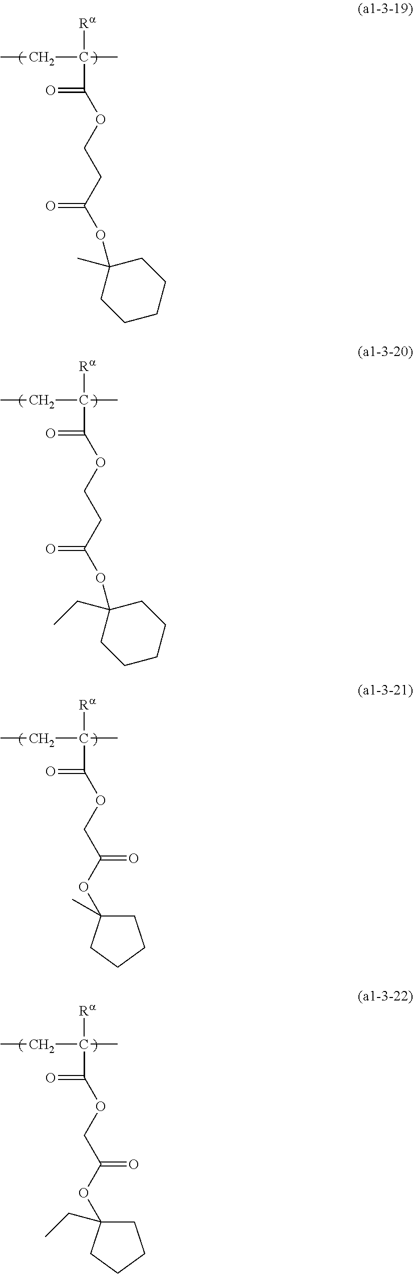

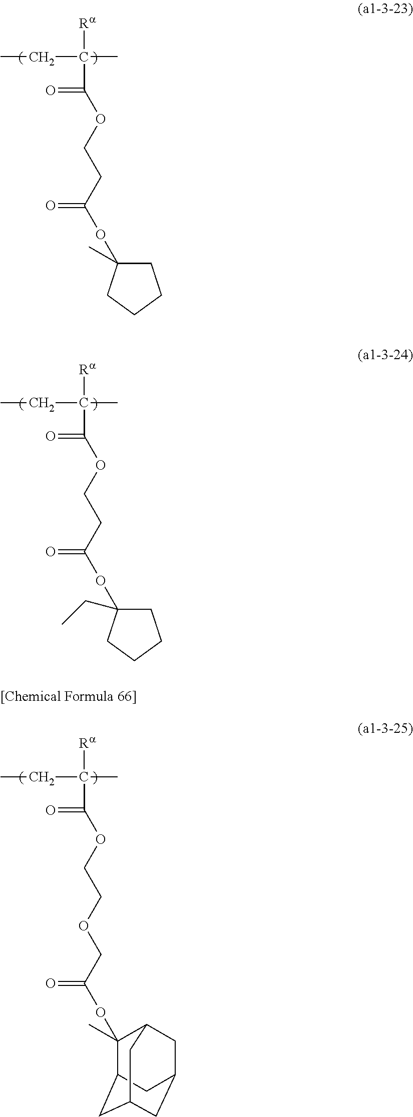

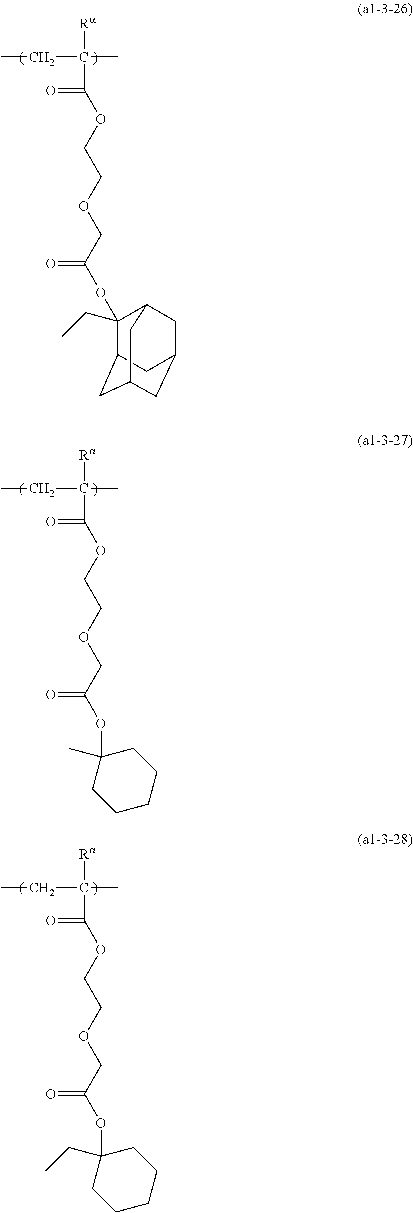

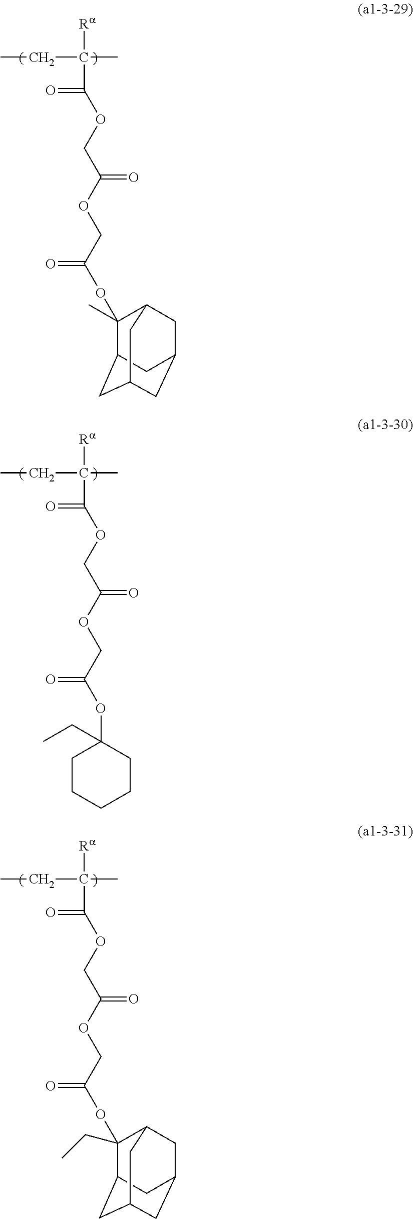

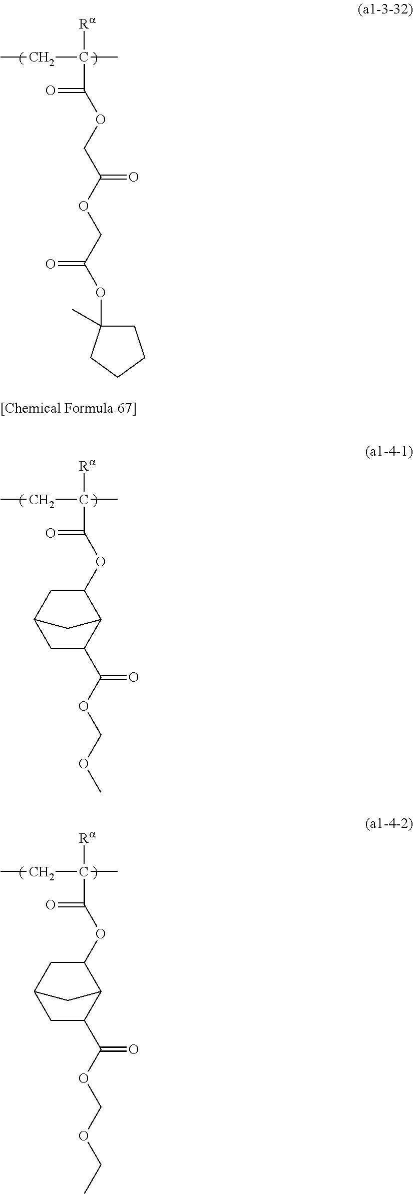

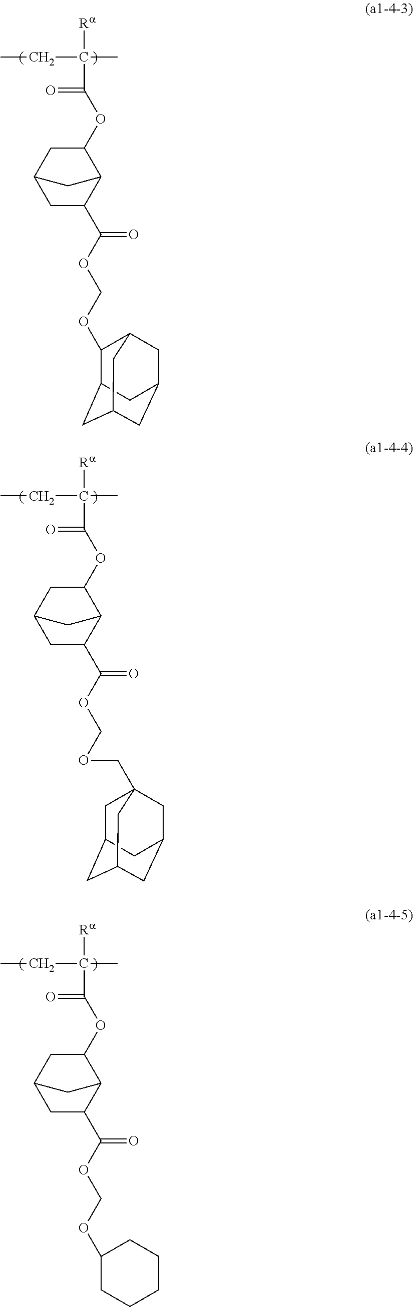

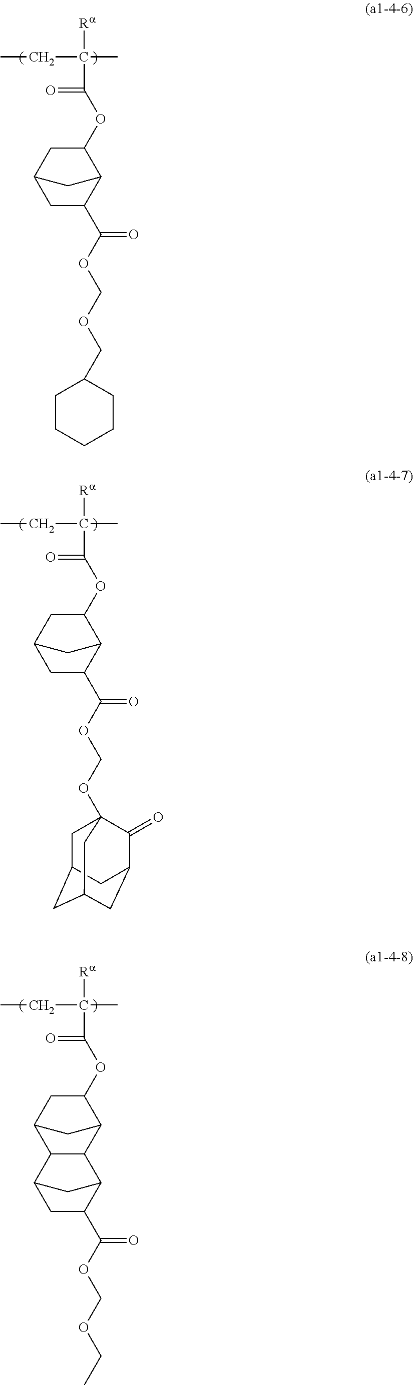

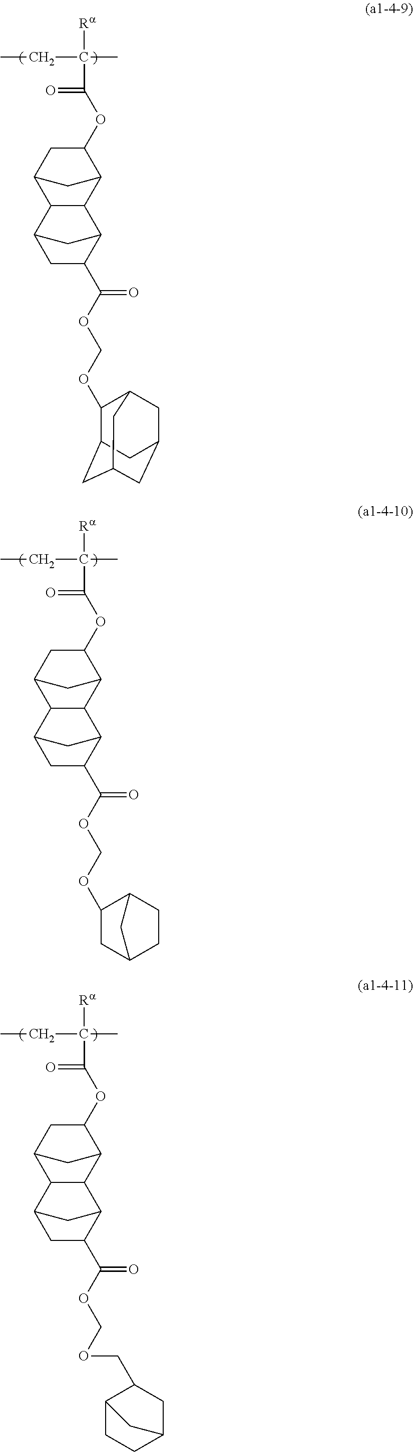

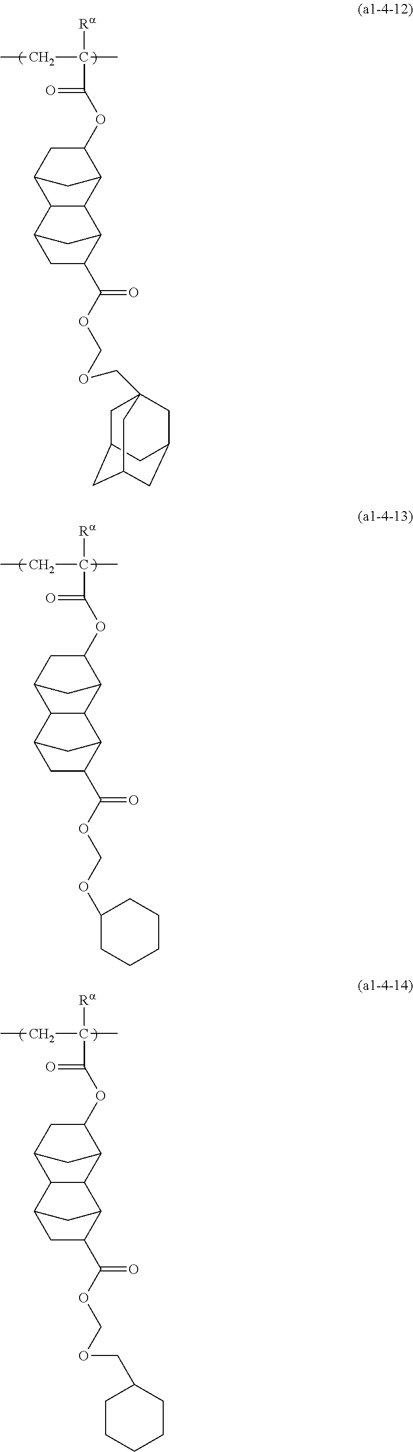

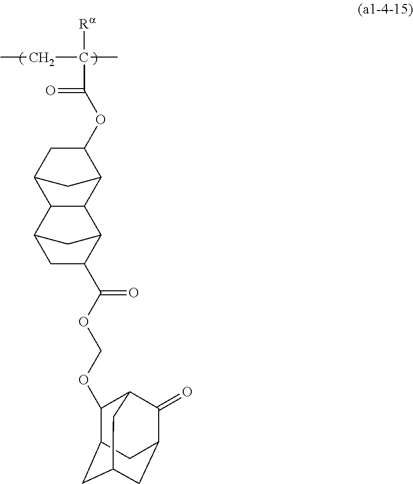

In the first aspect and third aspect of the present invention, it is preferable that the base component includes at least one structural unit selected from the group consisting of a structural unit represented by general formula (a1-0-11) shown below, a structural unit represented by general formula (a1-0-12) shown below, a structural unit represented by general formula (a1-0-13) shown below and a structural unit represented by general formula (a1-0-2) shown below as a structural unit (a11). It is particularly desirable that the base component include at least one member selected from the group consisting of a structural unit represented by general formula (a1-0-11) shown below, a structural unit represented by general formula (a1-0-12) shown below and a structural unit represented by general formula (a1-0-2) shown below.

In the second aspect of the present invention, it is desirable that a base component includes at least one member selected from the group consisting of a structural units represented by general formulas (a1-0-11) to (a1-0-15) shown below and a structural unit represented by general formula (a1-0-2) shown below as a structural unit (a11). As the structural unit (a11), at least one structural unit selected from the group consisting of structural units represented by general formulas (a1-0-11) to (a1-0-15) is preferable, and at least one structural unit selected from the group consisting of structural unit represented by general formulas (a1-0-11) to (a1-0-13) and (a1-0-15) is more preferable.

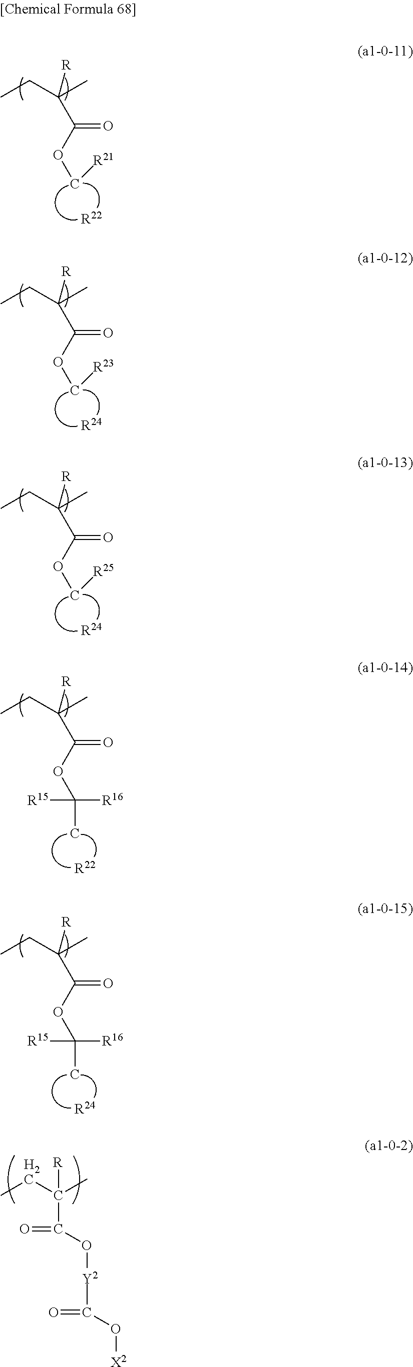

In the formulas, R represents a hydrogen atom, an alkyl group of 1 to 5 carbon atoms or a halogenated alkyl group of 1 to 5 carbon atoms; R²¹ represents an alkyl group; R²² represents a group which forms an aliphatic monocyclic group with the carbon atom having R²² bonded thereto; R²³ represents a branched alkyl group; R²⁴ represents a group which forms an aliphatic polycyclic group with the carbon atom having R²⁴ bonded thereto; R²⁵ represents a linear alkyl group of 1 to 5 carbon atoms; each of R¹⁵ and R¹⁶ independently represents an alkyl group; Y² represents a divalent linking group; and X² represents an acid dissociable group.

In the formulas, R, Y² and X² are the same as defined above.

In general formula (a1-0-11), as the alkyl group for R²¹, the same alkyl groups as those described above for R¹⁴ in formulas (1-1) to (1-9) can be used, and a methyl group, an ethyl group, an isopropyl group or a cyclic alkyl group (preferably polycyclic group) is preferable.

As the aliphatic monocyclic group formed by R²² and the carbon atoms having R²² bonded thereto, the same aliphatic cyclic groups as those described above in relation to the aforementioned tertiary alkyl ester-type acid dissociable group and which are monocyclic can be used. Specific examples include groups in which one or more hydrogen atoms have been removed from a monocycloalkane. The monocycloalkane is preferably a 3- to 11-membered ring, more preferably a 3- to 8-membered ring, still more preferably a 4- to 6-membered ring, and particularly preferably a 5- or 6-membered ring.

The monocycloalkane may or may not have part of the carbon atoms constituting the ring replaced with an ether bond (—O—).

Further, the monocycloalkane may have a substituent such as an alkyl group of 1 to 5 carbon atoms, a fluorine atom or a fluorinated alkyl group of 1 to 5 carbon atoms.

As an examples of R²² constituting such an aliphatic monocyclic group, a linear alkylene group which may have an ether bond (—O—) interposed between the carbon atoms can be given.

Specific examples of structural units represented by general formula (a1-0-11) include structural units represented by the aforementioned formulas (a1-1-16) to (a1-1-23), (a1-1-27), (a1-1-31) and (a1-1-37).

Among these, structural units represented by general formula (a1-1-02) shown below which includes the structural units represented by the aforementioned formulas (a1-1-16), (a1-1-17), (a1-1-20) to (a1-1-23), (a1-1-27), (a1-1-31), (a1-1-32), (a1-1-33) and (a1-1-37) are preferable. Further, a structural unit represented by general formula (a1-1-02′) shown below is also preferable.

In the formulas, h represents an integer of 1 to 4, and is preferably 1 or 2.

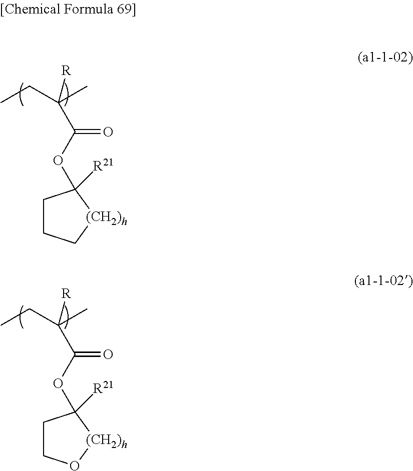

In the formulas, R and R²¹ are the same as defined above; and h represents an integer of 1 to 4.

In general formula (a1-0-12), as the branched alkyl group for R²³, the same alkyl groups as those described above for R¹⁴ which are branched in the formulas (1-1) to (1-9) can be used, and an isopropyl group is particularly desirable.

As the aliphatic polycyclic group formed by R²⁴ and the carbon atoms having R²⁴ bonded thereto, the same aliphatic cyclic groups as those described above in relation to the aforementioned tertiary alkyl ester-type acid dissociable group and which are polycyclic can be used.

Specific examples of structural units represented by general formula (a1-0-12) include structural units represented by the aforementioned formulas (a1-1-26) and (a1-1-28) to (a1-1-30).

As the structural unit (a1-0-12), a structural unit in which the aliphatic polycyclic group formed by R²⁴ and the carbon atom having R²⁴ bonded thereto is a 2-adamantyl group is preferable, and a structural unit represented by the aforementioned formula (a1-1-26) is particularly desirable.

In general formula (a1-0-13), R and R²⁴ are the same as defined above.

As the linear alkyl group for R²⁵, the same linear alkyl groups as those described above for R¹⁴ in the aforementioned formulas (1-1) to (1-9) can be mentioned, and a methyl group or an ethyl group is particularly desirable.

Specific examples of structural units represented by general formula (a1-0-13) include structural units represented by the aforementioned formulas (a1-1-1) to (a1-1-3) and (a1-1-7) to (a1-1-15) exemplified as specific examples of the structural unit represented by general formula (a1-1).

As the structural unit (a1-0-13), a structural unit in which the aliphatic polycyclic group formed by R²⁴ and the carbon atom having R²⁴ bonded thereto is a 2-adamantyl group is preferable, and a structural unit represented by the aforementioned formula (a1-1-1) or (a1-1-2) is particularly desirable.

As the aliphatic polycyclic group formed by R²⁴ and the carbon atom to which R²⁴ is bonded is preferably a group in which one or more hydrogen atoms have been removed from tetracyclododecane, and a structural unit represented by the aforementioned formulas (a1-1-8), (a1-1-9) or (a1-1-30) is also desirable.

In general formula (a11-0-14), R and R²² are the same as defined above. R¹⁵ and R¹⁶ are the same as defined for R¹⁵ and R¹⁶ in the general formulas (2-1) to (2-6).

Specific examples of structural units represented by general formula (a11-0-14) include structural units represented by the aforementioned formulas (a1-1-35) and (a1-1-36) which were described above as specific examples of the structural unit represented by general formula (a1-1).

Examples of structural units represented by general formula (a1-0-2) include structural units represented by the aforementioned formulas (a1-3) and (a1-4), and the structural unit represented by the formula (a1-3) is particularly preferable.

Specific examples of structural units represented by general formula (a1-0-2) include structural units represented by the aforementioned formulas (a1-1-26) and (a1-1-28) to (a1-1-30).

In particular, Y² is preferably a group represented by formula Y²¹—O—Y²²—, a group represented by formula —[Y²¹—C(═O)—O]_{m′}—Y²²— or a group represented by formula —Y²¹—O—C(═O)—Y²²—.

Preferable examples of such structural units include a structural unit represented by general formula (a1-3-01) shown below, a structural unit represented by general formula (a1-3-02) shown below, and a structural unit represented by general formula (a1-3-03) shown below.

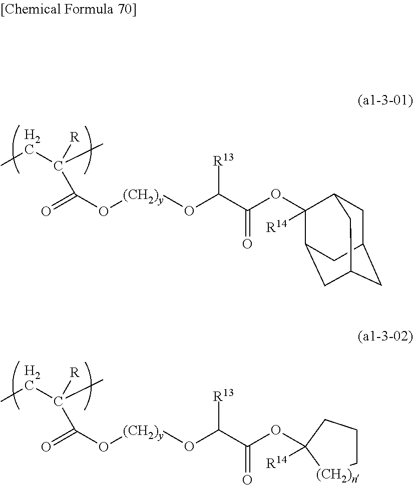

In the formulas, R is the same as defined above; R¹³ represents a hydrogen atom or a methyl group; R¹⁴ represents an alkyl group; y represents an integer of 1 to 10; and n′ represents an integer of 0 to 3.

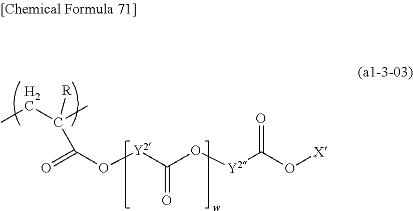

In the formula, R is as defined above; each of Y²′ and Y²″ independently represents a divalent linking group; X′ represents an acid dissociable group; and w represents an integer of 0 to 3.

In general formulas (a1-3-01) and (a1-3-02) R¹³ is preferably a hydrogen atom.

R¹⁴ is the same as defined for R¹⁴ in the aforementioned formulas (1-1) to (1-9).

y is preferably an integer of 1 to 8, more preferably 1 to 5, and most preferably 1 or 2.

n′ is preferably 1 or 2, and most preferably 2.

Specific examples of structural units represented by general formula (a1-3-01) include structural units represented by the aforementioned formulas (a1-3-25) and (a1-3-26).

Specific examples of structural units represented by general formula (a1-3-02) include structural units represented by the aforementioned formulas (a1-3-27) and (a1-3-28).

In general formula (a1-3-03), as the divalent linking group for Y²′ and Y²″, the same groups as those described above for Y² in the general formula (a1-3) can be used.

As Y²′, a divalent hydrocarbon group which may have a substituent is preferable, a linear aliphatic hydrocarbon group is more preferable, and a linear alkylene group is still more preferable. Among linear alkylene groups, a linear alkylene group of 1 to 5 carbon atoms is preferable, and a methylene group or an ethylene group is particularly desirable.

As Y²″, a divalent hydrocarbon group which may have a substituent is preferable, a linear aliphatic hydrocarbon group is more preferable, and a linear alkylene group is still more preferable. Among linear alkylene groups, a linear alkylene group of 1 to 5 carbon atoms is preferable, and a methylene group or an ethylene group is particularly desirable.

As the acid dissociable group for X′, the same groups as those described above can be used. X′ is preferably a tertiary alkyl ester-type acid dissociable group, more preferably the aforementioned group (i) in which a substituent is bonded to the carbon atom to which an atom adjacent to the acid dissociable group is bonded, on the ring skeleton to form a tertiary carbon atom. Among these, a group represented by the aforementioned general formula (1-1) is particularly desirable.

w represents an integer of 0 to 3, preferably an integer of 0 to 2, more preferably 0 or 1, and most preferably 1.

As the structural unit represented by general formula (a1-3-03), a structural unit represented by general formula (a1-3-03-1) or (a1-3-03-2) shown below is preferable, and a structural unit represented by general formula (a1-3-03-1) is particularly desirable.

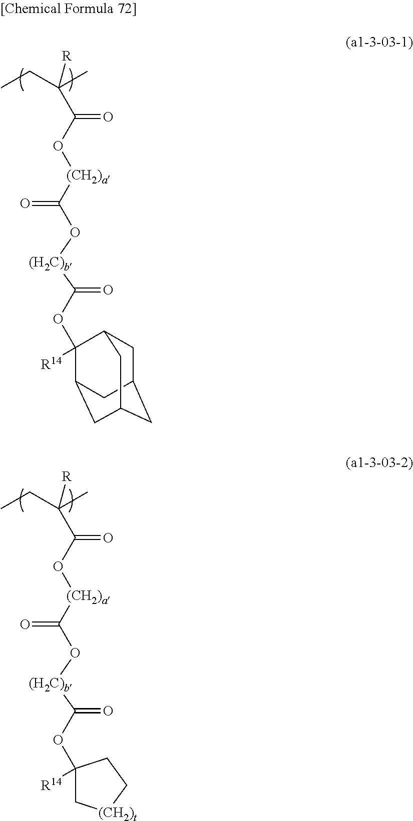

In the formulas, R and R¹⁴ are the same as defined above; a′ represents an integer of 1 to 10; b′ represents an integer of 1 to 10; and t represents an integer of 0 to 3.

In general formulas (a1-3-03-1) and (a1-3-03-2), a′ is preferably an integer of 1 to 8, more preferably 1 to 5, and most preferably 1 or 2.

b′ is preferably an integer of 1 to 8, more preferably 1 to 5, and most preferably 1 or 2.

t is preferably an integer of 1 to 3, and particularly preferably 1 or 2.

Specific examples of structural units represented by general formula (a1-3-03-1) or (a1-3-03-2) include structural units represented by the aforementioned formulas (a1-3-29) to (a1-3-32).

[Structural Unit (a12)]

The structural unit (a12) is a structural unit derived from a hydroxystyrene which may have the hydrogen atom bonded to the carbon atom on the α-position substituted with a substituent and may have the hydrogen atom bonded to the benzene ring substituted with a substituent other than a hydroxy group, and which has the hydrogen atom of the hydroxy group substituted with an acid dissociable group or a substituent having an acid dissociable group.

As the acid dissociable group for substituting the hydrogen atom of the hydroxy group, the aforementioned tertiary alkyl ester-type acid dissociable groups and acetal-type acid dissociable groups are preferable, and acetal-type acid dissociable groups are more preferable.

As the substituent containing an acid dissociable group, a group constituted of an acid dissociable group and a divalent linking group can be mentioned. As the divalent linking group, the same divalent linking group as those described for L⁰¹ in the formula (I-1), in relation to the component (W), and a group having a carbonyloxy group at the terminal of an acid dissociable group is particularly preferable. In this case, it is preferable that the acid dissociable group be bonded to the oxygen atom (—O—) in the carbonyloxy group.

As the substituent containing an acid dissociable group, a group represented by formula R¹¹′—O—C(═O)— and a group represented by formula R¹¹′—O—C(═O)—R¹²′— are preferable. In the formula, R¹¹′ represents an acid dissociable group, and R¹²′ represents a linear or branched alkylene group.

As the acid dissociable group for R¹¹′, the aforementioned tertiary alkyl ester-type acid dissociable groups and acetal-type acid dissociable groups are preferable, and tertiary alkyl ester-type acid dissociable groups are more preferable. Examples of the tertiary alkyl ester-type acid dissociable groups, aliphatic branched, acid dissociable groups represented by formula —C(R⁷¹)(R⁷²)(R⁷³) and groups represented by formula (1-1) to (1-9) and groups represented by formulas (2-1) to (2-6).

Examples of the alkylene group for R¹²′ include a methylene group, an ethylene group, a trimethylene group, a tetramethylene group and a 1,1-dimethylethylene group. As R¹²′, a linear alkylene group is preferable.

Specific examples of the structural unit (a12) includes structural units represented by the general formula (U-3), which is described in the explanation of the component (W), in which px of —(OC^{c})ₚₓ bonded to the benzene ring is an integer of 1 to 3 and at least one of is an acid dissociable group or a substituent having an acid dissociable group. When px is 2 or 3, the plurality of X^{c} group may be the same or different from each other. For example, one of X^{c} may be an acid dissociable group or a substituent having an acid dissociable group, and the other one or two of X^{c} may be a hydrogen atom.

[Structural Unit (a13)]

The structural unit (a13) is a structural unit derived from a vinyl(hydroxynaphthalene) which may have the hydrogen atom bonded to the carbon atom on the α-position substituted with a substituent and may have the hydrogen atom bonded to the naphthalene ring with a substituent other than a hydroxy group, and which has the hydrogen atom of the hydroxy group substituted with an acid dissociable group or a substituent having an acid dissociable group, or a structural unit derived from a vinylbenzoic acid which may have the hydrogen atom bonded to the carbon atom on the α-position substituted with a substituent and may have the hydrogen atom bonded to the benzene ring with a substituent other than a hydroxy group, and which has the hydrogen atom of the —C(═O)—OH substituted with an acid dissociable group or a substituent having an acid dissociable group.

In the structural unit (a13), example of the acid dissociable group and substituent having an acid dissociable group for substituting the hydrogen atom of the hydroxy group include the same groups as those described above in relation to the structural unit (a12).

Specific examples of the structural unit (a13) include a structural unit represented by the general formula (U-4), which is described in the explanation of the component (W), in which x of —(OX^{d})ₓ bonded to the benzene ring is an integer of 1 to 3 and at least one of X^{d} represents an acid dissociable group or a substituent containing an acid dissociable group.

When x is 2 or 3, the plurality of X^{d} group may be the same or different from each other. For example, one of X^{d} may be an acid dissociable group or a substituent having an acid dissociable group, and the other one or two of X^{d} may be a hydrogen atom.

As the preferable examples of the structural unit (a12) and structural unit (a13), a structural unit represented by any one of general formulas (a12-1) to (a12-4) and (a13-1) shown below.

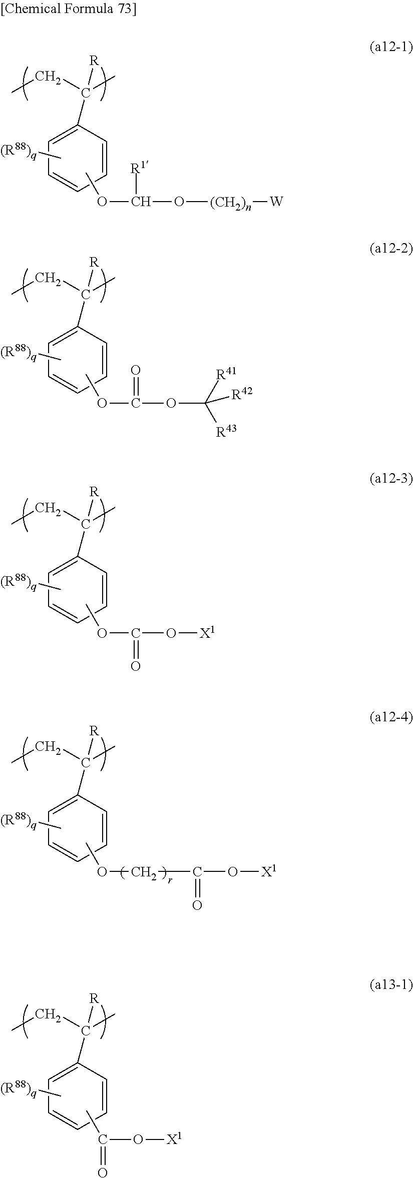

In the formulas (a12-1) to (a12-4) and (a13-1), R is the same as defined above; R⁸⁸ represents a halogen atom, an alkyl group of 1 to 5 carbon atoms or a halogenated alkyl group of 1 to 5 carbon atoms; q represents an integer of 0 to 4; R¹′ is the same as defined above; n represents an integer of 0 to 3; W represents an aliphatic cyclic group, an aromatic cyclic hydrocarbon group or an alkyl group of 1 to 5 carbon atoms; r represents an integer of 1 to 3; R⁴¹, R⁴² and R⁴³ each independently represents a linear or branched alkyl group; and X¹ represents an acid dissociable group.

In the formulas (a12-1) to (a12-4) and (a13-1), the bonding positions of “—O—CHR¹′—O—(CH₂)ₙ—W”, “—O—C(O)—O—C(R⁴¹)(R⁴²)(R⁴³)”, “—O—C(O)—O—X¹”, “—O—(CH₂)ᵣ—C(O)—O—X¹” and “—C(O)—O—X” may be o-position, m-position or p-position of the phenyl group, and in terms of the effect of the present invention, p-position is most preferable.

R⁸⁸ represents a halogen atom, an alkyl group of 1 to 5 carbon atoms or a halogenated alkyl group of 1 to 5 carbon atoms.

Examples of the halogen atom for R⁸⁸ include a fluorine atom, a chlorine atom, a bromine atom and an iodine atom, and a fluorine atom is preferable.

The alkyl group of 1 to 5 carbon atoms or halogenated alkyl group of 1 to 5 carbon atoms for R⁸⁸ are the same as the alkyl group of 1 to 5 carbon atoms or halogenated alkyl group of 1 to 5 carbon atoms as those described above for R.

When q is 1, the bonding position of R⁸⁸ may be o-position, m-position or p-position of the phenyl group.

When q is 2, a desired combination of the bonding positions can be used.

However, 1≦b+c≦5.

q represents an integer of 0 to 4, preferably 0 or 1, and most preferably 0 from an industrial viewpoint.

n represents an integer of 0 to 3, preferably an integer of 0 to 2, more preferably 0 or 1, and most preferably 0.

The aliphatic cyclic group for W is a monovalent aliphatic cyclic group. The aliphatic cyclic group can be selected appropriately, for example, from the multitude of groups that have been proposed for conventional ArF resists. Specific examples of the aliphatic cyclic group include an aliphatic monocyclic group of 5 to 7 carbon atoms and an aliphatic polycyclic group of 10 to 16 carbon atoms.

The aliphatic cyclic group may or may not have a substituent. Examples of the substituent include an alkyl group of 1 to 5 carbon atoms, an alkoxy group of 1 to 5 carbon atoms, a fluorine atom, a fluorinated alkyl group of 1 to 5 carbon atoms, and an oxygen atom (═O).

The basic ring of the “aliphatic cyclic group” exclusive of substituents is not limited to be constituted from only carbon and hydrogen (not limited to hydrocarbon groups), and may have an oxygen atom and the like in the ring structure thereof.

As the aliphatic monocyclic group of 5 to 7 carbon atoms, a group in which one hydrogen atom has been removed from a monocycloalkane can be mentioned, and specific examples include a group in which one hydrogen atom has been removed from cyclopentane or cyclohexane.

Examples of the aliphatic polycyclic group of 10 to 16 carbon atoms include groups in which one hydrogen atom has been removed from a bicycloalkane, tricycloalkane, tetracycloalkane or the like. Specific examples include groups in which one hydrogen atom has been removed from a polycycloalkane such as adamantane, norbornane, isobornane, tricyclodecane or tetracyclododecane. Of these, an adamantyl group, a norbornyl group and a tetracyclododecyl group is preferred industrially, and an adamantyl group is particularly desirable.

As the aromatic cyclic hydrocarbon group for W, aromatic polycyclic groups of 10 to 16 carbon atoms can be mentioned. Examples of such aromatic polycyclic groups include groups in which one hydrogen atom has been removed from naphthalene, anthracene, phenanthrene or pyrene. Specific examples include a 1-naphthyl group, a 2-naphthyl group, a 1-anthryl group, a 2-anthryl group, a 1-phenanthryl group, a 2-phenanthryl group, a 3-phenanthryl group and a 1-pyrenyl group, and a 2-naphthyl group is preferred industrially.

As the alkyl group of 1 to 5 carbon atoms for W, the same alkyl groups of 1 to 5 carbon atoms which may be bonded to α-position of hydroxystyrene as those described above can be used, although a methyl group or an ethyl group is preferable, and an ethyl group is most preferable.

It is preferable that R⁴¹ to R⁴³ each independently represents an alkyl group of 1 to 5 carbon atoms, and an alkyl group of 1 to 3 carbon atoms is more preferable. Specific examples thereof include the same alkyl group of 1 to 5 carbon atoms as described above for R.

The acid dissociable group for X¹ is the same acid dissociable group as those described above for X¹ in the formula (a11-0-1).

r is preferably 1 or 2, and more preferably 1.

In the structural units (a12) and (a13), the structural unit (a12) is preferable, and a structural unit represented by general formula (a12-1) or a structural unit represented by general formula (a12-4) is more preferable.

Specific examples of structural units preferable as the structural unit (a12) are shown below.

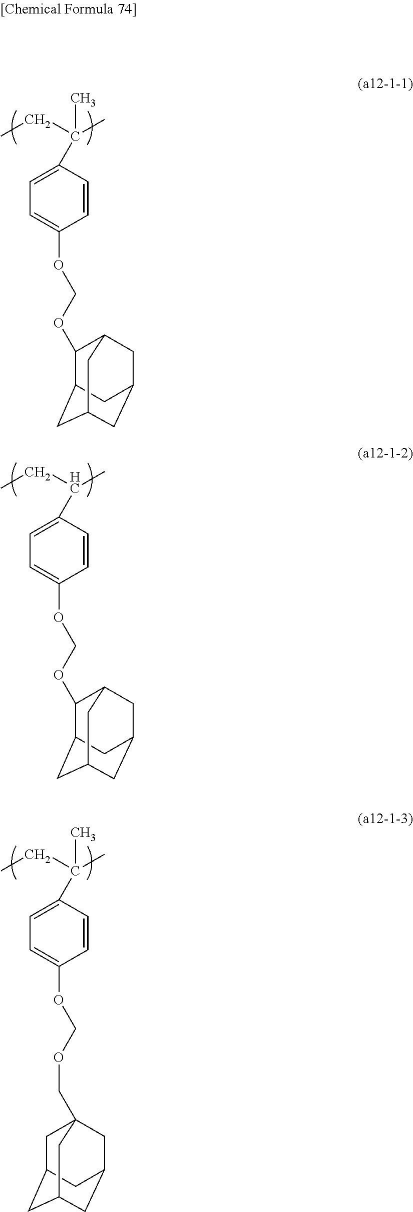

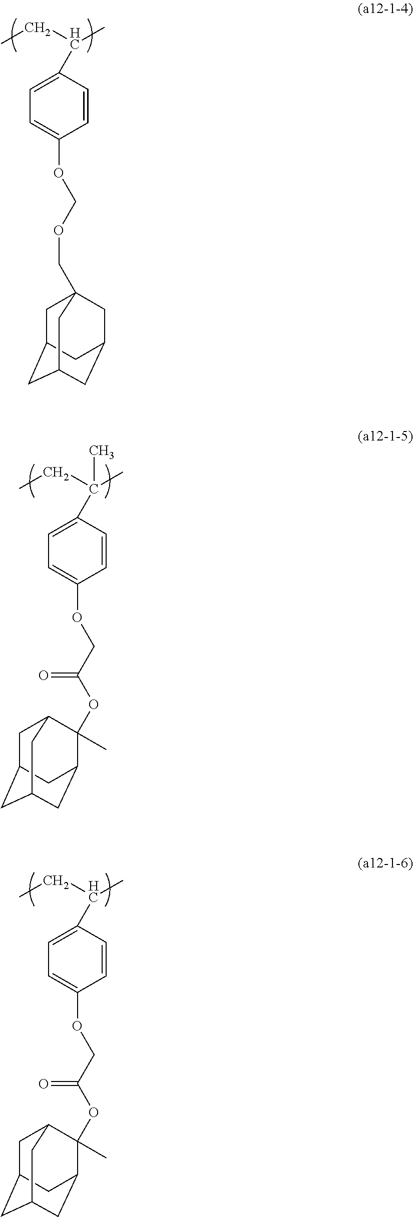

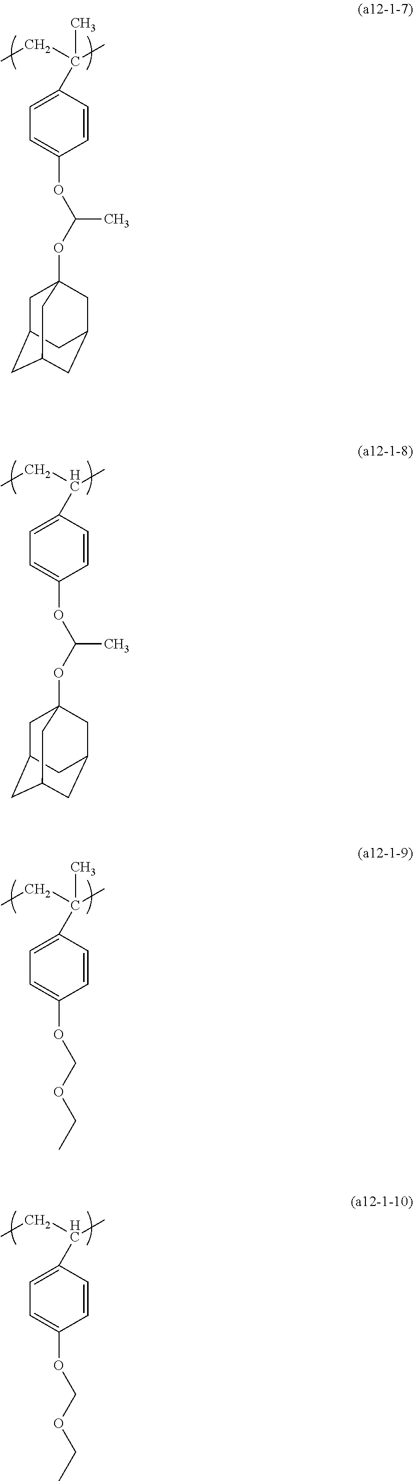

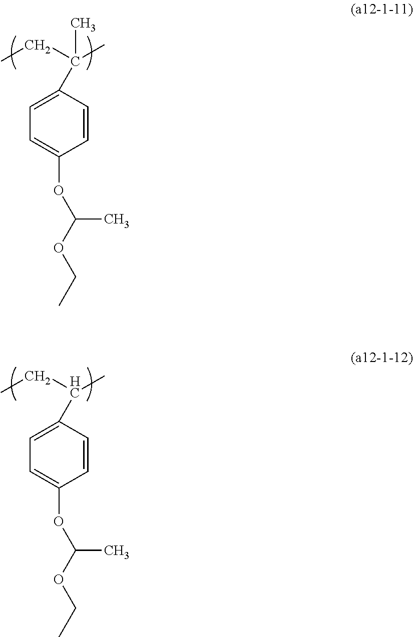

As the structural unit (a12), at least one structural unit selected from the group consisting of structural units represented by general formulas (a12-1-1) to (a12-1-12) is preferable, and a structural units represented by general formulas (a12-1-1), (a12-1-2) and (a12-1-5) to (a12-1-12) are most desirable.

As the structural unit (a1) contained in the component (A1), 1 type of structural unit may be used, or 2 or more types may be used.

In the first aspect and third aspect of the present invention, in the component (A1), the amount of the structural unit (a1) based on the combined total of all structural units constituting the component (A1) is preferably 15 to 70 mol %, more preferably 15 to 60 mol %, and still more preferably 20 to 55 mol %. When the amount of the structural unit (a1) is at least as large as the lower limit of the above-mentioned range, a pattern can be easily formed using a resist composition prepared from the component (A1), and various lithography properties such as sensitivity, resolution, pattern shape and the like are improved. On the other hand, when the amount of the structural unit (a1) is no more than the upper limit of the above-mentioned range, a good balance can be achieved with the other structural units.

As the structural unit (a1) contained in the component (A1b), 1 type of structural unit may be used, or 2 or more types may be used.

In the component (A1b), the amount of the structural unit (a1) based on the combined total of all structural units constituting the component (A1b) is preferably 10 to 70 mol %, more preferably 15 to 66 mol %, still more preferably 20 to 60 mol %, and particularly preferably 35 to 50 mol %.

When the amount of the structural unit (a1) is at least as large as the lower limit of the above-mentioned range, a pattern can be easily formed using a resist composition containing the component (A1), and various lithography properties such as sensitivity, resolution, LWR and the like are improved. On the other hand, when the amount of the structural unit (a1) is no more than the upper limit of the above-mentioned range, a good balance can be achieved with the other structural units.

(Structural Unit (a2))

In the first aspect and third aspect of the present invention, it is preferable that the component (A1) include a structural unit (a2) containing a —SO₂— containing cyclic group or a lactone-containing cyclic group, as well as the structural units (a0) and (a1).

In the second aspect of the present invention, it is preferable that the component (A1b) preferably includes a structural unit (a2′) containing a —SO₂— containing cyclic group, as well as the structural units (a0) and (a5), or the structural units (a0), (a5) and (a1).

When the component (A1) is used for forming a resist film, the —SO₂— containing cyclic group in the structural unit (a2¹) is effective in improving the adhesion between the resist film and the substrate. Furthermore, in the case of alkali developing process, the —SO₂— containing cyclic group in the structural unit (a2′) is effective in increasing the compatibility with a developing solution containing water such as an alkali developing solution.

In the first aspect and third aspect of the present invention, in the case where the structural unit (a0) or (a1) contains a —SO₂— containing cyclic group or a lactone-containing cyclic group in the structure thereof, the structural unit falls under the definition of the structural unit (a2). However, the structural unit is regarded as a structural unit (a0) or (a1), and is not regarded as a structural unit (a2).

In the second aspect of the present invention, in the case where the structural unit (a0), (a5) or (a1) contains a —SO₂— containing cyclic group in the structure thereof, the structural unit falls under the definition of the structural unit (a2′). However, the structural unit is regarded as a structural unit (a0), (a5) or (a1), and is not regarded as a structural unit (a2′).

Here, an “—SO₂— containing cyclic group” refers to a cyclic group having a ring containing —SO₂— within the ring skeleton thereof, i.e., a cyclic group in which the sulfur atom (5) within —SO₂— forms part of the ring skeleton of the cyclic group. The ring containing —SO₂— within the ring skeleton thereof is counted as the first ring. A cyclic group in which the only ring structure is the ring that contains —SO₂— in the ring skeleton thereof is referred to as a monocyclic group, and a group containing other ring structures is described as a polycyclic group regardless of the structure of the other rings. The —SO₂— containing cyclic group may be either a monocyclic group or a polycyclic group.

As the —SO₂— containing cyclic group, a cyclic group containing —O—SO₂— within the ring skeleton thereof, i.e., a cyclic group containing a sultone ring in which —O—S— within the —O—SO₂— group forms part of the ring skeleton thereof is particularly desirable.

The —SO₂— containing cyclic group preferably has 3 to 30 carbon atoms, more preferably 4 to 20, still more preferably 4 to 15, and particularly preferably 4 to 12. Herein, the number of carbon atoms refers to the number of carbon atoms constituting the ring skeleton, excluding the number of carbon atoms within a substituent.

The —SO₂— containing cyclic group may be either a —SO₂— containing aliphatic cyclic group or a —SO₂— containing aromatic cyclic group. A —SO₂— containing aliphatic cyclic group is preferable.

Examples of the —SO₂— containing aliphatic cyclic group include aliphatic cyclic groups in which part of the carbon atoms constituting the ring skeleton has been substituted with a —SO₂— group or a —O—SO₂— group and has at least one hydrogen atom removed from the aliphatic hydrocarbon ring. Specific examples include an aliphatic hydrocarbon ring in which a —CH₂— group constituting the ring skeleton thereof has been substituted with a —SO₂— group and has at least one hydrogen atom removed therefrom; and an aliphatic hydrocarbon ring in which a —CH₂—CH₂— group constituting the ring skeleton has been substituted with a —O—SO₂— group and has at least one hydrogen atom removed therefrom.

The alicyclic hydrocarbon ring preferably has 3 to 20 carbon atoms, and more preferably 3 to 12 carbon atoms.

The alicyclic hydrocarbon ring may be either a monocyclic group or a polycyclic group. As the monocyclic group, a group in which two hydrogen atoms have been removed from a monocycloalkane of 3 to 6 carbon atoms is preferable. Examples of the monocycloalkane include cyclopentane and cyclohexane. As the polycyclic alicyclic hydrocarbon group, a group in which two hydrogen atoms have been removed from a polycycloalkane of 7 to 12 carbon atoms is preferable. Examples of the polycycloalkane include adamantane, norbornane, isobornane, tricyclodecane and tetracyclododecane.

The —SO₂— containing cyclic group may have a substituent. Examples of substituents include an alkyl group, an alkoxy group, a halogen atom, a halogenated alkyl group, a hydroxy group, an oxygen atom (═O), —COOR″, —OC(═O)R″, a hydroxyalkyl group and a cyano group.

The alkyl group as a substituent is preferably an alkyl group of 1 to 6 carbon atoms. Further, the alkyl group is preferably a linear alkyl group or a branched alkyl group. Specific examples include a methyl group, ethyl group, propyl group, isopropyl group, n-butyl group, isobutyl group, tert-butyl group, pentyl group, isopentyl group, neopentyl group and hexyl group. Among these examples, a methyl group or an ethyl group is preferable, and a methyl group is particularly desirable.

As the alkoxy group as a substituent, an alkoxy group of 1 to 6 carbon atoms is preferable. Further, the alkoxy group is preferably a linear alkoxy group or a branched alkoxy group. Specific examples of the alkoxy groups include the aforementioned alkyl groups for the substituent having an oxygen atom (—O—) bonded thereto.

Examples of the halogen atom as a substituent include a fluorine atom, a chlorine atom, a bromine atom and an iodine atom, and a fluorine atom is preferable.

Examples of the halogenated alkyl group as a substituent include groups in which part or all of the hydrogen atoms within the aforementioned alkyl groups has been substituted with the aforementioned halogen atoms.

As examples of the halogenated alkyl group as a substituent, groups in which part or all of the hydrogen atoms of the aforementioned alkyl groups for the substituent have been substituted with the aforementioned halogen atoms can be given. As the halogenated alkyl group, a fluorinated alkyl group is preferable, and a perfluoroalkyl group is particularly desirable.

In the —COOR″ group and the —OC(═O)R″ group, R″ represents a hydrogen atom or a linear, branched or cyclic alkyl group of 1 to 15 carbon atoms.

When R″ represents a linear or branched alkyl group, it is preferably an alkyl group of 1 to 10 carbon atoms, more preferably an alkyl group of 1 to 5 carbon atoms, and most preferably a methyl group or an ethyl group.

When R″ is a cyclic alkyl group (cycloalkyl group), it preferably has 3 to 15 carbon atoms, more preferably 4 to 12 carbon atoms, and most preferably 5 to 10 carbon atoms. As examples of the cycloalkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Specific examples include groups in which one or more hydrogen atoms have been removed from a monocycloalkane such as cyclopentane and cyclohexane; and groups in which one or more hydrogen atoms have been removed from a polycycloalkane such as adamantane, norbornane, isobornane, tricyclodecane or tetracyclododecane.

The hydroxyalkyl group as a substituent preferably has 1 to 6 carbon atoms, and specific examples thereof include the aforementioned alkyl groups as a substituent in which at least one hydrogen atom has been substituted with a hydroxy group.

More specific examples of the —SO₂— containing cyclic group include groups represented by general formulas (3-1) to (3-4) shown below.

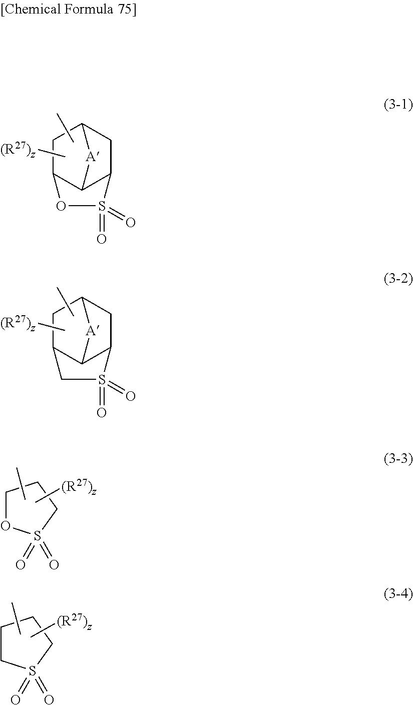

In the formulas, A′ represents an oxygen atom, a sulfur atom or an alkylene group of 1 to 5 carbon atoms which may contain an oxygen atom or a sulfur atom; z represents an integer of 0 to 2; and R²⁷ represents an alkyl group, an alkoxy group, a halogenated alkyl group, a hydroxyl group, —COOR″, —OC(═O)R″, a hydroxyalkyl group or a cyano group, wherein R″ represents a hydrogen atom or an alkyl group.

In general formulas (3-1) to (3-4) above, A′ represents an oxygen atom (—O—), a sulfur atom (—S—) or an alkylene group of 1 to 5 carbon atoms which may contain an oxygen atom or a sulfur atom.

As the alkylene group of 1 to 5 carbon atoms for A′, a linear or branched alkylene group is preferable, and examples thereof include a methylene group, an ethylene group, an n-propylene group and an isopropylene group.

Examples of alkylene groups that contain an oxygen atom or a sulfur atom include the aforementioned alkylene groups in which —O— or —S— is bonded to the terminal of the alkylene group or interposed within the alkylene group. Specific examples of such alkylene groups include —O—CH₂—, —CH₂—O—CH₂—, —S—CH₂— and —CH₂—S—CH₂—.

As A′, an alkylene group of 1 to 5 carbon atoms or —O— is preferable, more preferably an alkylene group of 1 to 5 carbon atoms, and most preferably a methylene group.

z represents an integer of 0 to 2, and is most preferably 0.

If there are two of the R²⁷ groups, as indicated by the value z, then the two of the R²⁷ groups may be the same or different from each other.

As the alkyl group, alkoxy group, halogenated alkyl group, —COOR″, —OC(═O)R″ and hydroxyalkyl group for R²⁷, the same alkyl groups, alkoxy groups, halogenated alkyl groups, —COOR″, —OC(═O)R″ and hydroxyalkyl groups as those described above as the substituent for the —SO₂— containing cyclic group can be mentioned.

Specific examples of the cyclic groups represented by general formulas (3-1) to (3-4) are shown below. In the formulas shown below, “Ac” represents an acetyl group.

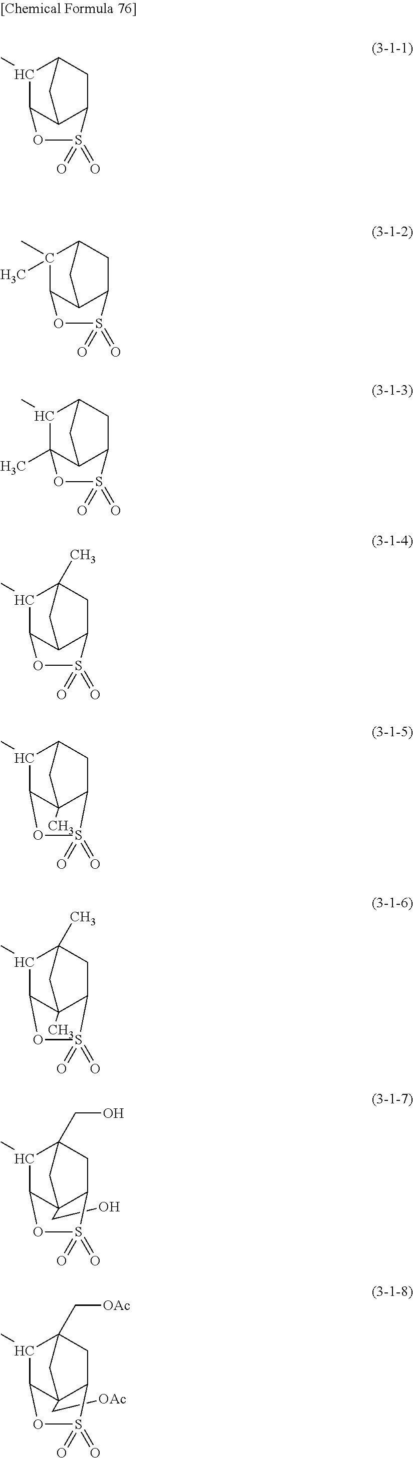

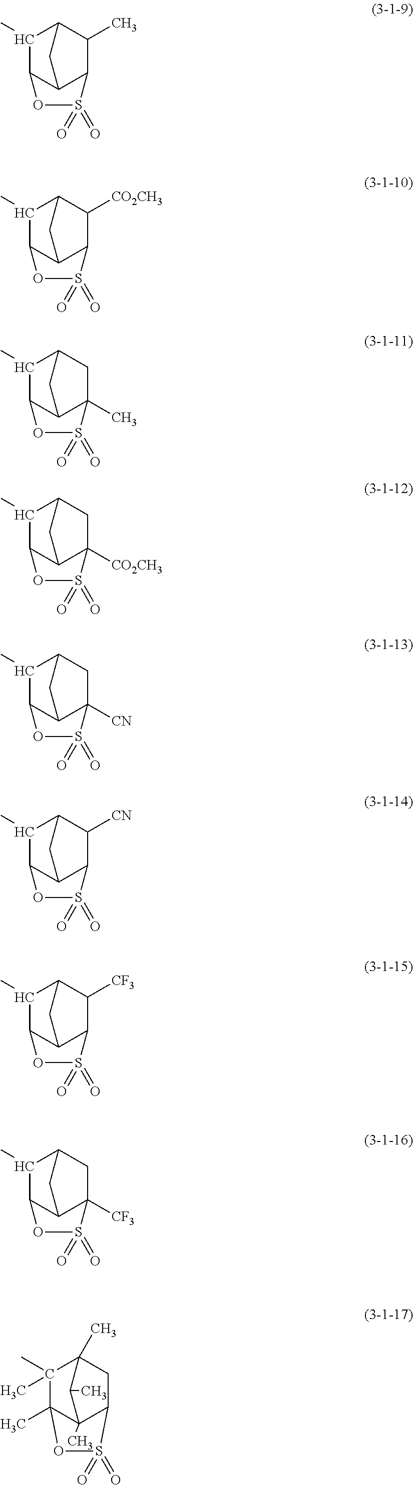

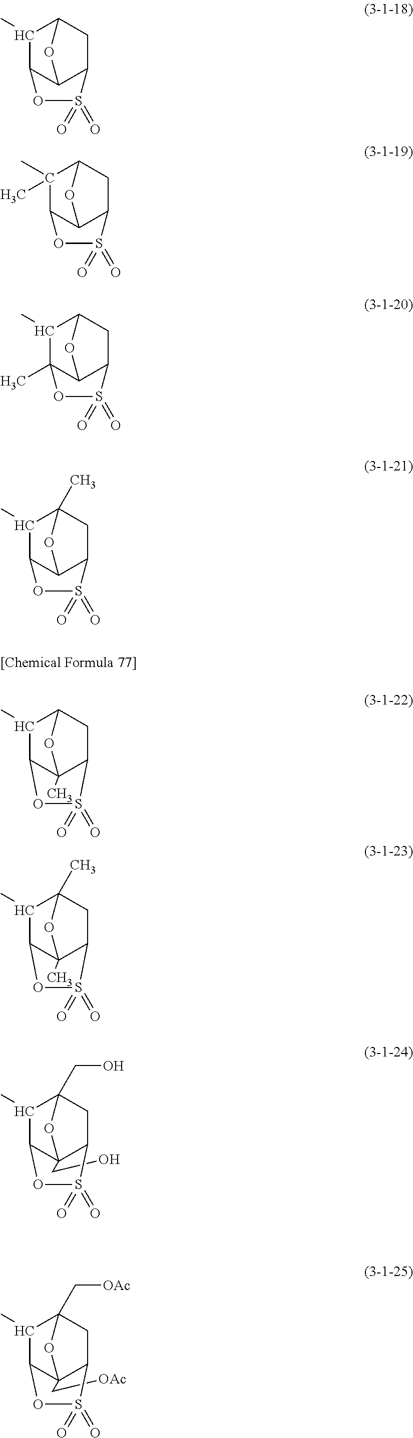

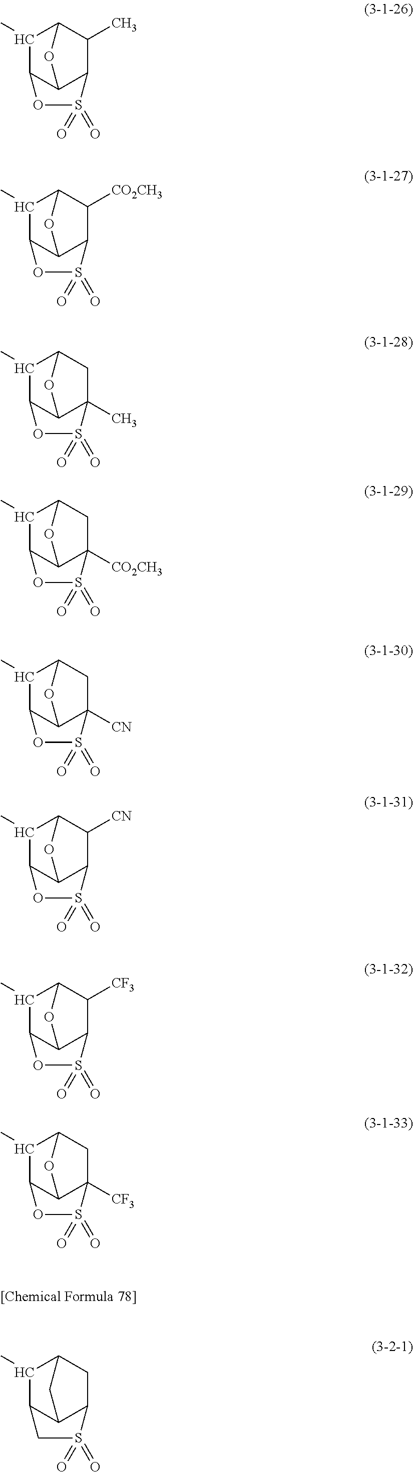

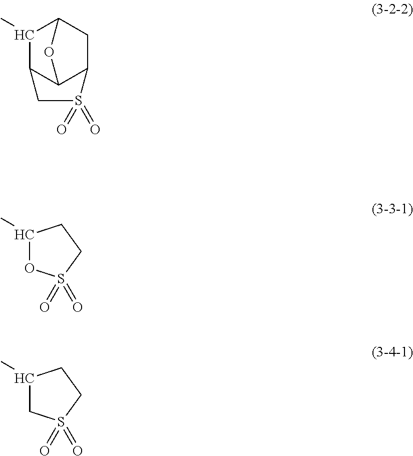

As the —SO₂— containing cyclic group, a group represented by the aforementioned general formula (3-1) is preferable, at least one member selected from the group consisting of groups represented by the aforementioned chemical formulas (3-1-1), (3-1-18), (3-3-1) and (3-4-1) is more preferable, and a group represented by the chemical formula (3-1-1) is most preferable.

The term “lactone-containing cyclic group” is the same as a “group containing a lactone ring” described later.

With respect to the structural unit (a2), the partial structure other than the —SO₂— containing cyclic group or a lactone-containing cyclic group is not particularly limited as long as the structural unit (a2) having an —SO₂— containing cyclic group or a lactone-containing cyclic group. The structural unit (a2) is preferably at least one structural unit selected from the group consisting of a structural unit derived from an acrylate ester which may have the hydrogen atom bonded to the carbon atom on the α-position substituted with a substituent and contains an —SO₂— containing cyclic group (hereafter, referred to as “structural unit (a2^{S})”), and a structural unit derived from an acrylate ester which may have the hydrogen atom bonded to the carbon atom on the α-position substituted with a substituent and contains a lactone-containing cyclic group (hereafter, referred to as “structural unit (a2^{L})”).

The structural unit (a2′) is not particularly limited as long as it has an —SO₂— containing cyclic group, and is preferable a structural unit (a2^{S}) derived from an acrylate ester which may have the hydrogen atom bonded to the carbon atom on the α-position substituted with a substituent and contains an —SO₂— containing cyclic group.

—Structural Unit (a2^{S}):

More specific examples of the structural unit (a2^{S}) include structural units represented by general formula (a2-0) shown below.

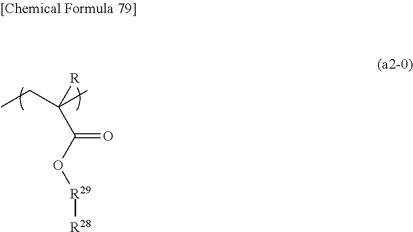

In the formula, R represents a hydrogen atom, an alkyl group of 1 to 5 carbon atoms or a halogenated alkyl group of 1 to 5 carbon atoms; R²⁸ represents a —SO₂— containing cyclic group; and R²⁹ represents a single bond or a divalent linking group.

In genera formula (a2-0), R is the same as defined above.

R²⁸ is the same as defined for the aforementioned —SO₂— containing group.

R²⁹ may be either a single bond or a divalent linking group. In terms of the effects of the present invention, a divalent linking group is preferable.

R²⁹ is not particularly limited. For example, the same divalent linking groups as those described for L⁰¹ in general formula (1-1) in relation to the component (W) can be mentioned. Among these, an alkylene group or a divalent linking group containing an ester bond (—C(═O)—O—) is preferable.

As the alkylene group, a linear or branched alkylene group is preferable. Specific examples include the same linear alkylene groups and branched alkylene groups as those described above in relation to the aliphatic hydrocarbon group for Y².

As the divalent linking group containing an ester bond, a group represented by general formula: —R³⁰—C(═O)—O— (in the formula, R³⁰ represents a divalent linking group) is particularly desirable. That is, the structural unit (a2^{S}) is preferably a structural unit represented by general formula (a2-0-1) shown below.

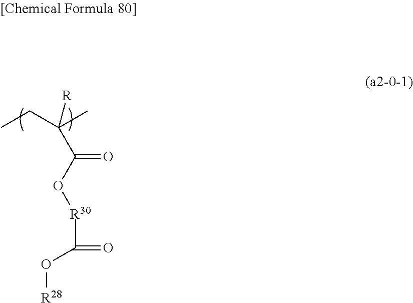

In the formula, R and R²⁸ are the same as defined above; and R³⁰ represents a divalent linking group.

R³⁰ is not particularly limited. For example, the same divalent linking groups as those described for L⁰¹ in general formula (1-1) in relation to the component (W) can be mentioned.

As the divalent linking group for R³⁰, a linear or branched alkylene group, an aliphatic hydrocarbon group containing a ring in the structure thereof or a divalent linking group containing a hetero atom is preferable, and a linear or branched alkylene group or a divalent linking group containing an oxygen atom as a hetero atom is more preferable.

As the linear alkylene group, a methylene group or an ethylene group is preferable, and a methylene group is particularly desirable.

As the branched alkylene group, an alkylmethylene group or an alkylethylene group is preferable, and —CH(CH₃)—, —C(CH₃)₂— or —C(CH₃)₂CH₂— is particularly desirable.

As the divalent linking group containing an oxygen atom, a divalent linking group containing an ether bond or an ester bond is preferable, and a group represented by the aforementioned formulas —Y²¹—O—Y²²—, —[Y²¹—C(═O)—O]_{m′}—Y²²— or —Y²¹—O—C(═O)—Y²²— is more preferable. Each of Y²¹ and Y²² independently represents a divalent hydrocarbon group which may have a substituent and m′ represents an integer of 0 to 3. Among these, a group represented by formula —Y²¹—O—C(═O)—Y²²— is preferable, and a group represented by formula —(CH₂)_{c}—O—C(═O)—(CH₂)_{d}— is particularly preferable. c represents an integer of 1 to 5, and preferably 1 or 2. d represents an integer of 1 to 5, and preferably 1 or 2.

In particular, as the structural unit (a2^{S}), a structural unit represented by general formula (a2-0-11) or (a2-0-12) shown below is preferable, and a structural unit represented by general formula (a2-0-12) shown below is more preferable.

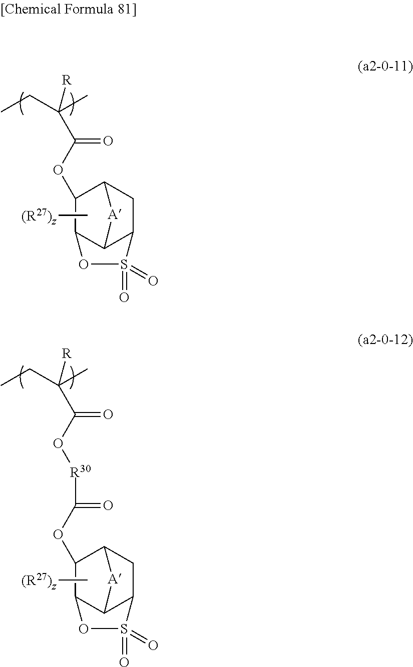

In the formulas, R, A′, R²⁷, z and R³⁰ are the same as defined above.

In general formula (a2-0-11), A′ is preferably a methylene group, an oxygen atom (—O—) or a sulfur atom (—S—).

As R³⁰ a linear or branched alkylene group or a divalent linking group containing an oxygen atom is preferable. As the linear or branched alkylene group and the divalent linking group containing an oxygen atom for R³⁰, the same linear or branched alkylene groups and the divalent linking groups containing an oxygen atom as those described above can be mentioned.

As the structural unit represented by general formula (a2-0-12), a structural unit represented by general formula (a2-0-12a) or (a2-0-12b) shown below is particularly desirable.

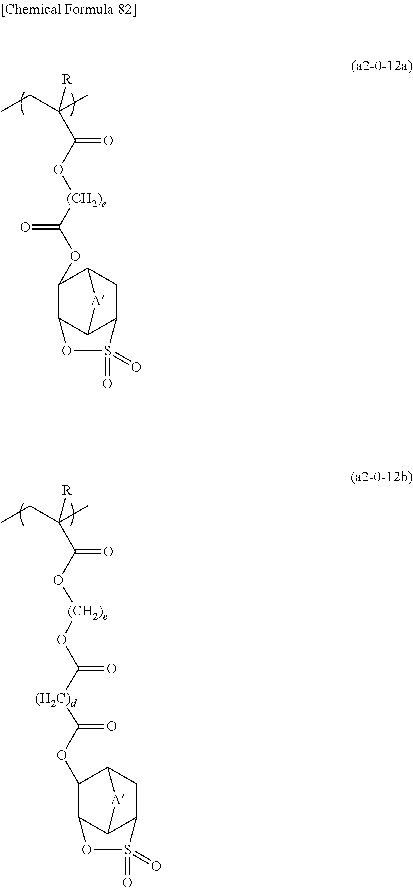

In the formulas, R and A′ are the same as defined above; and each of c to e independently represents an integer of 1 to 3.

—Structural Unit (a2^{L}):

Examples of the structural unit (a2^{L}) include structural units represented by the aforementioned general formula (a2-0) in which the R²⁸ group has been substituted with a lactone-containing cyclic group. Specific examples include structural units represented by general formulas (a2-1) to (a2-5) shown below.

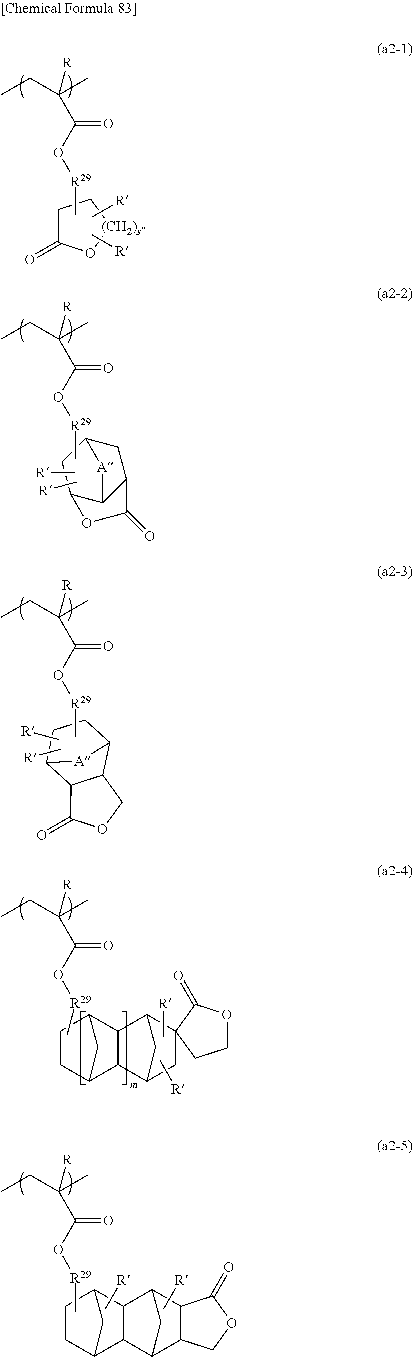

In the formulas, R represents a hydrogen atom, an alkyl group of 1 to 5 carbon atoms or a halogenated alkyl group of 1 to 5 carbon atoms; each R′ independently represents a hydrogen atom, an alkyl group, an alkoxy group, a halogen atom, a halogenated alkyl group, a hydroxy group, an oxygen atom (═O), —COOR″, —OC(═O)R″, a hydroxyalkyl group, or a cyano group, wherein R″ represents a hydrogen atom or an alkyl group; R²⁹ represents a single bond or a divalent linking group; s″ represents an integer of 0 to 2; A″ represents an oxygen atom, a sulfur atom or an alkylene group of 1 to 5 carbon atoms which may contain an oxygen atom or a sulfur atom; and m represents 0 or 1.

In general formulas (a2-1) to (a2-5), R is the same as defined above.

As the alkyl group, alkoxy group, halogen atom, halogenated alkyl group, —COOR″, —OC(═O)R″ and hydroxyalkyl group for R′, the same alkyl groups, alkoxy groups, halogen atoms, halogenated alkyl groups, —COOR″, —OC(═O)R″ (wherein R″ is the same as defined above) and hydroxyalkyl groups as those described above as the substituent for the —SO₂— containing cyclic group can be mentioned.

In terms of industrial availability, R′ is preferably a hydrogen atom.

As examples of A″, the same groups as those described above for A′ in general formula (3-1) can be given. A″ is preferably an alkylene group of 1 to 5 carbon atoms, an oxygen atom (—O—) or a sulfur atom (—S—), and more preferably an alkylene group of 1 to 5 carbon atoms or —O—. As the alkylene group of 1 to 5 carbon atoms, a methylene group or a dimethylethylene group is preferable, and a methylene group is particularly desirable.

R²⁹ is the same as defined for R²⁹ in the aforementioned general formula (a2-0).

In formula (a2-1), s″ is preferably 1 or 2.

Specific examples of structural units represented by general formulas (a2-1) to (a2-5) are shown below. In the formulas shown below, R^{α} represents a hydrogen atom, a methyl group or a trifluoromethyl group.

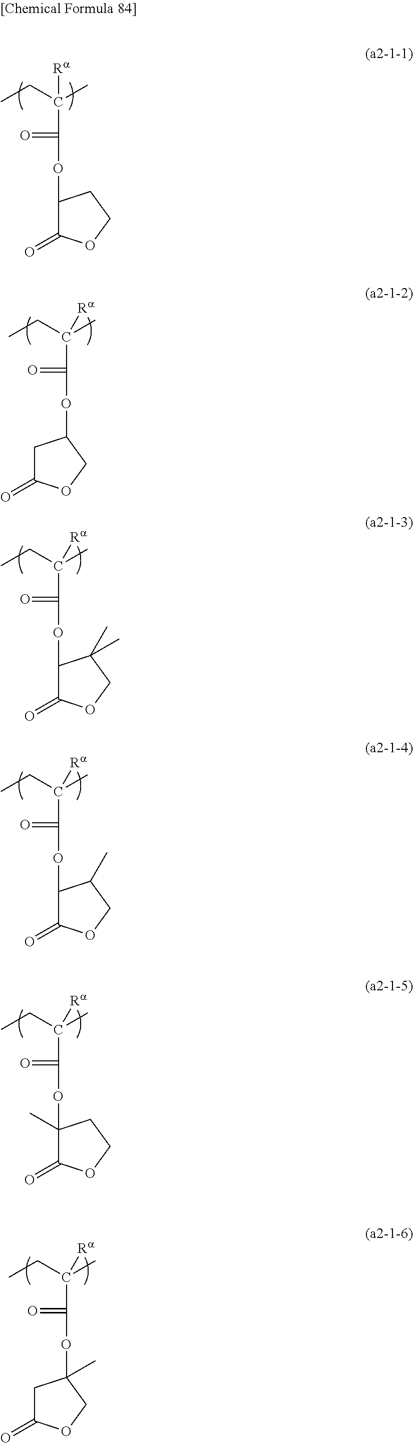

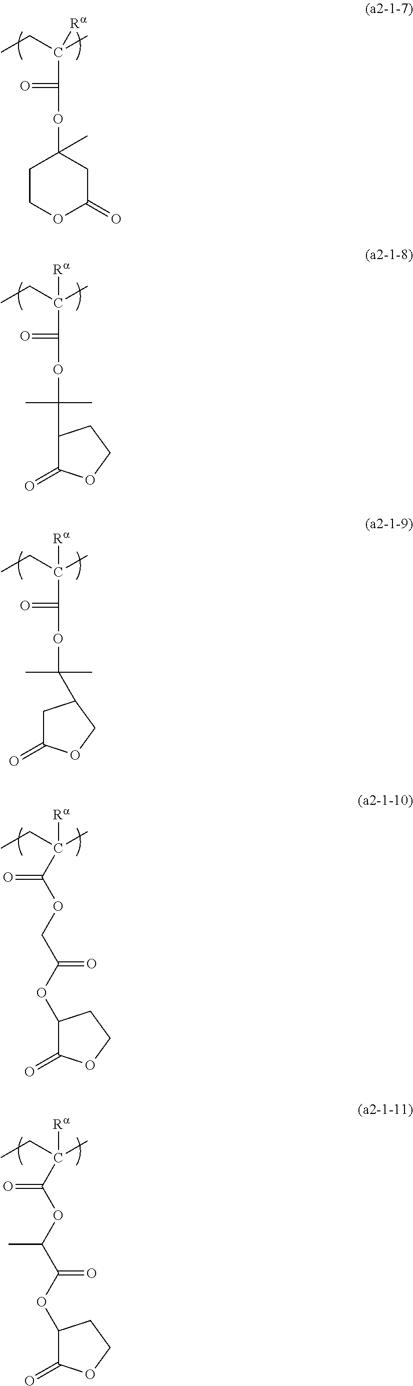

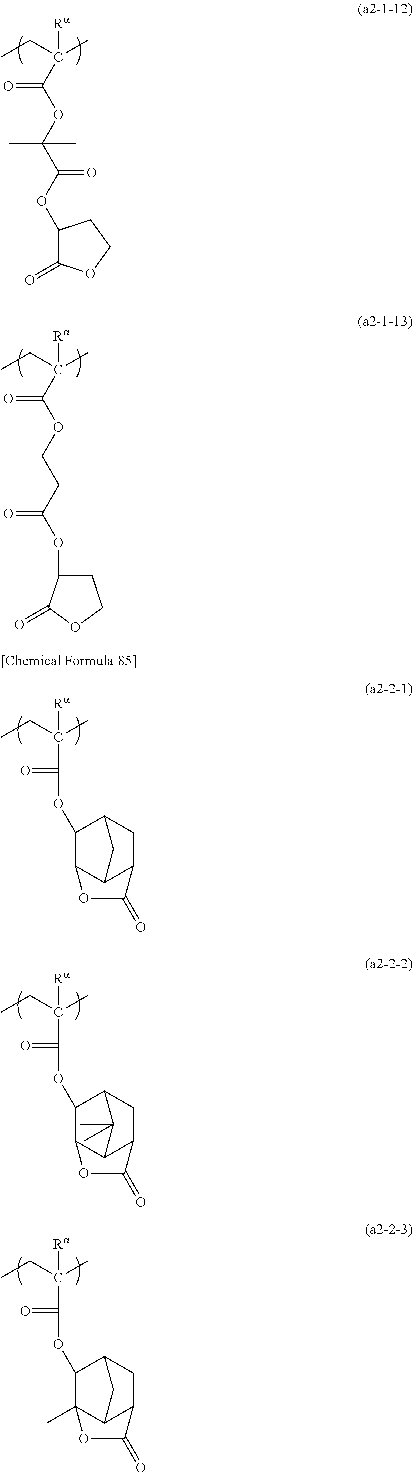

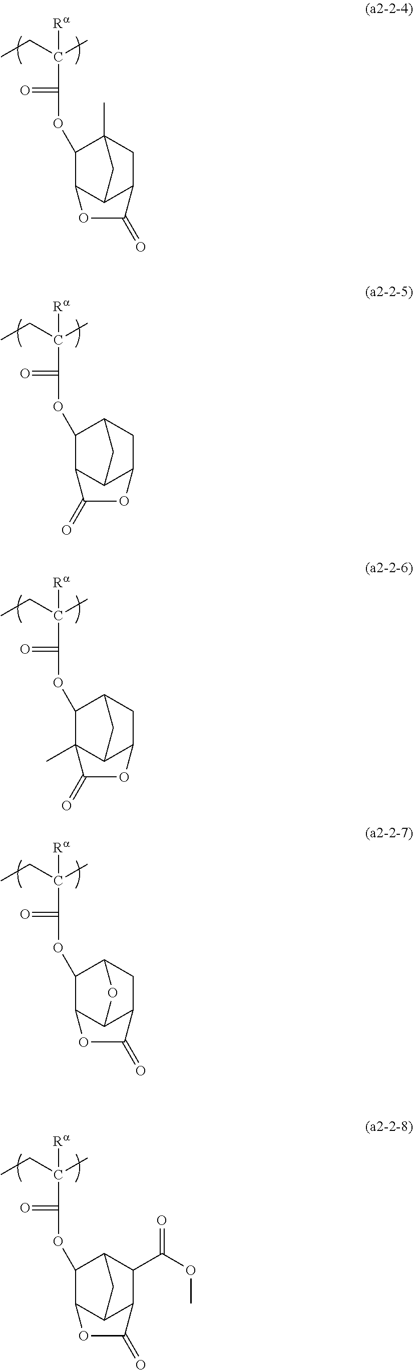

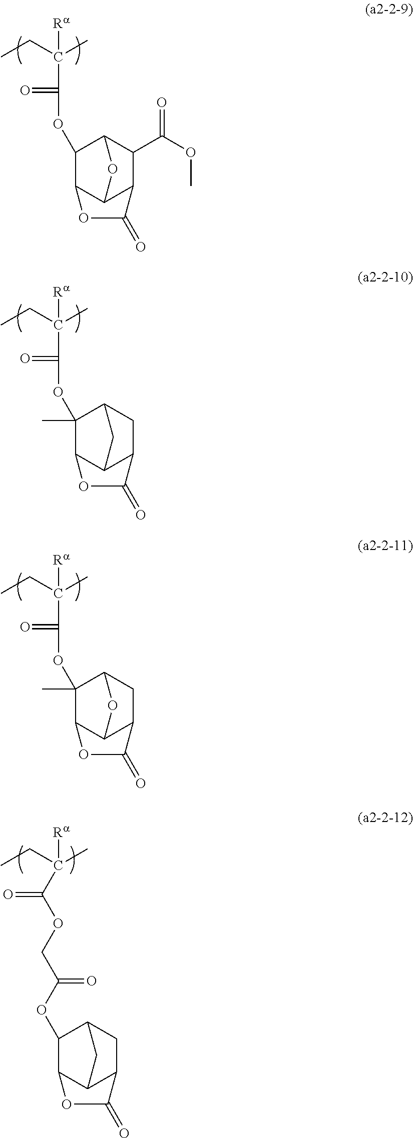

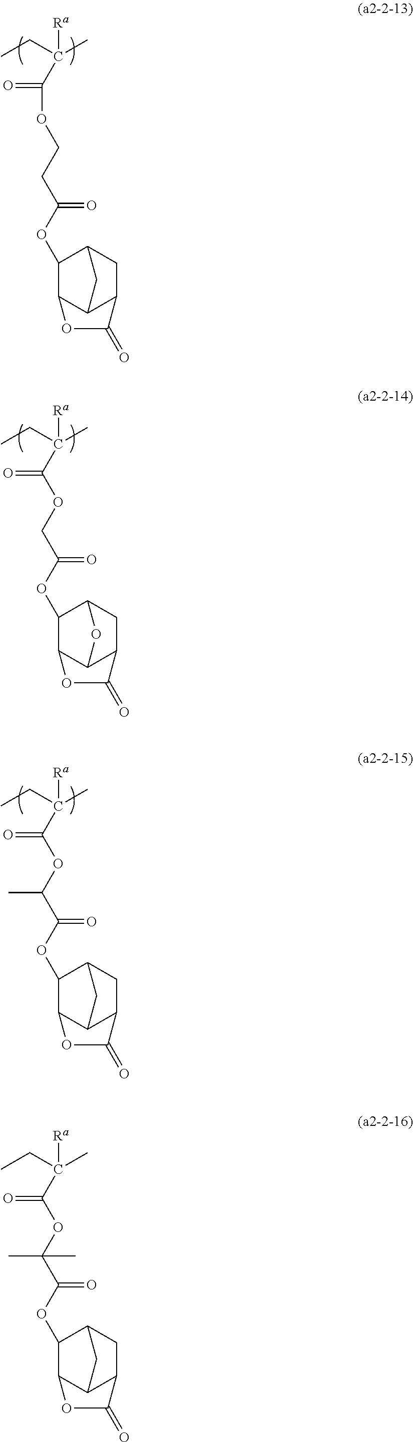

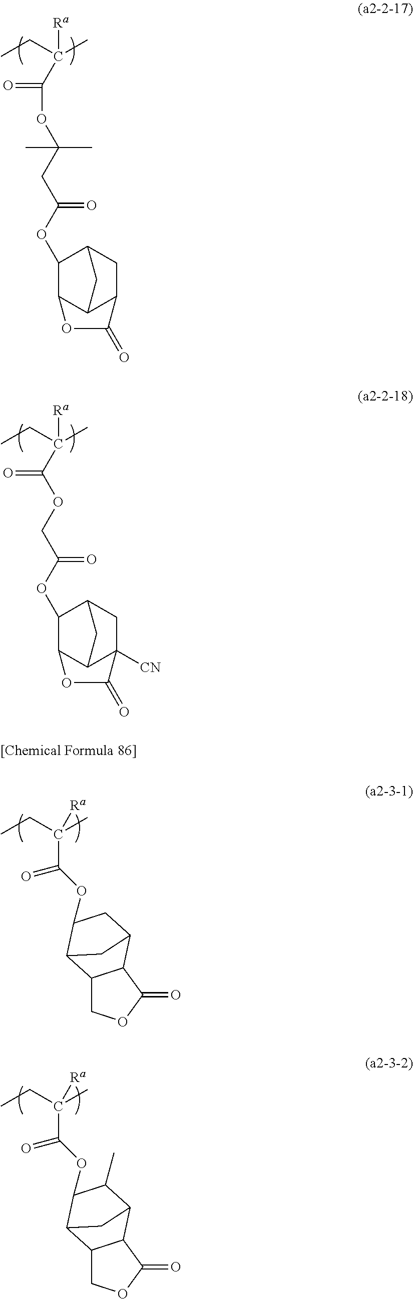

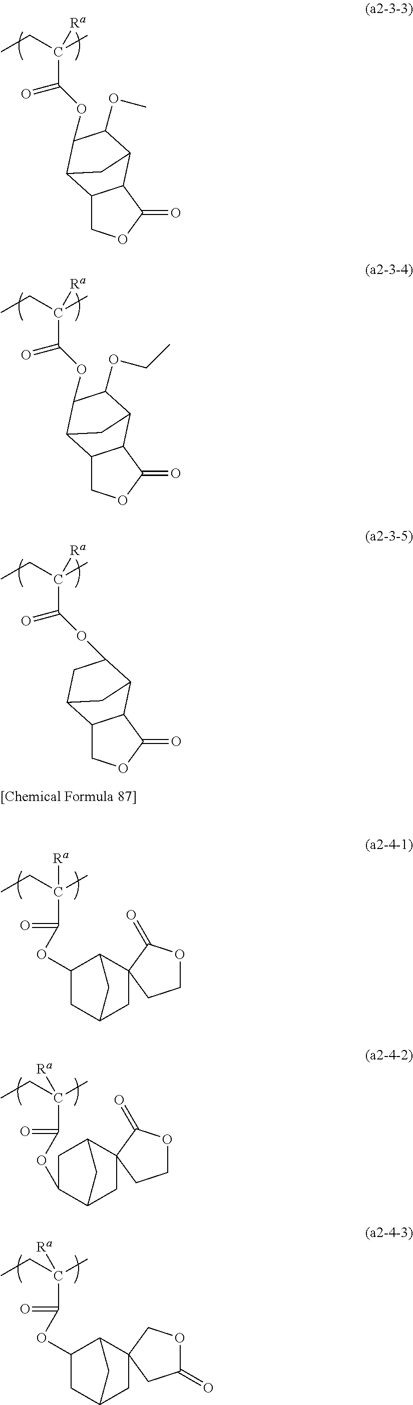

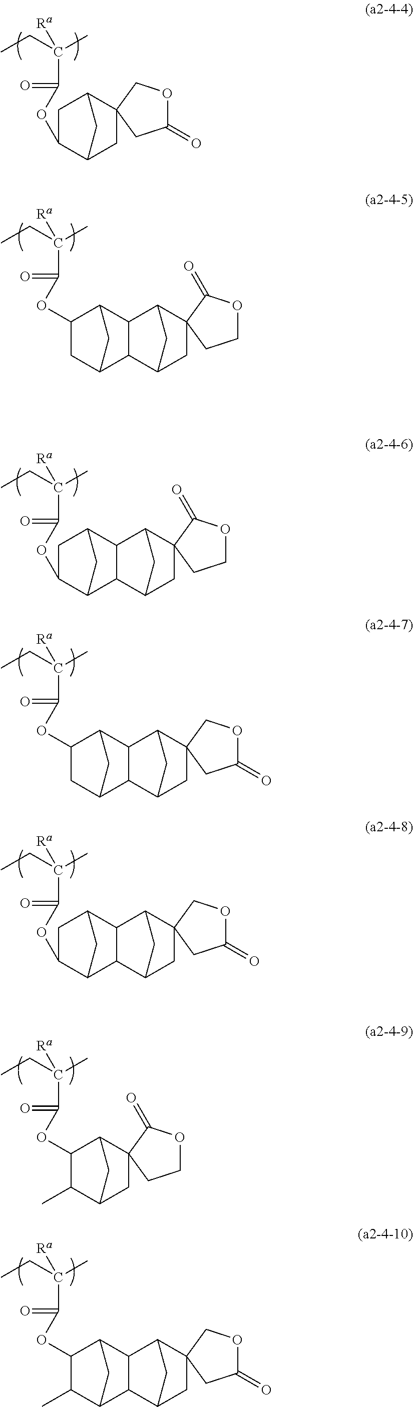

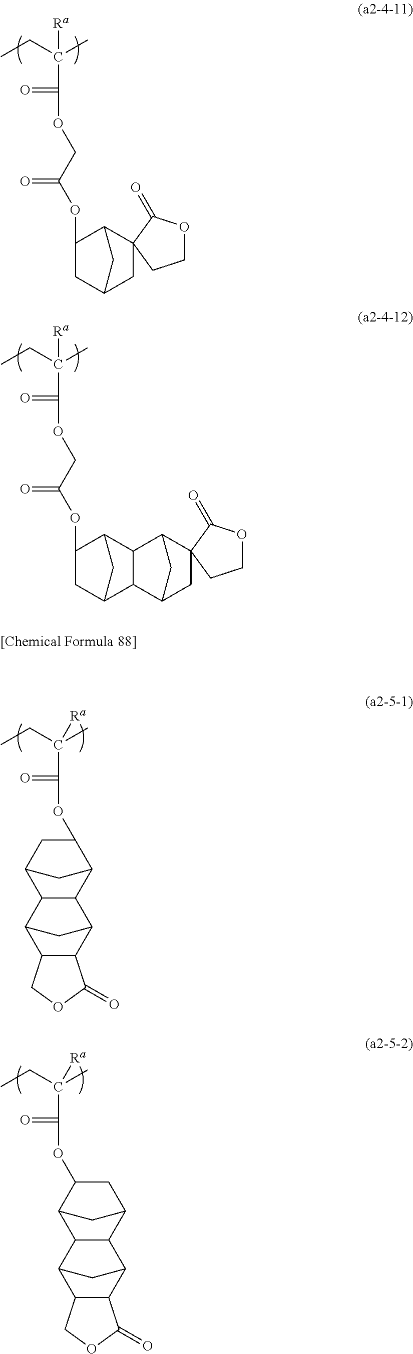

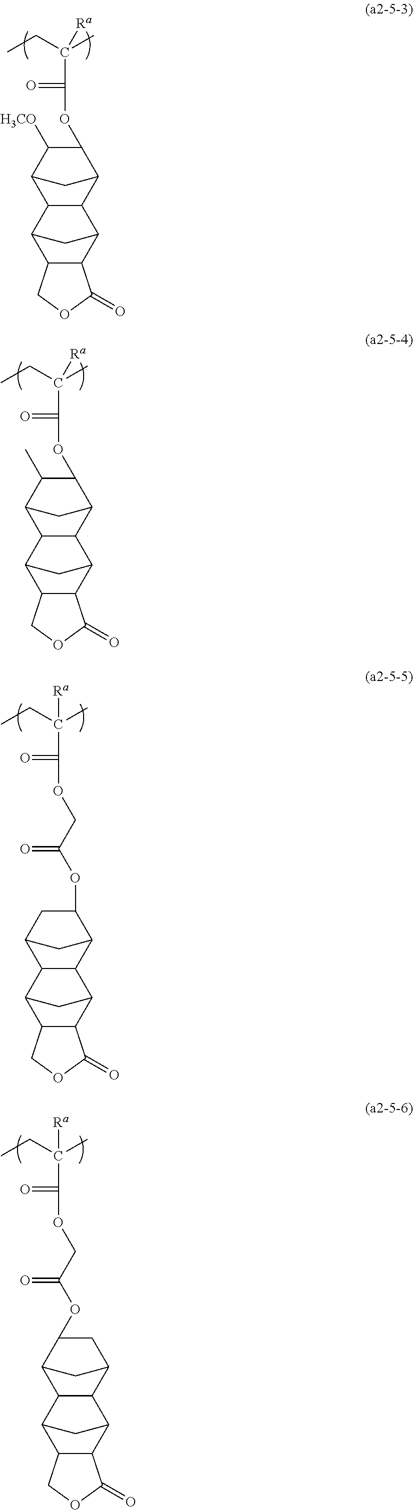

As the structural unit (a2^{L}), a base component preferably includes at least one structural unit selected from the group consisting of structural units represented by the aforementioned general formulas (a2-1) to (a2-5), more preferably at least one structural unit selected from the group consisting of structural units represented by the aforementioned general formulas (a2-1) to (a2-3), and particularly preferably at least one structural unit selected from the group consisting of structural units represented by the aforementioned general formulas (a2-1) and (a2-3).

Specifically, a base component preferably includes at least one structural unit selected from the group consisting of formulas (a2-1-1), (a2-1-2), (a2-2-1), (a2-2-7), (a2-2-12), (a2-2-14), (a2-3-1) and (a2-3-5).

Furthermore, as the structural unit (a2^{L}), structural units represented by general formulas (a2-6) and (a2-7) shown below are also preferable.

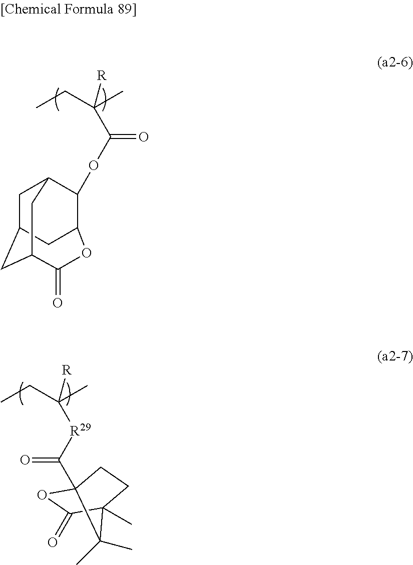

In the formula, R²⁹ is the same as those defined above.

As the structural unit (a2) contained in the component (A1), 1 type of structural unit may be used, or 2 or more types may be used. For example, as the structural unit (a2), a structural unit (a2^{S}) or a structural unit (a2^{L}) may be used alone, or a combination of these structural units may be used. Further, as the structural unit (a2^{S}) or the structural unit (a2^{L}), either a single type of structural unit may be used, or two or more types may be used in combination.

In the first aspect or third aspect of the present invention, in the component (A1), the amount of the structural unit (a2) based on the combined total of all structural units constituting the component (A1) is preferably 1 to 80 mol %, more preferably 10 to 70 mol %, still more preferably 10 to 65 mol %, and most preferably 10 to 60 mol %. When the amount of the structural unit (a2) is at least as large as the lower limit of the above-mentioned range, the effect of using the structural unit (a2) can be satisfactorily achieved. On the other hand, when the amount of the structural unit (a2) is no more than the upper limit of the above-mentioned range, a good balance can be achieved with the other structural units, and various lithography properties such as DOF and CDU and pattern shape can be improved.

As the structural unit (a2′) contained in the component (A1b), 1 type of structural unit may be used, or 2 or more types may be used.

In the second aspect of the present invention, when the component (A1b) contains the structural unit (a2′), the amount of the structural unit (a2′) based on the combined total of all structural units constituting the component (A1b) is preferably 1 to 80 mol %, more preferably 10 to 70 mol %, still more preferably 10 to 65 mol %, and most preferably 10 to 60 mol %. When the amount of the structural unit (a2′) is at least as large as the lower limit of the above-mentioned range, the effect of using the structural unit (a2′) can be satisfactorily achieved. On the other hand, when the amount of the structural unit (a2′) is no more than the upper limit of the above-mentioned range, a good balance can be achieved with the other structural units, and various lithography properties such as DOF and CDU and pattern shape can be improved.

(Structural Unit (a3))

The structural unit (a3) is a structural unit containing a polar group and does not fall under the definition of the aforementioned structural units (a0-1), (a0-2), (a1), (a2) and (a2′).

In the first aspect or third aspect of the present invention, the component (A1) may include a structural unit (a3) containing a polar group, as well as the structural units (a0) and (a1), or the structural units (a0), (a1) and (a2). When the component (A1) includes the structural unit (a3), the polarity of the component (A1) after exposure is enhanced. In the case of alkali development process, a high polarity contributes to improving resolution and the like.

In the second aspect of the present invention, the component (A1b) may include a structural unit (a3) containing a polar group, as well as the structural units (a0) and (a5), or the structural units (a0), (a5) and (a1). When the component (A1b) includes the structural unit (a3), the polarity of the component (A1b) after exposure is enhanced. In the case of alkali development process, a high polarity contributes to improving resolution and the like.

Examples of the polar group include —OH, —COOH, —CN, —SO₂NH₂— and —CONH₂. As the structural unit containing —COOH, a structural unit derived from the (α-substituted) acrylic acid.

The structural unit (a3) is a structural unit containing a hydrocarbon group in which part of the hydrogen atoms within the hydrocarbon group is substituted with the polar group. The hydrocarbon group may be either an aliphatic hydrocarbon group or an aromatic hydrocarbon group. Among these, the hydrocarbon group is preferably an aliphatic hydrocarbon group.

Examples of the aliphatic hydrocarbon group in the hydrocarbon group include linear or branched hydrocarbon groups (preferably alkylene groups) of 1 to 10 carbon atoms, and aliphatic cyclic groups (monocyclic groups and polycyclic groups).

These aliphatic cyclic groups (monocyclic groups and polycyclic groups) can be selected appropriately from the multitude of groups that have been proposed for the resins of resist compositions designed for use with ArF excimer lasers. The aliphatic cyclic group preferably has 3 to 30 carbon atoms, more preferably 5 to 30, still more preferably 5 to 20, particularly preferably 6 to 15, and most preferably 6 to 12. As the aliphatic cyclic group, a group in which two or more hydrogen atoms have been removed from a monocycloalkane or a polycycloalkane such as a bicycloalkane, tricycloalkane or tetracycloalkane can be used. Specific examples include groups in which two or more hydrogen atoms have been removed from a monocycloalkane such as cyclopentane or cyclohexane; and groups in which two or more hydrogen atoms have been removed from a polycycloalkane such as adamantane, norbornane, isobornane, tricyclodecane or tetracyclododecane. The aliphatic cyclic group may or may not have a substituent. Examples of the substituent include an alkyl group of 1 to 5 carbon atoms, a fluorine atom and a fluorinated alkyl group of 1 to 5 carbon atoms.

The aromatic hydrocarbon group in the hydrocarbon group is a hydrocarbon group containing a aromatic ring, and more preferably has 5 to 30 carbon atoms, still more preferably 6 to 20, particularly preferably 6 to 15, and most preferably 6 to 10. Here, the number of carbon atoms within a substituent(s) is not included in the number of carbon atoms of the aromatic hydrocarbon group. The aromatic ring in the aromatic hydrocarbon group is the same as defined above and specific examples thereof include aromatic hydrocarbon rings such as benzene, biphenyl, fluorene, naphthalene, anthracene and phenanthrene.

Specific examples of the aromatic hydrocarbon group include a group in which two or more hydrogen atoms have been removed from the aromatic ring (arylene group); a group in which two hydrogen atoms have been removed from an aromatic compound having two or more aromatic rings (for example, biphenyl or fluorene); and a group in which one hydrogen atom has been removed from the aromatic ring (aryl group) and another one hydrogen atom has been substituted with an alkylene group (for example, a group in which one hydrogen atom has been removed from an aryl group of an arylalkyl group such as a benzyl group, a phenethyl group, a 1-naphthylmethyl group, a 2-naphthylmethyl group, a 1-naphthylethyl group, or a 2-naphthylethyl group). The alkylene group (alkyl chain within the arylalkyl group) preferably has 1 to 4 carbon atom, more preferably 1 or 2, and particularly preferably 1.

In the aromatic hydrocarbon group, part of the carbon atom constituting the aromatic ring may be substituted with a hetero atom to form an aromatic heterocycle.

Examples of hetero atoms within the aromatic heterocycle include an oxygen atom, a nitrogen atom, and a sulfur atom.

Specific examples of aromatic heterocycles include a pyridine ring and a thiophene ring.

The aromatic hydrocarbon group may or may not have a substituent. For example, the hydrogen atom bonded to the aromatic ring within the aromatic hydrocarbon group may be substituted with a substituent. Examples of substituents include an alkyl group, an alkoxy group, a halogen atom, a halogenated alkyl group, a hydroxy group and an oxygen atom (═O).

The alkyl group as a substituent is preferably an alkyl group of 1 to 5 carbon atoms, and a methyl group, an ethyl group, a propyl group, an n-butyl group or a tert-butyl group is most desirable.

Examples of the halogen atom as a substituent for the aromatic hydrocarbon group include a fluorine atom, a chlorine atom, a bromine atom and an iodine atom, and a fluorine atom is preferable.

Examples of the halogenated alkyl group as a substituent include groups in which part or all of the hydrogen atoms within the aforementioned alkyl groups has been substituted with the aforementioned halogen atoms.

Among these, as the structural unit (a3), a structural unit represented by general formula (a3-1) shown below is preferable.

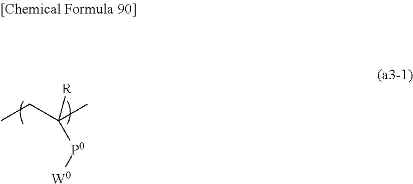

In the formula, R represents a hydrogen atom, an alkyl group of 1 to 5 carbon atoms or a halogenated alkyl group of 1 to 5 carbon atoms; P⁰ represents —C(═O)—O—, —C(═O)—NR⁰— (wherein R⁰ represents a hydrogen atom or an alkyl group of 1 to 5 carbon atoms) or a single bond; and W⁰ represents —COOH, a hydrocarbon group containing at least one group as a substituent selected from the group consisting of —OH, —COOH, —CN, —SO₂NH₂ and —CONH₂ or a group represented by formula —CONHCO—R^{a3} (wherein R^{a3} represents a hydrocarbon group) and may contain an oxygen atom or a sulfur atom at an arbitrary position.

As the alkyl group for R in the formula (a3-1), a linear or branched alkyl group is preferable, and specific examples include a methyl group, an ethyl group, a propyl group, an isopropyl group, an n-butyl group, an isobutyl group, a tert-butyl group, a pentyl group, an isopentyl group and a neopentyl group.

Examples of the halogenated alkyl group for R include groups in which part or all of the hydrogen atoms within the aforementioned alkyl groups for R. Examples of the halogen atom include a fluorine atom, a chlorine atom, a bromine atom and an iodine atom, and a fluorine atom is particularly preferred.

As R, a hydrogen atom, an alkyl group of 1 to 5 carbon atoms or a fluorinated alkyl group of 1 to 5 carbon atoms is preferable, and a hydrogen atom or a methyl group is particularly desirable.

In the formula (a3-1), P⁰ represents —C(═O)—O—, —C(═O)—NR⁰— (wherein R⁰ represents a hydrogen atom or an alkyl group of 1 to 5 carbon atoms) or a single bond. The alkyl group for R⁰ is the same alkyl group as described above for R.

In the formula (a3-1), W⁰ represents a hydrocarbon group containing at least one group as a substituent selected from the group consisting of —OH, —COOH, —CN, —SO₂NH₂ and —CONH₂ or a group represented by formula —CONHCO—R^{a3} (wherein R^{a3} represents a hydrocarbon group) and may contain an oxygen atom or a sulfur atom at an arbitrary position.

A “hydrocarbon group which have a substituent” means a group in which part or all of the hydrogen atoms within the hydrocarbon group is substituted with a substituent.

The hydrocarbon group for W⁰ or R^{a3} may be either an aliphatic hydrocarbon group, or an aromatic hydrocarbon group.

Examples of the aliphatic hydrocarbon group for W⁰ or R^{a3} include linear or branched hydrocarbon groups (preferably alkylene groups) of 1 to 10 carbon atoms, and aliphatic cyclic groups (monocyclic groups and polycyclic groups), and these definitions are the same as those described above.

The aromatic hydrocarbon group for W⁰ or R^{a3} is a hydrocarbon group having an aromatic ring, and these definitions are the same as those described above.

W⁰ may include an oxygen atom or a sulfur atom at an arbitrary position. The group “may includes an oxygen atom or a sulfur atom at an arbitrary position” means a group in which part of the carbon atom constituting the hydrocarbon group or hydrocarbon group containing a substituent may be substituted with an oxygen atom or a sulfur atom, or a group in which a hydrogen atom bonded to the hydrocarbon group may be substituted with an oxygen atom or a sulfur atom.

Examples of W⁰ containing an oxygen atom at an arbitrary position are shown below.

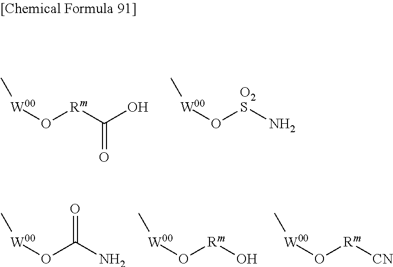

In the formulas, W⁰⁰ represents a hydrocarbon group; and R^{m} represents an alkylene group of 1 to 5 carbon atoms.

In the formula, W⁰⁰ represents a hydrocarbon group, and the same hydrocarbon group as those described for W⁰ in the formula (a3-1). W⁰⁰ is preferably an aliphatic hydrocarbon group, more preferably an aliphatic cyclic group (monocyclic group and polycyclic group).

R^{m} is preferably a linear or branched group, preferably an alkylene group of 1 to 3 carbon atoms, and more preferably a methylene group or an ethylene group.

Specific examples of the structural unit (a3) include structural units derived from (α-substituted) acrylic acid and structural units represented by general formulas (a3-11) to (a3-13) shown below. Specific examples of the structural unit derived from the (α-substituted) acrylic acid include a structural unit represented by the general formula (a3-1) in which P⁰ is a single bond and W⁰ is —COOH.

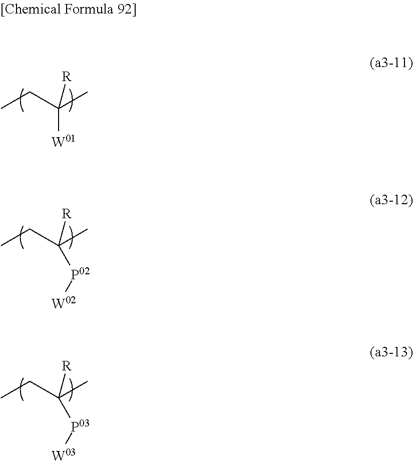

In the formulas, R represents a hydrogen atom, an alkyl group of 1 to 5 carbon atoms or a halogenated alkyl group of 1 to 5 carbon atoms; W⁰¹ is an aromatic hydrocarbon group containing at least one group selected from the group consisting of —OH, —COOH, —CN, —SO₂NH₂ and —CONH₂ as a substituent; P⁰² and P⁰³ each —C(═O)—O—, —C(═O)—NR⁰— (wherein R⁰ represents a hydrogen atom or an alkyl group of 1 to 5 carbon atoms) or a single bond. W⁰² represents a cyclic hydrocarbon group containing at least one group as a substituent selected from the group consisting of —OH, —COOH, —CN, —SO₂NH₂ and —CONH₂ or a group represented by formula —CONHCO—R^{a32} (wherein R^{a32} represents a cyclic hydrocarbon group) and which may contain an oxygen atom or a sulfur atom at an arbitrary position. W⁰³ is a chain-like hydrocarbon group containing at least one group as a substituent selected from the group consisting of —OH, —COOH, —CN, —SO₂NH₂ and —CONH₂ or a group represented by formula —CONHCO—R^{a33} (wherein R^{a33} represents a chain-like hydrocarbon group).

[Structural Unit Represented by General Formula (a3-11)]

In general formula (a3-11), R is the same as defined for R in general formula (a3-1).

The aromatic hydrocarbon group for W⁰¹ is the same as defined for the aromatic hydrocarbon group for W⁰ in general formula (a3-1).

Specific examples of structural units represented by general formula (a3-11) are shown below. In the formulas shown below, R^{α} represents a hydrogen atom, a methyl group or a trifluoromethyl group.

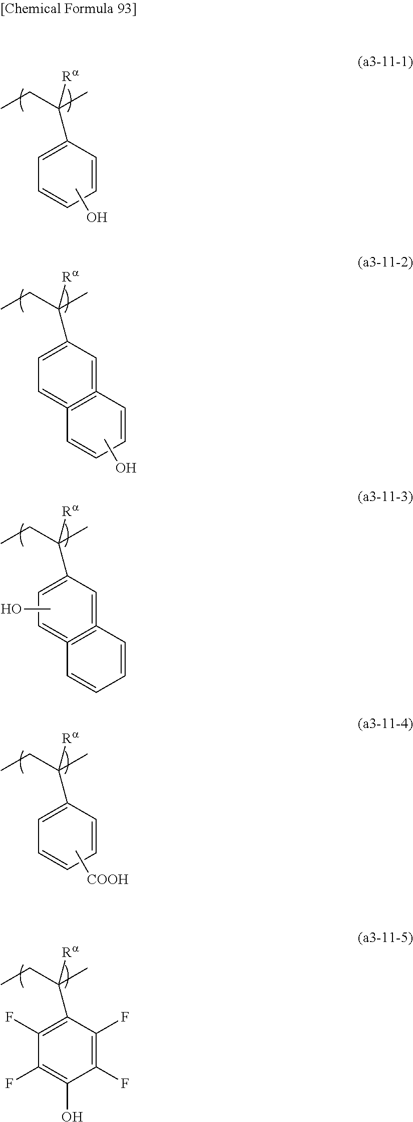

[Structural Unit Represented by General Formula (a3-12)]

In general formula (a3-12), R is the same as defined for R in general formula (a3-1).

P⁰² represents —C(═O)—O— or —C(═O)—NR⁰— (wherein R⁰ represents a hydrogen atom or an alkyl group of 1 to 5 carbon atoms) or a single bond, and preferably —C(═O)—O— or a single bond. The alkyl group for R⁰ is the same alkyl group as described above for R.

The cyclic hydrocarbon group for W⁰² or R^{a32} is the same as defined for the aliphatic cyclic group (monocyclic group and polycyclic group) and aromatic hydrocarbon group for W⁰ in general formula (a3-1).

W⁰² or R^{a32} may include an oxygen atom or a sulfur atom at an arbitrary position, and the definition is the same as defined for W⁰ in the formula (a3-1).

Specific examples of structural units represented by general formula (a3-12) are shown below. In the formulas shown below, R^{α} represents a hydrogen atom, a methyl group or a trifluoromethyl group.

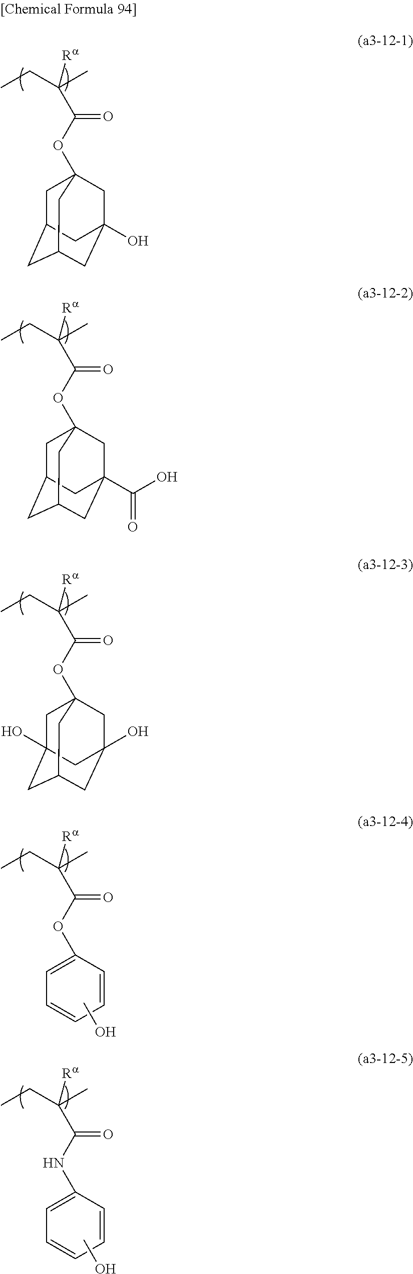

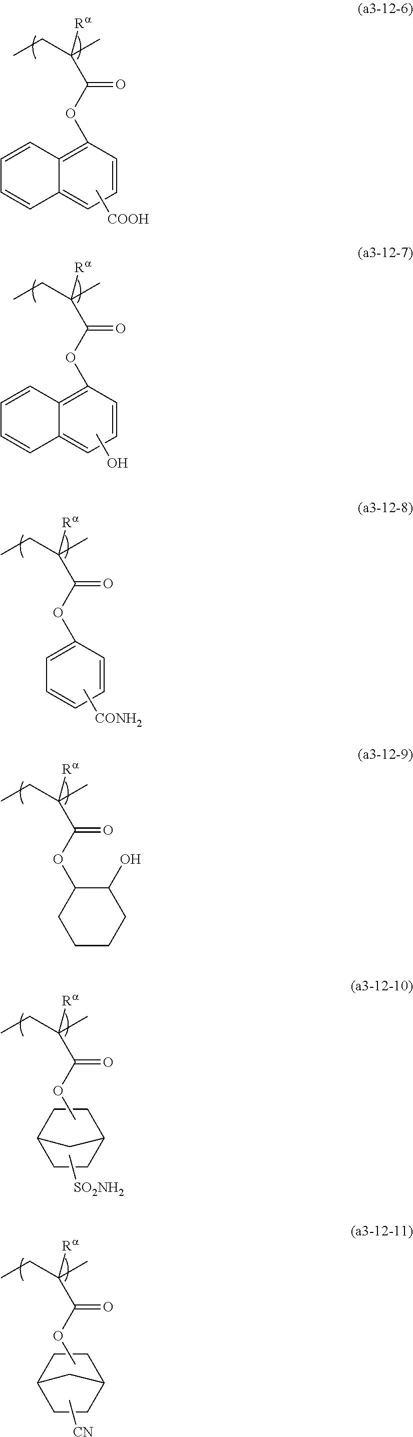

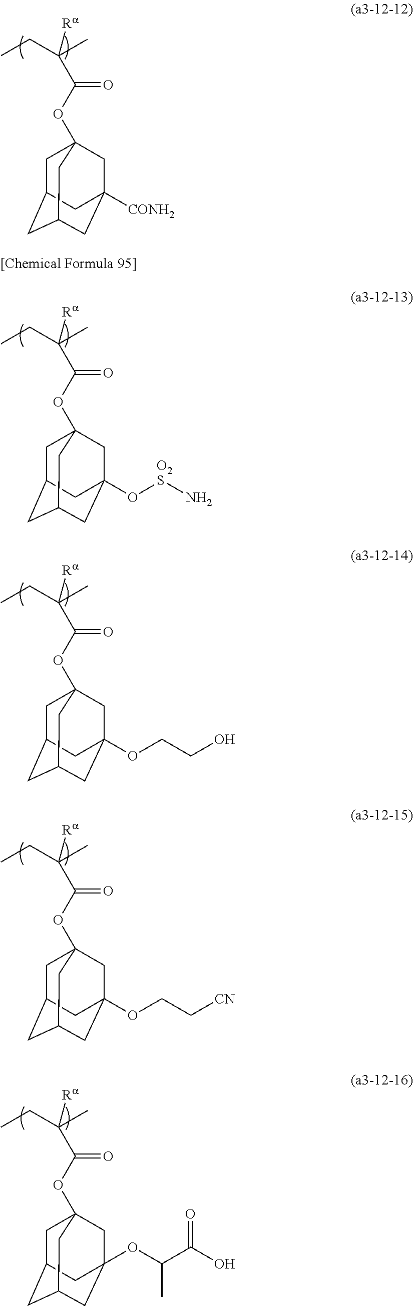

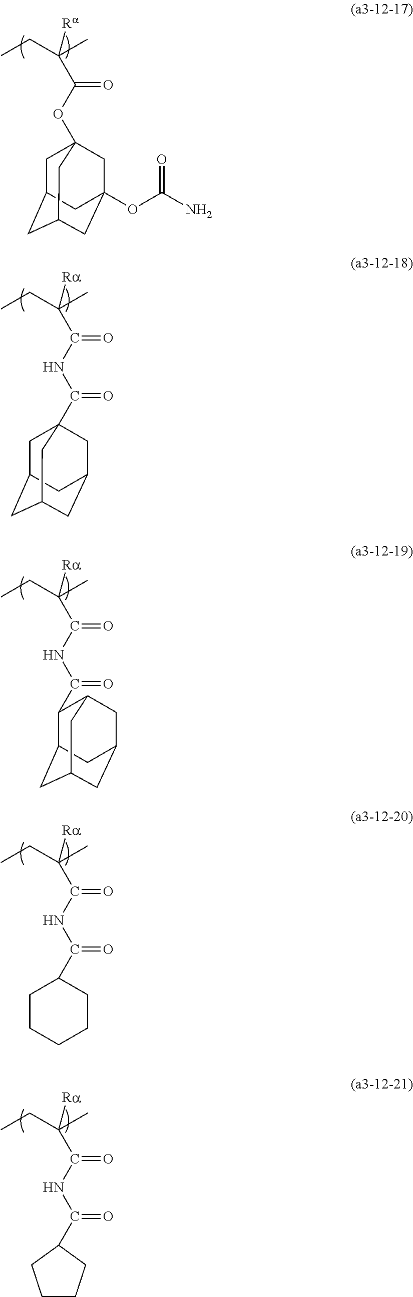

[Structural Unit Represented by General Formula (a3-13)]

In general formula (a3-13), R is the same as defined for R in general formula (a3-1).

P⁰³ represents —C(═O)—O— or —C(═O)—NR⁰— (wherein R⁰ represents a hydrogen atom or an alkyl group of 1 to 5 carbon atoms) or a single bond, and preferably —C(═O)—O— or a single bond. The alkyl group for R⁰ is the same alkyl group as described above for R.

The chain-like hydrocarbon group for W⁰³ or R^{a33} preferably has 1 to 10 carbon atoms, more preferably 1 to 5 carbon atoms, and still more preferably 1 or 3 carbon atoms.

The linear hydrocarbon group for W⁰³ or R^{a33} may have a substituent (a) other than —OH, —COOH, —CN, —SO₂NH₂ and —CONH₂. Examples of the substituent (a) include an alkyl group of 1 to 5 carbon atoms, an aliphatic cyclic group (monocyclic group and polycyclic group), a fluorine atom and a fluorinated alkyl group of 1 to 5 carbon atoms. The aliphatic cyclic group for the substituent (a) preferably has 3 to 30 carbon atoms, more preferably 5 to 30, still more preferably 5 to 20, particularly more preferably 6 to 15, and most preferably 6 to 12. As the aliphatic cyclic group, a group in which two or more hydrogen atoms have been removed from a monocycloalkane or a polycycloalkane such as a bicycloalkane, tricycloalkane or tetracycloalkane can be used. Specific examples include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

In addition, the linear hydrocarbon group for W⁰³ may have a plurality of substituents (a), and the plurality of substituents (a) may be mutually bonded to form a ring, as in the case with the structural unit represented by the general formula (a3-13-a) shown below.

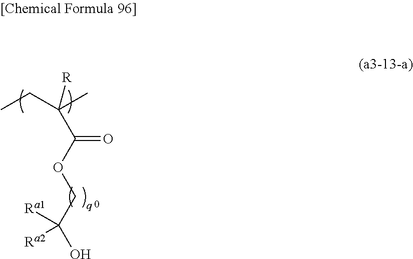

In the formula, R represents a hydrogen atom, an alkyl group of 1 to 5 carbon atoms or a halogenated alkyl group of 1 to 5 carbon atoms; each of R^{a1} and R^{a2} independently represents an alkyl group of 1 to 5 carbon atom, an aliphatic cyclic group (monocyclic group and polycyclic group), a fluorine atom or a fluorinated alkyl group of 1 to 5 carbon atoms, provided that R^{a1} and R^{a2} may be mutually bonded to form a ring; and q⁰ represents an integer of 1 to 4.

In general formula (a3-13-a), R is the same as defined for R in general formula (a3-1).

The aliphatic cyclic group for R^{a1} and R^{a2} is the same aliphatic cyclic group (monocyclic group and polycyclic group) for substituent (a) as described above.

R^{a1} and R^{a2} may be mutually bonded to form a ring. In such a case, a cyclic group is formed by R^{a1}, R^{a2} and the carbon atom having R^{a1} and R^{a2} bonded thereto. The cyclic group may be either a monocyclic group or a polycyclic group. Specific examples include groups in which one or more hydrogen atoms have been removed from a monocycloalkane or polycycloalkane which is exemplified in the explanation of the aliphatic cyclic group (monocyclic group and polycyclic group) for the substituent (a).

q⁰ is preferably 1 or 2, and more preferably 1.

Specific examples of structural units represented by general formula (a3-13) are shown below. In the formulas shown below, R^{α} represents a hydrogen atom, a methyl group or a trifluoromethyl group.

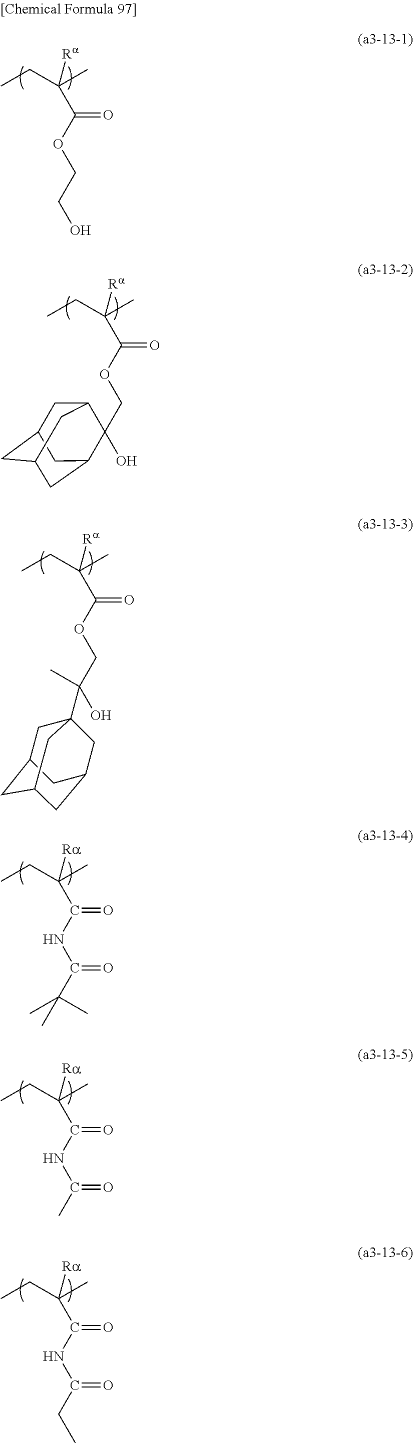

As the structural unit (a3) contained in the component (A1), one type of structural unit may be used, or two or more types may be used.

In the first aspect and third aspect of the present invention, in the component (A1), the amount of the structural unit (a3) based on the combined total of all structural units constituting the component (A1) is preferably 0 to 85 mol %, and more preferably 0 to 80 mol %. When the amount of the structural unit (a3) is at least as large as the lower limit of the above-mentioned range, the effect of using the structural unit (a3) (such as improvement effect in resolution, lithography properties and pattern shape) can be satisfactorily achieved. On the other hand, when the amount of the structural unit (a3) is no more than the upper limit of the above-mentioned range, a good balance can be achieved with the other structural units.

In the case that the structural unit (a3) is contained in the component (A1b), 1 type of structural unit (a3) may be used, or 2 or more types may be used.

In the second aspect of the present invention, in the component (A1b), the amount of the structural unit (a3) based on the combined total of all structural units constituting the component (A1b) is preferably 0 to 85 mol %, and more preferably 0 to 80 mol %. When the amount of the structural unit (a3) is at least as large as the lower limit of the above-mentioned range, the effect of using the structural unit (a3) (such as improvement effect in resolution, lithography properties and pattern shape) can be satisfactorily achieved. On the other hand, when the amount of the structural unit (a3) is no more than the upper limit of the above-mentioned range, a good balance can be achieved with the other structural units.

(Structural Unit (a4))

The components (A1) and (A1b) may further include a structural unit (a4) containing an acid non-dissociable cyclic group as necessary. When the component (A1) includes the structural unit (a4), the dry etching resistance of the resist pattern to be formed can be improved. The hydrophobicity of the component (A1) is enhanced.

In particular, in the case of conducting the development using a developing solution containing an organic solvent, improvement in hydrophobicity of the polymer contributes to improve resolution, resist pattern shape, and the like.

An “acid non-dissociable, aliphatic cyclic group” in the structural unit (a4) refers to a cyclic group which is not dissociated by the action of the acid generated from the aforementioned structural unit (a0) or an acid generator component (B) described later upon exposure, and remains in the structural unit.

Specific examples of the structural unit (a4) include a structural unit in which an acid dissociable group in the structural unit (a1) has been substituted with an acid non-dissociable cyclic group. Among these, a structural unit (a41) derived from an acrylate ester which may have the hydrogen atom bonded to the carbon atom on the α-position substituted with a substituent and contains a non-acid-dissociable aliphatic polycyclic group, a structural unit (a42) derived from a styrene which may have the hydrogen atom bonded to the carbon atom on the α-position substituted with a substituent, and a structural unit (a43) derived from a vinylnaphthalene which may have the hydrogen atom bonded to the carbon atom on the α-position substituted with a substituent.

In the structural unit (a41), specific examples of the acid non-dissociable aliphatic cyclic group include monovalent aliphatic cyclic groups in which the carbon atom having an atom adjacent to the aliphatic cyclic group (e.g., —O— within —C(═O)—O—) bonded thereto has no substituent (a group or an atom other than hydrogen) and groups in which one hydrogen atom of a primary or secondary alkyl group has been substituted with a monovalent aliphatic cyclic group.

The monovalent aliphatic cyclic group is not particularly limited as long as it is acid non-dissociable, and any of the multitude of conventional polycyclic groups used within the resin component of resist compositions for ArF excimer lasers or KrF excimer lasers (and particularly for ArF excimer lasers) can be used. The aliphatic cyclic group may be either saturated or unsaturated, preferably saturated.

The aliphatic cyclic group may or may not have a substituent. Examples of the substituent include an alkyl group of 1 to 5 carbon atoms, an alkoxyl group of 1 to 5 carbon atoms, a fluorine atom, a fluorinated alkyl group of 1 to 5 carbon atoms, and an oxygen atom (═O).

The basic ring of the “aliphatic cyclic group” exclusive of substituents is not limited to be constituted from only carbon atom and hydrogen atom (not limited to hydrocarbon groups), but is preferably a hydrocarbon group. Further, the “hydrocarbon group” may be either saturated or unsaturated, but is preferably saturated.

The aliphatic cyclic group preferably has 3 to 30 carbon atoms, more preferably 5 to 30, still more preferably 5 to 20, particularly preferably 6 to 15, and most preferably 6 to 12.

The aliphatic cyclic group may be either a monocyclic group or a polycyclic group. As the monocyclic aliphatic cyclic group, a group in which one or more hydrogen atoms have been removed from a monocycloalkane is preferable. The monocycloalkane preferably has 3 to 6 carbon atoms, and specific examples thereof include cyclobutane, cyclopentane and cyclohexane. As the polycyclic aliphatic cyclic group, a group in which one or more hydrogen atoms have been removed from a polycycloalkane is preferable, and the polycyclic group preferably has 7 to 12 carbon atoms. Examples of the polycycloalkane include adamantane, norbornane, isobornane, tricyclodecane and tetracyclododecane. In these aliphatic cyclic groups, part of the carbon atoms constituting the ring may be replaced with an ethereal oxygen atom (—O—).

In terms of the aforementioned effects, as the aliphatic cyclic group, a polycyclic group is preferable. In particular, a bi-, tri- or tetracyclic group is preferable. In consideration of industrial availability and the like, at least one polycyclic group selected from amongst a tricyclodecyl group, an adamantyl group, a tetracyclododecyl group, an isobornyl group and a norbornyl group is particularly desirable.

Specific examples of the monovalent aliphatic cyclic group as an acid non-dissociable aliphatic cyclic group include monovalent aliphatic cyclic groups in which the carbon atom having an atom adjacent to the aliphatic cyclic group (e.g., —O— within —C(═O)—O—) bonded thereto has no substituent (a group or an atom other than hydrogen). More specific examples include groups represented by general formulas (1-1) to (1-9) explained above in relation to the acid dissociable group, in which the R¹⁴ group has been substituted with a hydrogen atom; and a cycloalkane having a tertiary carbon atom bonded to three carbon atoms constituting the ring skeleton and having one hydrogen atom removed therefrom.

As the groups in which one hydrogen atom of a primary or secondary alkyl group has been substituted with a monovalent aliphatic cyclic group, a group represented by the formulas (2-1) to (2-6) explained above in relation to the acid dissociable group, in which at least one of R¹⁵ and R¹⁶ represents a hydrogen atom, can be mentioned.

As the structural unit (a41), a structural unit in which the acid dissociable group in the structural unit (a11) has been replaced with an acid non-dissociable group can be mentioned, and a structural unit represented by the general formula (a1-0-1) in which X¹ is replaced with an acid non-dissociable, aliphatic polycyclic group, that is, a structural unit represented by general formula (a4-0) shown below are preferable, and structural units represented by general formulas (a4-1) and (a4-5) shown below are particularly preferable.

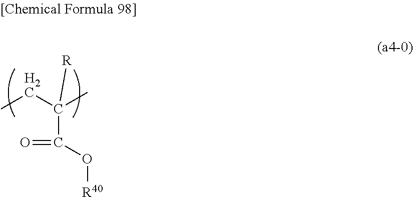

In the formula, R is the same as defined above; and R⁴⁰ represents an acid non-dissociable, aliphatic polycyclic group.

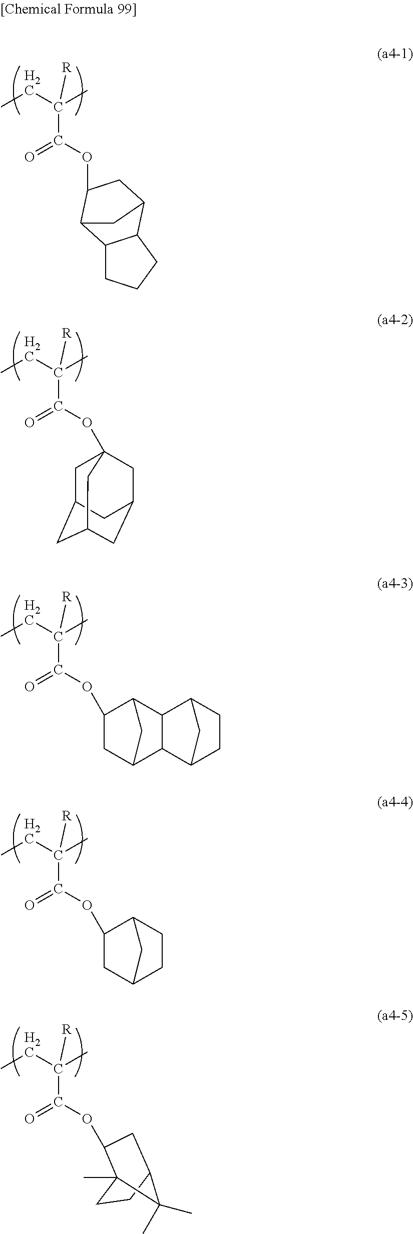

In the formulas, R is the same as defined above.

Specific examples of the structural unit (a42) includes structural units represented by the general formula (U-3), which is described in the explanation of the component (W), in which px of —(OX^{c})ₚₓ bonded to the benzene ring is an integer of 0.

Specific examples of the structural unit (a43) includes structural units represented by the general formula (U-3), which is described in the explanation of the component (W), in which x of —(OX^{d})ₓ bonded to the benzene ring is an integer of 0.

As the structural unit (a4) contained in the component (A1), 1 type of structural unit may be used, or 2 or more types may be used.

When the component (A1) contains the structural unit (a4), the amount of the structural unit (a4) based on the combined total of all structural units constituting the component (A1) is preferably 1 to 30 mol %, more preferably 1 to 20 mol %, and still more preferably 5 to 20 mol %. When the amount of the structural unit (a4) is at least as large as the lower limit of the above-mentioned range, the effect of using the structural unit (a4) can be satisfactorily achieved. On the other hand, when the amount of the structural unit (a4) is no more than the upper limit of the above-mentioned range, a good balance can be achieved with the other structural units.

In the second aspect of the present invention, when the structural unit (a4) is included in the component (A1b), the amount of the structural unit (a4) based on the combined total of all the structural units that constitute the component (A1b) is preferably within the range from 1 to 30 mol %, and more preferably from 10 to 20 mol %.

(Structural Unit (a5))

The structural unit (a5) is a structural unit represented by general formula (a5-1) shown below.

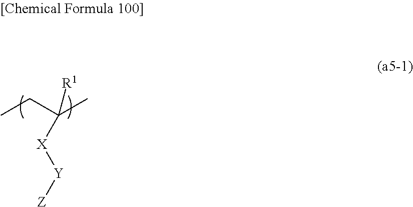

R¹ represents a hydrogen atom, a methyl group or an alkyl group which has a substituent; X represents a divalent linking group; Y represents —O—, —COO—, —CON(R′)—, —OCO—, —CONHCO— or —CONHCS—, R′ represents a hydrogen atom or a methyl group, provided that when Y is —O—, X is a divalent linking group other than C(═O); and Z represents a group containing a lactone ring which may have a substituent and which may be either monocyclic or polycyclic.

(Structural Unit Represented by General Formula (a5-1))

In the formula (a5-1), R¹ represents a hydrogen atom, a methyl group or an alkyl group which has a substituent. The alkyl group is preferably an alkyl group of 1 to 5 carbon atoms, and a methyl group, an ethyl group, a propyl group, an n-butyl group or a tert-butyl group is most desirable.

X represents a divalent linking group; Examples of the divalent linking group include the same divalent linking groups as those described for Q¹ in the general formula (a0-1). As the divalent linking group containing a hetero atom, a linear group containing an oxygen atom as the hetero atom (e.g., a group containing an ether bond or an ester bond) or an aromatic group which may have a substituent is preferable, and a group represented by the aforementioned formula —Y²¹—O—Y²²—, —[Y²¹—C(═O)—O]_{m′}—Y²²—, —C(═O)—O—Y²²—, —C(═O)—NH—Y²²—, —Y²¹—O—C(═O)—Y²²— or an arylene group which may have a substituent is more preferable.

In the formula (a5-1), as X, a group represented by formula (a5-0-1), (a5-0-2), (a5-0-3) or (a5-0-4) shown below can be mentioned.

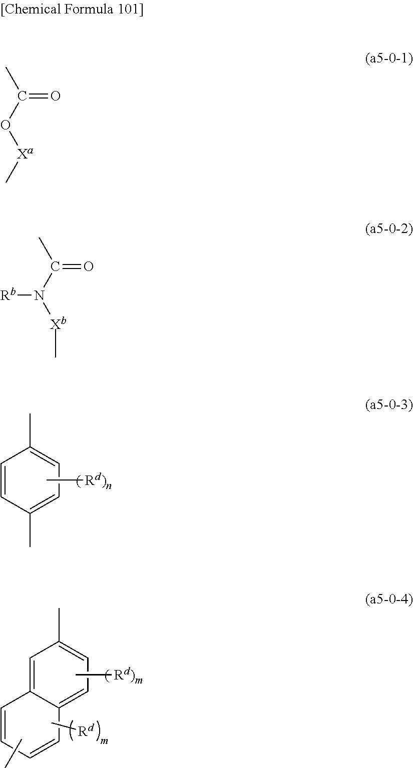

In the formulas, X^{a} and X^{b} each independently represents an organic group; R^{b} represents a hydrogen atom or an alkyl group of 1 to 5 carbon atoms; R^{d} each independently represents an alkyl group of 1 to 5 carbon atoms, a fluorine atom or a fluorinated alkyl group of 1 to 5 carbon atoms; n represents an integer of 0 to 4; and m each independently represents an integer of 0 to 3.

As the organic group for X^{a} and X^{b}, the same divalent linking group as described above for R³ in the formula (a0-1) is preferable. As the alkyl group of 1 to 5 carbon atoms for R^{b} and R^{c}, the same alkyl group of 1 to 5 carbon atoms as those described above for R can be mentioned.

As the fluorinated alkyl group of 1 to 5 carbon atoms for R^{c} include groups in which part or all of the hydrogen atoms of the aforementioned alkyl group of 1 to 5 carbon atoms are substituted with fluorine atoms for R^{c}.

In the formula (a5-1), Y represents —O—, —COO—, —CON(R′)—, —OCO—, —CONHCO— or —CONHCS—, and R′ represents a hydrogen atom or a methyl group, provided that when Y is —O—, X is a divalent linking group other than C(═O).

In the formula (a5-1), Z represents a group a group containing a lactone ring which may have a substituent and may be either monocyclic or polycyclic. The term “group containing a lactone ring” refers to a cyclic group including a ring containing a —O—C(═O)— structure (lactone ring). The term “lactone ring” refers to a single ring containing a —O—C(═O)— structure, and this ring is counted as the first ring. A lactone-containing cyclic group in which the only ring structure is the lactone ring is referred to as a monocyclic group, and groups containing other ring structures are described as polycyclic groups regardless of the structure of the other rings. The lactone-containing cyclic group may be either a monocyclic group or a polycyclic group.

The lactone-containing cyclic group for the structural unit (a5) is not particularly limited, and an arbitrary structural unit may be used. Specific examples of lactone-containing monocyclic groups include a group in which one hydrogen atom has been removed from a 4- to 6-membered lactone ring, such as a group in which one hydrogen atom has been removed from β-propionolatone, a group in which one hydrogen atom has been removed from γ-butyrolactone, and a group in which one hydrogen atom has been removed from δ-valerolactone. Further, specific examples of lactone-containing polycyclic groups include groups in which one hydrogen atom has been removed from a lactone ring-containing bicycloalkane, tricycloalkane or tetracycloalkane.

In the formula (a5-1), as Z, groups represented by formulas (a5-2-1) to (a5-2-7) shown below can be mentioned.

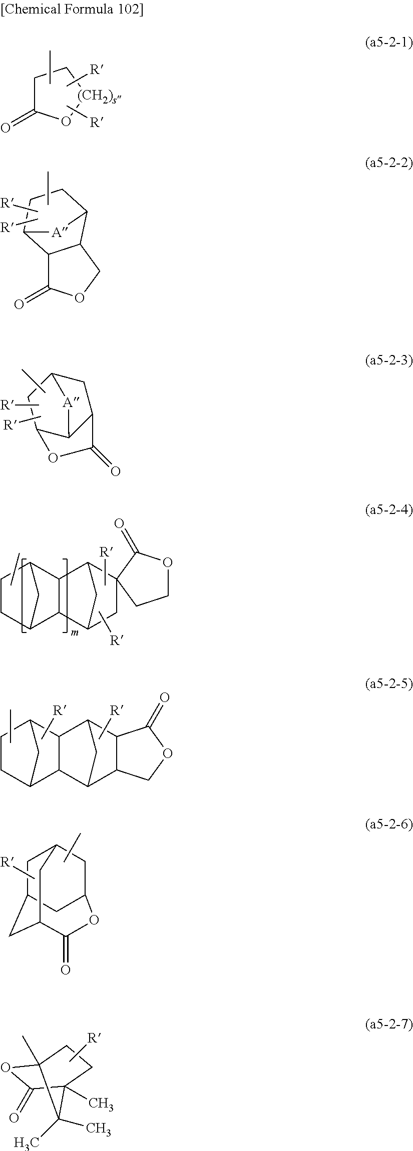

In the formulas, R represents a hydrogen atom, an alkyl group, an alkoxy group, a halogen atom, a halogenated alkyl group, a hydroxy group, —COOR″, —OC(═O)R″, a hydroxyalkyl group, or a cyano group, wherein R″ represents a hydrogen atom or an alkyl group; R²⁹ represents a single bond or a divalent linking group; s″ represents an integer of 0 to 2; A″ represents an oxygen atom, a sulfur atom or an alkylene group of 1 to 5 carbon atoms which may contain an oxygen atom or a sulfur atom; and m represents 0 or 1.

The alkyl group for R′ is preferably an alkyl group of 1 to 6 carbon atoms. Further, the alkyl group is preferably a linear alkyl group or a branched alkyl group. Specific examples include a methyl group, ethyl group, propyl group, isopropyl group, n-butyl group, isobutyl group, tert-butyl group, pentyl group, isopentyl group, neopentyl group and hexyl group. Among these examples, a methyl group or an ethyl group is preferable, and a methyl group is particularly desirable.

As the alkoxy group, an alkoxy group of 1 to 6 carbon atoms is preferable.

Further, the alkoxy group is preferably a linear alkoxy group or a branched alkoxy group. Specific examples of the alkoxy groups include the aforementioned alkyl groups for the substituent having an oxygen atom (—O—) bonded thereto.

Examples of the halogen atom include a fluorine atom, a chlorine atom, a bromine atom and an iodine atom, and a fluorine atom is preferable.

Examples of the halogenated alkyl group include groups in which part or all of the hydrogen atoms within the aforementioned alkyl groups has been substituted with the aforementioned halogen atoms.

As examples of the halogenated alkyl group, groups in which part or all of the hydrogen atoms of the aforementioned alkyl groups for the substituent have been substituted with the aforementioned halogen atoms can be given. As the halogenated alkyl group, a fluorinated alkyl group is preferable, and a perfluoroalkyl group is particularly desirable.

In the —COOR″ group and the —OC(═O)R″ group, R″ represents a hydrogen atom or a linear, branched or cyclic alkyl group of 1 to 15 carbon atoms.

When R″ represents a linear or branched alkyl group, it is preferably an alkyl group of 1 to 10 carbon atoms, more preferably an alkyl group of 1 to 5 carbon atoms, and most preferably a methyl group or an ethyl group.

When R″ is a cyclic alkyl group (cycloalkyl group), it preferably has 3 to 15 carbon atoms, more preferably 4 to 12 carbon atoms, and most preferably 5 to 10 carbon atoms. As examples of the cycloalkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Specific examples include groups in which one or more hydrogen atoms have been removed from a monocycloalkane such as cyclopentane and cyclohexane; and groups in which one or more hydrogen atoms have been removed from a polycycloalkane such as adamantane, norbornane, isobornane, tricyclodecane or tetracyclododecane.

The hydroxyalkyl group preferably has 1 to 6 carbon atoms, and specific examples thereof include the aforementioned alkyl groups for the substituent in which at least one hydrogen atom has been substituted with a hydroxy group.

In terms of industrial availability, R′ is preferably a hydrogen atom.

The alkyl group for R″ within —COOR″ is preferably an alkyl group which contains a tertiary carbon atom having the oxygen atom bonded thereto and which is dissolved by the action of acid. Examples of R″ include groups represented by formulas (1-1) to (1-9) and (2-1) to (2-6).

A″ is an oxygen atom (—O—), a sulfur atom (—S—) or an alkylene group of 1 to 5 carbon atoms which may contain an oxygen atom or a sulfur atom, and A″ is preferably an alkylene group of 1 to 5 carbon atoms, an oxygen atom (—O—) or a sulfur atom (—S—) and more preferably an alkylene group of 1 to 5 carbon atoms or an oxygen atom (—O—). As the alkylene group of 1 to 5 carbon atoms, a methylene group or a dimethylethylene group is preferable, and a methylene group is particularly desirable.

R²⁹ represents a single bond or a divalent linking group.

Specific examples of structural units represented by general formulas (a5-2-1) to (a5-2-7) are shown below.

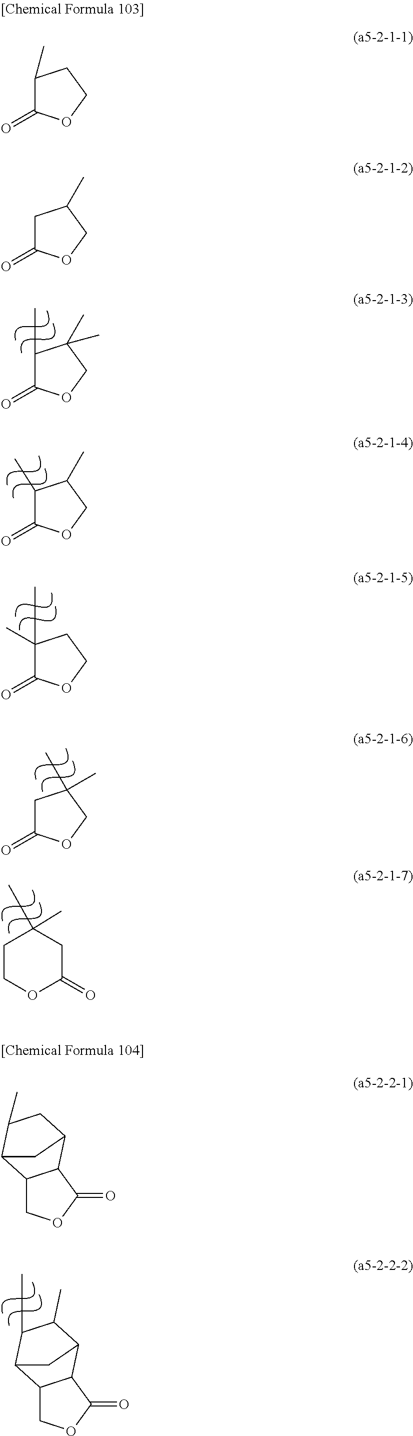

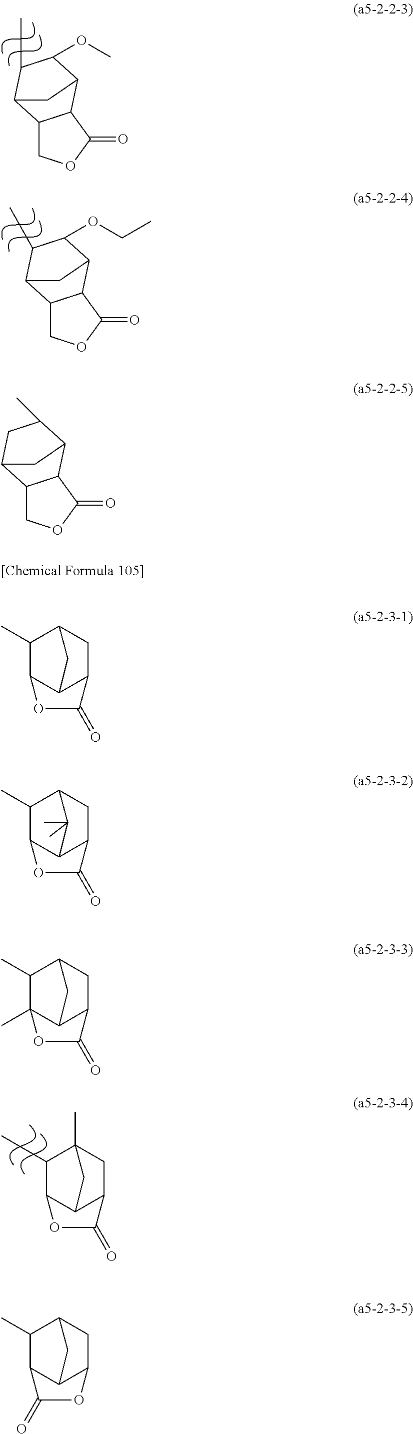

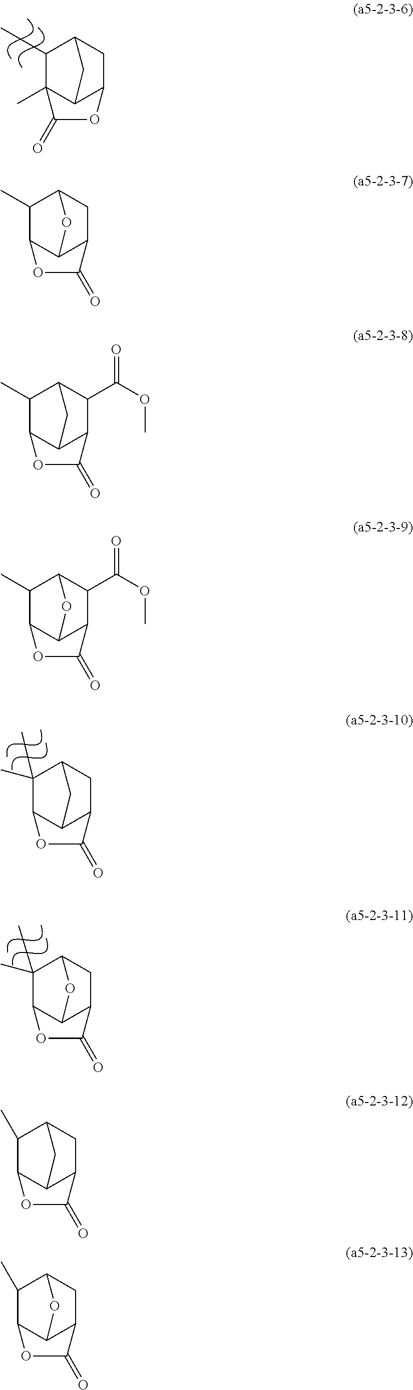

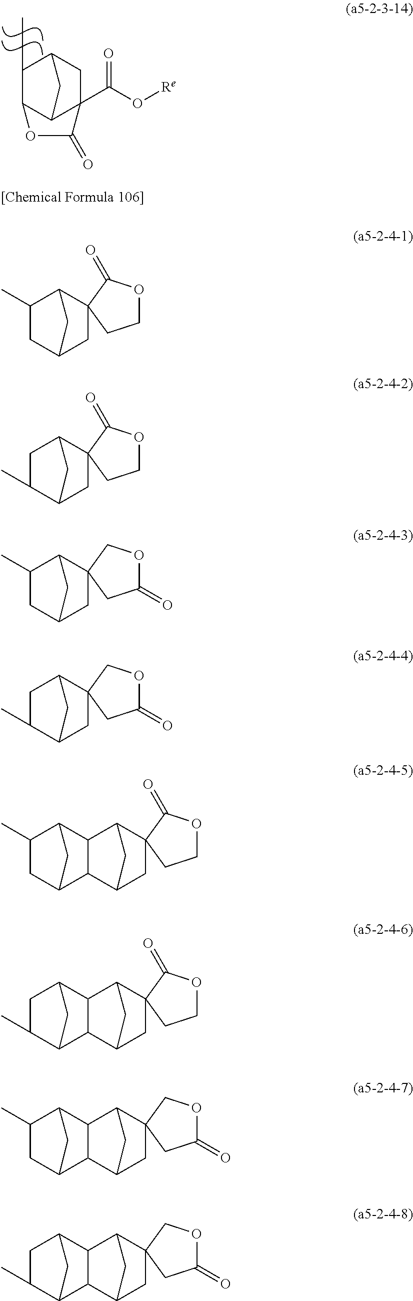

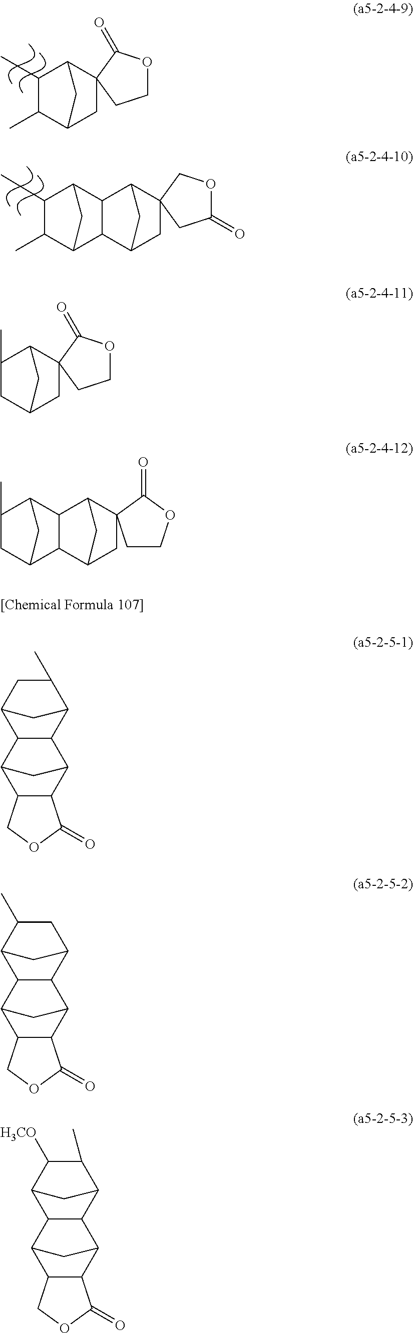

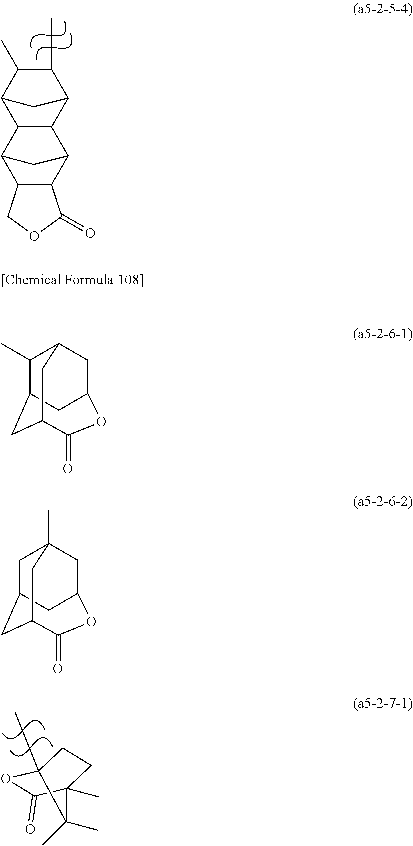

Specific examples of structural units represented by general formula (a5-1) are shown below.

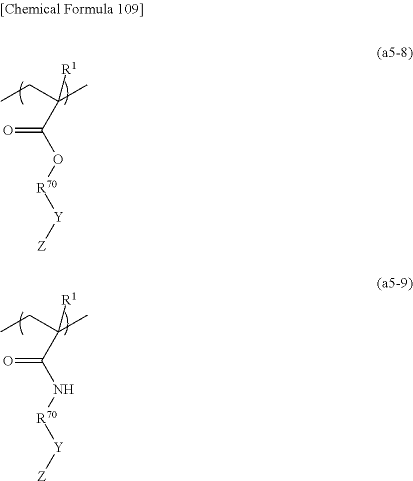

In the formulas, R¹, Y and Z are the same as defined above in the general formula (a5-1); and R⁷⁰ represents an alkyl group of 1 to 10 carbon atoms which may have a substituent.

In the formulas (a5-8) and (a5-9), as the alkyl group of 1 to 10 carbon atom which may have a substituent, the same groups as those described above for R⁴ and R⁵ in the formula (a0-1) can be mentioned.

Specific examples of structural units represented by general formula (a5-1) are shown below. R^{α} is the same as defined above.

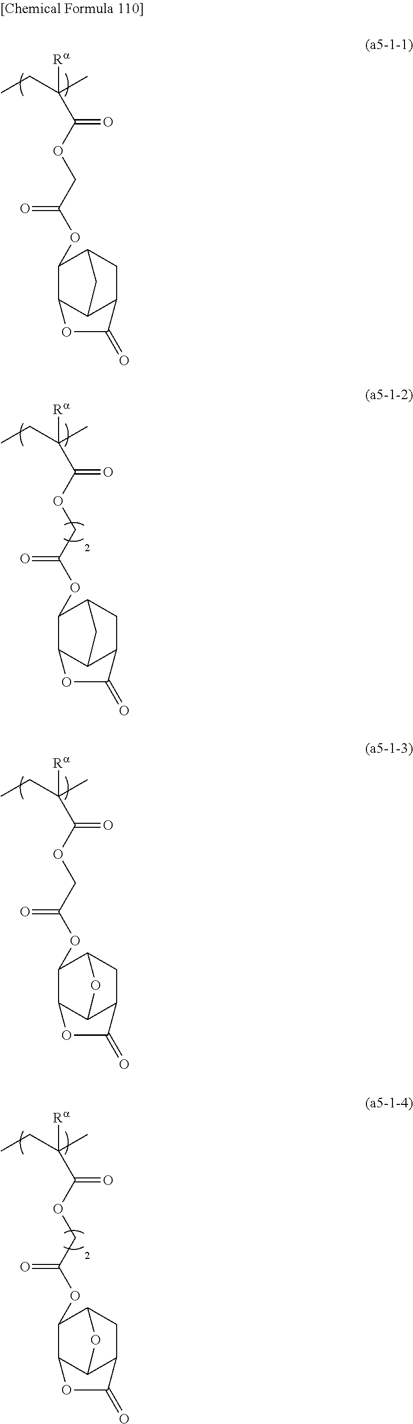

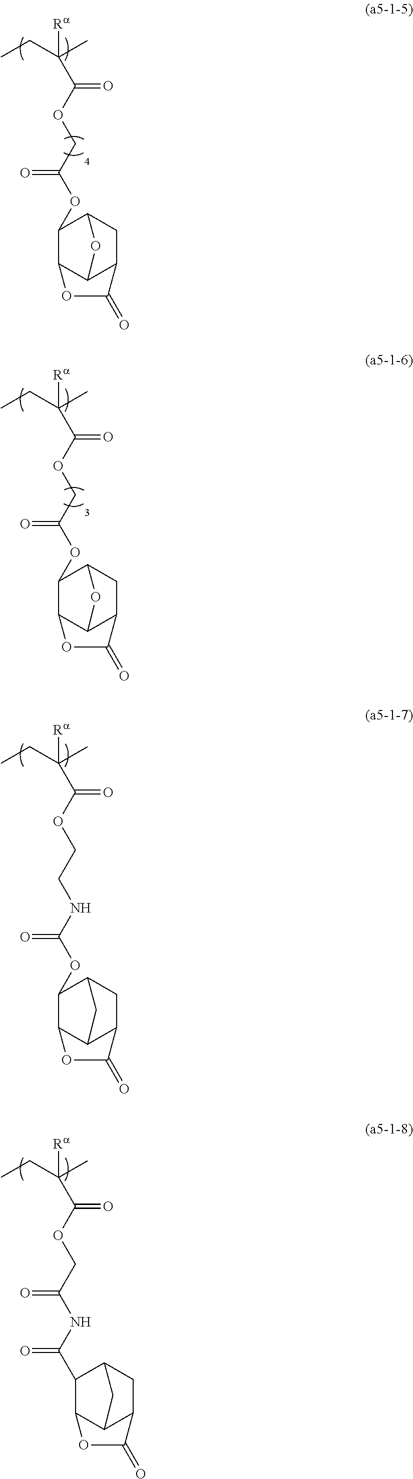

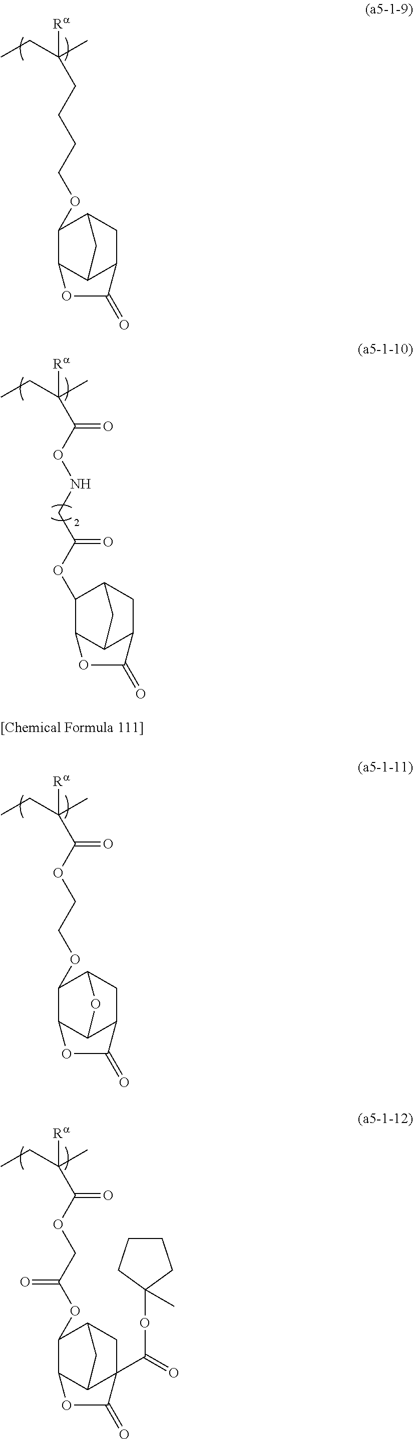

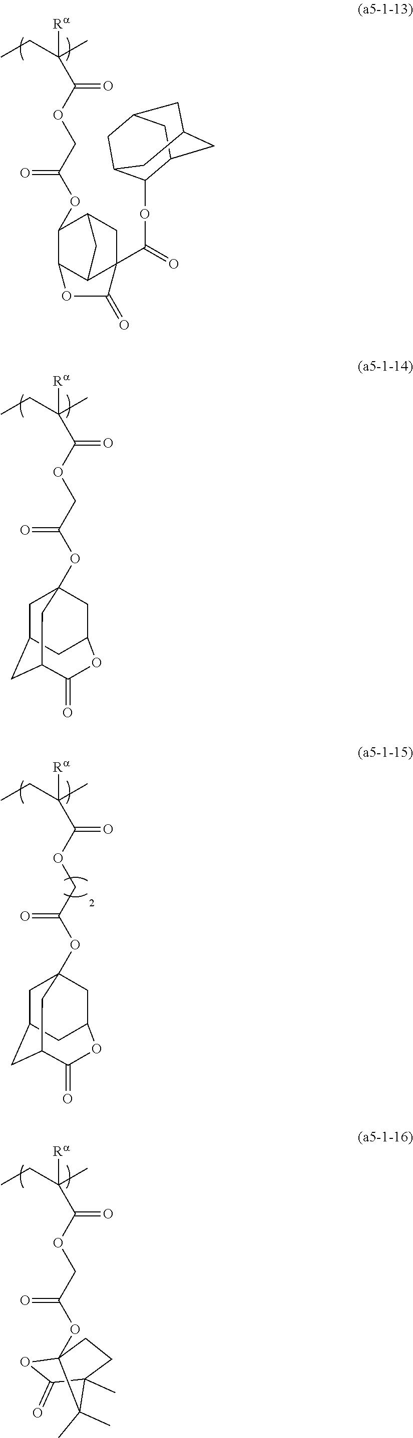

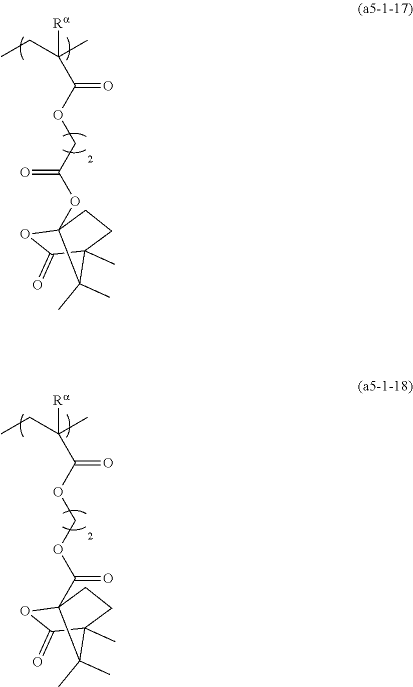

In the second aspect of the present invention, as the structural unit (a5), one type of structural unit selected from the group consisting of the structural units represented by the general formulas (a5-1-1) to (a5-1-18) or two type or more may be used.

In the second aspect of the present invention, in the component (A1b), the amount of the structural unit (a5) based on the combined total of all structural units constituting the polymer is preferably 10 to 60 mol %, more preferably 15 to 55 mol % and still more preferably 20 to 50 mol %.

The component (A1) may also have a structural unit other than the above-mentioned structural units (a0) to (a4), as long as the effects of the present invention are not impaired.

As such a structural unit, any other structural unit which cannot be classified as one of the above structural units (a0) to (a4) can be used without any particular limitation, and any of the multitude of conventional structural units used within resist resins for ArF excimer lasers, KrF excimer lasers, EB or EUV can be used.

In the first aspect or third aspect of the present invention, the component (A1) is preferably a copolymer containing structural units (a0) and (a1), and more preferably a copolymer containing structural units (a0), (a1) and (a2), and still more preferably a copolymer containing structural units (a0), (a1), (a2) and (a3).

Examples of the copolymer containing structural units (a0) and (a1) include a copolymer consisting of the structural units (a0) and (a1); a copolymer consisting of the structural units (a0), (a1) and (a2); a copolymer consisting of the structural units (a0), (a1) and (a3); a copolymer consisting of the structural units (a0), (a1), (a2) and (a3); a copolymer consisting of the structural units (a0), (a1), (a2) and (a4); and a copolymer consisting of the structural units (a0), (a1), (a2), (a3) and (a4).

In the second aspect of the present invention, specific examples of the component (A1b) include a polymeric compound consisting of a structural unit (a0), a structural unit (a1) and a structural unit (a2); a polymeric compound consisting of a structural unit (a0), a structural unit (a1) and a structural unit (a3); and a polymeric compound consisting of a structural unit (a0), a structural unit (a1), a structural unit (a2) and a structural unit (a3).

The weight average molecular weight (Mw) (the polystyrene equivalent value determined by gel permeation chromatography) of the component (A) is not particularly limited, but is preferably 1,000 to 50,000, more preferably 1,500 to 30,000, and most preferably 2,000 to 20,000. When the weight average molecular weight of the component (A) is no more than the upper limit of the above-mentioned range, the resist composition exhibits a satisfactory solubility in a resist solvent. On the other hand, when the weight average molecular weight is at least as large as the lower limit of the above-mentioned range, the dry etching resistance and the cross-sectional shape of the resist pattern becomes satisfactory.

Further, the dispersity (Mw/Mn) is not particularly limited, but is preferably 1.0 to 5.0, more preferably 1.0 to 3.0, and most preferably 1.2 to 2.5. Here, Mn is the number average molecular weight.

The component (A) can be obtained, for example, by a conventional radical polymerization or the like of the monomers corresponding to each of the structural units, using a radical polymerization initiator such as azobisisobutyronitrile (AIBN).

Furthermore, in the component (A), by using a chain transfer agent such as HHS—CH₂—CH₂—CH₂—C(CF₃)₂—OH, a —C(CF₃)₂—OH group can be introduced at the terminals of the component (A). Such a copolymer having introduced a hydroxyalkyl group in which some of the hydrogen atoms of the alkyl group are substituted with fluorine atoms is effective in reducing developing defects and LER (line edge roughness: unevenness of the side walls of a line pattern).

As the monomers for deriving the corresponding to structural units, commercially available monomers may be used, or the monomers may be synthesized by a conventional method.

In the third aspect of the present invention, as the monomer which derives a structural unit (a0), a compound containing a polymerizable group such as an ethylenic double bond and containing a group represented by the general formula (a0-1) or (a0-2), for example, a compound represented by formula CH₂═C(R)-Q¹-R³—S⁺(R⁴)(R⁵) V⁻ or a compound represented by formula CH₂═C(R)-Q²-A⁻(M^{m+})_{l/m} can be used, and a compound represented by the aforementioned formula in which V⁻ has been replaced by other anion or cation moiety or a compound represented by the aforementioned formula in which (M^{m+})_{l/m} has been replaced by other cation moiety (for example, H⁺, Na⁺, NH₄⁺, N⁺(CH₃)₄) can be also used. In the latter case, after obtaining a polymer, the polymer is subjected to a salt-exchange reaction using a salt of V⁻ with a countercation or a salt of (M^{m+})_{l/m} with a counteranion (for example, Cl⁻), thereby obtaining the component (A1).

In the third aspect of the present invention, the group represented the general formula (a0-1) or (a0-2) can be introduced to the component (A) by reacting a polymer having a polar group such as a hydroxy group with a compound having a group represented by formula R³—S⁺(R⁴)(R⁵) V⁻ or a group represented by formula -A⁻(M^{m+})_{l/m}.

In the third aspect of the present invention, in the component (A1), by using a chain transfer agent such as HS—CH₂—CH₂—CH₂—C(CF₃)₂—OH, a —C(CF₃)₂—OH group can be introduced at the terminals of the component (A1). Such a copolymer having introduced a hydroxyalkyl group in which some of the hydrogen atoms of the alkyl group are substituted with fluorine atoms is effective in reducing developing defects and LER (line edge roughness: unevenness of the side walls of a line pattern).

As the component (A), one type may be used, or two or more types of compounds may be used in combination.

In the resist composition according to the present invention, the amount of the component (A) can be appropriately adjusted depending on the thickness of the resist film to be formed, and the like.

In the resist composition of the second aspect of the present invention, in the component (A), as the component (A1b), one type may be used, or two or more types may be used in combination.

In the component (A), the amount of the component (A1b) based on the total weight of the component (A) is preferably 25% by weight or more, more preferably 50% by weight or more, still more preferably 75% by weight or more, and may be even 100% by weight. When the amount of the component (A1b) is 25% by weight or more, the effects of the present invention are further improved.

In the third aspect of the present invention, in the component (A), the amount of the component (A1) or (A1b) based on the total weight of the component (A) is preferably 25% by weight or more, more preferably 50% by weight or more, still more preferably 75% by weight or more, and may be even 100% by weight. When the amount is 25 parts by weight or more, pattern shape and critical resolution property of a resist pattern formed by EUV exposure or EB exposure can be improved.

The component (A) may contain a base component other than the component (A1) (hereafter, referred to as “component (A2)”), as long as the effects of the present invention are not impaired.

As the component (A2), a low molecular weight compound that has a molecular weight of at least 500 and less than 4,000, contains a hydrophilic group, and also contains an acid dissociable group described above in connection with the component (A1) may be used. Specific examples include compounds containing a plurality of phenol skeletons in which part or all of the hydrogen atoms within hydroxyl groups have been substituted with the aforementioned acid dissociable groups.

Examples of the low-molecular weight compound include low molecular weight phenolic compounds in which a portion of the hydroxyl group hydrogen atoms have been substituted with an aforementioned acid dissociable group, and these types of compounds are known, for example, as sensitizers or heat resistance improvers for use in non-chemically amplified g-line or i-line resists, and these compounds may be arbitraritly selected for use.

Examples of these low molecular weight phenol compounds include bis(4-hydroxyphenyl)methane, bis(2,3,4-trihydroxyphenyl)methane, 2-(4-hydroxyphenyl)-2-(4′-hydroxyphenyl)propane, 2-(2,3,4-trihydroxyphenyl)-2-(2′,3′,4′-trihydroxyphenyl)propane, tris(4-hydroxyphenyl)methane, bis(4-hydroxy-3,5-dimethylphenyl)-2-hydroxyphenylmethane, bis(4-hydroxy-2,5-dimethylphenyl)-2-hydroxyphenylmethane, bis(4-hydroxy-3,5-dimethylphenyl)-3,4-dihydroxyphenylmethane, bis(4-hydroxy-2,5-dimethylphenyl)-3,4-dihydroxyphenylmethane, bis(4-hydroxy-3-methylphenyl)-3,4-dihydroxyphenylmethane, bis(3-cyclohexyl-4-hydroxy-6-methylphenyl)-4-hydroxyphenylmethane, bis(3-cyclohexyl-4-hydroxy-6-methylphenyl)-3,4-dihydroxyphenylmethane, 1-[1-(4-hydroxyphenyl)isopropyl]-4-[1,1-bis(4-hydroxyphenyl)ethyl]benzene, and dimers, trimers, tetramers, pentamers and hexamers of formalin condensation products of phenols such as phenol, m-cresol, p-cresol and xylenol. Needless to say, the low molecular weight phenol compound is not limited to these examples. In particular, a phenol compound having 2 to 6 triphenylmethane skeletons is preferable in terms of resolution and line width roughness (LER). Also, there are no particular limitations on the acid dissociable group, and suitable examples include the groups described above.

In the resist composition according to the present invention, the amount of the component (A) can be appropriately adjusted depending on the thickness of the resist film to be formed, and the like.

### <Photoreactive Quencher (C)>

The resist composition according to the third aspect of the present invention contains a photoreactive quencher (hereafter, referred to as component (C)) as well as the component (A).

The “quencher” is an acid diffusion control agent which traps acid generated from the component (A) or the acid-generator component (B), which is appropriately added, upon exposure.

The “photoreactive quencher” acts as an quencher prior to exposure (at exposed portions), and does not act as a quencher after exposure (after irradiation of radiation such as EB and EUV).

As the component (C), the conventional photoreactive quencher can be used. For example, a basic compound consisting of a cation moiety and an anion moiety can be mentioned. These basic compound traps acid (strong acid), which generated from the component (A) or the acid-generator component (B), by a salt-exchange reaction.

In the present invention, a “basic compound” refers to a compound which exhibits basicity relative to the component (A) or the acid-generator component (B).

Specific examples of the component (C) include a compound represented by general formula (c1) shown below, a compound represented by general formula (c2) shown below and a compound represented by general formula (c3) shown below.

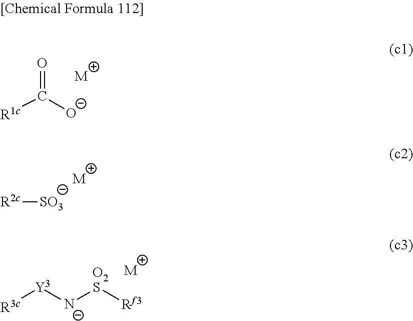

In the formula, R^{1c} represents a hydrocarbon group which may have a substituent; Z^{2c} represents a hydrocarbon group of 1 to 30 carbon atoms which may have a substituent, provided that the carbon atom adjacent to the sulfur atom has no fluorine atom as a substituent; R^{3c} is an organic group; Y³ represents a linear, branched or cyclic alkylene group or arylene group; and R^{f3} represents a hydrocarbon group containing a fluorine atom; and each of M⁺ represents a sulfonium cation or a iodonium cation.

### [Compound (C1)]

### —Anion Moiety

In formula (c1), R^{1c} represents a hydrocarbon group which may have a substituent.

The hydrocarbon group for R^{1c} which may have a substituent may be either an aliphatic hydrocarbon group or an aromatic hydrocarbon group, and the same groups as those described above for the aforementioned X³ within X³-Q′- which R⁴″ in the general formula R⁴″SO₃⁻ may have as a substituent, can be used.

Among these, as the hydrocarbon group for R^{1c} which may have a substituent, an aromatic hydrocarbon group which may have a substituent or an aliphatic cyclic group which may have a substituent is preferable, and a phenyl group or a naphthyl group which may have a substituent, or a group in which one or more hydrogen atoms have been removed from a polycycloalkane such as adamantane, norbornane, isobornane, tricyclodecane or tetracyclododecane is more preferable.

As the hydrocarbon group for R^{1c} which may have a substituent, a linear or branched alkyl group or a fluorinated alkyl group is also preferable.

The linear or branched alkyl group for R^{1c} preferably has 1 to 10 carbon atoms, and specific examples thereof include a linear alkyl group such as a methyl group, an ethyl group, a propyl group, a butyl group, a pentyl group, a hexyl group, a heptyl group, an octyl group, a nonyl or a decyl group, and a branched alkyl group such as a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group or a 4-methylpentyl group.

The fluorinated alkyl group for R^{1c} may be either chain-like or cyclic, but is preferably linear or branched.

The fluorinated alkyl group preferably has 1 to 11 carbon atoms, more preferably 1 to 8, and still more preferably 1 to 4. Specific examples include a group in which part or all of the hydrogen atoms constituting a linear alkyl group (such as a methyl group, an ethyl group, a propyl group, a butyl group, a pentyl group, a hexyl group, a heptyl group, an octyl group, a nonyl group or a decyl group) have been substituted with fluorine atom(s), and a group in which part or all of the hydrogen atoms constituting a branched alkyl group (such as a 1-methylethyl group, a 1-methylpropyl group, a 2-methylpropyl group, a 1-methylbutyl group, a 2-methylbutyl group or a 3-methylbutyl group) have been substituted with fluorine atom(s).

The fluorinated alkyl group for R^{1c} may contain an atom other than fluorine atom. Examples of the atom other than fluorine include an oxygen atom, a carbon atom, a hydrogen atom, an oxygen atom, a sulfur atom and a nitrogen atom.

Among these, as the fluorinated alkyl group for R^{1c}, a group in which part or all of the hydrogen atoms constituting a linear alkyl group have been substituted with fluorine atom(s) is preferable, and a group in which all of the hydrogen atoms constituting a linear alkyl group have been substituted with fluorine atoms (i.e., a pertluoroalkyl group) is more preferable.

Specific examples of preferable anion moieties for the compound (C1) are shown below.

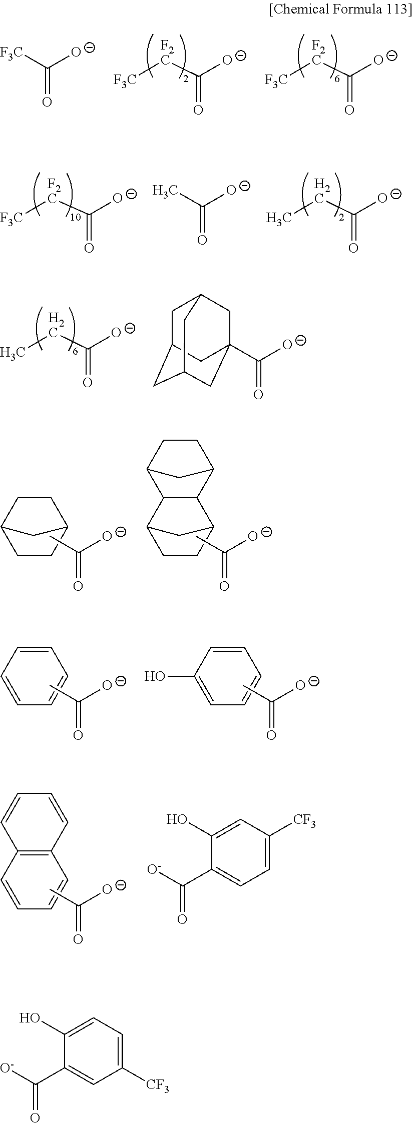

### —Cation Moiety

In formula (c1), M⁺ represents an organic cation.

The organic cation for M⁺ is not particularly limited, and an organic cation conventionally known as the cation moiety of a photo-decomposable base (i.e., photoreactive quencher) used as a quencher for a resist composition or the cation moiety of an onium salt acid generator for a resist composition can be used.

Examples of the organic cation include a cation moiety represented by general formula (ca-1) or (ca-2) shown below. Among these, a cation moiety represented by the formula (ca-1) is preferable.

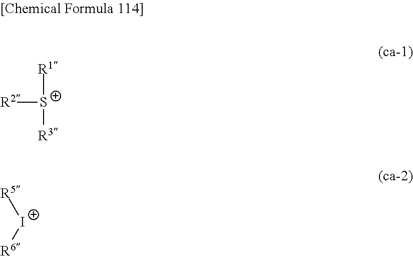

In the formulas, each of R¹″ to R³″, and R⁵″ to R⁶″ independently represents an aryl group, alkyl group or alkenyl group which may have a substituent; In the formula (ca-1), two of R¹″ to R³″ may be mutually bonded to form a ring with the sulfur atom.

As the aryl group which may have a substituent, alkyl group which may have a substituent or alkenyl group which may have a substituent for R¹″ to R³″ in the formula (ca-1), the same aryl group, alkyl group or alkenyl group as those described above for R⁴″ and R⁵″ in the general formula (a0-1) can be mentioned.

Examples of the substituent which the aryl group, alkyl group or alkenyl group may have include the same groups as those described above in the explanation for R³ in the formula (a0-1) for substituents which the substituted alkylene group may have. Specific examples of the substituent include a halogen atom, an oxo group (═O), a cyano group, an alkyl group, an alkoxyalkyloxy group, an alkoxycarbonylalkyloxy group, —C(═O)—O—R⁷″, —O—C(═O)—R⁸″, —O—R⁹″ and an aryl group. R⁷″, R⁸″ and R⁹″ each independently represents a hydrogen atom or a hydrocarbon group, and a hydrogen atom, a saturated hydrocarbon group or an aliphatic, unsaturated hydrocarbon group is preferable.

With respect to the cation moiety represented by the formula (ca-1), when R¹″ to R³″ each independently represents an aryl group, an alkyl group or an alkenyl group, preferable examples of the cation moiety include cation moieties represented by formulas (ca-1-1) to (ca-1-34) shown below.

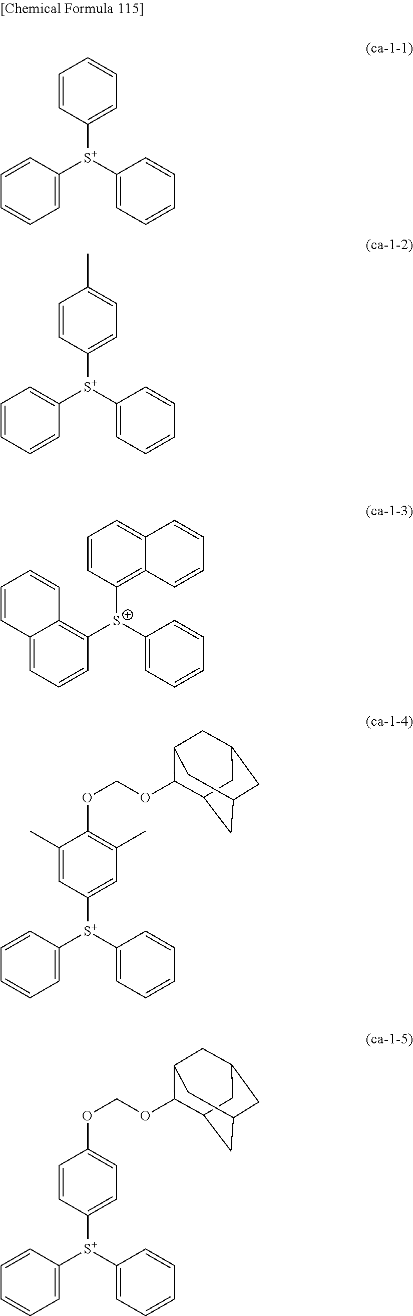

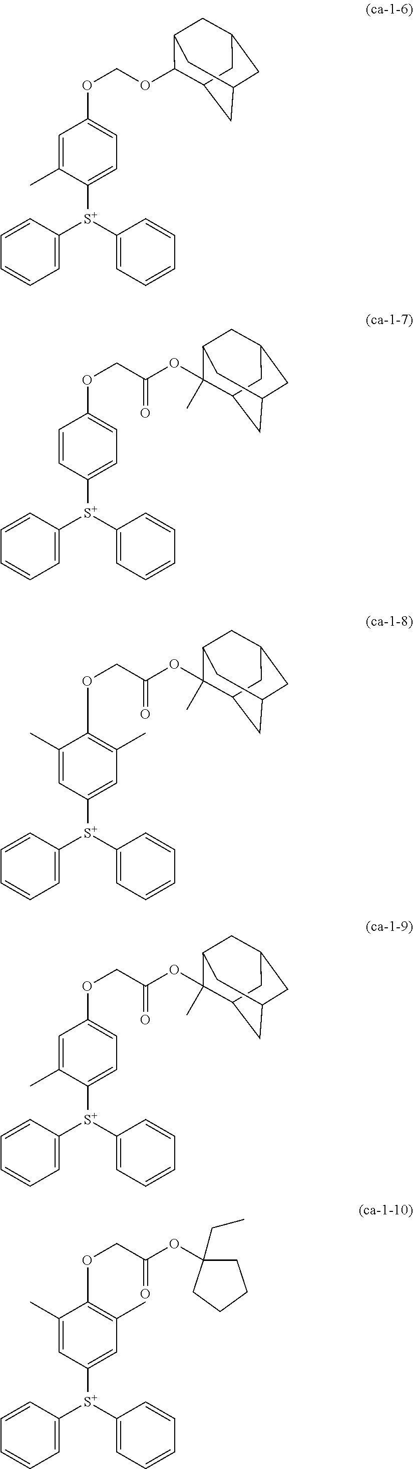

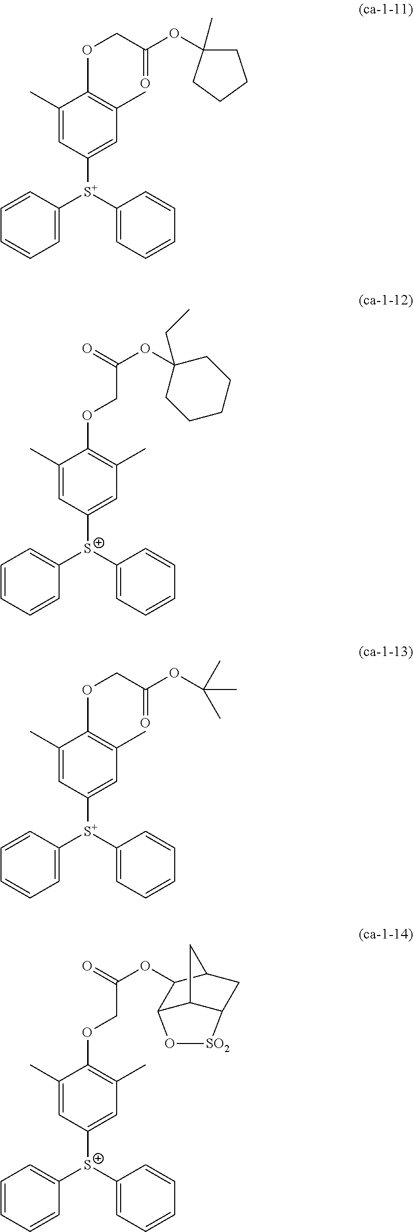

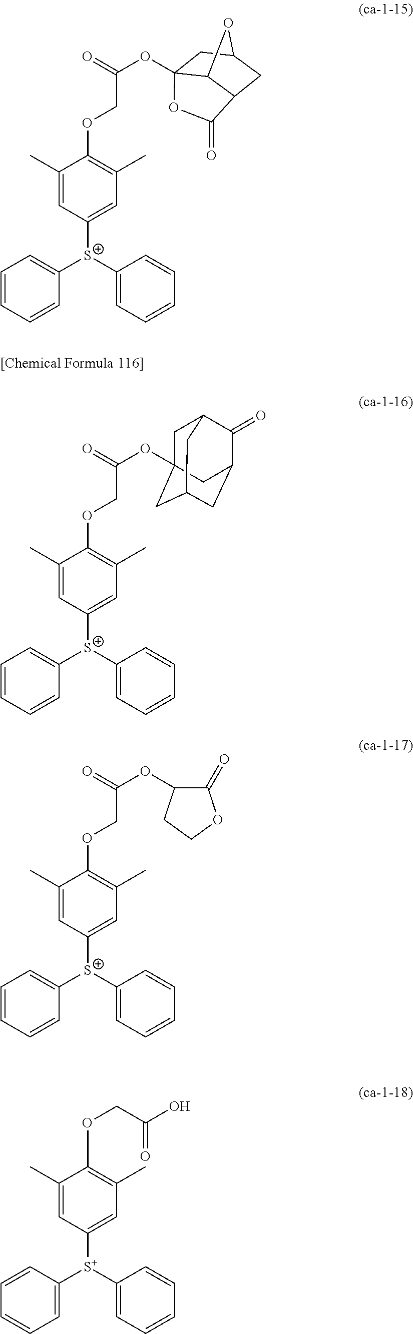

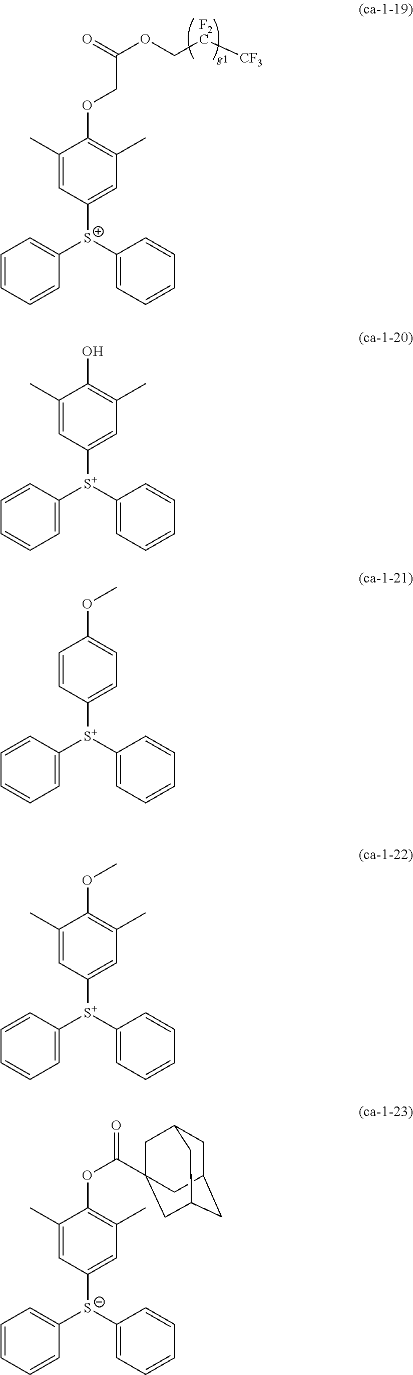

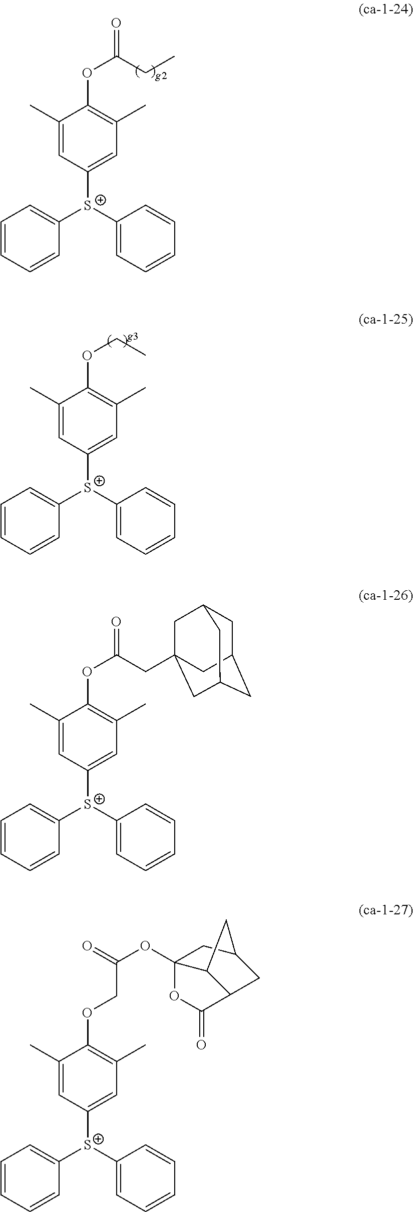

In the formulas, g1, g2 and g3 represent recurring numbers, wherein g1 is an integer of 1 to 5, g2 is an integer of 0 to 20, and g3 is an integer of 0 to 20.

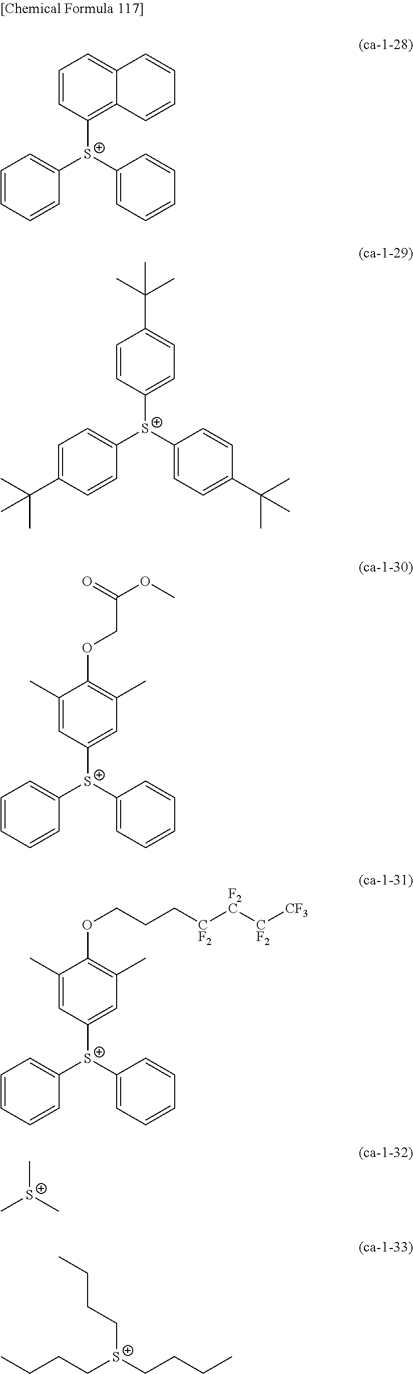

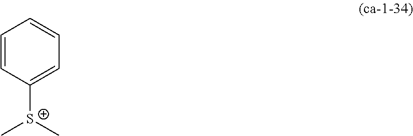

in formula (ca-1), two of R¹″ to R³″ may be mutually bonded to form a ring with the sulfur atom. The ring may be saturated or unsaturated. Further, the ring may be monocyclic or polycyclic. For example, in the case where either one or both of the two of R¹″ to R³″ represent a cyclic group (a cyclic alkyl group or an aryl group), when the two groups are bonded, a polycyclic ring (fused ring) is formed.

As the ring to be formed, the ring containing the sulfur atom in the skeleton thereof is preferably a 3 to 10-membered ring, and most preferably a 5 to 7-membered ring.

The ring may have a hetero atom as an atom constituting the ring skeleton other than the sulfur atom having R¹″ to R³″ bonded thereto. Examples of hetero atoms include an oxygen atom, a nitrogen atom, and a sulfur atom.

Specific examples of the rings to be formed include a thiophene ring, a thiazole ring, a benzothiophene ring, a thianthrene ring, a benzothiophene ring, a dibenzothiophene ring, a 9H-thioxanthene ring, a thioxanthone ring, a thianthrene ring, a phenoxathiin ring, a tetrahydrothiophenium ring and tetrahydrothiopyranium ring.

With respect to the cation moiety represented by the formula (ca-1), when two of R¹″ to R³″ are mutually bonded to form a ring with the sulfur atom, preferable examples of the cation moiety include cation moieties represented by formula (ca-2) to (ca-5).

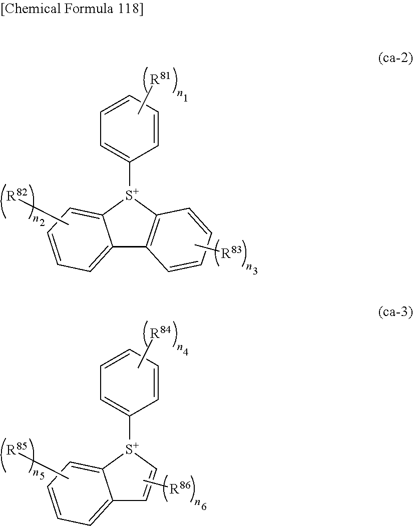

In formulas, each of R⁸¹ to R⁸⁶ independently represents an alkyl group, an acetyl group, an alkoxy group, a carboxy group, a hydroxyl group or a hydroxyalkyl group; each of n₁ to n₅ independently represents an integer of 0 to 3; and n₆ represents an integer of 0 to 2.

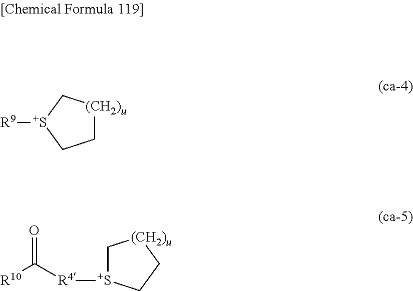

In the formulas, u represents an integer of 1 to 3; R⁹ represents a phenyl group, a naphthyl group or an alkyl group which may have a substituent; R¹⁹ represents a hydroxy group, a phenyl group, a naphthyl group, an alkyl group or an alkoxy group which may have a substituent; and R⁴′ represents an alkylene group which may have a substituent.

In the formulas (ca-2) and (ca-3), the alkyl group for R⁸¹ to R⁸⁶ is preferably an alkyl group of 1 to 5 carbon atoms, more preferably a linear or branched alkyl group, and particularly preferably a methyl group, an ethyl group, a propyl group, an isopropyl group, an n-butyl group or a tert butyl group.

The alkoxy group is preferably an alkoxy group of 1 to 5 carbon atoms, more preferably a linear or branched alkoxy group, and most preferably a methoxy group or an ethoxy group.

The hydroxyalkyl group is preferably a group in which one or more hydrogen atoms in the aforementioned alkyl group have been substituted with hydroxy groups, and examples thereof include a hydroxymethyl group, a hydroxyethyl group and a hydroxypropyl group.

If there are two or more of an individual R⁸¹ to R⁸⁶ group, as indicated by the corresponding value of n₁ to n₆ then the two or more of the individual R⁸¹ to R⁸⁶ group may be the same or different from each other.

n₁ is preferably 0 to 2, more preferably 0 or 1, and still more preferably 0.

It is preferable that each of n₂ and n₃ independently represent 0 or 1, and more preferably 0.

n₄ is preferably 0 to 2, and more preferably 0 or 1.

n₅ is preferably 0 or 1, and more preferably 0.

n₆ is preferably 0 or 1, and more preferably 1.

Preferable examples of the cation represented by formula (ca-2) or (ca-3) are shown below.

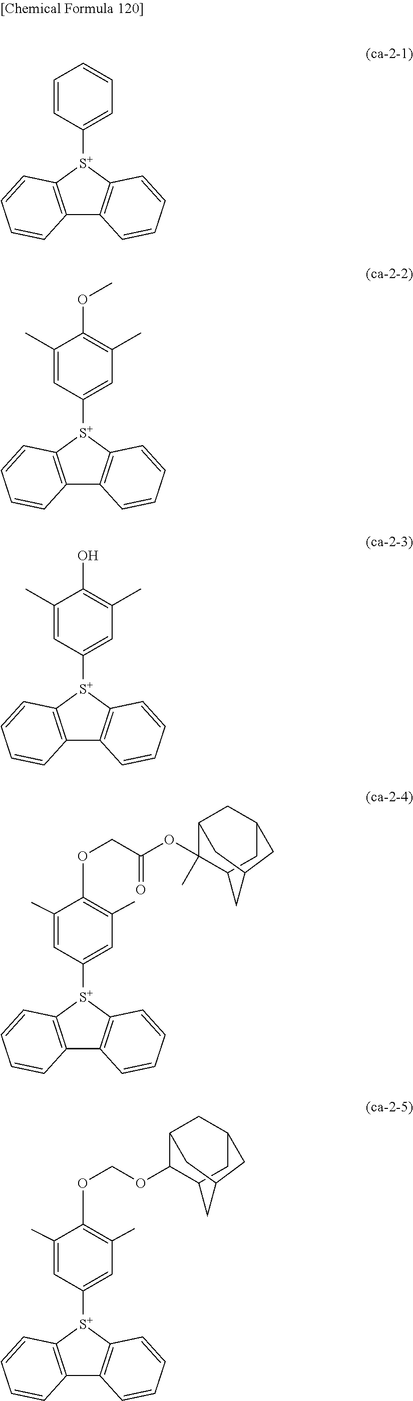 [SMILES: c1ccc(-[s+]2c3ccccc3c3ccccc32)cc1 ; COc1c(C)cc(-[s+]2c3ccccc3c3ccccc32)cc1C ; Cc1cc(-[s+]2c3ccccc3c3ccccc32)cc(C)c1O ; Cc1cc(-[s+]2c3ccccc3c3ccccc32)cc(C)c1OCC(=O)OC1(C)C2CC3CC(C2)CC1C3 ; Cc1cc(-[s+]2c3ccccc3c3ccccc32)cc(C)c1OCOC1C2CC3CC(C2)CC1C3]

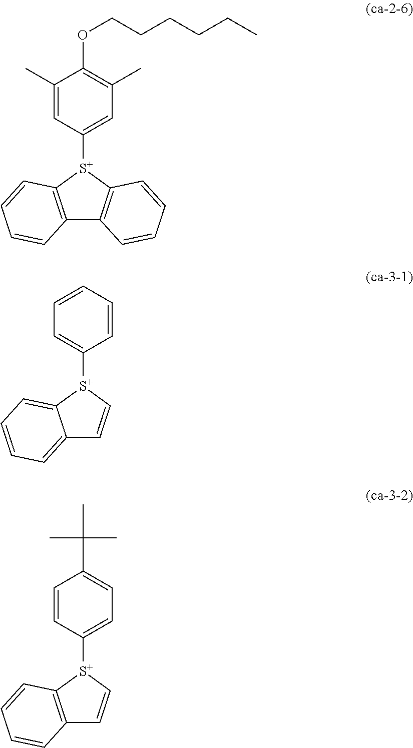 [SMILES: CCCCCCOc1c(C)cc(-[s+]2c3ccccc3c3ccccc32)cc1C ; c1ccc(-[s+]2ccc3ccccc32)cc1 ; CC(C)(C)c1ccc(-[s+]2ccc3ccccc32)cc1]

In the formulas (ca-4) and (ca-5), u is an integer of 1 to 3, and most preferably 1 or 2.

R⁹ represents a phenyl group, a naphthyl group or an alkyl group which may have a substituent.

As the alkyl group for R⁹, the same alkyl group for R¹″ to R³″ can be used.

Examples of the substituent which the phenyl group, naphthyl group or alkyl group for R⁹ may have include the same groups as those described above in the explanation for R³ in the formula (a0-1) for substituents which the substituted alkylene group may have. Specific examples of the substituent include a halogen atom, an oxo group (═O), a cyano group, an alkyl group, an alkoxyalkyloxy group, an alkoxycarbonylalkyloxy group, —C(═O)—O—R⁷″, —O—C(═O)—R⁸″, —O—R⁹″ and an aryl group. R⁷″, R⁸″ and R⁹″ each independently represents a hydrogen atom or a hydrocarbon group, and a hydrogen atom, a saturated hydrocarbon group or an aliphatic, unsaturated hydrocarbon group is preferable.

R¹⁰ represents a hydroxy group, a phenyl group, a naphthyl group, an alkyl group and an alkoxy group which may have a substituent. As the alkyl group in the alkyl group or alkoxy group for R⁹, the same alkyl group for R¹″ to R³″ can be used.

Examples of the substituent which the phenyl group, naphthyl group, alkyl group or alkoxy group for R¹⁰ may have include the same groups as those described above for substituent which the phenyl group, naphthyl group, alkyl group or alkoxy group represented by R⁹ may have.

As the alkylene group for R⁴′, a linear or branched alkylene group is preferable. The alkylene group preferably has 1 to 12 carbon atoms, more preferably 1 to 5 carbon atoms, still more preferably 1 to 3 carbon atoms and particularly preferably 1 or 2 carbon atoms.

Examples of the substituent which the alkylene group may have include the same groups as those described above for substituents in substituted alkylene group for R³ (e.g., a halogen atom, an oxo group (═O), a cyano group, an alkyl group, an alkoxyalkyloxy group, an alkoxycarbonylalkyloxy group, —C(═O)—O—R⁷″, —O—C(═O)—R⁸″, —O—R⁹″ and an aryl group).

Preferable examples of the cation represented by formula (ca-4) or (ca-5) are shown below.

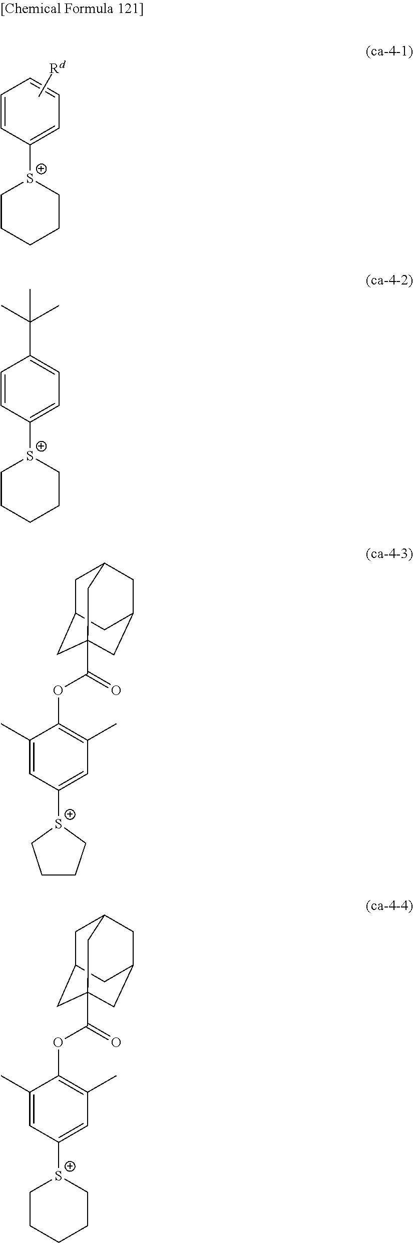

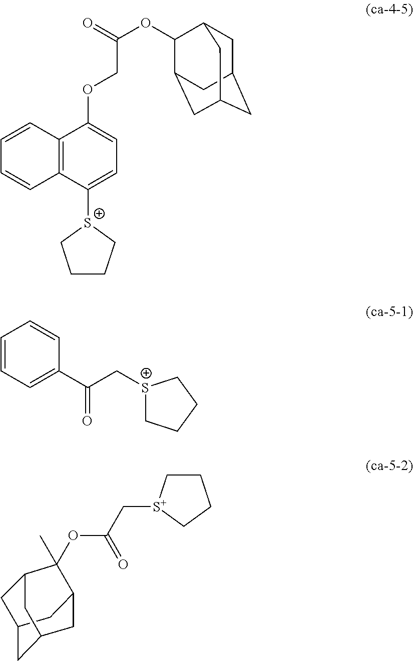

In formula (ca-4-1), R^{d} represents a substituent. Examples of substituents include the same groups as those described above for substituents which the phenyl group, naphthyl group or alkyl group for R⁹ may have. Specific examples of the substituent include a halogen atom, an oxo group (═O), a cyano group, an alkyl group, an alkoxyalkyloxy group, an alkoxycarbonylalkyloxy group, —C(═O)—O—R⁷″-O—C(═O)—R⁸″, —O—R⁹″ and an aryl group. R⁷″, R⁸″ and R⁹″ each independently represents a hydrogen atom or a hydrocarbon group, and a hydrogen atom, a saturated hydrocarbon group or an aliphatic, unsaturated hydrocarbon group is preferable.

In the present invention, the organic cation (M^{m+}) has one aromatic ring or no aromatic ring, as well as M^{m+} in the general formula (a0-2).

As the organic cation having a single aromatic ring or no aromatic ring, the same cation moieties as those described above for M^{m+} in the general formula (a0-2) can be mentioned. Among these, a cation moiety represented by the general formula (m-1) or (m-2) is preferable, and a cation moiety represented by the general formula (m-1) is more preferable, and a cation moiety represented by the general formula (m-11), (m-12), (m-13) or (m-14) is particularly preferable.

As the compound (C1), one type of compounds may be used alone, or two or more types of compounds may be used in combination.

### [Compound (C2)]

### —Anion Moiety

In formula (c2), R^{2c} represents a hydrocarbon group of 1 to 30 carbon atoms which may have a substituent,

The hydrocarbon group of 1 to 30 carbon atoms for R^{2c} which may have a substituent may be either an aliphatic hydrocarbon group or an aromatic hydrocarbon group, and the same aliphatic hydrocarbon groups and aromatic hydrocarbon groups as those described above for the aforementioned R^{1c} in the formula (c1) can be used.

Among these, as the hydrocarbon group for R^{2c} which may have a substituent, an aliphatic cyclic group which may have a substituent is preferable, and a group in which one or more hydrogen atoms have been removed from adamantane, norbornane, isobornane, tricyclodecane, tetracyclododecane or camphor (which may have a substituent) is more preferable.

Examples of the substituent which the hydrocarbon group for R^{2c} may have include the same substituents for substituting R⁴″ in the formula “R⁴″SO₃⁻” as those described above in relation to V⁻ in the general formula (a0-1). Specific examples of the substituents include a halogen atom, a hetero atom, an alkyl group, and a group represented by the formula X³-Q′- (in the formula, Q′ represents a divalent linking group containing an oxygen atom; and X³ represents a hydrocarbon group of 3 to 30 carbon atoms which may have a substituent). Provided that, in R^{2c}, the carbon atom adjacent to the sulfur atom within SO₃⁻ has no fluorine atom as a substituent. Since the carbon atom adjacent to the sulfur atom within SO₃⁻ has no fluorine atom as a substituent, the anion of the component (C2) becomes an appropriately weak acid anion, thereby improving the quenching ability of the component (C).

Specific examples of preferable anion moieties for the compound (C2) are shown below.

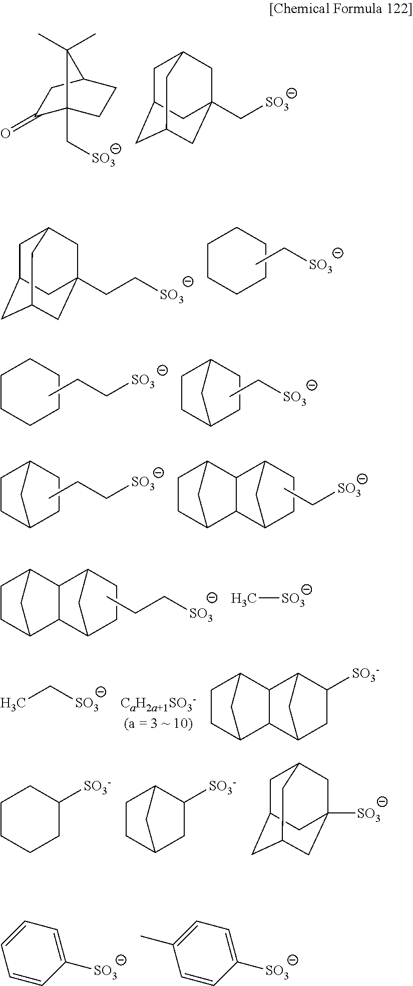

### —Cation Moiety

In formula (c2), M⁺ is the same as defined for M⁺ in the aforementioned formula (c1).

As the compound (C2), one type of compound may be used alone, or two or more types of compounds may be used in combination.

### [Compound (C3)]

### —Anion Moiety

In formula (c3), R^{3c} represents an organic group.

The organic group for R^{3c} is not particularly limited, and preferable examples thereof include an alkyl group, an alkoxy group, —O—C(═O)—C(R^{c2})═CH₂ (wherein R^{C2} represents a hydrogen atom, an alkyl group of 1 to 5 carbon atoms or a halogenated alkyl group of 1 to 5 carbon atoms) and —O—C(═O)—R^{C3} (wherein, R^{C3} represents a hydrocarbon group).

The alkyl group for R^{3c} is preferably a linear or branched alkyl group of 1 to 5 carbon atoms, and specific examples include a methyl group, an ethyl group, a propyl group, an isopropyl group, an n-butyl group, an isobutyl group, a tert-butyl group, a pentyl group, an isopentyl group, and a neopentyl group. Part of the hydrogen atoms within the alkyl group for R² may be substituted with a hydroxy group, a cyano group or the like.

The alkoxy group for R^{3c} is preferably an alkoxy group of 1 to 5 carbon atoms, and specific examples thereof include a methoxy group, an ethoxy group, an n-propoxy group, an iso-propoxy group, an n-butoxy group and a tert-butoxy group. Among these, a methoxy group and an ethoxy group are particularly desirable.

In —O—C(═O)—C(R^{C2})═CH₂, R^{C2} represents a hydrogen atom, an alkyl group of 1 to 5 carbon atoms or a halogenated alkyl group of 1 to 5 carbon atoms.

The alkyl group of 1 to 5 carbon atoms for R^{C2} is preferably a linear or branched alkyl group of 1 to 5 carbon atoms, and specific examples thereof include a methyl group, an ethyl group, a propyl group, an isopropyl group, an n-butyl group, an isobutyl group, a tert-butyl group, a pentyl group, an isopentyl group and a neopentyl group.

The halogenated alkyl group for R^{C2} is a group in which part or all of the hydrogen atoms of the aforementioned alkyl group of 1 to 5 carbon atoms has been substituted with halogen atoms. Examples of the halogen atom include a fluorine atom, a chlorine atom, a bromine atom and an iodine atom, and a fluorine atom is particularly preferred.

As R^{C2}, a hydrogen atom, an alkyl group of 1 to 3 carbon atoms or a fluorinated alkyl group of 1 to 3 carbon atoms is preferable, and a hydrogen atom or a methyl group is particularly desirable in terms of industrial availability.

In the formula —O—C(═O)—R^{C3}, R^{C3} represents a hydrocarbon group.

The hydrocarbon group for R^{C3} may be either an aromatic hydrocarbon group or an aliphatic hydrocarbon group. Examples of the hydrocarbon groups for R^{C3} include the same hydrocarbon groups as those described above for R^{1c} in the general formula (c1).

Among these, as the hydrocarbon group for R^{C3}, an alicyclic group (e.g., a group in which one or more hydrogen atoms have been removed from a cycloalkane such as cyclopentane, cyclohexane, adamantane, norbornane, isobornane, tricyclodecane or tetracyclododecane) or an aromatic group (e.g., a phenyl group or a naphthyl group) is preferable. When R^{C3} is an alicyclic group, the resist composition can be satisfactorily dissolved in an organic solvent, thereby improving the lithography properties.

As R^{3c}, —O—C(═O)—C(R^{C2}′)═CH₂ (wherein R^{C2}′ represents a hydrogen atom or a methyl group) or —O—C(═O)—R^{C3}′ (wherein, R^{C3}′ represents an aliphatic cyclic group) is preferable.

In formula (c3), Y³ represents a linear, branched or cyclic alkylene group or an arylene group.

Examples of the linear or branched alkylene group for Y³ include the same “linear or branched aliphatic hydrocarbon group” described above as the divalent linking group for Q¹ in the formula (a0-1).

Examples of the cyclic alkylene group for Y³ include the same “cyclic aliphatic hydrocarbon group” described above as the divalent linking group for Q¹ in the formula (a0-1).

Examples of the arylene group for Y³ include the same “aromatic hydrocarbon group” described above as the divalent linking group for Q¹ in the formula (a0-1).

Among these, as Y³, an alkylene group is preferable, a linear or branched alkylene group is more preferable, and a methylene group or an ethylene group is still more preferable.

In formula (c3), R^{f3} represents a hydrocarbon group containing a fluorine atom.

The hydrocarbon group containing a fluorine atom for R^{f3} is preferably a fluorinated alkyl group, and more preferably the same fluorinated alkyl groups as those described above for R^{1c}.

Specific examples of preferable anion moieties for the compound (C3) are shown below.

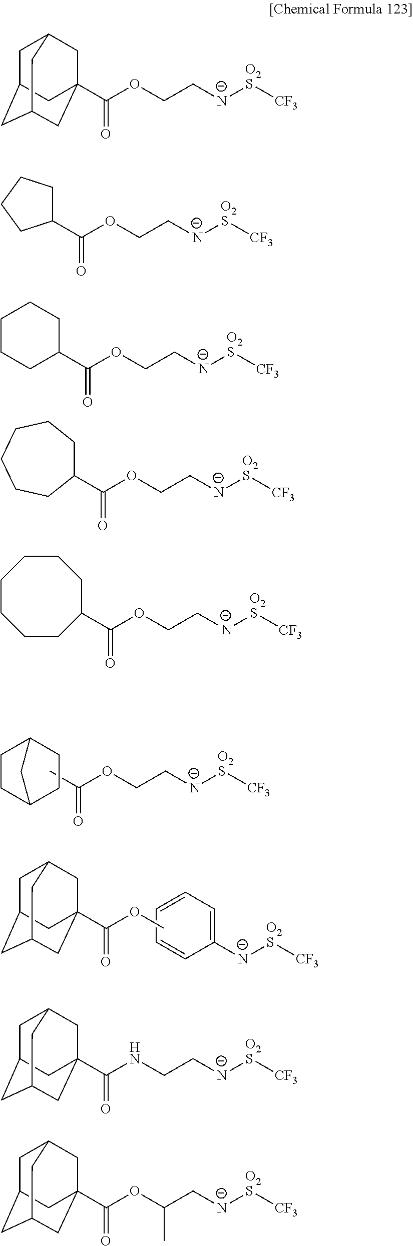

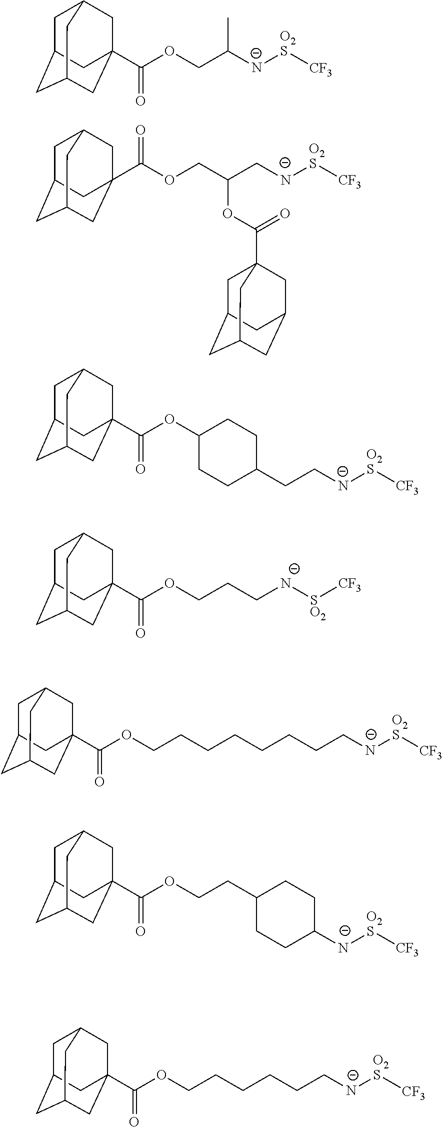

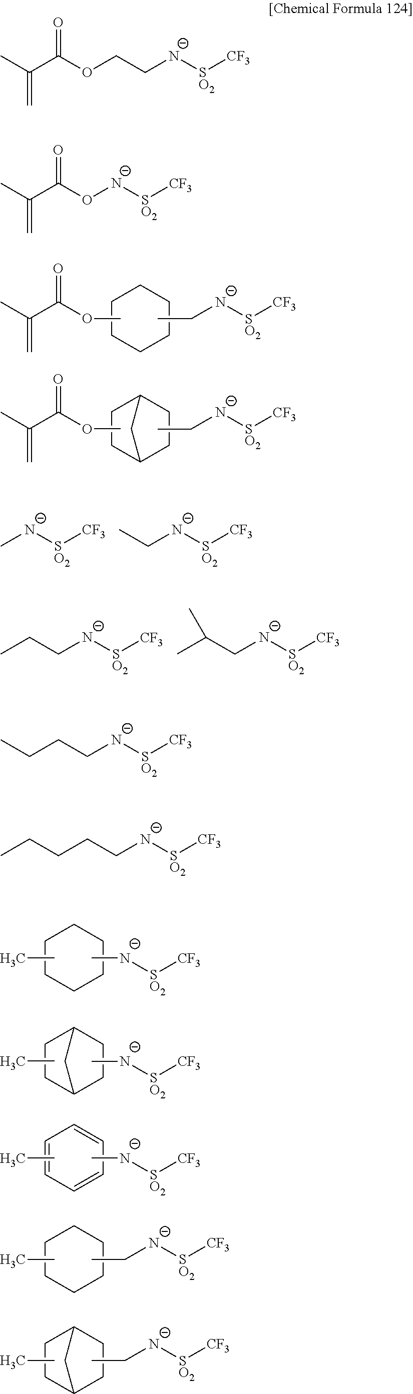

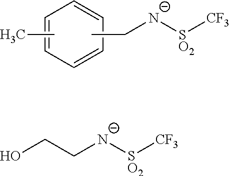

### —Cation Moiety

In formula (c3), M⁺ is the same as defined for M⁺ in the aforementioned formula (c1).

As the compound (C3), one type of compound may be used alone, or two or more types of compounds may be used in combination.

In terms of excellent lithography properties such as roughness, the component (C) preferably includes at least one of the compound selected from the group consisting of the compounds (C1), (C2) and (C3). The component (C) may contain one of the aforementioned compounds (C1) to (C3), or at least two of the aforementioned components (C1) to (C3). Among these, the component (C) preferably contains the component (C2).

In the third aspect of the present invention, the amount of the component (C) relative to 100 parts by weight of the component (A) is preferably within a range from 0.5 to 10.0 parts by weight, more preferably from 0.5 to 8.0 parts by weight, still more preferably from 1.0 to 8.0 parts by weight, and particularly preferably from 1.5 to 5.5 parts by weight.

When the amount of the component (C) is at least as large as the lower limit of the above-mentioned range, various lithography properties such as resolution, roughness and exposure latitude are improved. Further, a resist pattern having an excellent shape can be obtained. On the other hand, in the case where the amount of the component (C) is no more than the upper limit of the above-mentioned range, sensitivity can be maintained at a satisfactory level, and throughput becomes excellent.

As the compounds (C1) to (C3), commercially available compounds may be used, or the compounds may be synthesized by a conventional method.

The production methods of the components (C1) and (C2) are not particularly limited, and the components (C1) and (C2) can be produced by conventional methods.

The production method of the compound (C3) of the present invention is not particularly limited. For example, in the case where R^{3c} in formula (c3) is a group having an oxygen atom on the terminal thereof which is bonded to Y³, the compound (C3) represented by general formula (c3) can be produced by reacting a compound (i-1) represented by general formula (i-1) shown below with a compound (i-2) represented by general formula (i-2) shown below to obtain a compound (i-3) represented by general formula (i-3), and then reacting the compound (i-3) with a compound Z⁻M⁺ having the desired cation M⁺, thereby obtaining the compound (C3).

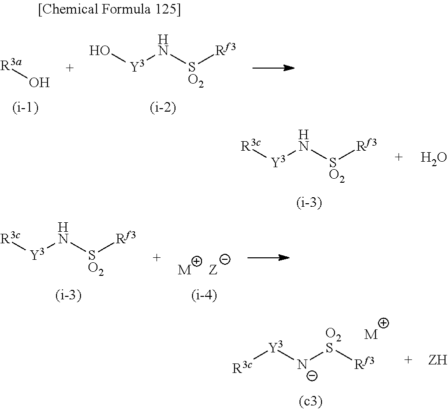

In the formulas, R^{3c}, Y³, R^{f3} and M⁺ are respectively the same as defined for R^{3c}, Y³, R^{f3} and M⁺ in the formula (c3); R^{3a} represented a group in which the terminal oxygen atom has been removed from R^{3c}; and Z⁻ represents a counteranion.

Firstly, the compound (i-1) is reacted with the compound (i-2), thereby obtaining the compound (i-3).

In formula (i-1), R^{3a} represents a group in which the terminal oxygen atom has been removed from R^{3c}. In formula (i-2), Y³ and R^{f3} are the same as defined above.

As the compound (i-1) and the compound (i-2), commercially available compounds may be used, or the compounds may be synthesized.

The method for reacting the compound (i-1) with the compound (i-2) to obtain the compound (i-3) is not particularly limited, but can be performed, for example, by reacting the compound (i-1) with the compound (i-2) in an organic solvent in the presence of an appropriate acidic catalyst, followed by washing and recovering the reaction mixture.

The acidic catalyst used in the above reaction is not particularly limited, and examples thereof include toluenesulfonic acid and the like. The amount of the acidic catalyst is preferably 0.05 to 5 moles, per 1 mole of the compound (i-2).

As the organic solvent used in the above reaction, any organic solvents which are capable of dissolving the raw materials, i.e., the compound (i-1) and the compound (i-2) can be used, and specific examples thereof include toluene and the like. The amount of the organic solvent is preferably 0.5 to 100 parts by weight, more preferably 0.5 to 20 parts by weight, relative to the amount of the compound (i-1). As the solvent, one type may be used alone, or two or more types may be used in combination.

In general, the amount of the compound (i-2) used in the above reaction is preferably 0.5 to 5 moles per 1 mole of the compound (i-1), and more preferably 0.8 to 4 moles per 1 mole of the compound (i-1).

The reaction time varies depending on the reactivity of the compounds (i-1) and (i-2), the reaction temperature or the like. However, in general, the reaction time is preferably 1 to 80 hours, and more preferably 3 to 60 hours.

The reaction temperature in the above reaction is preferably 20 to 200° C., and more preferably 20 to 150° C.

Next, the obtained compound (i-3) is reacted with the compound (i-4), thereby obtaining the compound (C3).

In formula (i-4), M⁺ is the same as defined above, and Z⁻ represents a counteranion.

The method for reacting the compound (i-3) with the compound (i-4) to obtain the compound (C3) is not particularly limited, but can be performed, for example, by dissolving the compound (i-3) in an organic solvent and water in the presence of an appropriate alkali metal hydroxide, followed by addition of the compound (i-4) and stirring.

The alkali metal hydroxide used in the above reaction is not particularly limited, and examples thereof include sodium hydroxide, potassium hydroxide and the like. The amount of the alkali metal hydroxide is preferably 0.3 to 3 moles, per 1 mole of the compound (i-3).

Examples of the organic solvent used in the above reaction include dichloromethane, chloroform, ethyl acetate and the like. The amount of the organic solvent is preferably 0.5 to 100 parts by weight, and more preferably 0.5 to 20 parts by weight, relative to the amount of the compound (i-3). As the solvent, one type may be used alone, or two or more types may be used in combination.

In general, the amount of the compound (i-4) used in the above reaction is preferably 0.5 to 5 moles per 1 mole of the compound (i-3), and more preferably 0.8 to 4 moles per 1 mole of the compound (i-3).

The reaction time varies depending on the reactivity of the compounds (i-3) and (i-4), the reaction temperature or the like. However, in general, the reaction time is preferably 1 to 80 hours, and more preferably 3 to 60 hours.

The reaction temperature in the above reaction is preferably 20 to 200° C., and more preferably 20 to 150° C.

After the reaction, the compound (C3) contained in the reaction mixture may be separated and purified. The separation and purification can be conducted by a conventional method. For example, any one of concentration, solvent extraction, distillation, crystallization, recrystallization and chromatography can be used alone, or two or more of these methods may be used in combination.

The structure of the compound (C3) obtained in the above-described manner can be confirmed by a general organic analysis method such as ¹H-nuclear magnetic resonance (NMR) spectrometry, ¹³C-NMR spectrometry, ¹⁹F-NMR spectrometry, infrared absorption (IR) spectrometry, mass spectrometry (MS), elementary analysis and X-ray diffraction analysis.

### <Optional Components>

### [Component (A″)]

The resist composition of the third aspect of the present invention may contain a base component which exhibits changed solubility in an alkali developing solution by the action of acid other than the component (A) (hereafter, referred to as component (A″)), as long as the effects of the present invention are not impaired.

The component (A″) may be either a base component that exhibit increased solubility in a developing solution by the action of acid or a base component that exhibits decreased solubility in a developing solution by the action of acid. When the component (A) is a component that exhibit increased solubility in a developing solution by the action of acid, as the component (A″), a base component that exhibit increased solubility in a developing solution by the action of acid is used. When the component (A) is a component that exhibit decreased solubility in a developing solution by the action of acid, as the component (A″), a base component that exhibit decreased solubility in a developing solution by the action of acid is used.

The component (A″) is not particularly limited, and any of the multitude of conventional base components used within chemically amplified resist compositions (e.g., base resins used within chemically amplified resist compositions for ArF excimer lasers or KrF excimer lasers, preferably ArF excimer lasers) can be used.

The component (A″) may be a resin, a low molecular weight compound, or a combination of these materials.

As the component (A″), one type may be used, or two or more types may be used in combination.

### <Acid-Generator Component (B)>

The resist composition of the present invention may also contain an acid-generator component (B) which generates acid upon exposure and which does not fall under the definition of the aforementioned component (A) (hereafter, referred to as “component (B)”), as long as the effects of the present invention are not impaired.

As the component (B), there is no particular limitation, and any of the known acid generators used in conventional chemically amplified resist compositions can be used. Examples of these acid generators are numerous, and include onium salt acid generators such as iodonium salts and sulfonium salts; oxime sulfonate acid generators; diazomethane acid generators such as bisalkyl or bisaryl sulfonyl diazomethanes and poly(bis-sulfonyl)diazomethanes; nitrobenzylsulfonate acid generators; iminosulfonate acid generators; and disulfone acid generators.

As an onium salt acid generator, a compound represented by general formula (b-1) or (b-2) shown below can be used.

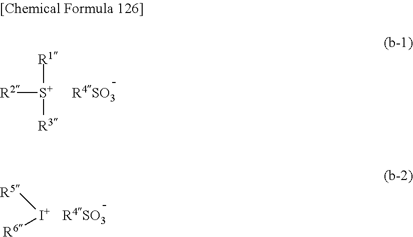

In the formulas, each of R¹″ to R³″, and R⁵″ to R⁶″ independently represents an aryl group, alkyl group or alkenyl group which may have a substituent; in formula (I-1), two of R¹″ to R³″ may be bonded to each other to form a ring with the sulfur atom, Provided that —R³—S⁺(R²″)(R³″) has one aromatic ring or no aromatic ring in total; R⁵″ to R⁶″ has one aromatic ring or no aromatic ring in total; and R⁴″ represents an alkyl group, a halogenated alkyl group, an aryl group or an alkenyl group which may have a substituent.

R¹″ to R³″ in the formula (b-1) and R⁵″ to R⁶″ in the formula (b-2) are each the same as defined for R¹″ to R³″ in the formula (m-1) and R⁵″ to R⁶″ in the formula (m-2).

R⁴″SO₃⁻ in the formulas (b-1) and (b-2) is the same as defined above for R⁴″SO₃⁻ in the explanation of V⁻ in the formula (a0-1) in relation to the structural unit (a0).

Further, onium salt-based acid generators in which the anion moiety (R⁴″SO₃⁻) in the general formula (b-1) or (b-2) is replaced by an anion moiety represented by the general formula (b-3) or (b-4) (the cation moiety is the same as (b-1) or (b-2)) may be used.

In the present description, an oximesulfonate-based acid generator is a compound having at least one group represented by general formula (B-1) shown below, and has a feature of generating acid by irradiation. Such oxime sulfonate acid generators are widely used for a chemically amplified resist composition, and can be appropriately selected.

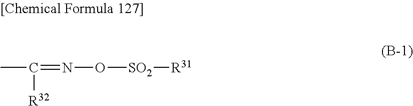

In the formula, R³¹ and R³² each independently represent an organic group.

The organic group for R³¹ and R³² refers to a group containing a carbon atom, and may include atoms other than carbon atoms (e.g., a hydrogen atom, an oxygen atom, a nitrogen atom, a sulfur atom, a halogen atom (such as a fluorine atom and a chlorine atom) and the like).

As the organic group for R³¹, a linear, branched, or cyclic alkyl group or aryl group is preferable. The alkyl group or the aryl group may have a substituent. The substituent is not particularly limited, and examples thereof include a fluorine atom and a linear, branched, or cyclic alkyl group having 1 to 6 carbon atoms. The alkyl group or the aryl group “has a substituent” means that part or all of the hydrogen atoms of the alkyl group or the aryl group is substituted with a substituent.

The alkyl group preferably has 1 to 20 carbon atoms, more preferably 1 to 10 carbon atoms, still more preferably 1 to 8 carbon atoms, particularly preferably 1 to 6 carbon atoms, and most preferably 1 to 4 carbon atoms. As the alkyl group, a partially or completely halogenated alkyl group (hereinafter, sometimes referred to as a “halogenated alkyl group”) is particularly desirable. The “partially halogenated alkyl group” refers to an alkyl group in which part of the hydrogen atoms are substituted with halogen atoms and the “completely halogenated alkyl group” refers to an alkyl group in which all of the hydrogen atoms are substituted with halogen atoms. Examples of halogen atoms include fluorine atoms, chlorine atoms, bromine atoms and iodine atoms, and fluorine atoms are particularly desirable. In other words, the halogenated alkyl group is preferably a fluorinated alkyl group.

The aryl group preferably has 4 to 20 carbon atoms, more preferably 4 to 10 carbon atoms, and most preferably 6 to 10 carbon atoms. As the aryl group, partially or completely halogenated aryl group is particularly desirable. The “partially halogenated aryl group” refers to an aryl group in which part of the hydrogen atoms are substituted with halogen atoms, and the “completely halogenated aryl group” refers to an aryl group in which all of hydrogen atoms are substituted with halogen atoms.

As R³¹, an alkyl group of 1 to 4 carbon atoms which has no substituent or a fluorinated alkyl group of 1 to 4 carbon atoms is particularly desirable.

As the organic group for R³², a linear, branched, or cyclic alkyl group, aryl group, or cyano group is preferable. As the alkyl group or aryl group for R³², the same alkyl groups or aryl groups as those described above for R³¹ can be used.

As R³², a cyano group, an alkyl group of 1 to 8 carbon atoms having no substituent or a fluorinated alkyl group of 1 to 8 carbon atoms is particularly desirable.

Preferable examples of the oxime sulfonate-based acid generator include compounds represented by general formula (B-2) or (B-3) shown below.

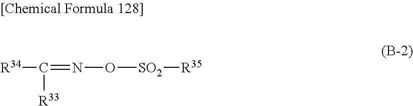

In the formula, R³³ represents a cyano group, an alkyl group having no substituent or a halogenated alkyl group; R³⁴ represents an aryl group; and R³⁵ represents an alkyl group having no substituent or a halogenated alkyl group.

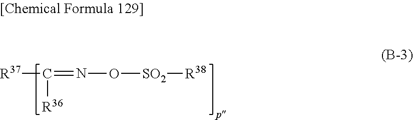

In the formula (B-3), R³⁶ represents a cyano group, an alkyl group having no substituent or a halogenated alkyl group; R³⁷ represents a divalent or trivalent aromatic hydrocarbon group; R³⁸ represents an alkyl group having no substituent or a halogenated alkyl group; and p″ represents 2 or 3.

In general formula (B-2), the alkyl group having no substituent or the halogenated alkyl group for R³³ preferably has 1 to 10 carbon atoms, more preferably 1 to 8 carbon atoms, and most preferably 1 to 6 carbon atoms.

As R³³, a halogenated alkyl group is preferable, and a fluorinated alkyl group is more preferable.

The fluorinated alkyl group for R³³ preferably has 50% or more of the hydrogen atoms thereof fluorinated, more preferably 70% or more, and most preferably 90% or more.

Examples of the aryl group for R³⁴ include groups in which one hydrogen atom has been removed from an aromatic hydrocarbon ring, such as a phenyl group, a biphenyl group, a fluorenyl group, a naphthyl group, an anthryl group, and a phenantryl group, and heteroaryl groups in which some of the carbon atoms constituting the ring(s) of these groups are substituted with hetero atoms such as an oxygen atom, a sulfur atom, and a nitrogen atom. Of these, a fluorenyl group is preferable.

The aryl group for R³⁴ may have a substituent such as an alkyl group of 1 to 10 carbon atoms, a halogenated alkyl group, or an alkoxy group. The alkyl group and halogenated alkyl group as the substituent preferably has 1 to 8 carbon atoms, and more preferably 1 to 4 carbon atoms. Further, the halogenated alkyl group is preferably a fluorinated alkyl group.

The alkyl group having no substituent or the halogenated alkyl group for R³⁵ preferably has 1 to 10 carbon atoms, more preferably 1 to 8 carbon atoms, and most preferably 1 to 6 carbon atoms.

As R³⁵, a halogenated alkyl group is preferable, and a fluorinated alkyl group is more preferable.

In terms of enhancing the strength of the acid generated, the fluorinated alkyl group for R³⁵ preferably has 50% or more of the hydrogen atoms fluorinated, more preferably 70% or more, still more preferably 90% or more. A completely fluorinated alkyl group in which 100% of the hydrogen atoms are substituted with fluorine atoms is particularly desirable.

In general formula (B-3), as the alkyl group having no substituent and the halogenated alkyl group for R³⁶, the same alkyl group having no substituent and the halogenated alkyl group described above for R³³ can be used.

Examples of the divalent or trivalent aromatic hydrocarbon group for R³⁷ include groups in which one or two hydrogen atoms have been removed from the aryl group for R³⁴.

As the alkyl group having no substituent or the halogenated alkyl group for R³⁸, the same one as the alkyl group having no substituent or the halogenated alkyl group for R³⁵ can be used.

p″ is preferably 2.

Specific examples of suitable oxime sulfonate acid generators include α-(p-toluenesulfonyloxyimino)-benzyl cyanide, α-(p-chlorobenzenesulfonyloxyimino)-benzyl cyanide, α-(4-nitrobenzenesulfonyloxyimino)-benzyl cyanide, α-(4-nitro-2-trifluoromethylbenzenesulfonyloxyimino)-benzyl cyanide, α-(benzenesulfonyloxyimino)-4-chlorobenzyl cyanide, α-(benzenesulfonyloxyimino)-2,4-dichlorobenzyl cyanide, α-(benzenesulfonyloxyimino)-2,6-dichlorobenzyl cyanide, α-(benzenesulfonyloxyimino)-4-methoxybenzyl cyanide, α-(2-chlorobenzenesulfonyloxyimino)-4-methoxybenzyl cyanide, α-(benzenesulfonyloxyimino)-thien-2-yl acetonitrile, α-(4-dodecylbenzenesulfonyloxyimino)benzyl cyanide, α-[(p-toluenesulfonyloxyimino)-4-methoxyphenyl]acetonitrile, α-[(dodecylbenzenesulfonyloxyimino)-4-methoxyphenyl]acetonitrile, α-(tosyloxyimino)-4-thienyl cyanide, α-(methylsulfonyloxyimino)-1-cyclopentenyl acetonitrile, α-(methylsulfonyloxyimino)-1-cyclohexenyl acetonitrile, α-(methylsulfonyloxyimino)-1-cycloheptenyl acetonitrile, α-(methylsulfonyloxyimino)-1-cyclooctenyl acetonitrile, α-(trifluoromethylsulfonyloxyimino)-1-cyclopentenyl acetonitrile, α-(trifluoromethylsulfonyloxyimino)-cyclohexyl acetonitrile, α-(ethylsulfonyloxyimino)-ethyl acetonitrile, α-(propylsulfonyloxyimino)-propyl acetonitrile, α-(cyclohexylsulfonyloxyimino)-cyclopentyl acetonitrile, α-(cyclohexylsulfonyloxyimino)-cyclohexyl acetonitrile, α-(cyclohexylsulfonyloxyimino)-1-cyclopentenyl acetonitrile, α-(ethyl sulfonyloxyimino)-1-cyclopentenyl acetonitrile, α-(isopropylsulfonyloxyimino)-1-cyclopentenyl acetonitrile, α-(n-butylsulfonyloxyimino)-1-cyclopentenyl acetonitrile, α-(ethylsulfonyloxyimino)-1-cyclohexenyl acetonitrile, α-(isopropylsulfonyloxyimino)-1-cyclohexenyl acetonitrile, α-(n-butylsulfonyloxyimino)-1-cyclohexenyl acetonitrile, α-(methylsulfonyloxyimino)-phenyl acetonitrile, α-(methyl sulfonyloxyimino)-p-methoxyphenyl acetonitrile, α-(trifluoromethylsulfonyloxyimino)-phenyl acetonitrile, α-(trifluoromethylsulfonyloxyimino)-p-methoxyphenyl acetonitrile, α-(ethylsulfonyloxyimino)-p-methoxyphenyl acetonitrile, α-(propyl sulfonyloxyimino)-p-methylphenyl acetonitrile, and α-(methylsulfonyloxyimino)-p-bromophenyl acetonitrile.

Further, oxime sulfonate-based acid generators disclosed in Japanese Unexamined Patent Application, First Publication No. Hei 9-208554 (Chemical Formulas 18 and 19 shown in paragraphs [0012] to [0014]) and oxime sulfonate-based acid generators disclosed in WO 2004/074242A2 (Examples 1 to 40 described at pages 65 to 86) may be preferably used.

Furthermore, as preferable examples, the following can be used.

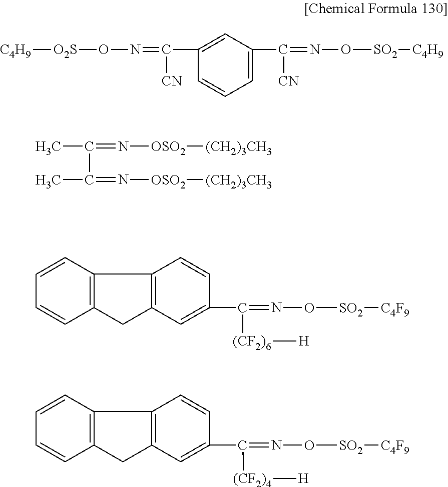

Of the aforementioned diazomethane-based acid generators, specific examples of suitable bisalkyl or bisaryl sulfonyl diazomethanes include bis(isopropylsulfonyl)diazomethane, bis(p-toluenesulfonyl)diazomethane, bis(1,1-dimethylethylsulfonyl)diazomethane, bis(cyclohexylsulfonyl)diazomethane, and bis(2,4-dimethylphenylsulfonyl)diazomethane.

Further, diazomethane-based acid generators disclosed in Japanese Unexamined Patent Application, First Publication No. Hei 11-035551, Japanese Unexamined Patent Application, First Publication No. Hei 11-035552 and Japanese Unexamined Patent Application, First Publication No. Hei 11-035573 may be preferably used.

Furthermore, as poly(bis-sulfonyl)diazomethanes, those disclosed in Japanese Unexamined Patent Application, First Publication No. Hei 11-322707, including 1,3-bis(phenylsulfonyldiazomethylsulfonyl)propane, 1,4-bis(phenylsulfonyldiazomethylsulfonyl)butane, 1,6-bis(phenylsulfonyldiazomethylsulfonyl)hexane, 1,10-bis(phenylsulfonyldiazomethylsulfonyl)decane, 1,2-bis(cyclohexylsulfonyldiazomethylsulfonyl)ethane, 1,3-bis(cyclohexylsulfonyldiazomethylsulfonyl)propane, 1,6-bis(cyclohexylsulfonyldiazomethylsulfonyl)hexane, and 1,10-bis(cyclohexylsulfonyldiazomethylsulfonyl)decane, may be mentioned.

As the component (B), one type of these acid generators may be used alone, or two or more types may be used in combination.

In the resist composition of the first aspect or third aspect of the present invention, the amount of the component (B) relative to 100 parts by weight of the component (A) is preferably 0 to 60 parts by weight, more preferably 0 to 40 parts by weight, and still more preferably 0 to 10 parts by weight. In the case where the amount of the component (B) is 40 parts by weight or less, when these components of the resist composition are dissolved in the organic solvent, a uniform solution can be obtained and the storage stability becomes satisfactory. In particular, when the amount of the component (B) is 10 parts by weight or less, a good balance between high sensitivity and suppression of reduction in lithography properties caused by OoB light can be achieved.

When the resist composition of the second aspect of the present invention contains the component (B), the amount of the component (B) relative to 100 parts by weight of the component (A) is preferably 0.5 to 60 parts by weight, more preferably 1 to 50 parts by weight, and still more preferably 1 to 40 parts by weight. When the amount of the component (B) is within the above-mentioned range, formation of a resist pattern can be satisfactorily performed. Further, when these components of the resist composition are dissolved in the organic solvent, a uniform solution can be obtained and the storage stability becomes satisfactory.

### <Other Optional Components>

The resist composition of the present invention may contain a basic compound (D) (hereafter referred to as the component (D)) as an optional component. In the present invention, the component (D) functions as an acid diffusion control agent, i.e., a quencher which traps the acid generated from the component (A) or the component (B) upon exposure. In the present invention, a “basic compound” refers to a compound which is basic relative to the component (A) or the component (B).

Provided that, in the third aspect of the present invention, the component (D) is a compound which does not fall under the definition of the component (C) (i.e., the component (D) is a component (D2) described later).

In the present invention, the component (D) may be a basic compound (D1) (hereafter, referred to as “component (D1)”) which has a cation moiety and an anion moiety, or a basic compound (D2) (hereafter, referred to as “component (D2)”) which does not fall under the definition of component (D1).

### [Component (D1)]

As the component (D1), the same examples as those described above for the component (C) can be mentioned.

### [Component (D2)]

The component (D2) is not particularly limited, as long as it is a compound which exhibits basicity relative to the component (A) or the component (B) and functions as an acid diffusion inhibitor, that is, a quencher which traps acid generated from the component (A) or the component (B) upon exposure, and which does not fall under the definition of the component (D1). As the component (D), any of the conventionally known compounds may be selected for use. Examples thereof include an aliphatic amine and an aromatic amine. Among these, an aliphatic amine is preferable, and a secondary aliphatic amine or tertiary aliphatic amine is particularly desirable.

An aliphatic amine is an amine having one or more aliphatic groups, and the aliphatic groups preferably have 1 to 12 carbon atoms.

Examples of these aliphatic amines include amines in which at least one hydrogen atom of ammonia (NH₃) has been substituted with an alkyl group or hydroxyalkyl group of no more than 20 carbon atoms (i.e., alkylamines or alkylalcoholamines), cyclic amines and other aliphatic amines.

The alkyl group in the alkylamine may be any of linear, branched or cyclic.

When the alkyl group is linear or branched, the number of carbon atoms thereof is preferably 2 to 20, and more preferably 2 to 8.

When the alkyl group is cyclic (i.e., a cycloalkyl group), the number of carbon atoms is preferably 3 to 30, more preferably 3 to 20, still more preferably 3 to 15, still more preferably 4 to 12, and most preferably 5 to 10. The alkyl group may be monocyclic or polycyclic. Examples thereof include groups in which one or more of the hydrogen atoms have been removed from a monocycloalkane; and groups in which one or more of the hydrogen atoms have been removed from a polycycloalkane such as a bicycloalkane, a tricycloalkane, or a tetracycloalkane. Specific examples of the monocycloalkane include cyclopentane and cyclohexane. Specific examples of the polycycloalkane include adamantane, norbornane, isobornane, tricyclodecane and tetracyclododecane.

As the alkyl group in the hydroxyalkyl group in the alkylalcoholamine, the same alkyl group as those in the aforementioned alkylamine can be mentioned.

Specific examples of the alkylamines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; and trialkylamines such as trimethylamine, triethylamine, tri-n-propylamine, tri-n-butylamine, tri-n-hexylamine, tri-n-pentylamine, tri-n-heptylamine, tri-n-octylamine, tri-n-nonylamine, tri-n-decanylamine, and tri-n-dodecylamine.

Specific examples of alkylalcoholamines include diethanolamine, triethanolamine, diisopropanolamine, triisopropanolamine, di-n-octanolamine, tri-n-octanolamine, stearyldiethanolamine and lauryldiethanolamine.

Among these, trialkylamines of 5 to 10 carbon atoms are preferable, and tri-n-pentylamine and tri-n-octylamine are particularly desirable.

Examples of the cyclic amine include heterocyclic compounds containing a nitrogen atom as a hetero atom. The heterocyclic compound may be a monocyclic compound (aliphatic monocyclic amine), or a polycyclic compound (aliphatic polycyclic amine) can be used.

Specific examples of the aliphatic monocyclic amine include piperidine, and piperazine.

The aliphatic polycyclic amine preferably has 6 to 10 carbon atoms, and specific examples thereof include 1,5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris {2-(1-methoxyethoxy)ethyl}amine, tris{2-(1-ethoxyethoxy)ethyl}amine, tris{2-(1-ethoxypropoxy)ethyl}amine, tris[2-{2-(2-hydroxyethoxy)ethoxy}ethyl]amine and triethanolamine triacetate.

Examples of aromatic amines include aniline, pyridine, 4-dimethylaminopyridine, pyrrole, indole, pyrazole, imidazole and derivatives thereof, diphenylamine, triphenylamine, tribenzylamine, 2,6-diisopropylaniline and N-tert-butoxycarbonylpyrrolidine.

As the component (D2), one type of may be used alone, or two or more types may be used in combination.

The component (D2) is typically used in an amount within a range from 0.01 to 5.0 parts by weight, relative to 100 parts by weight of the component (A). When the amount of the component (D) is within the above-mentioned range, the shape of the resist pattern and the post exposure stability of the latent image formed by the pattern-wise exposure of the resist layer are improved.

As the component (D), one type may be used, or two or more types may be used in combination.

When the resist composition of the first aspect of the present invention contains the component (D), the amount of the component (D) relative to 100 parts by weight of the component (A) is preferably within a range from 0.1 to 15 parts by weight, more preferably from 0.3 to 12 parts by weight, and still more preferably from 0.5 to 12 parts by weight. When the amount of the component (D) is at least as large as the lower limit of the above-mentioned range, various lithography properties such as roughness are improved. Further, a resist pattern having an excellent shape can be obtained. On the other hand, in the case where the amount of the component (D) is no more than the upper limit of the above-mentioned range, sensitivity can be maintained at a satisfactory level, and throughput becomes excellent.

When the resist composition of the second aspect of the present invention contains the component (D), the amount of the component (D) (total amount of the components (D1) and (D2)) relative to 100 parts by weight of the component (A) is preferably within a range from 0.1 to 15 parts by weight, more preferably from 0.3 to 12 parts by weight, and still more preferably from 0.5 to 12 parts by weight.

When the amount of the component (D) is at least as large as the lower limit of the above-mentioned range, various lithography properties such as roughness are improved. Further, a resist pattern having an excellent shape can be obtained. On the other hand, in the case where the amount of the component (D) is no more than the upper limit of the above-mentioned range, sensitivity can be maintained at a satisfactory level, and throughput becomes excellent.

When the resist composition of the third aspect of the present invention includes the component (D2), the component (D2) is used in an amount within a range from 0.01 to 5.0 parts by weight, relative to 100 parts by weight of the component (A). When the amount of the component (D) is within the above-mentioned range, the shape of the resist pattern and the post exposure stability of the latent image formed by the pattern-wise exposure of the resist layer are improved.

### [Component (E)]

Furthermore, in the resist composition of the present invention, for preventing any deterioration in sensitivity, and improving the resist pattern shape and the post exposure stability of the latent image formed by the pattern-wise exposure of the resist layer, at least one compound (E) (hereafter referred to as the component (E)) selected from the group consisting of an organic carboxylic acid, or a phosphorus oxo acid or derivative thereof can be added.

Examples of suitable organic carboxylic acids include acetic acid, malonic acid, citric acid, malic acid, succinic acid, benzoic acid, and salicylic acid.

Examples of phosphorus oxo acids include phosphoric acid, phosphonic acid and phosphinic acid. Among these, phosphonic acid is particularly desirable.

Examples of phosphorous oxo acid derivatives include esters in which a hydrogen atom within the above-mentioned phosphorous oxo acids is substituted with a hydrocarbon group. Examples of the hydrocarbon group include an alkyl group of 1 to 5 carbon atoms and an aryl group of 6 to 15 carbon atoms.

Examples of phosphoric acid derivatives include phosphoric acid esters such as di-n-butyl phosphate and diphenyl phosphate.

Examples of phosphonic acid derivatives include phosphonic acid esters such as dimethyl phosphonate, di-n-butyl phosphonate, phenyl phosphonate, diphenyl phosphonate and dibenzyl phosphonate.

Examples of phosphinic acid derivatives include phosphinic acid esters and phenylphosphinic acid.

As the component (E), one type may be used alone, or two or more types may be used in combination.

The component (E) is typically used in an amount within a range from 0.01 to 5.0 parts by weight, relative to 100 parts by weight of the component (A).

If desired, other miscible additives can also be added to the resist composition of the present invention. Examples of such miscible additives include additive resins for improving the performance of the resist film, surfactants for improving the applicability, dissolution inhibitors, plasticizers, stabilizers, colorants, halation prevention agents, and dyes.

The resist composition according to the present invention can be prepared by dissolving the materials for the resist composition in an organic solvent (hereafter, frequently referred to as “component (S)”).

The component (S) may be any organic solvent which can dissolve the respective components to give a uniform solution, and one or more kinds of any organic solvent can be appropriately selected from those which have been conventionally known as solvents for a chemically amplified resist.

Examples thereof include lactones such as γ-butyrolactone;

ketones such as acetone, methyl ethyl ketone, cyclohexanone, methyl-n-pentyl ketone, methyl isopentyl ketone, and 2-heptanone;

polyhydric alcohols, such as ethylene glycol, diethylene glycol, propylene glycol and dipropylene glycol;

compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkylether (e.g., monomethylether, monoethylether, monopropylether or monobutylether) or monophenylether of any of these polyhydric alcohols or compounds having an ester bond (among these, propylene glycol monomethyl ether acetate (PGMEA) and propylene glycol monomethyl ether (PGME) are preferable);

cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate;

and aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene and mesitylene.

These solvents can be used individually, or in combination as a mixed solvent.

Among these, propylene glycol monomethyl ether acetate (PGMEA), propylene glycol monomethyl ether (PGME) and ethyl lactate (EL) are preferable.

Further, among the mixed solvents, a mixed solvent obtained by mixing PGMEA with a polar solvent is preferable. The mixing ratio (weight ratio) of the mixed solvent can be appropriately determined, taking into consideration the compatibility of the PGMEA with the polar solvent, but is preferably in the range of 1:9 to 9:1, more preferably from 2:8 to 8:2. For example, when EL is mixed as the polar solvent, the PGMEA:EL weight ratio is preferably from 1:9 to 9:1, and more preferably from 2:8 to 8:2. Alternatively, when PGME is mixed as the polar solvent, the PGMEA:PGME is preferably from 1:9 to 9:1, more preferably from 2:8 to 8:2, and still more preferably 3:7 to 7:3. Alternatively, when PGME and cyclohexanone is mixed as the polar solvent, the PGMEA:(PGME+cyclohexanone) weight ratio is preferably from 1:9 to 9:1, more preferably from 2:8 to 8:2, and still more preferably 3:7 to 7:3.

Further, as the component (S), a mixed solvent of PGMEA, EL, or PGMEA with a polar solvent and a mixed solvent of PGMEA, EL, or PGMEA with γ-butyrolactone are also preferable. The mixing ratio (former:latter) of such a mixed solvent is preferably from 70:30 to 95:5.

The amount of the organic solvent is not particularly limited, and is appropriately adjusted to a concentration which enables coating of a coating solution to a substrate, depending on the thickness of the coating film. In general, the organic solvent is used in an amount such that the solid content of the resist composition becomes within the range from 1 to 20% by weight, and preferably from 2 to 15% by weight.

By using the resist composition according to the present invention, a resist pattern having excellent lithography properties such as resolution and exposure latitude when forming a resist pattern with EUV exposure or EB exposure, and having reduced roughness, excellent rectangularity of the cross-sectional shape (excellent verticality of the side wall of a pattern) and excellent pattern shape. The reason why these effects can be achieved is presumed as follows.

In the resist composition of the present invention, the component (A1) includes a structural unit (a0) that generates acid upon exposure. Therefore, acid is uniformly generated from the structural unit (a0) which is distributed uniformly in a resist film. At exposed portions, the acid decomposable group in the component (A1) is satisfactorily decomposed. As a result, the lithography properties such as resolution can be improved as compared to a resist composition containing a conventional acid generator instead of the structural unit (a0).

It is presumed that by including the structural unit (a0) having a cation moiety or an anion moiety which has no aromatic ring or one aromatic ring in total, the sensitivity of the cation moiety to the light having a wavelength within DUV region, in particular, to the light having a wavelength of 150 to 300 nm is reduced. As a result, the incidence of the light which has a wavelength within DUV region and is contained in OoB light generated from an EUV light source to unexposed portions, and the diffusion (scattering) of electrons at the surface of the resist film during exposure can be suppressed, and hence, defects (e.g., reduced optical contrast, generation of acid at unexposed portions and changed solubility in a development caused by the generated acid) can be also suppressed, thereby obtaining the aforementioned effects. Even though a cation moiety or an anion moiety has no aromatic ring or one aromatic ring in total, the sensitivity to the light having a wavelength within EUV region (light having a wavelength of about 13.5 nm) and the sensitivity to EB are not reduced. Therefore, at exposed portions, a satisfactory sensitivity can be achieved.

With respect to the resist composition according to the first aspect of the present invention, by virtue of the component (W), developing defects which generates after alkali development can be suppressed.

The term “defects” refers to general abnormalities within a resist film that are detected when the developed resist pattern is observed from directly above using by using a surface defect detection apparatus (product name: “KLA”) manufactured by KLA-TENCOR Corporation. Examples of these abnormalities include abnormalities caused by the adhesion of foreign particles and precipitates to the surface of resist pattern such as post-developing scum (resist residue), foam and dust, abnormalities in pattern shape such as bridges formed between line patterns, filled holes in the contact hole pattern, and abnormalities in color irregularities.

One of the factors related to the generation of defects is considered to be the hydrophobicity of the resist material. In the case where the resist film exhibits a high hydrophobicity, when conducting alkali development and then rinsing with water, in particular at unexposed portions of the resist film, precipitates is likely to adhere to the surface of resist pattern. In the resist composition according to the present invention, a base component having an acid generating ability is used, and a conventional acid generator consisting of a low molecular compound may be used as an optional component. Since the resist composition of the present invention contains a base component as a main component of the resist film, there is a tendency that the hydrophobicity of the resist film is enhanced, and hence, there is an important object to reduce defects for forming a fine pattern and for improving lithography properties. To solve the problem, the resist composition of the present invention contains a component (W) as an essential component which exhibits hydrophobicity at the surface of the resist film during exposure prior to development and exhibits hydrophilicity after alkali development. By virtue of the component (W), the resist film formed by using the resist composition of the present invention exhibits hydrophilicity during development. By the component (W) containing a fluorine atom or a silicon atom, the component (W) is likely to present in the vicinity of the surface of the resist film. Therefore, the surface of the resist film formed using a resist composition containing the component (W) which exhibits hydrophobicity prior to exposure, but exhibits hydrophilicity after exposure. When the surface of the resist film exhibits hydrophilicity after exposure, defects detected after development, in particular, defects caused by adhesion of scum or dust to the surface of the resist film (Blob) can be reduced.

With respect to the resist composition according to the second aspect of the present invention, by virtue of the structural unit (a0) containing a cation moiety or a cation moiety having a hydrophobicity, the polarity of entire resin component is decreased and the adhesion between the resist composition and the substrate is also decreased. As a result, resolution is likely to be decreased. However, with respect to the resist composition according to the present invention, by virtue of the structural unit (a5) containing a lactone group-containing group which has a lactone ring at the terminal of the long side chain, the effect of the lactone ring can be achieved, thereby improving the adhesion between the resist composition and the substrate.

By using a structural unit (a5) having a long side chain, Tg of the resist composition (resist film after formed by applying the resist composition) is appropriately reduced. Therefore, a difference between Tg of the resist composition and a baking temperature during forming a pattern can be reduced. As a result, lithography properties such as resolution and LWR can be improved.

With respect to the resist composition according to the third aspect of the present invention, it is presumed that by virtue of the structural unit (a0) in the resin component, the diffusion of acid can be suppressed, and by containing the component (C), the diffusion of acid to unexposed portions can be suppressed, and the aforementioned effect can be achieved.

In the case of irradiating light within DUV region, the decomposition of an acid generating portion is caused by absorption of light at a cation moiety. In the present invention, when the structural unit (a0) contains an acid generating portion in which a cation moiety has no aromatic ring or one aromatic ring, the aforementioned effect can be achieved regardless of the number of aromatic ring in the anion moiety.

### <<Method of Forming a Resist Pattern>>

The method of forming a resist pattern according to the fourth aspect of the present invention includes: using a resist composition according to the first aspect or third aspect of the present invention to form a resist film on a surface; conducting exposure of the resist film by EUV or EB; and developing the resist film to form a resist pattern.

The method of forming a resist pattern according to the fifth aspect of the present invention includes: using a resist composition according to the second aspect of the present invention to form a resist film on a surface; conducting exposure of the resist film; and developing the resist film to form a resist pattern.

The method for forming a resist pattern according to the present invention can be performed, for example, as follows.

Firstly, a resist composition of the first aspect, second aspect or third aspect of the present invention is applied to a substrate using a spinner or the like, and a bake treatment (post applied bake (PAB)) is conducted at a temperature of 80 to 150° C. for 40 to 120 seconds, preferably 60 to 90 seconds, to form a resist film.

Following selective exposure of the thus formed resist film, either by exposure through a mask having a predetermined pattern formed thereon (mask pattern) using an exposure apparatus such as an electron beam lithography apparatus or an EUV exposure apparatus, or by patterning via direct irradiation with an electron beam without using a mask pattern, baking treatment (post exposure baking (PEB)) is conducted under temperature conditions of 80 to 150° C. for 40 to 120 seconds, and preferably 60 to 90 seconds. In the fifth aspect, an ArF exposure apparatus can be also used as an exposure apparatus.

Next, the resist film is subjected to a developing treatment. In the case of an alkali developing process, an alkali developing solution such as a 0.1 to 10% by weight aqueous solution of tetramethylammonium hydroxide (TMAH) is used to perform an alkali developing treatment. In the case of a solvent developing process, an organic solvent or a developing solution containing an organic solvent (organic developing solution) is used to perform a developing treatment. As the organic solvent, any of the conventional organic solvents can be used which are capable of dissolving the component (A) (prior to exposure). Specific examples of the organic solvent include polar solvents such as ketone solvents, ester solvents, alcohol solvents, amide solvents and ether solvents, and hydrocarbon solvents. Among these, ester solvents are preferable. As an ester solvent, butyl acetate is preferable.

After the developing treatment, it is preferable to conduct a rinse treatment. In the case of an alkali developing process, it is preferable to conduct a water rinse using pure water. In the case of a solvent developing process, it is preferable to use a rinse liquid containing the aforementioned organic solvent.

In the case of a solvent developing process, after the developing treatment or the rinsing, the developing solution or the rinse liquid remaining on the pattern can be removed by a treatment using a supercritical fluid.

After the developing treatment or the rinse treatment, drying is conducted. If desired, bake treatment (post bake) can be conducted following the developing.

In this manner, a resist pattern can be obtained. The resist composition according to the present invention can be used satisfactorily when forming a positive-tone resist pattern in an alkali developing process.

The substrate is not specifically limited and a conventionally known substrate can be used. For example, substrates for electronic components, and such substrates having wiring patterns formed thereon can be used. Specific examples of the material of the substrate include metals such as silicon wafer, copper, chromium, iron and aluminum; and glass. Suitable materials for the wiring pattern include copper, aluminum, nickel, and gold.

Further, as the substrate, any one of the above-mentioned substrates provided with an inorganic and/or organic film on the surface thereof may be used. As the inorganic film, an inorganic antireflection film (inorganic BARC) can be used. As the organic film, an organic antireflection film (organic BARC) and an organic film such as a lower-layer organic film used in a multilayer resist method can be used.

Here, a “multilayer resist method” is method in which at least one layer of an organic film (lower-layer organic film) and at least one layer of a resist film (upper resist film) are provided on a substrate, and a resist pattern formed on the upper resist film is used as a mask to conduct patterning of the lower-layer organic film. This method is considered as being capable of forming a pattern with a high aspect ratio. More specifically, in the multilayer resist method, a desired thickness can be ensured by the lower-layer organic film, and as a result, the thickness of the resist film can be reduced, and an extremely fine pattern with a high aspect ratio can be formed.

The multilayer resist method is broadly classified into a method in which a double-layer structure consisting of an upper-layer resist film and a lower-layer organic film is formed (double-layer resist method), and a method in which a multilayer structure having at least three layers consisting of an upper-layer resist film, a lower-layer organic film and at least one intermediate layer (thin metal film or the like) provided between the upper-layer resist film and the lower-layer organic film (triple-layer resist method).

In the fifth aspect of the present invention, the wavelength to be used for exposure is not particularly limited and the exposure can be conducted using radiations such as ArF excimer laser, KrF excimer laser, F₂ excimer laser, extreme ultraviolet rays (EUV), vacuum ultraviolet rays (VUV), electron beam (EB), X-rays, and soft X-rays. The resist composition of the present invention is effective to KrF excimer laser, ArF excimer laser, EB and EUV.

The exposure of the resist film can be either a general exposure (dry exposure) conducted in air or an inert gas such as nitrogen, or immersion exposure (liquid immersion lithography).

In immersion lithography, the region between the resist film and the lens at the lowermost point of the exposure apparatus is pre-filled with a solvent (immersion medium) that has a larger refractive index than the refractive index of air, and the exposure (immersion exposure) is conducted in this state.

The immersion medium preferably exhibits a refractive index larger than the refractive index of air but smaller than the refractive index of the resist film to be exposed. The refractive index of the immersion medium is not particularly limited as long at it satisfies the above-mentioned requirements.

Examples of this immersion medium which exhibits a refractive index that is larger than the refractive index of air but smaller than the refractive index of the resist film include water, fluorine-based inert liquids, silicon-based solvents and hydrocarbon-based solvents.

Specific examples of the fluorine-based inert liquids include liquids containing a fluorine-based compound such as C₃HCl₂F₅, C₄F₉OCH₃, C₄F₉OC₂H₅ or C₅H₃F₇ as the main component, which have a boiling point within a range from 70 to 180° C. and preferably from 80 to 160° C. A fluorine-based inert liquid having a boiling point within the above-mentioned range is advantageous in that the removal of the immersion medium after the exposure can be conducted by a simple method.

As a fluorine-based inert liquid, a pertluoroalkyl compound in which all of the hydrogen atoms of the alkyl group are substituted with fluorine atoms is particularly desirable. Examples of these perfluoroalkyl compounds include perfluoroalkylether compounds and perfluoroalkylamine compounds.

compounds and perfluoroalkylamine compounds. Specifically, one example of a suitable perfluoroalkylether compound is perfluoro(2-butyl-tetrahydrofuran) (boiling point 102° C.), and an example of a suitable perfluoroalkylamine compound is perfluorotributylamine (boiling point 174° C.).

As the immersion medium, water is preferable in terms of cost, safety, environment and versatility.

As an example of the alkali developing solution used in an alkali developing process, a 0.1 to 10% by weight aqueous solution of tetramethylammonium hydroxide (TMAH) can be given.

As the organic solvent contained in the organic developing solution used in a solvent developing process, any of the conventional organic solvents which are capable of dissolving the component (A) (prior to exposure) can be used. Specific examples of the organic solvent include polar solvents such as ketone-based solvents, ester-based solvents, alcohol-based solvents, amide-based solvents and ether-based solvents, and hydrocarbon solvents.

If desired, the organic developing solution may have a conventional additive blended. Examples of the additive include surfactants. The surfactant is not particularly limited, and for example, an ionic or non-ionic fluorine surfactant and/or silicon surfactant can be used.

When a surfactant is added, the amount thereof based on the total amount of the organic developing solution is generally 0.001 to 5% by weight, preferably 0.005 to 2% by weight, and more preferably 0.01 to 0.5% by weight.

The developing treatment can be performed by a conventional developing method. Examples thereof include a method in which the substrate is immersed in the developing solution for a predetermined time (a dip method), a method in which the developing solution is cast up on the surface of the substrate by surface tension and maintained for a predetermined period (a puddle method), a method in which the developing solution is sprayed onto the surface of the substrate (spray method), and a method in which the developing solution is continuously ejected from a developing solution ejecting nozzle while scanning at a constant rate to apply the developing solution to the substrate while rotating the substrate at a constant rate (dynamic dispense method).

As the organic solvent contained in the rinse liquid used in the rinse treatment after the developing treatment in the case of a solvent developing process, any of the aforementioned organic solvents contained in the organic developing solution can be used which hardly dissolves the resist pattern. In general, at least one solvent selected from the group consisting of hydrocarbon solvents, ketone-based solvents, ester-based solvents, alcohol-based solvents, amide-based solvents and ether-based solvents is used. Among these, at least one solvent selected from the group consisting of hydrocarbon-based solvents, ketone-based solvents, ester-based solvents, alcohol-based solvents and amide-based solvents is preferable, more preferably at least one solvent selected from the group consisting of alcohol-based solvents and ester-based solvents, and an alcohol-based solvent is particularly desirable.

The rinse treatment (washing treatment) using the rinse liquid can be performed by a conventional rinse method. Examples thereof include a method in which the rinse liquid is continuously applied to the substrate while rotating it at a constant rate (rotational coating method), a method in which the substrate is immersed in the rinse liquid for a predetermined time (dip method), and a method in which the rinse liquid is sprayed onto the surface of the substrate (spray method).

### EXAMPLES

As follows is a description of examples of the present invention, although the scope of the present invention is by no way limited by these examples.

### Polymer Synthesis Examples 1A to 20A

### Synthesis of Polymeric Compounds 1A to 20A

Polymeric compounds 1A to 20A were produced by a normal method using monomers (1A) to (29A) corresponding to structural units constituting each polymeric compound. The polymeric compounds including structural units derived from monomers (4A) to (6A), (8A) to (14A), (19A) and (23A) were produced by porimerization using monomers (4A) to (6A), (8A) to (14A), (19A) and (23A) having a triphenylsulfonium as a countercation, and then conducting salt-exchange reaction by a normal method to replace the triphenylsulfonium with the predetermined countercation. The synthesis example of a precursor of the monomer (8A) used in the salt-exchange reaction will be described later.

Further, with respect to the obtained polymeric compounds, the compositional ratio (the molar ratio of the respective structural units indicated in the structural formula shown below) as determined by carbon 13 nuclear magnetic resonance spectroscopy (600 MHz, ¹³C-NMR), and the weight average molecular weight (Mw) and the molecular weight distribution (Mw/Mn) determined by the polystyrene equivalent value as measured by GPC are shown in Tables 1 and 2.

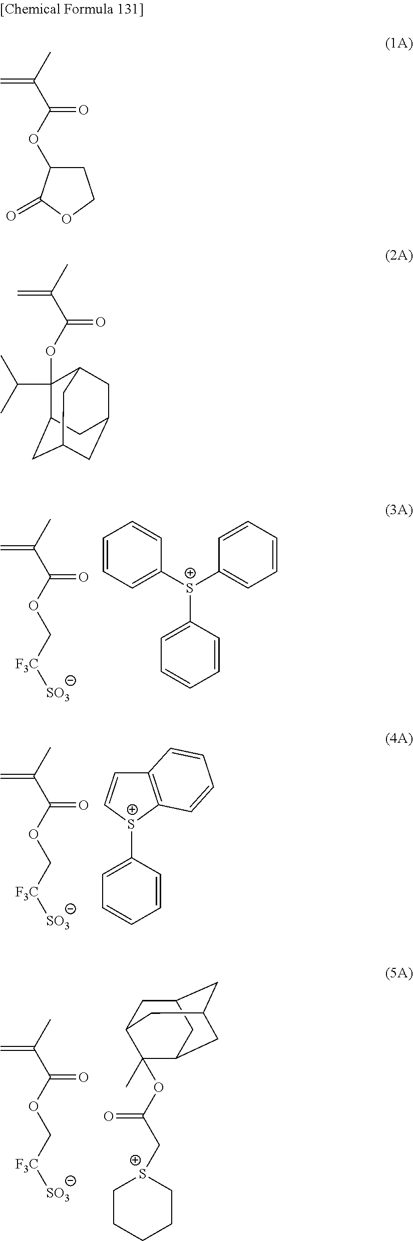

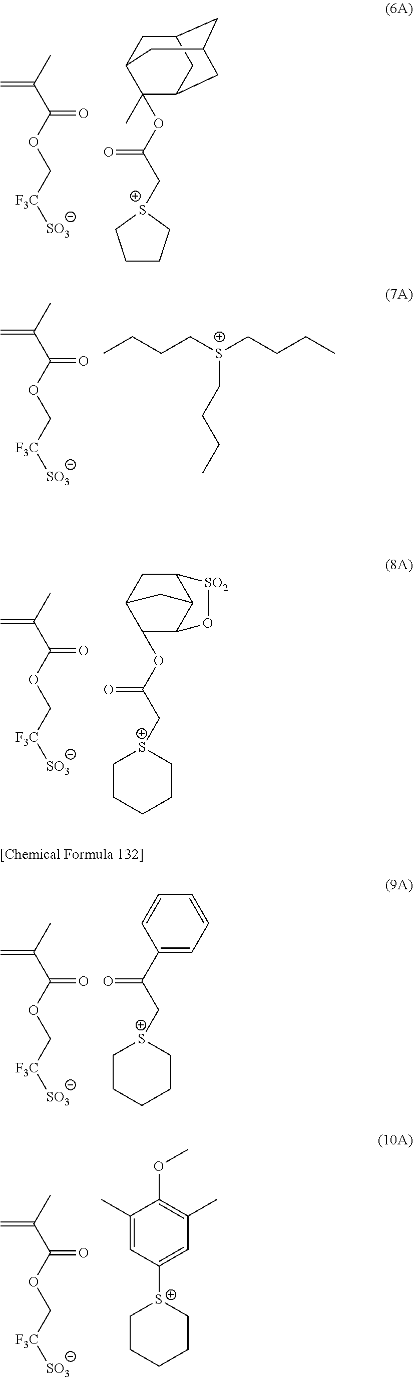

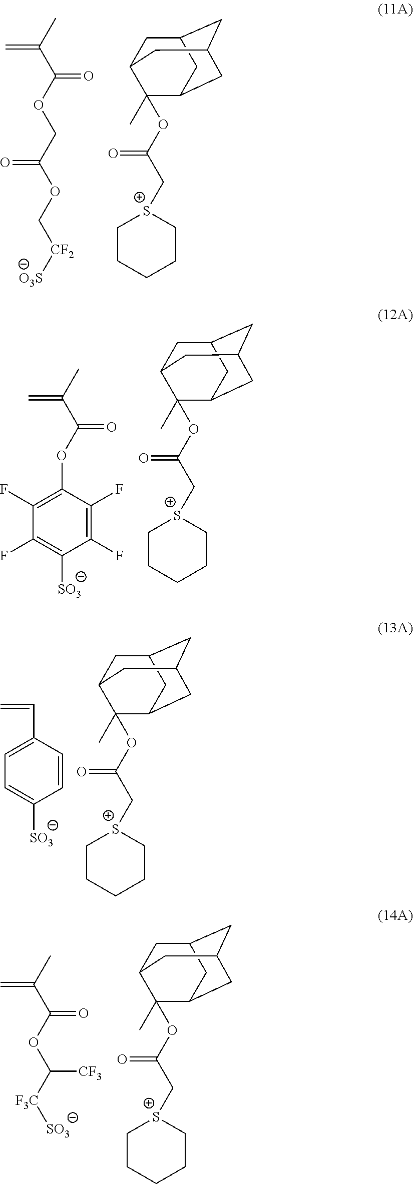

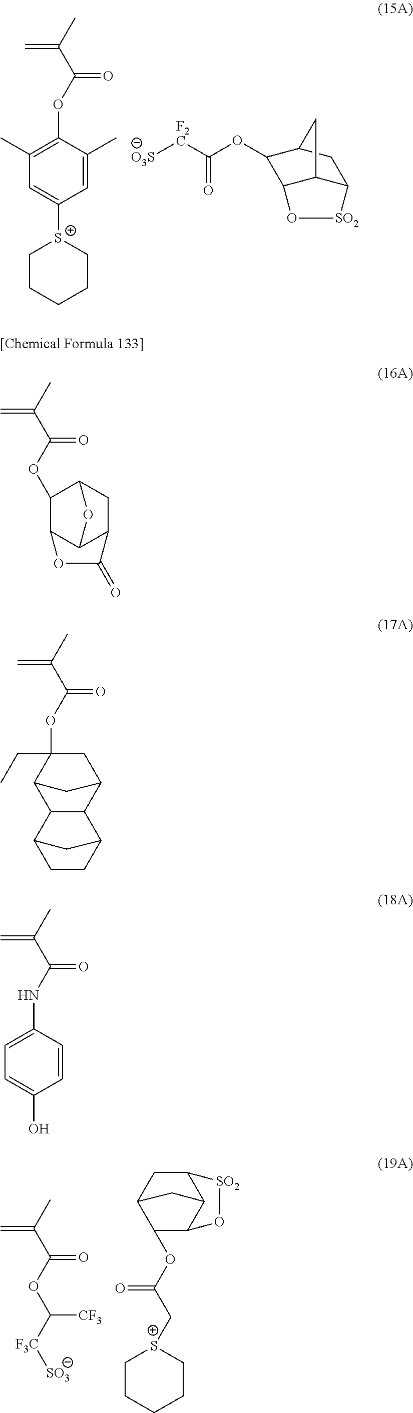

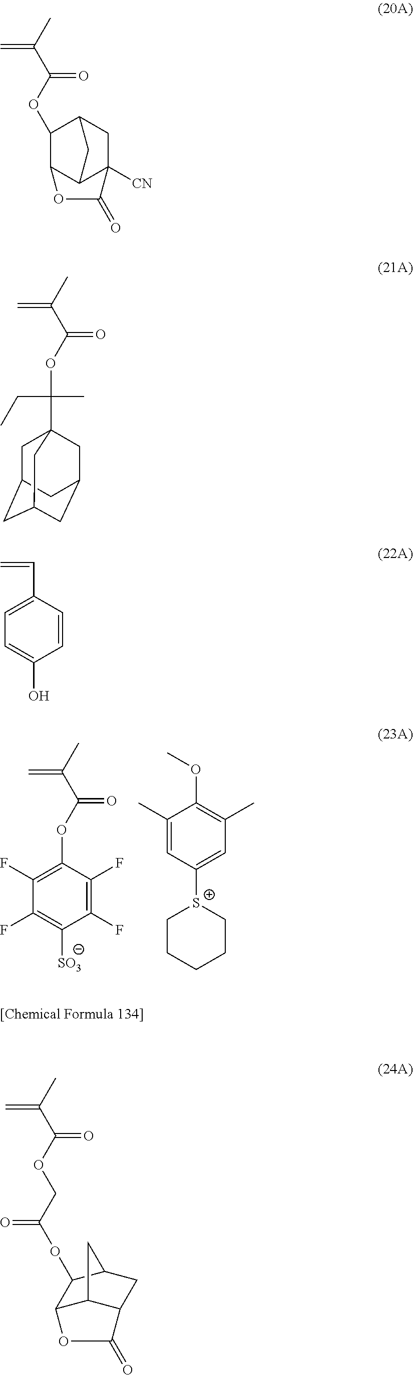

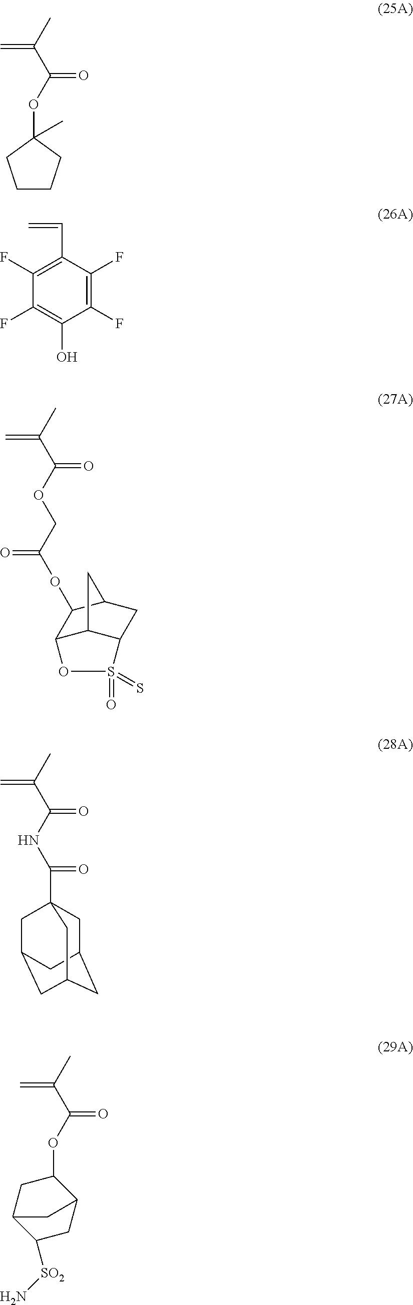

### Synthesis Example

Under a nitrogen atmosphere, 4.3 g of the compound A was dissolved in 21.6 g of acetonitrile, and 2.0 g of heptahydrothiophene was added thereto in a dropwise manner, followed by stirring at 25° C. for 12 hours. Thereafter, the precipitated-white powder was separated by suction filtration, followed by washing with 11.3 g of acetonitrile, and then drying under reduced pressure, thereby obtaining 2.9 g of a precursor of the monomer 8A.

The obtained compound was analyzed by NMR, and the structure thereof was identified by the following results.

¹H-NMR (400 MHz, DMSO-d₆+D₂O): δ(ppm)=5.1 (t, 2H, CH), 4.6 (t, 2H, CH), 4.3 (s, 1H, CH2), 3.9 (m, 3H, CH), 3.6-3.8 (t, 2H, SCH2), 3.4 (t, 2H, CH₂), 2.9 (m, 5H, CH), 2.4 (4H, CH), 2.0 (t, 2H, CH₂), 1.7-1.9 (m, 3H, CH₂CH₂), 1.2-1.4 (m, 4H, CH₂CH₂CH₂)

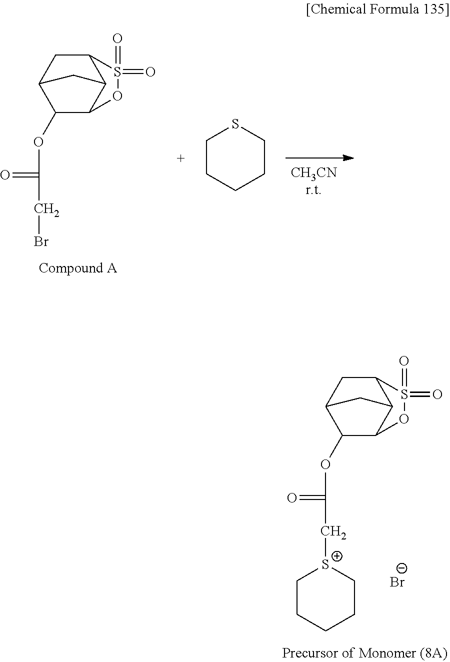 [SMILES: O=C(CBr)OC1C2CC3C1OS(=O)(=O)C3C2 ; C1CCSCC1 ; O=C(C[S+]1CCCCC1)OC1C2CC3C1OS(=O)(=O)C3C2 ; [Br-]]

TABLE 1

| | | Polymeric compound | | | | | | | | | |
|---|---|---|---|---|---|---|---|---|---|---|---|
| | | 1A | 2A | 3A | 4A | 5A | 6A | 7A | 8A | 9A | 10A |
| Monomer | (1A) | 45 | 45 | 45 | 45 | 44 | 45 | 45 | 45 | 44 | 45 |
| | (2A) | 41 | 41 | 41 | 41 | 42 | 41 | 41 | 41 | 42 | 42 |
| | (3A) | 14 | | | | | | | | | |
| | (4A) | | 14 | | | | | | | | |
| | (5A) | | | 14 | | | | | | | |
| | (6A) | | | | 14 | | | | | | |
| | (7A) | | | | | 14 | | | | | |
| | (8A) | | | | | | 14 | | | | |
| | (9A) | | | | | | | 14 | | | |
| | (10A) | | | | | | | | 14 | | |
| | (11A) | | | | | | | | | 14 | |
| | (12A) | | | | | | | | | | 13 |
| | (13A) | | | | | | | | | | |
| | (14A) | | | | | | | | | | |
| | (15A) | | | | | | | | | | |
| | (16A) | | | | | | | | | | |
| | (17A) | | | | | | | | | | |
| | (18A) | | | | | | | | | | |
| | (19A) | | | | | | | | | | |
| | (20A) | | | | | | | | | | |
| | (21A) | | | | | | | | | | |
| | (22A) | | | | | | | | | | |
| | (23A) | | | | | | | | | | |
| | (24A) | | | | | | | | | | |
| | (25A) | | | | | | | | | | |
| | (26A) | | | | | | | | | | |
| | (27A) | | | | | | | | | | |
| | (28A) | | | | | | | | | | |
| | (29A) | | | | | | | | | | |

| | | | | | | | | | | |
|---|---|---|---|---|---|---|---|---|---|---|
| Mw | 13100 | 13000 | 12900 | 12900 | 12100 | 13400 | 1290 | 13000 | 12100 | 11900 |
| Mw/Mn | 1.70 | 1.68 | 1.68 | 1.69 | 1.80 | 1.65 | 1.67 | 1.70 | 1.60 | 1.80 |

TABLE 2

| | | Polymeric compound | | | | | | | | | |
|---|---|---|---|---|---|---|---|---|---|---|---|
| | | 11A | 12A | 13A | 14A | 15A | 16A | 17A | 18A | 19A | 20A |
| Monomer | (1A) | 45 | 45 | 44 | | | 11 | | | 14 | |
| | (2A) | 42 | 42 | 42 | | | | 40 | | | 34 |
| | (3A) | | | | | | | | | | |
| | (4A) | | | | | | | | | | |
| | (5A) | | | | | | | 14 | 10 | | |
| | (6A) | | | | | | | | | | |
| | (7A) | | | | | | | | | | |
| | (8A) | | | | | | | | | 13 | |
| | (9A) | | | | | | 14 | | | | |
| | (10A) | | | | | | | | | | |
| | (11A) | | | | | | | | | | 14 |
| | (12A) | | | | | | | | | | |
| | (13A) | 13 | | | | | | | | | |
| | (14A) | | 13 | | | | | | | | |
| | (15A) | | | 14 | | | | | | | |
| | (16A) | | | | 30 | | | | 30 | | |
| | (17A) | | | | 30 | | | | 30 | | |
| | (18A) | | | | 30 | | | | 30 | | |
| | (19A) | | | | 10 | | | | | | |
| | (20A) | | | | | 30 | | | | | |
| | (21A) | | | | | 30 | | | | | |
| | (22A) | | | | | 30 | | | | | |
| | (23A) | | | | | 10 | | | | | |
| | (24A) | | | | | | 25 | | | | |
| | (25A) | | | | | | 35 | | | 35 | |
| | (26A) | | | | | | 15 | | | | |
| | (27A) | | | | | | | 46 | | 26 | 34 |
| | (28A) | | | | | | | | | 12 | |
| | (29A) | | | | | | | | | | 18 |

| | | | | | | | | | | |
|---|---|---|---|---|---|---|---|---|---|---|
| Mw | 11900 | 11900 | 12500 | 10700 | 10700 | 12500 | 12600 | 10400 | 12000 | 13000 |
| Mw/Mn | 1.80 | 1.80 | 1.72 | 1.60 | 1.60 | 1.75 | 1.67 | 1.60 | 1.61 | 1.77 |

### Examples 1A to 24A and Comparative Examples 1A to 3A

The components shown in Tables 3 and 4 were mixed together and dissolved to obtain resist compositions.

TABLE 3

| | Component | Component | Component | Component | Component | |
|---|---|---|---|---|---|---|
| | (A) | (W) | (D) | (E) | (S) | |
| Comparative | (A)-1A | (W)-1 | (D)-1A | | (S)-1A | (S)-2A |
| Example 1A | [100] | [10] | [2.1] | | [100] | [5000] |
| Comparative | (A)-2A | (W)-1 | (D)-1A | | (S)-1A | (S)-2A |
| Example 2A | [100] | [10] | [2.1] | | [100] | [5000] |
| Comparative | (A)-3A | | (D)-1A | | (S)-1A | (S)-2A |
| Example 3A | [100] | | [2.1] | | [100] | [5000] |
| Example 1A | (A)-3A | (W)-1 | (D)-1A | | (S)-1A | (S)-2A |
| | [100] | [10] | [2.1] | | [100] | [5000] |
| Example 2A | (A)-4A | (W)-1 | (D)-1A | | (S)-1A | (S)-2A |
| | [100] | [10] | [2.1] | | [100] | [5000] |
| Example 3A | (A)-5A | (W)-1 | (D)-1A | | (S)-1A | (S)-2A |
| | [100] | [10] | [2.1] | | [100] | [5000] |
| Example 4A | (A)-6A | (W)-1 | (D)-1A | | (S)-1A | (S)-2A |
| | [100] | [10] | [2.1] | | [100] | [5000] |
| Example 5A | (A)-7A | (W)-1 | (D)-1A | | (S)-1A | (S)-2A |
| | [100] | [10] | [2.1] | | [100] | [5000] |
| Example 6A | (A)-8A | (W)-1 | (D)-1A | | (S)-1A | (S)-2A |
| | [100] | [10] | [2.1] | | [100] | [5000] |
| Example 7A | (A)-9A | (W)-1 | (D)-1A | | (S)-1A | (S)-2A |
| | [100] | [10] | [2.1] | | [100] | [5000] |
| Example 8A | (A)-10A | (W)-1 | (D)-1A | | (S)-1A | (S)-2A |
| | [100] | [10] | [2.1] | | [100] | [5000] |
| Example 9A | (A)-11A | (W)-1 | (D)-1A | | (S)-1A | (S)-2A |
| | [100] | [10] | [2.1] | | [100] | [5000] |
| Example 10A | (A)-12A | (W)-1 | (D)-1A | | (S)-1A | (S)-2A |
| | [100] | [10] | [2.1] | | [100] | [5000] |

TABLE 4

| | Component | Component | Component | Component | Component | |
|---|---|---|---|---|---|---|
| | (A) | (W) | (D) | (E) | (S) | |
| Example 11A | (A)-13A | (W)-1 | (D)-1A | | (S)-1A | (S)-2A |
| | [100] | [10] | [2.1] | | [100] | [5000] |
| Example 12A | (A)-14A | (W)-1 | (D)-2A | (E)-1A | (S)-1A | (S)-2A |
| | [100] | [10] | [1.6] | [0.64] | [100] | [5000] |
| Example 13A | (A)-15A | (W)-1 | (D)-3A | | (S)-1A | (S)-2A |
| | [100] | [10] | [2.0] | | [100] | [5000] |
| Example 14A | (A)-16A | (W)-1 | (D)-3A | | (S)-1A | (S)-2A |
| | [100] | [10] | [2.0] | | [100] | [5000] |
| Example 15A | (A)-17A | (W)-1 | (D)-1A | | (S)-1A | (S)-2A |
| | [100] | [10] | [2.1] | | [100] | [5000] |
| Example 18A | (A)-18A | (W)-1 | (D)-1A | | (S)-1A | (S)-2A |
| | [100] | [10] | [2.2] | | [100] | [5000] |
| Example 17A | (A)-19A | (W)-1 | (D)-1A | | (S)-1A | (S)-2A |
| | [100] | [10] | [2.1] | | [100] | [5000] |
| Example 18A | (A)-20A | (W)-1 | (D)-1A | | (S)-1A | (S)-2A |
| | [100] | [10] | [2.1] | | [100] | [5000] |
| Example 19A | (A)-3A | (W)-2 | (D)-1A | | (S)-1A | (S)-2A |
| | [100] | [10] | [2.1] | | [100] | [5000] |
| Example 20A | (A)-3A | (W)-3 | (D)-1A | | (S)-1A | (S)-2A |
| | [100] | [10] | [2.1] | | [100] | [5000] |
| Example 21A | (A)-3A | (W)-4 | (D)-1A | | (S)-1A | (S)-2A |
| | [100] | [10] | [2.1] | | [100] | [5000] |
| Example 22A | (A)-3A | (W)-5 | (D)-1A | | (S)-1A | (S)-2A |
| | [100] | [10] | [2.1] | | [100] | [5000] |
| Example 23A | (A)-3A | (W)-6 | (D)-1A | | (S)-1A | (S)-2A |
| | [100] | [10] | [2.1] | | [100] | [5000] |
| Example 24A | (A)-3A | (W)-7 | (D)-1A | | (S)-1A | (S)-2A |
| | [100] | [10] | [2.1] | | [100] | [5000] |

In Tables 3 and 4, the reference characters indicate the following. Further, the values in brackets [ ] indicate the amount (in terms of parts by weight) of the component added. The component (W) was synthesized by a normal method.

(A)-1A to (A)-20A: the aforementioned polymeric compounds (1A) to (20A)

(W)-1: a copolymer represented by formula (W)-1 shown below [Mw=14,000, Mw/Mn=1.70, l/m=70/30 (molar ratio)]

(W)-2: a copolymer represented by formula (W)-2 shown below [Mw=20,000, Mw/Mn=1.93, l/m=80/20 (molar ratio)]

(W)-3: a copolymer represented by formula (W)-3 shown below [Mw=24,000, Mw/Mn=1.83, l/m=77/23 (molar ratio)]

(W)-4: a copolymer represented by formula (W)-4 shown below [Mw=19,200, Mw/Mn=1.83, l/m/n=25/20/55 (molar ratio)]

(W)-5: a copolymer represented by formula (W)-5 shown below [Mw=15,600, Mw/Mn=1.86, l/m/n=60/17/23 (molar ratio)]

(W)-6: a copolymer represented by formula (W)-6 shown below [Mw=24,800, Mw/Mn=2.30, l/m=65/35 (molar ratio)]

(W)-7: a copolymer represented by formula (W)-7 shown below [Mw=17,700, Mw/Mn=1.90, l/m=55/45 (molar ratio)]

(D)-1A: a compound represented by formula (D)-1A shown below

(D)-2A: tri-n-octylamine.

(D)-3A: a compound represented by formula (D)-3A shown below

(D)-4A: a compound represented by formula (D)-4A shown below

(E)-1A: salicylic acid

(S)-1A: γ-butyrolactone

(S)-2A: a mixed solvent of PGMEA/PGME/cyclohexanone=15/10/25 (weight ratio)

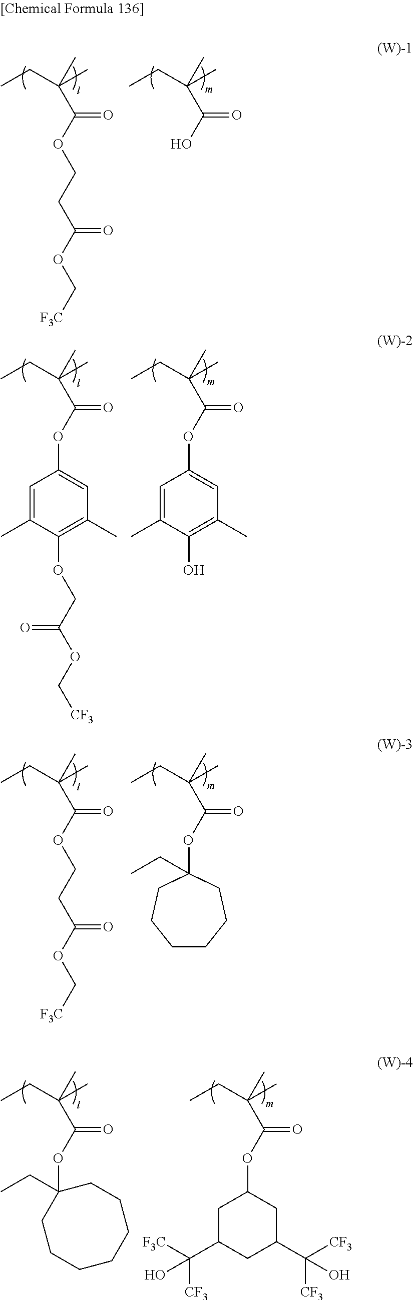

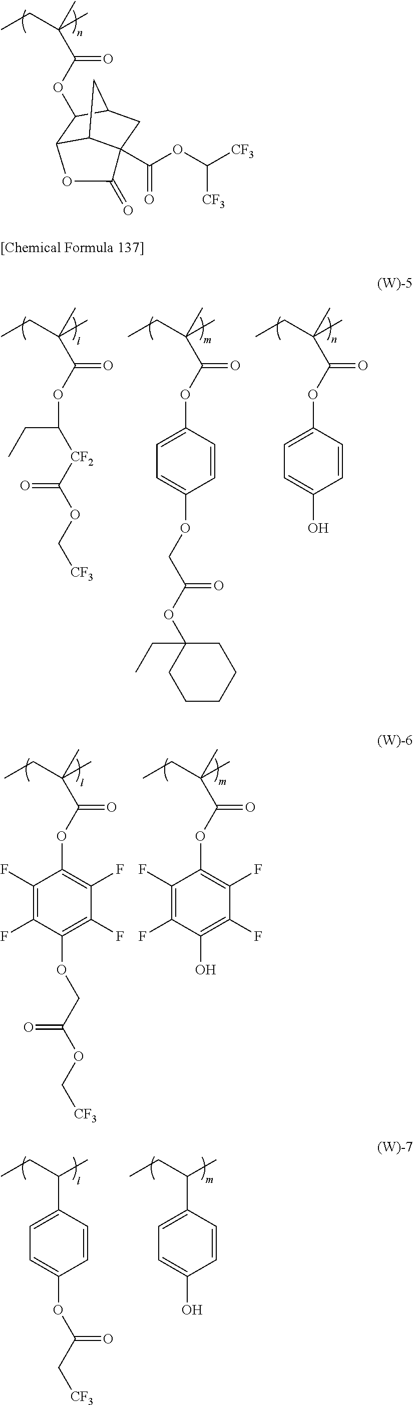

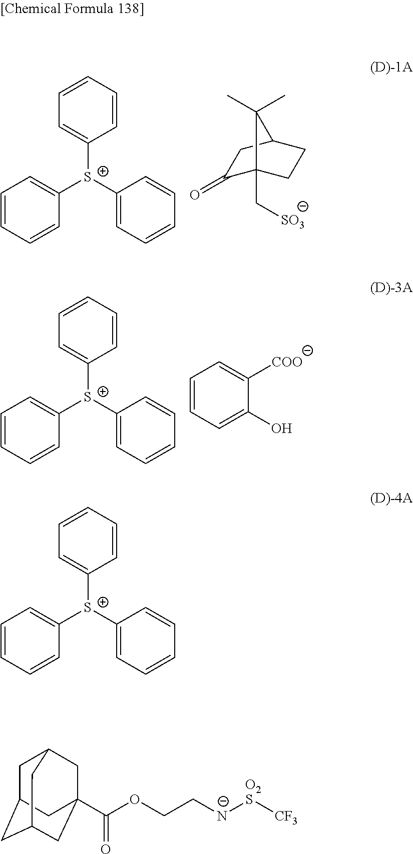

Using the obtained resist compositions, the following evaluations were conducted.

### [Formation of Resist Pattern 1]

Using a spinner, each resist composition was uniformity applied to an 8-inch silicon wafer that had been treated with hexamethyldisilazane (HMDS) at 90° C. for 36 seconds, and the solution was then subjected to a bake treatment (PAB) at a temperature indicated in Tables 5 and 6 for 60 seconds, thereby forming a resist film (film thickness: 60 nm). Subsequently, the resist film was subjected to drawing (exposure) with an accelerating voltage of 50 kV using an electron beam lithography apparatus HL-800D (VSB) (manufactured by Hitachi, Ltd.), followed by a bake treatment (PEB) for 60 seconds at a temperature indicated in Tables 5 and 6. Then, development was conducted with a 2.38 wt % aqueous TMAH solution (product name: NMD-3; manufactured by Tokyo Ohka Kogyo Co., Ltd.) at 23° C. for 60 seconds.

As a result, in each of the examples, a line and space pattern (hereafter, referred to as “LS pattern”) having a line width of 100 nm and a pitch of 200 nm was formed.

The optimum exposure dose Eop (μC/cm²) with which the LS pattern was formed was determined. The results are shown in Tables 5 and 6.

It was thought that the higher accelerate voltage was effective in formation of fine pattern. However, in this evaluation, in order to simulate the exposure condition in which OoB light was generated, a relatively-low accelerate voltage of 50 kV was used.

### [Evaluation of Resolution 1]

The critical resolution (nm) with the above Eop was determined using a scanning electron microscope (product name: S-9380, manufactured by Hitachi High-Technologies Corporation). The results are indicated as “resolution” in Tables 5 and 6.

### [Evaluation of Line Edge Roughness (LER) 1]

With respect to the LS pattern having a line width of 100 nm and a pitch of 200 nm formed in the aforementioned [Formation of resist pattern 1], 3σ was determined as a yardstick of LWR. The “3σ” refers to a value of 3 times the standard deviation (σ) (unit: nm) which is calculated from a result in which the line width at 400 points in the lengthwise direction of the line were measured using a scanning electron microscope (SEM) (product name: S-9220, manufactured by Hitachi High-Technologies Corporation; acceleration voltage: 800V). The smaller this 3s value is, the lower the level of roughness of the side walls of a line pattern, indicating that a LS pattern with a uniform width was obtained. The results are shown in Tables 5 and 6.

### [Evaluation of Exposure Latitude (10% EL) 1]

With respect to the aforementioned [Formation of resist pattern 1], the exposure dose with which an LS pattern having a dimension of the target dimension (line width: 100 nm)±10% (i.e., 90 nm to 110 nm) was determined, and the EL margin (unit: %) was determined by the following formula. The larger the value of the EL, the smaller the change in the pattern size by the variation of the exposure dose. The results are indicated “10% EL” in Tables 5 and 6.

EL margin (%)=(|E1−E2|/Eop)×100

In the formula, E1 represents the exposure dose (μC/cm²) for forming a LS pattern having a line width of 90 nm, and E2 represents the exposure dose (μC/cm²) for forming a LS pattern having a line width of 110 nm.

TABLE 5

| | PAB/PEB | Eop | LWR | 10% EL | Resolution |
|---|---|---|---|---|---|
| | [° C.] | [μC/cm²] | [nm] | [%] | [nm] |
| Comparative | 130/105 | 68 | 10.5 | 16.0 | 60 |
| Example 1A | | | | | |
| Comparative | 130/105 | 66 | 11.5 | 14.8 | 70 |
| Example 2A | | | | | |
| Comparative | 130/105 | 52 | 9.8 | 16.8 | 50 |
| Example 3A | | | | | |
| Example 1A | 130/105 | 50 | 6.0 | 24.8 | 50 |
| Example 2A | 130/105 | 46 | 6.6 | 21.0 | 50 |
| Example 3A | 130/105 | 48 | 7.6 | 20.0 | 50 |
| Example 4A | 130/105 | 52 | 5.0 | 6.4 | 50 |
| Example 5A | 130/105 | 52 | 70 | 24.2 | 50 |
| Example 6A | 130/105 | 46 | 7.5 | 24.0 | 50 |
| Example 7A | 120/95 | 38 | 6.0 | 23.8 | 50 |
| Example 8A | 130/105 | 56 | 7.6 | 20.0 | 50 |
| Example 9A | 130/105 | 60 | 7.3 | 19.8 | 50 |
| Example 10A | 130/105 | 44 | 6.4 | 22.0 | 50 |

TABLE 6

| | PAB/PEB | Eop | LWR | 10% EL | Resolution |
|---|---|---|---|---|---|
| | [° C.] | [μC/cm²] | [nm] | [%] | [nm] |
| Example 11A | 120/95 | 40 | 7.2 | 20.1 | 50 |
| Example 12A | 120/95 | 50 | 6.5 | 23.8 | 50 |
| Example 13A | 130/105 | 48 | 6.0 | 22.2 | 50 |
| Example 14A | 130/105 | 48 | 5.8 | 24.5 | 50 |
| Example 15A | 130/105 | 50 | 5.6 | 25.6 | 50 |
| Example 16A | 120/95 | 50 | 6.6 | 23.4 | 50 |
| Example 17A | 130/105 | 45 | 5.8 | 24.2 | 50 |
| Example 18A | 120/95 | 50 | 6.2 | 25.2 | 50 |
| Example 19A | 130/105 | 50 | 5.6 | 24.8 | 50 |
| Example 20A | 130/105 | 50 | 5.8 | 25.0 | 50 |
| Example 21A | 130/105 | 50 | 6.5 | 22.1 | 50 |
| Example 22A | 130/105 | 50 | 5.9 | 24.5 | 50 |
| Example 23A | 130/105 | 50 | 6.4 | 24.4 | 50 |
| Example 24A | 130/105 | 50 | 8.0 | 23.8 | 50 |

From the results shown above, it was confirmed that the resist compositions of Examples 1A to 24A exhibited excellent sensitivity to EB, and excellent resolution and excellent lithography properties such as exposure latitude and roughness, as compared to the resist compositions of Comparative Examples 1A to 3A.

### Polymer Synthesis Example 2

Polymeric compounds 1B to 22B were produced by a normal method using monomers (1B) to (34B) corresponding to the structural units constituting each polymeric compound.

Further, with respect to the obtained polymeric compounds, the compositional ratio (the molar ratio of the respective structural units indicated in the structural formula shown below) as determined by carbon 13 nuclear magnetic resonance spectroscopy (600 MHz, ¹³C-NMR, internal standard: tetramethylsilane (TMS)), and the weight average molecular weight (Mw) and the molecular weight distribution (Mw/Mn) determined by the polystyrene equivalent value as measured by GPC are shown in Tables 7 to 9.

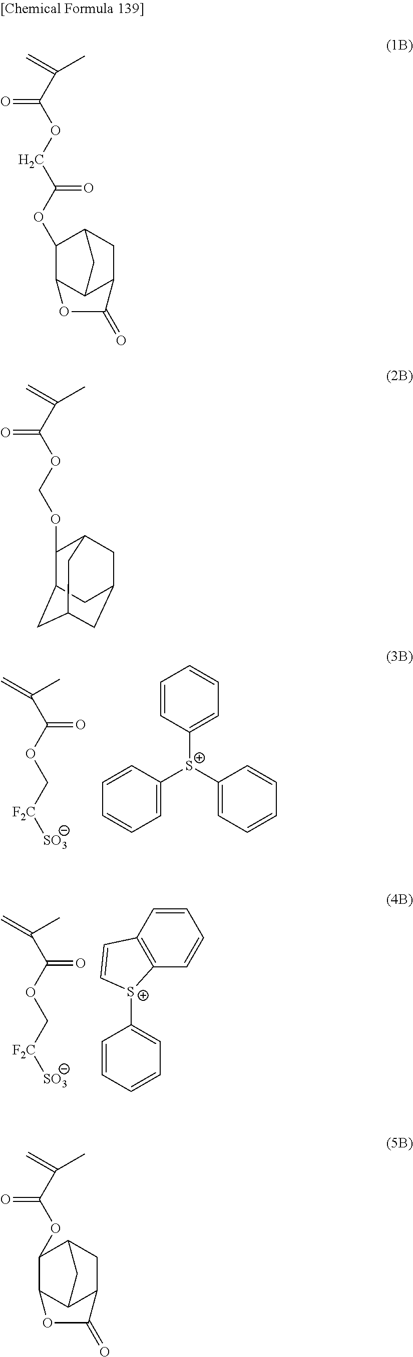

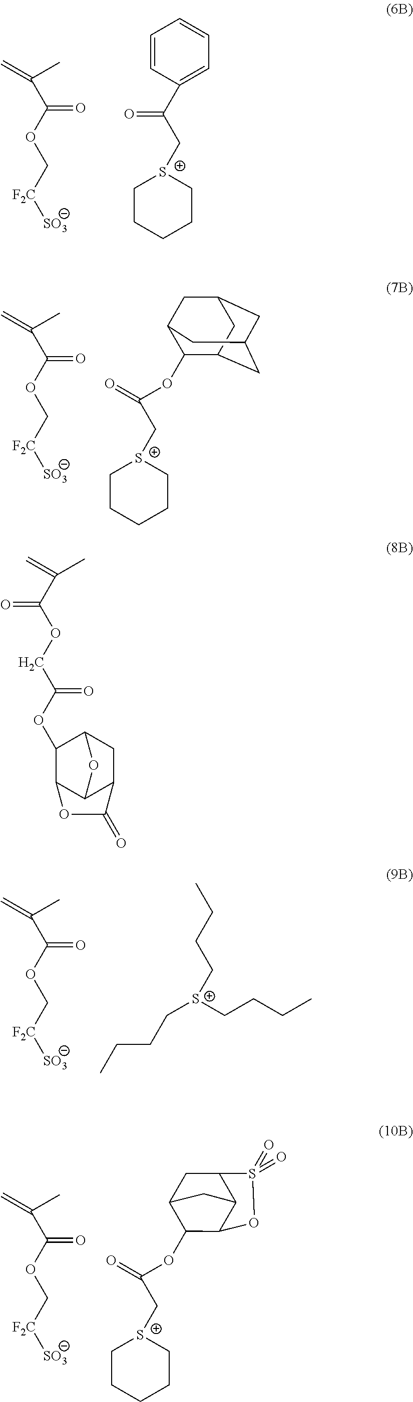

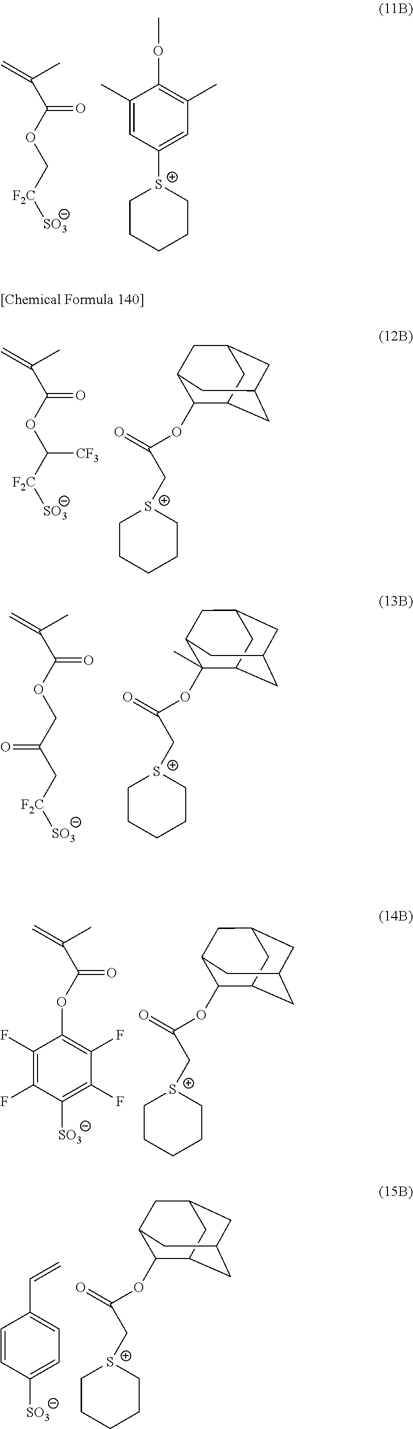

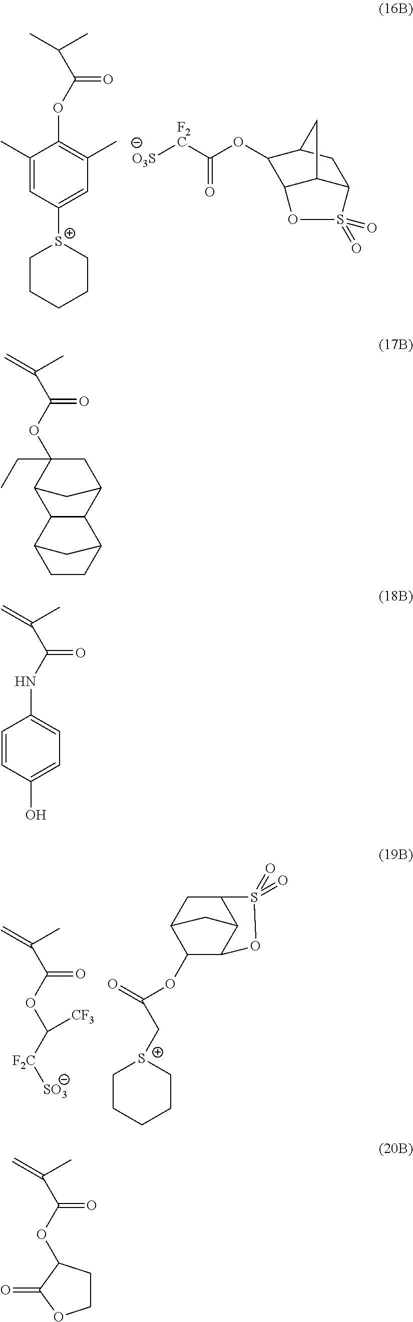

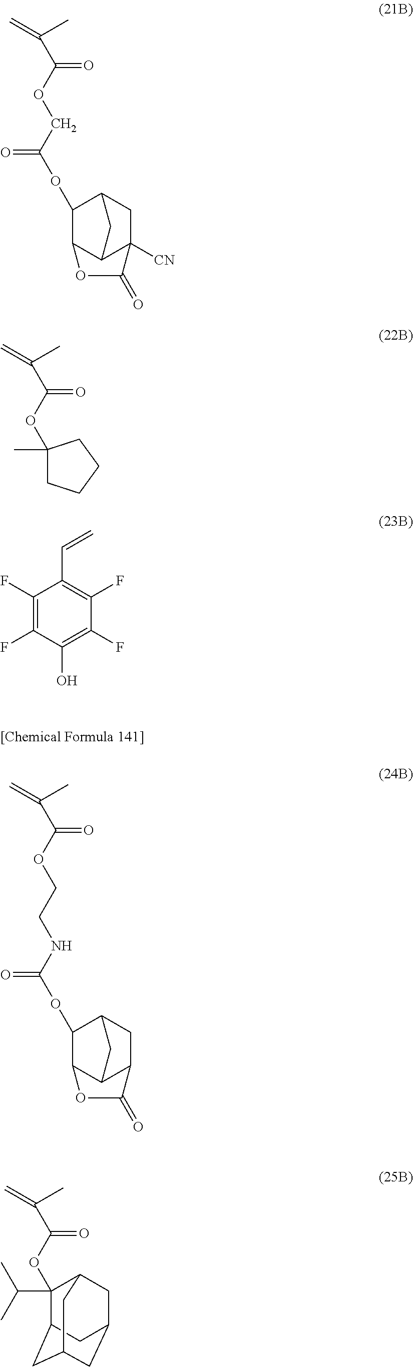

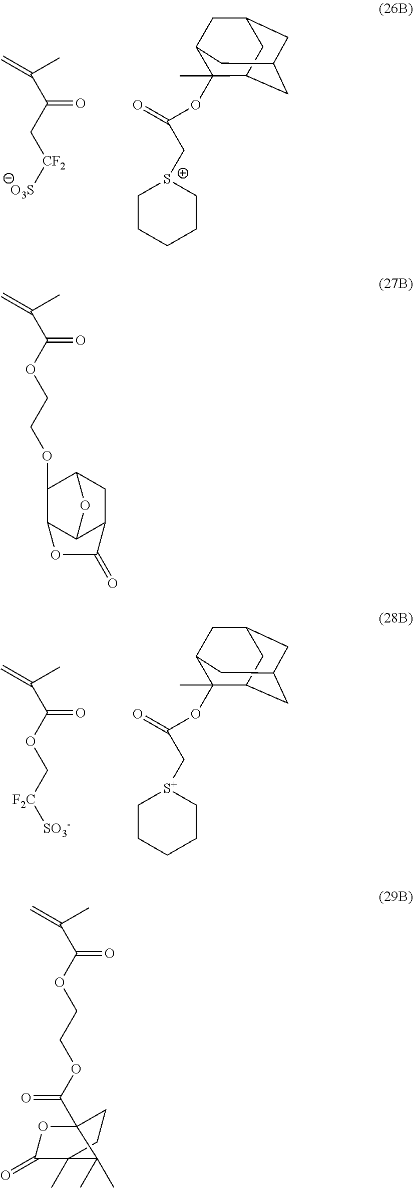

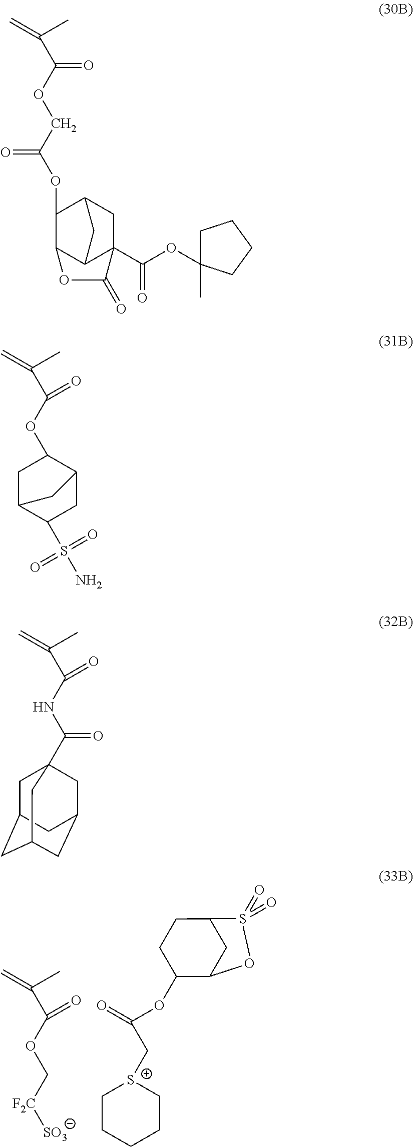

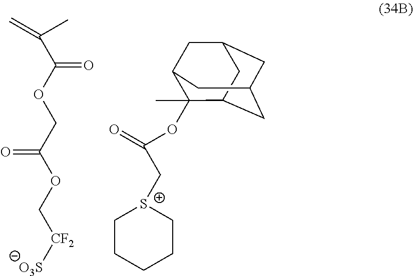

TABLE 7

| | | Polymeric compound | | | | | | | | | |
|---|---|---|---|---|---|---|---|---|---|---|---|
| | | 1B | 2B | 3B | 4B | 5B | 6B | 7B | 8B | 9B | 10B |
| Monomer | (1B) | 45 | 45 | | | | | 44 | 45 | 45 | 45 |
| | (2B) | 41 | 41 | 41 | 41 | 41 | 41 | 42 | 41 | 41 | 41 |
| | (3B) | 14 | | 14 | | | | | | | |
| | (4B) | | 14 | | 14 | | | | | | |
| | (5B) | | | 45 | 45 | 45 | 45 | | | | |
| | (6B) | | | | | 14 | | 14 | | | |
| | (7B) | | | | | | 14 | | 14 | | |
| | (8B) | | | | | | | | | | |
| | (9B) | | | | | | | | | 14 | |
| | (10B) | | | | | | | | | | 14 |
| | (11B) | | | | | | | | | | |
| | (12B) | | | | | | | | | | |
| | (13B) | | | | | | | | | | |
| | (14B) | | | | | | | | | | |
| | (15B) | | | | | | | | | | |
| | (16B) | | | | | | | | | | |
| | (17B) | | | | | | | | | | |
| | (18B) | | | | | | | | | | |
| | (19B) | | | | | | | | | | |
| | (20B) | | | | | | | | | | |
| | (21B) | | | | | | | | | | |
| | (22B) | | | | | | | | | | |
| | (23B) | | | | | | | | | | |
| | (24B) | | | | | | | | | | |
| | (25B) | | | | | | | | | | |
| | (26B) | | | | | | | | | | |
| | (27B) | | | | | | | | | | |
| | (28B) | | | | | | | | | | |
| | (29B) | | | | | | | | | | |
| | (30B) | | | | | | | | | | |
| | (31B) | | | | | | | | | | |
| | (32B) | | | | | | | | | | |
| | (33B) | | | | | | | | | | |
| | (34B) | | | | | | | | | | |

| | | | | | | | | | | |
|---|---|---|---|---|---|---|---|---|---|---|
| Mw | 12900 | 12900 | 13100 | 13000 | 13100 | 13000 | 12100 | 13400 | 12900 | 13000 |
| Mw/Mn | 1.68 | 1.69 | 1.63 | 1.61 | 1.7 | 1.68 | 1.8 | 1.85 | 1.67 | 1.7 |

TABLE 8

| | | Polymeric compound | | | | | | | | | |
|---|---|---|---|---|---|---|---|---|---|---|---|
| | | 11B | 12B | 13B | 14B | 15B | 16B | 17B | 18B | 19B | 20B |
| Monomer | (1B) | 44 | 44 | 45 | 44 | 45 | 44 | | | | |
| | (2B) | 42 | 42 | 42 | 42 | 42 | 42 | | | | |
| | (3B) | | | | | | | | | | |
| | (4B) | | | | | | | | | | |
| | (5B) | | | | | | | | | | |
| | (6B) | | | | | | | | 14 | | |
| | (7B) | | | | | | | | | | |
| | (8B) | | | | | | | 30 | | | |
| | (9B) | | | | | | | | | | |
| | (10B) | | | | | | | | | | |
| | (11B) | 14 | | | | | | | | | |
| | (12B) | | 13 | | | | | | | | |
| | (13B) | | | 13 | | | | | | | |
| | (14B) | | | | 14 | | | | | | |
| | (15B) | | | | | 13 | | | | | |
| | (16B) | | | | | | 14 | | | | |
| | (17B) | | | | | | | 30 | | | 30 |
| | (18B) | | | | | | | 30 | | | 30 |
| | (19B) | | | | | | | 10 | | | |
| | (20B) | | | | | | | | 11 | | |
| | (21B) | | | | | | | | 25 | | |
| | (22B) | | | | | | | | 35 | | |
| | (23B) | | | | | | | | 15 | | |
| | (24B) | | | | | | | | | 40 | |
| | (25B) | | | | | | | | | 40 | |
| | (26B) | | | | | | | | | 14 | |
| | (27B) | | | | | | | | | | 30 |
| | (28B) | | | | | | | | | | 10 |
| | (29B) | | | | | | | | | | |
| | (30B) | | | | | | | | | | |
| | (31B) | | | | | | | | | | |
| | (32B) | | | | | | | | | | |
| | (33B) | | | | | | | | | | |
| | (34B) | | | | | | | | | | |

| | | | | | | | | | | |
|---|---|---|---|---|---|---|---|---|---|---|
| Mw | 12100 | 11900 | 11900 | 12500 | 11900 | 12500 | 10700 | 12500 | 12600 | 10400 |
| Mw/Mn | 1.6 | 1.8 | 1.8 | 1.75 | 1.8 | 1.72 | 1.6 | 1.75 | 1.67 | 1.6 |

TABLE 9

| | | Polymeric compound | |
|---|---|---|---|
| | | 21B | 22B |
| Monomer | (1B) | | |
| | (2B) | | |
| | (3B) | | |
| | (4B) | | |
| | (5B) | | |
| | (6B) | | |
| | (7B) | | |
| | (8B) | | |
| | (9B) | | |
| | (10B) | | |
| | (11B) | | |
| | (12B) | | |
| | (13B) | | |
| | (14B) | | |
| | (15B) | | |
| | (16B) | | |
| | (17B) | | |
| | (18B) | | |
| | (19B) | | |
| | (20B) | 14 | |
| | (21B) | | |
| | (22B) | 35 | |
| | (23B) | | |
| | (24B) | | |
| | (25B) | | 34 |
| | (26B) | | |
| | (27B) | | |
| | (28B) | | |
| | (29B) | 26 | |
| | (30B) | | 34 |
| | (31B) | | 18 |
| | (32B) | 12 | |
| | (33B) | 13 | |
| | (34B) | | 14 |

| | | |
|---|---|---|
| Mw | 13000 | 13000 |
| Mw/Mn | 1.68 | 1.77 |

### Examples 1B to 16B and Comparative Examples 1B to 6B

The components shown in Tables 10 and 11 were mixed together and dissolved to obtain resist compositions.

TABLE 10

| | Resin | Component | Component | Component | |
|---|---|---|---|---|---|
| | Component | (D) | (E) | (S) | |
| Example | (A) - 1B | (D) - 1B | (E) - 1B | (S) - 1B | (S) - 2B |
| 1B | [100] | [1.7] | [1.17] | [5000] | [100] |
| Example | (A) - 2B | (D) - 1B | (E) - 1B | (S) - 1B | (S) - 2B |
| 2B | [100] | [1.7] | [1.17] | [5000] | [100] |
| Example | (A) - 3B | (D) - 1B | (E) - 1B | (S) - 1B | (S) - 2B |
| 3B | [100] | [1.7] | [1.17] | [5000] | [100] |
| Example | (A) - 4B | (D) - 1B | (E) - 1B | (S) - 1B | (S) - 2B |
| 4B | [100] | [1.7] | [1.17] | [5000] | [100] |
| Example | (A) - 5B | (D) - 1B | (E) - 1B | (S) - 1B | (S) - 2B |
| 5B | [100] | [1.7] | [1.17] | [5000] | [100] |
| Example | (A) - 6B | (D) - 1B | (E) - 1B | (S) - 1B | (S) - 2B |
| 6B | [100] | [1.7] | [1.17] | [5000] | [100] |
| Example | (A) - 7B | (D) - 1B | (E) - 1B | (S) - 1B | (S) - 2B |
| 7B | [100] | [1.7] | [1.17] | [5000] | [100] |
| Example | (A) - 8B | (D) - 1B | (E) - 1B | (S) - 1B | (S) - 2B |
| 8B | [100] | [1.7] | [1.17] | [5000] | [100] |
| Example | (A) - 9B | (D) - 1B | (E) - 1B | (S) - 1B | (S) - 2B |
| 9B | [100] | [1.7] | [1.17] | [5000] | [100] |
| Example | (A) - 10B | (D) - 1B | (E) - 1B | (S) - 1B | (S) - 2B |
| 10B | [100] | [1.7] | [1.17] | [5000] | [100] |
| Example | (A) - 11B | (D) - 1B | (E) - 1B | (S) - 1B | (S) - 2B |
| 11B | [100] | [1.7] | [1.17] | [5000] | [100] |
| Example | (A) - 12B | (D) - 1B | (E) - 1B | (S) - 1B | (S) - 2B |
| 12B | [100] | [1.7] | [1.17] | [5000] | [100] |
| Example | (A) - 13B | (D) - 2B | (E) - 1B | (S)-1B | (S) - 2B |
| 13B | [100] | [2.1] | [1.17] | [5000] | [100] |
| Example | (A) - 14B | (D) - 1B | (E) - 1B | (S) - 1B | (S) - 2B |
| 14B | [100] | [1.7] | [1.17] | [5000] | [100] |
| Example | (A) - 15B | (D) - 3B | (E) - 1B | (S) - 1B | (S) - 2B |
| 15B | [100] | [2.2] | [1.17] | [5000] | [100] |
| Example | (A) -16B | (D) - 1B | (E) - 1B | (S) - 1B | (S) - 2B |
| 16B | [100] | [1.7] | [1.17] | [5000] | [100] |

TABLE 11

| | Resin | Compo- | Compo- | Component | |
|---|---|---|---|---|---|
| | Component | nent (D) | nent (E) | (S) | |
| Comparative | (A′) - 1B | (D) - 1B | (E) - 1B | (S) - 1B | (S) - 2B |
| Example 1B | [100] | [1.7] | [1.17] | [5000] | [100] |
| Comparative | (A′) - 2B | (D) - 1B | (E) - 1B | (S) - 1B | (S) - 2B |
| Example 2B | [100] | [1.7] | [1.17] | [5000] | [100] |
| Comparative | (A′) - 3B | (D) - 1B | (E) - 1B | (S) - 1B | (S) - 2B |
| Example 3B | [100] | [1.7] | [1.17] | [5000] | [100] |
| Comparative | (A′) - 4B | (D) - 1B | (E) - 1B | (S) - 1B | (S) - 2B |
| Example 4B | [100] | [1.7] | [1.17] | [5000] | [100] |
| Comparative | (A′) - 5B | (D) - 1B | (E) - 1B | (S) - 1B | (S) - 2B |
| Example 5B | [100] | [1.7] | [1.17] | [5000] | [100] |
| Comparative | (A′) - 6 B | (D) - 1B | (E) - 1B | (S) - 1B | (S) - 2B |
| Example 6B | [100] | [1.7] | [1.17] | [5000] | [100] |

In Tables 10 and 11, the reference characters indicate the following. Further, the values in brackets [ ] indicate the amount (in terms of parts by weight) of the component added.

(A)-1B to (A)-16B: the aforementioned polymeric compounds 7B to 22B.

(A′)-1B to (A′)-6B: the aforementioned polymeric compounds 1B to 6B.

(D)-1B: a compound represented by formula (D)-1B shown below

(D)-2B: a compound represented by formula (D)-2B shown below

(D)-3B: a compound represented by formula (D)-3B shown below

(E)-1B: salicylic acid

(S)-1B: a mixed solvent of PGMEA/PGME/cyclohexanone=1500/1000/2500 (weight ratio)

(S)-2: γ-butyrolactone

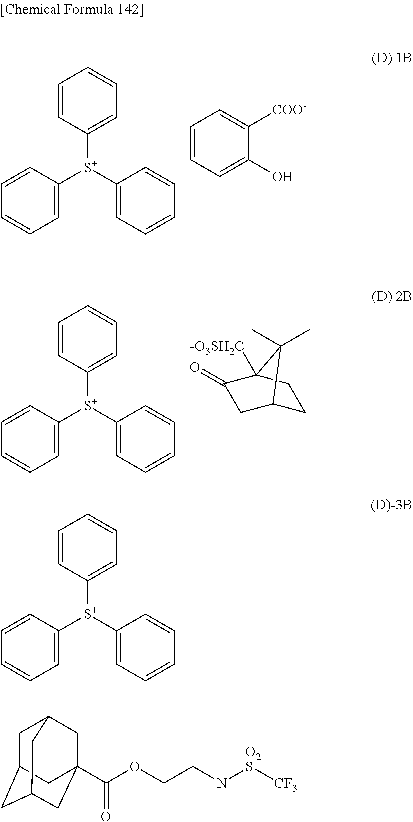

Using the obtained resist compositions, the following evaluations were conducted.

### <Formation of Resist Pattern 2>

Using a spinner, each resist composition was uniformity applied to an 8-inch silicon wafer that had been treated with hexamethyldisilazane (HMDS) at 90° C. for 36 seconds, and the solution was then subjected to a bake treatment (PAB) at a temperature indicated in Table 12 for 60 seconds, thereby forming a resist film (film thickness: 60 nm Subsequently, the resist film was subjected to drawing (exposure) with an accelerating voltage of 100 kV using an electron beam lithography apparatus JBX-9300FS (manufactured by JEOL Ltd.), followed by a bake treatment (PEB) for 60 seconds at a temperature indicated in Table 12. Then, development was conducted with a 2.38 wt % aqueous TMAH solution (product name: NMD-3; manufactured by Tokyo Ohka Kogyo Co., Ltd.) at 23° C. for 60 seconds.

As a result, in each of the examples, a line and space pattern (hereafter, referred to as “LS pattern”) having a line width of 100 nm and a pitch of 200 nm was formed.

### [Evaluation of Sensitivity]

The optimum exposure dose Eop (μC/cm²) with which the LS pattern was formed was determined. The results are shown in Table 12.

### [Evaluation of Line Width Roughness (LWR) 2]

With respect to the LS pattern having a line width of 100 nm and a pitch of 200 nm formed in the aforementioned <Formation of resist pattern 2>, 3σ was determined as a yardstick of LWR.

The “3σ” refers to a value of 3 times the standard deviation (σ) (unit: nm) which is calculated from a result in which the line width at 400 points in the lengthwise direction of the line were measured using a scanning electron microscope (SEM) (product name: S-9220, manufactured by Hitachi High-Technologies Corporation; acceleration voltage: 800V). The smaller this 3s value is, the lower the level of roughness of the side walls of a line pattern, indicating that a LS pattern with a uniform width was obtained. The results are indicated under “LWR (nm)” in Table 12.

### [Evaluation of Exposure Latitude (10% EL) 2]

With respect to the aforementioned <Formation of resist pattern 2>, the exposure dose with which an LS pattern having a dimension of the target dimension (line width: 100 nm)±10% (i.e., 90 nm to 110 nm) was determined, and the EL margin (unit: %) was determined by the following formula.

The larger the value of the EL, the smaller the change in the pattern size by the variation of the exposure dose. The results are indicated “10% EL” in Table 12.

EL margin (%)=(|E1−E2|/Eop)×100

In the formula, E1 represents the exposure dose (μC/cm²) for forming a LS pattern having a line width of 90 nm, and E2 represents the exposure dose (μC/cm²) for forming a LS pattern having a line width of 110 nm.

### [Evaluation of Resolution]

The critical resolution (nm) with the above Eop was determined using a scanning electron microscope (product name: S-9380, manufactured by Hitachi High-Technologies Corporation). The results are indicated under “resolution (nm)” in Table 12.

TABLE 12

| | PAB/PEB (° C.) | Eop | LWR | 10% EL | Resolution |
|---|---|---|---|---|---|
| | each 60 sec | [uC/cm²] | [nm] | (nm) | [nm] |
| Example 1B | 130/110 | 50 | 4.0 | 24.8 | 35 |
| Example 2B | 130/110 | 46 | 4.6 | 21.0 | 35 |
| Example 3B | 130/110 | 48 | 5.6 | 20.0 | 40 |
| Example 4B | 130/110 | 52 | 3.0 | 26.4 | 35 |
| Example 5B | 130/110 | 52 | 5.0 | 24.2 | 35 |
| Example 6B | 130/110 | 46 | 5.5 | 24.0 | 35 |
| Example 7B | 130/110 | 38 | 3.2 | 23.8 | 32 |
| Example 8B | 130/110 | 56 | 5.6 | 20.0 | 35 |
| Example 9B | 130/110 | 60 | 5.3 | 19.8 | 40 |
| Example 10B | 130/110 | 44 | 4.4 | 22.0 | 35 |
| Example 11B | 120/95 | 40 | 5.2 | 20.1 | 35 |
| Example 12B | 120/95 | 50 | 4.5 | 23.8 | 35 |
| Example 13B | 120/95 | 48 | 4.0 | 22.2 | 35 |
| Example 14B | 130/110 | 48 | 3.8 | 24.5 | 35 |
| Example 15B | 130/105 | 50 | 3.6 | 25.6 | 35 |
| Example 16B | 130/105 | 50 | 4.6 | 23.4 | 35 |
| Comparative | 130/110 | 52 | 6.0 | 16.0 | 50 |
| Example 1B | | | | | |
| Comparative | 130/110 | 52 | 6.6 | 14.8 | 50 |
| Example 2B | | | | | |
| Comparative | 140/120 | 52 | 8.6 | 10.5 | 60 |
| Example 3B | | | | | |
| Comparative | 140/120 | 56 | 8.0 | 12.0 | 60 |
| Example 4B | | | | | |
| Comparative | 140/120 | 68 | 7.2 | 16.8 | 50 |
| Example 5B | | | | | |
| Comparative | 140/120 | 62 | 7.3 | 16.8 | 50 |
| Example 6B | | | | | |

From the results shown above, it was confirmed that the resist compositions of Examples 1B to 16B were superior to the resist compositions of Comparative Examples 1B to 6B in that they exhibited excellent sensitivity, large exposure latitude, reduced LWR and excellent resolution.

By comparison between Comparative Examples 1B and 2B and Examples 1B to 9B, 11B, 13B, 14B and 16B, it was confirmed that when a cation moiety of a structural unit that generates acid upon exposure had one aromatic ring or no aromatic ring, the resist composition exhibited excellent resolution and excellent lithography properties such as exposure latitude and LWR.

By comparison between Comparative Examples 5B and 613 and Examples 1B to 11B, 13B, 14B and 16B, it was confirmed that when the structural unit having a lactone ring had a longer side chain, the resist composition exhibited more excellent lithography properties.

### Polymer Synthesis Examples 1C to 20C

Polymeric compounds 1C to 14C, 1C″ and 1C′ to 5C″ indicated in Tables 13 to 17 were produced by a normal method using vinyl-based monomers corresponding to the structural units constituting the polymeric compounds in the blend ratio (molar ratio) indicated in Tables 13 to 17. The polymeric compounds 1C to 14C including a structural unit (a0) were produced by porymerization using monomers having a triphenylsulfonium as a countercation, and then conducting salt-exchange reaction by a normal method to replace the triphenylsulfonium with the predetermined countercation.

Further, with respect to the obtained polymeric compounds, the compositional ratio (the molar ratio of the respective structural units indicated in the structural formula shown below) as determined by carbon 13 nuclear magnetic resonance spectroscopy (600 MHz, ¹³C-NMR, internal standard: tetramethylsilane (TMS)), and the weight average molecular weight (Mw) and the molecular weight distribution (Mw/Mn) determined by the polystyrene equivalent value as measured by GPC are shown in Tables 13 to 17.

TABLE 13
Polymeric compound 1C

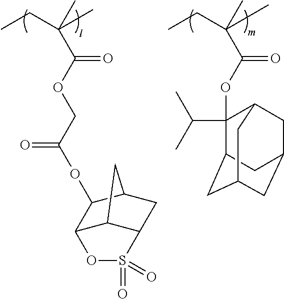

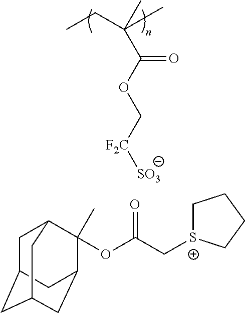

| | compositional ratio | | |
|---|---|---|---|
| blend ratio | (l/m/n) | Mw | Mw/Mn |
| 44/44/12 | 45.9/44.0/10.1 | 4300 | 1.87 |

Polymeric compound 2C

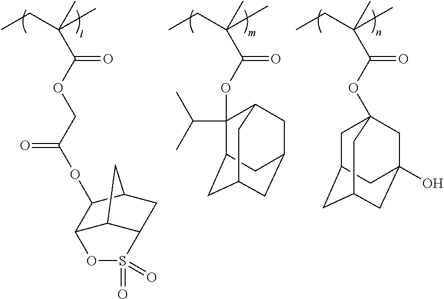

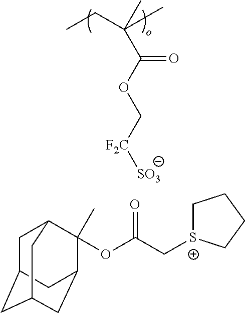

| | compositional ratio | | |
|---|---|---|---|
| blend ratio | (l/m/n/o) | Mw | Mw/Mn |
| 35/35/18/12 | 33.8/33.9/19.1/13.3 | 5100 | 1.64 |

Polymeric compound 3C

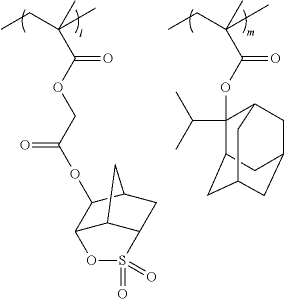

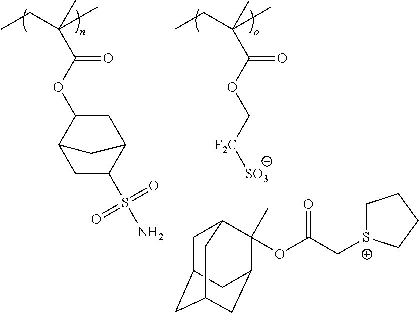

| | compositional ratio | | |
|---|---|---|---|
| blend ratio | (l/m/n/o) | Mw | Mw/Mn |
| 35/35/18/12 | 34.5/33.9/18.6/13.0 | 5700 | 1.72 |

Polymeric compound 4C

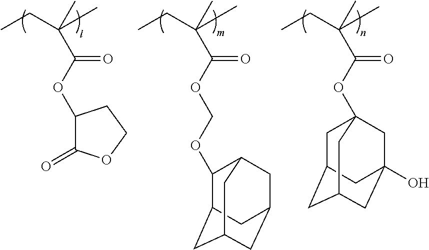

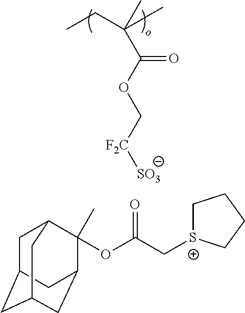

| | compositional ratio | | |
|---|---|---|---|
| blend ratio | (l/m/n/o) | Mw | Mw/Mn |
| 35/35/18/12 | 35.2/35.4/17.5/12.1 | 6200 | 1.84 |

TABLE 14
Polymeric compound 5C

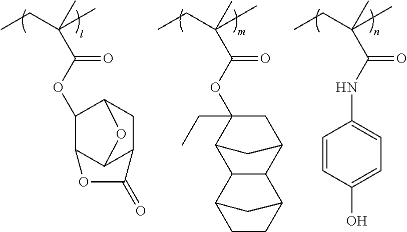

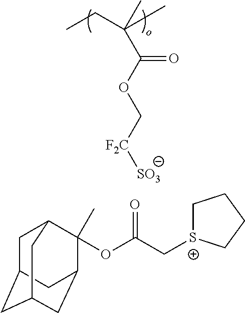

| | compositional ratio | | |
|---|---|---|---|
| blend ratio | (l/m/n/o) | Mw | Mw/Mn |
| 35/35/18/12 | 33.6/33.9/19.2/13.3 | 4800 | 1.89 |

Polymeric compound 6C

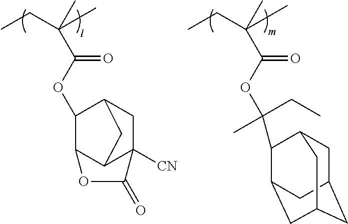

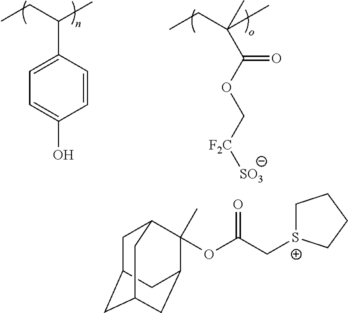

| | compositional ratio | | |
|---|---|---|---|
| blend ratio | (l/m/n/o) | Mw | Mw/Mn |
| 35/35/18/12 | 34.6/35.4/18.6/11.4 | 4400 | 1.72 |

Polymeric compound 7C

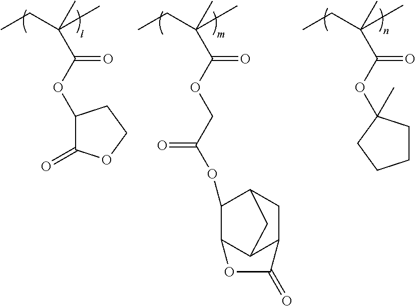

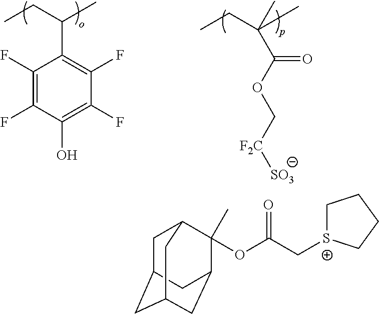

| | compositional ratio | | |
|---|---|---|---|
| blend ratio | (l/m/n/o/p) | Mw | Mw/Mn |
| 25/25/25/13/12 | 24.4/25.0/25.1/13.2/12.3 | 3600 | 1.75 |

Polymeric compound 8C

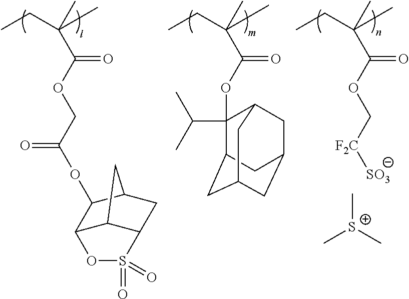

| | compositional ratio | | |
|---|---|---|---|
| blend ratio | (l/m/n) | Mw | Mw/Mn |
| 44/44/12 | 44.2/43.5/12.3 | 6300 | 1.8 |

TABLE 15
Polymeric compound 9C

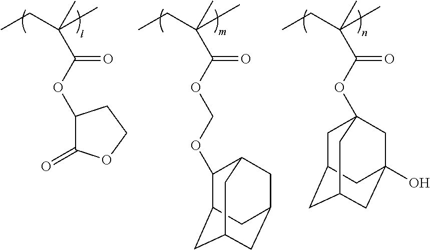

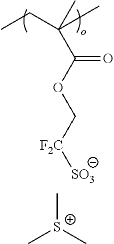

| | compositional ratio | | |
|---|---|---|---|
| blend ratio | (l/m/n/o) | Mw | Mw/Mn |
| 35/35/18/12 | 44.1/43.6/18.4/11.9 | 6700 | 1.78 |

Polymeric compound 10C

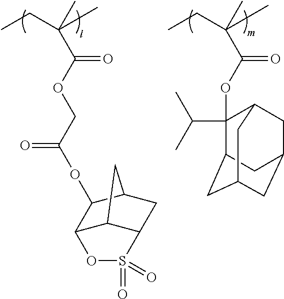

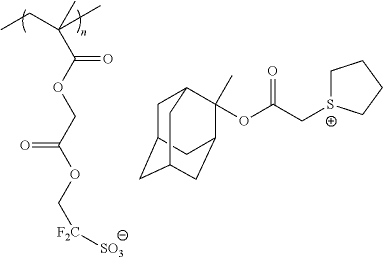

| | compositional ratio | | |
|---|---|---|---|
| blend ratio | (l/m/n) | Mw | Mw/Mn |
| 44/44/12 | 45.7/44.6/9.7 | 4400 | 1.93 |

Polymeric compound 11C

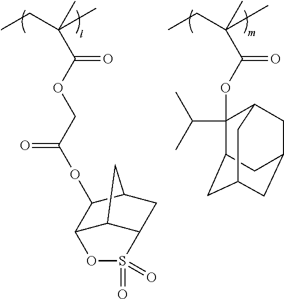

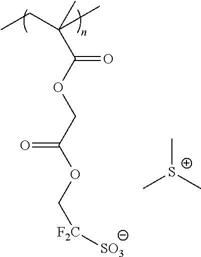

| | compositional ratio | | |
|---|---|---|---|
| blend ratio | (l/m/n) | Mw | Mw/Mn |
| 44/44/12 | 48.8/44.1/11.1 | 3800 | 1.85 |

Polymeric compound 12C

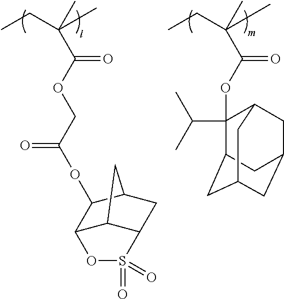

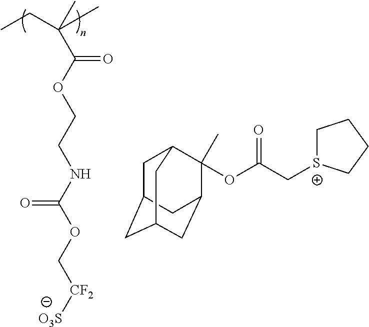

| | compositional ratio | | |
|---|---|---|---|
| blend ratio | (l/m/n) | Mw | Mw/Mn |
| 44/44/12 | 45.3/45.1/9.6 | 3700 | 1.88 |

TABLE 16

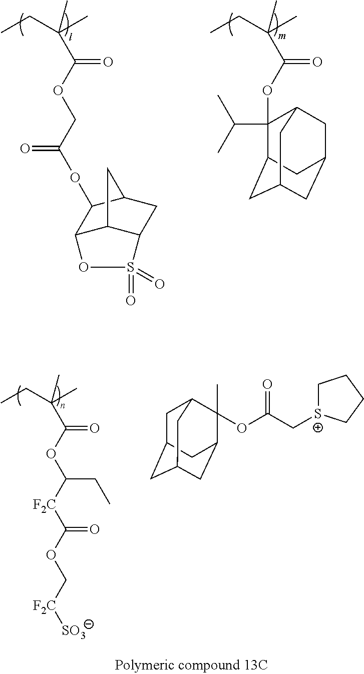

| blend ratio | compositional ratio (l/m/n) | Mw | Mw/Mn |
|---|---|---|---|
| 44/44/12 | 43.9/44.6/11.5 | 4500 | 1.73 |

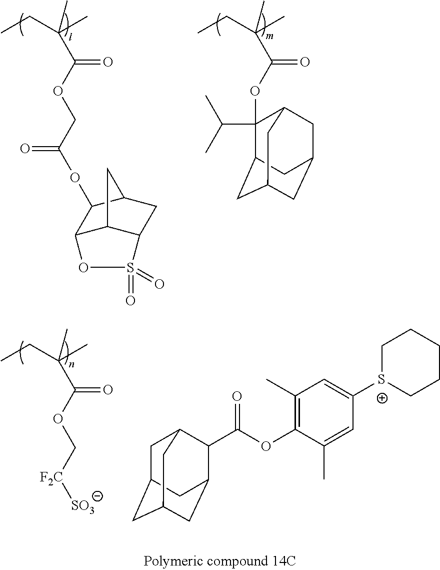

| blend ratio | compositional ratio (l/m/n) | Mw | Mw/Mn |
|---|---|---|---|
| 44/44/12 | 43.6/43.2/13.4 | 4700 | 1.77 |

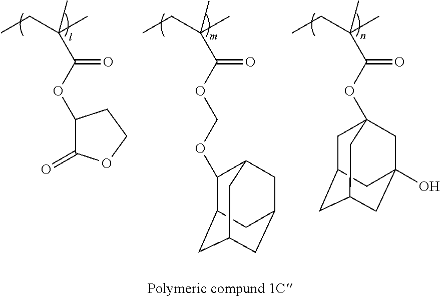

| blend ratio | compositional ratio (l/m/n) | Mw | Mw/Mn |
|---|---|---|---|
| 44/44/12 | 44.6/43.8/11.6 | 7100 | 1.51 |

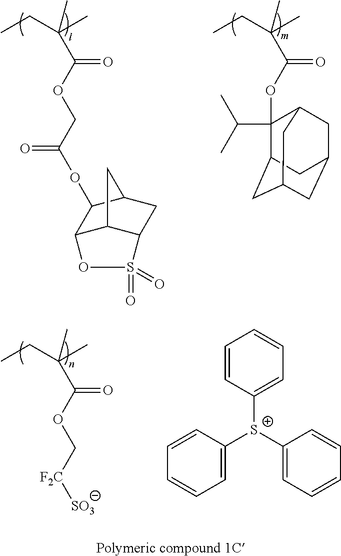

| blend ratio | compositional ratio (l/m/n) | Mw | Mw/Mn |
|---|---|---|---|
| 44/44/12 | 44.3/44.1/11.6 | 6900 | 1.78 |

TABLE 17
Polymeric compound 2C′

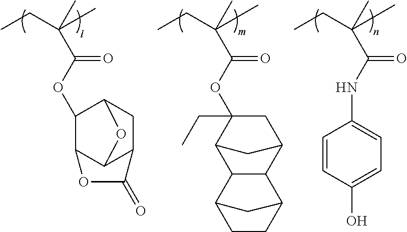

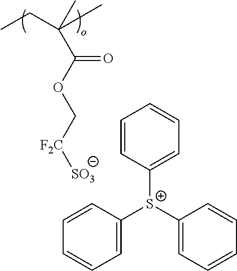

| | compositional ratio | | |
|---|---|---|---|
| blend ratio | (l/m/n/o) | Mw | Mw/Mn |
| 35/35/18/12 | 34.5/34.9/18.4/12.2 | 5200 | 1.91 |

Polymeric compound 3C′

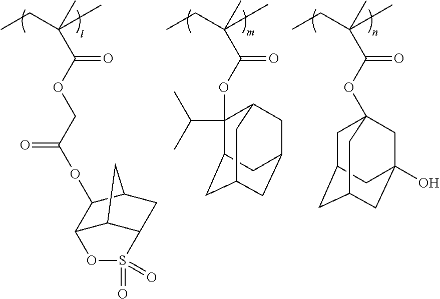

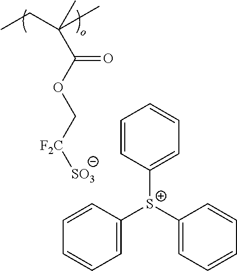

| | compositional ratio | | |
|---|---|---|---|
| blend ratio | (l/m/n/o) | Mw | Mw/Mn |
| 35/35/18/12 | 33.8/33.9/19.1/13.3 | 5600 | 1.76 |

Polymeric compound 4C′

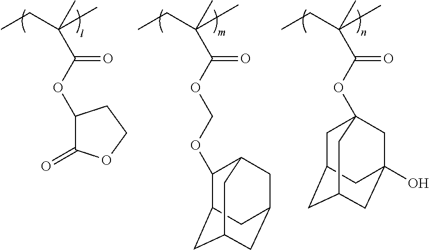

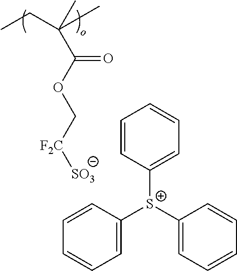

| | compositional ratio | | |
|---|---|---|---|
| blend ratio | (l/m/n/o) | Mw | Mw/Mn |
| 35/35/18/12 | 34.2/35.4/18.3/12.1 | 6100 | 1.82 |

Polymeric compound 5C′

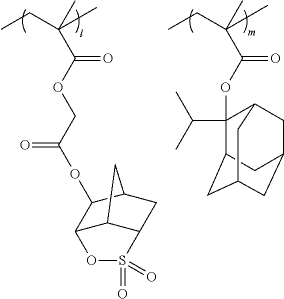

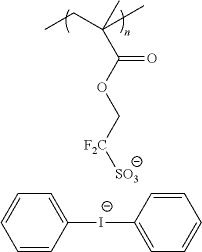

| | compositional ratio | | |
|---|---|---|---|
| blend ratio | (l/m/n) | Mw | Mw/Mn |
| 44/44/12 | 45.1/44.2/10.7 | 5900 | 1.69 |

### Examples 1C to 30C and Comparative Examples 1C to 9C

The components shown in Tables 18 to 20 were mixed together and dissolved to obtain resist compositions.

TABLE 18

| | Resin | Component | Component |
|---|---|---|---|
| | component | (C) | (S) |
| Example 1C | (A) - 1C | (C) -1C | (S) - 1C |
| | [100] | [2.0] | [5000] |
| Example 2C | (A) - 2C | (C) - 1C | (S) - 1C |
| | [100] | [2.0] | [5000] |
| Example 3C | (A) - 3C | (C) - 1C | (S) - 1C |
| | [100] | [2.0] | [5000] |
| Example 4C | (A) - 4C | (C) - 1C | S) - 1C |
| | [100] | [2.0] | [5000] |
| Example 5C | (A) - 5C | (C) - 1C | (S) - 1C |
| | [100] | [2.0] | [5000] |
| Example 6C | (A) - 6C | (C) - 1C | (S) - 1C |
| | [100] | [2.0] | [5000] |
| Example 7C | (A) - 7C | (C) -1C | (S) - 1C |
| | [100] | [2.0] | [5000] |
| Example 8C | (A) - 8C | (C) - 1C | (S) - 1C |
| | [100] | [2.0] | [5000] |
| Example 9C | (A) - 9C | (C) - 1C | (S) - 1C |
| | [100] | [2.0] | [5000] |
| Example 10C | (A) - 10C | (C) - 1C | (S) - 1C |
| | [100] | [2.0] | [5000] |
| Example 11C | (A) - 11C | (C) - 1C | (S) - 1C |
| | [100] | [2.0] | [5000] |
| Example 12C | (A) - 12C | (C) - 1C | (S) - 1C |
| | [100] | [2.0] | [5000] |
| Example 13C | (A) - 13C | (C) - 1C | (S) - 1C |
| | [100] | [2.0] | [5000] |

TABLE 19

| | Resin | Component | Component |
|---|---|---|---|
| | component | (C) | (S) |
| Example 14C | (A) - 1C | (C) - 2C | (S) - 1C |
| | [100] | [1.6] | [5000] |
| Example 15C | (A) - 1C | (C) - 3C | (S) - 1C |
| | [100] | [2.5] | [5000] |
| Example 16C | (A) - 1C | (C) - 4C | (S) - 1C |
| | [100] | [1.4] | [5000] |
| Example 17C | (A) - 1C | (C) - 5C | (S) - 1C |
| | [100] | [1.5] | [5000] |
| Example 18C | (A) - 1C | (C) - 6C | (S) - 1C |
| | [100] | [1.5] | [5000] |
| Example 19C | (A) - 1C | (C) - 7C | (S) - 1C |
| | [100] | [1.7] | [5000] |
| Example 20C | (A) - 1C | (C) - 8C | (S) - 1C |
| | [100] | [5000] | [5000] |
| Example 21C | (A) - 1C | (C) - 9C | (S) - 1C |
| | [100] | [2.5] | [5000] |
| Example 22C | (A) - 1C | (C) - 10C | (S) - 1C |
| | [100] | [2.1] | [5000] |
| Example 23C | (A) - 1C | (C) - 11C | (S) - 1C |
| | [100] | [3.0] | [5000] |
| Example 24C | (A) - 1C | (C) - 12C | (S) - 1C |
| | [100] | [2.1] | [5000] |
| Example 25C | (A) - 1C | (C) - 13C | (S) - 1C |
| | [100] | [1.7] | [5000] |
| Example 26C | (A) - 1C | (C) - 14C | (S) - 1C |
| | [100] | [2.6] | [5000] |
| Example 27C | (A) - 14C | (C) - 1C | (S) - 1C |
| | [100] | [2.0] | [5000] |
| Example 28C | (A) - 14C | (C) - 6C | (S) - 1C |
| | [100] | [2.1] | [5000] |
| Example 29C | (A) - 14C | (C) - 9C | (S) - 1C |
| | [100] | [2.5] | [5000] |
| Example 30C | (A) - 14C | (C) - 12C | (S) - 1C |
| | [100] | [2.1] | [5000] |

TABLE 20

| | Resin | Compo- | Compo- | Compo- | Compo- |
|---|---|---|---|---|---|
| | component | nent (B) | nent (C) | nent (D) | nent (S) |
| Comparative | (A″) - 1C | ( B) - 1C | (C) - 1C | — | (S) - 2C |
| Example 1C | [100] | [25] | [2.0] | | [5000] |
| Comparative | (A′) - 1C | — | — | (D) - 1C | (S) - 1C |
| Example 2C | [100] | | | [1.9] | [5000] |
| Comparative | (A′) - 1C | — | (C) - 1C | — | (S) - 1C |
| Example 3C | [100] | | [2.0] | | [5000] |
| Comparative | (A′) - 2C | — | (C) - 1C | — | (S) - 1C |
| Example 4C | [100] | | [2.0] | | [5000] |
| Comparative | (A′) - 3C | — | (C) - 1C | — | (S) - 1C |
| Example 5C | [100] | | [2.0] | | [5000] |
| Comparative | (A′) - 4C | — | (C) - 1C | — | (S) - 1C |
| Example 6C | [100] | | [2.0] | | [5000] |
| Comparative | (A′) - 5C | — | (C) - 1C | — | (S) - 1C |
| Example 7C | [100] | | [2.0] | | [5000] |
| Comparative | (A) - 14C | — | — | (D) - 1C | (S) - 1C |
| Example 8C | [100] | | | [1.9] | [5000] |
| Comparative | (A) - 1C | — | — | (D) - 1C | (S) - 1C |
| Example 9C | [100] | | | [1.9] | [5000] |

In Tables 18 to 20, the reference characters indicate the following. Further, the values in brackets [ ] indicate the amount (in terms of parts by weight) of the component added.

(A)-1C to (A)-14C: the aforementioned polymeric compounds 1C to 14C

(A″)-1C: the aforementioned polymeric compound 1C″

(A′)-1C to (A′)-5C: the aforementioned polymeric compounds 1C′ to 5C′

(B)-1C: a compound represented by structural formula (B)-1C shown below

(C)-1C to (C)-14C: compounds represented by chemical formulas (C)-1C to (C)-14C shown below

(D)-1C: tri-n-octylamine

(S)-1C: a mixed solvent of PGMEA/PGME/cyclohexanone=1500/1000/2500 (weight ratio)

(S)-2C: a mixed solvent of PGMEA/PGME=3000/2000 (weight ratio)

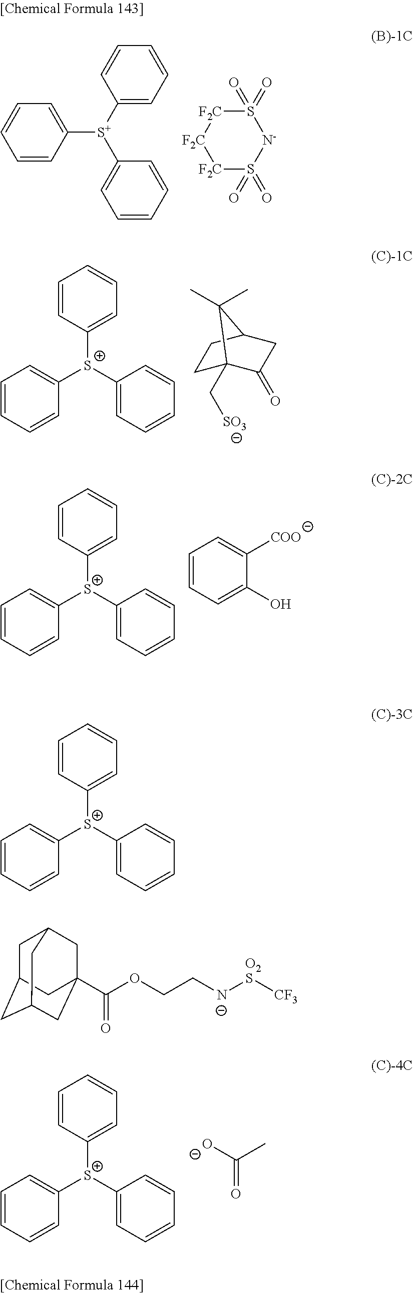

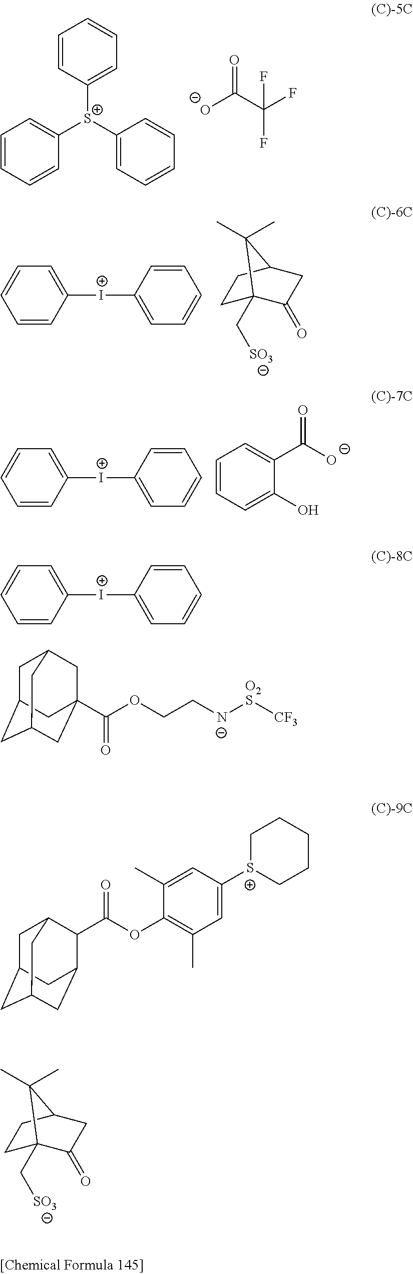

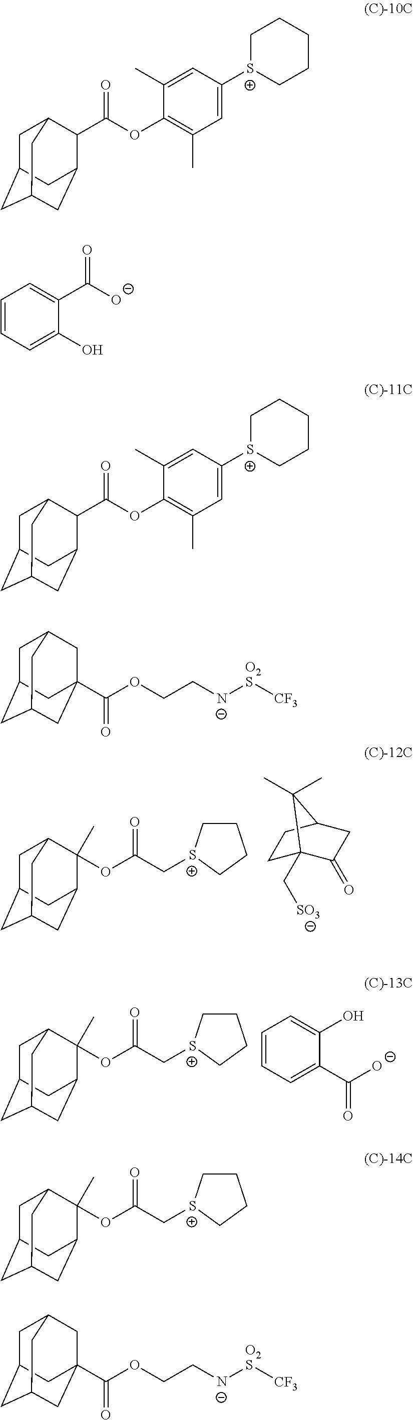

Using the obtained resist compositions, the following evaluations were conducted.

### [Formation of Resist Pattern 3]

Using a spinner, each resist composition was uniformity applied to an 8-inch silicon wafer that had been treated with hexamethyldisilazane (HMDS) at 90° C. for 36 seconds, and the solution was then subjected to a bake treatment (PAB) at a temperature indicated in Table 21 for 60 seconds, thereby forming a resist film (film thickness: 60 nm). Subsequently, the resist film was subjected to drawing (exposure) with an accelerating voltage of 50 kV using an electron beam lithography apparatus HL-800D (VSB) (manufactured by Hitachi, Ltd.), followed by a bake treatment (PEB) for 60 seconds at a temperature indicated in Table 21. Then, development was conducted with a 2.38 wt % aqueous TMAH solution (product name: NMD-3; manufactured by Tokyo Ohka Kogyo Co., Ltd.) at 23° C. for 60 seconds.

As a result, in each of the examples, a line and space pattern (hereafter, referred to as “LS pattern”) having a line width of 100 nm and a pitch of 200 nm was formed.

It was thought that the higher accelerate voltage was effective in formation of fine pattern. However, in this evaluation, in order to simulate the exposure condition in which OoB light was generated, a relatively-low accelerate voltage of 50 kV was used.

### [Evaluation of Resolution 2]

The critical resolution (nm) with the above Eop (μC/cm²) with which the LS pattern was formed was determined using a scanning electron microscope (product name: S-9220, manufactured by Hitachi High-Technologies Corporation). The results are indicated as “resolution” in Table 21.

### [Evaluation of Line Edge Roughness (LER) 3]

With respect to the LS pattern having a line width of 100 nm and a pitch of 200 nm formed in the aforementioned <Formation of resist pattern 3>, 3σ was determined as a yardstick of LER. The “3σ” refers to a value of 3 times the standard deviation (σ) (unit: nm) which is calculated from a result in which the line width at 400 points in the lengthwise direction of the line were measured using a scanning electron microscope (SEM) (product name: S-9220, manufactured by Hitachi High-Technologies Corporation; acceleration voltage: 800V). The smaller this 3s value is, the lower the level of roughness of the side walls of a line pattern, indicating that a LS pattern with a uniform width was obtained. The results are shown in Table 21.

### [Evaluation of Exposure Latitude (10% EL) 3]

With respect to the aforementioned [Formation of resist pattern 3], the exposure dose with which an LS pattern having a dimension of the target dimension (line width: 100 nm)+10% (i.e., 90 nm to 110 nm) was determined, and the EL margin (unit: %) was determined by the following formula. The larger the value of the EL, the smaller the change in the pattern size by the variation of the exposure dose. The results are indicated “10% EL” in Table 21.

EL margin (%)=(|E1−E2|/Eop)×100

In the formula, E1 represents the exposure dose (μC/cm²) for forming a LS pattern having a line width of 90 nm, and E2 represents the exposure dose (μC/cm²) for forming a LS pattern having a line width of 110 nm.

TABLE 21

| | PAB/PEB | LER | 10% EL | Resolution |
|---|---|---|---|---|
| | (° C.) | (nm) | (nm) | (nm) |
| Example 1C | 130/100 | 6.3 | 25.4 | 50 |
| Example 2C | 130/100 | 6.5 | 24.1 | 50 |
| Example 3C | 130/100 | 6.3 | 23.8 | 50 |
| Example 4C | 120/100 | 7.4 | 24.4 | 60 |
| Example 5C | 130/100 | 7.1 | 23.2 | 60 |
| Example 6C | 130/100 | 6.7 | 23.3 | 50 |
| Example 7C | 130/100 | 6.5 | 22.8 | 50 |
| Example 8C | 130/110 | 7.3 | 21.6 | 60 |
| Example 9C | 120/100 | 7.7 | 22.3 | 70 |
| Example 10C | 130/110 | 6.6 | 24.0 | 50 |
| Example 11C | 130/110 | 6.9 | 21.2 | 60 |
| Example 12C | 130/100 | 6.5 | 22.6 | 50 |
| Example 13C | 120/95 | 6.6 | 22.2 | 50 |
| Example 14C | 130/100 | 6.9 | 23.8 | 50 |
| Example 15C | 130/100 | 6.2 | 23.0 | 50 |
| Example 16C | 130/100 | 7.2 | 22.6 | 60 |
| Example 17C | 130/100 | 7.0 | 20.9 | 60 |
| Example 18C | 130/100 | 7.2 | 22.3 | 60 |
| Example 19C | 130/100 | 7.5 | 22.5 | 60 |
| Example 20C | 130/100 | 7.1 | 21.5 | 60 |
| Example 21C | 130/100 | 6.4 | 20.9 | 50 |
| Example 22C | 130/100 | 6.8 | 21.1 | 60 |
| Example 23C | 130/100 | 6.4 | 20.8 | 50 |
| Example 24C | 130/100 | 5.9 | 24.7 | 50 |
| Example 25C | 130/100 | 6.4 | 23.7 | 50 |
| Example 26C | 130/100 | 6.1 | 22.9 | 50 |
| Example 27C | 130/100 | 6.4 | 23.3 | S0 |
| Example 28C | 130/100 | 7 0 | 22.2 | 60 |
| Example 29C | 130/100 | 6.8 | 22.5 | 50 |
| Example 30C | 130/100 | 6.5 | 23.8 | 50 |
| Comparative | 100/90 | 8.9 | 16.4 | 60 |
| Example 1C | | | | |
| Comparative | 130/110 | 8.6 | 15.6 | 60 |
| Example 2C | | | | |
| Comparative | 130/110 | 7.8 | 17.2 | 60 |
| Example 3C | | | | |
| Comparative | 130/100 | 8.4 | 18.6 | 70 |
| Example 4C | | | | |
| Comparative | 120/110 | 6.7 | 19.8 | 60 |
| Example 5C | | | | |
| Comparative | 120/100 | 8.3 | 18.3 | 70 |
| Example 6C | | | | |
| Comparative | 130/100 | 8.8 | 17.5 | 80 |
| Example 7C | | | | |
| Comparative | 130/100 | 7.4 | 19.1 | 60 |
| Example 8C | | | | |
| Comparative | 130/100 | 7.2 | 20.1 | 70 |
| Example 9C | | | | |

As seen from the results, the resist compositions of Examples 1C to 30C exhibited large exposure latitude. Further, resolution, reduced LER and the shape of the resist pattern were also excellent. In particular, by comparison between Examples 1C and 14C to 26C or by comparison between Examples 27C to 30C in which only the type of composition (C) was varied, it was confirmed that there was a tendency that the smaller the number of the benzene ring in the cation moiety, the more excellent each evaluation result.

On the other hand, the resist composition of Comparative Example 1C in which the resin component (A″)-1C having no structural unit that generates acid upon exposure, an acid-generator component (B) and a component (C) were used, exhibited small exposure latitude and large LER.

The resist composition of Comparative Example 2C in which the component (A′)-1C having a structural unit that generates acid upon exposure and has a triphenylsulfonium ion as a cation moiety, and a component (D) were used, exhibited most small exposure latitude and large LER. The resist composition of Comparative Examples 3C in which the component (A′)-1 and a component (C) were used, was superior to the resist composition of Comparative Example 2C, but exhibited small exposure latitude and large LER, as compared to the resist composition of Examples 1C and 8C having the same composition exclusive of the cation moiety in the structural unit that generates acid upon exposure.

The resist composition of Comparative Example 4C in which the component (A′)-2C having a structural unit that generates acid upon exposure and has a triphenylsulfonium ion as a cation moiety and a component (C) were used, exhibited small exposure latitude, reduced resolution and large LER, as compared to the resist composition of Example 5C having the same composition exclusive of the cation moiety in the structural unit that generates acid upon exposure. The resist composition of Comparative Example 5C in which the resin component (A′)-3C and a component (C) were used, exhibited small exposure latitude, reduced resolution and large LER, as compared to the resist composition of Example 2C having the same composition exclusive of the cation moiety in the structural unit that generates acid upon exposure. The resist composition of Comparative Example 6C in which the resin component (A′)-4C and a component (C) were used, exhibited small exposure latitude, reduced resolution and large LER, as compared to the resist composition of Example 4C having the same composition exclusive of the cation moiety in the structural unit that generates acid upon exposure.

The resist composition of Comparative Example 7C in which the resin component (A′)-5C and a component (C) were used, exhibited small exposure latitude, reduced resolution and large LER, as compared to the resist compositions of Examples 1C and 8C having the same composition exclusive of the cation moiety in the structural unit that generates acid upon exposure.

The resist composition of Comparative Example 8C in which the resin component (A)-14C and a component (D) were used, exhibited small exposure latitude and large LER, as compared to the resist compositions of Examples 27C to 30C in which the component (A)-14C and a component (C) were used.

The resist composition of Comparative Example 9C in which the resin component (A)-1C and a component (D) were used, exhibited small exposure latitude and reduced resolution, as compared to the resist compositions of Examples 1C and 14C to 26C in which the component (A)-1C and a component (C) were used.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A resist composition for EUV or EB comprising:
a base component (A) which generates acid upon exposure and exhibits changed solubility in a developing solution by the action of acid; and
a resin component (W) which contains at least one atom selected from a fluorine atom or a silicon atom and contains a polarity conversion group that exhibits increased polarity after decomposition by the action of base, wherein
the base component (A) contains a polymeric compound (A1) which contains a structural unit (a0) having a group represented by general formula (a0-1) or (a0-2) shown below; and
the amount of the resin component (W) relative to 100 parts by weight of the base component (A) is 1 to 15 parts by weight: 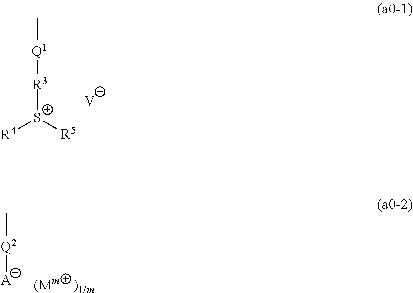
wherein each of Q¹ and Q² independently represent a single bond or a divalent linking group; each of R³, R⁴ and R⁵ independently represents an organic group, R⁴ and R⁵ may be mutually bonded to form a ring with the sulfur atom, provided that —R³—S⁺(R⁴)(R⁵) has one aromatic ring or no aromatic ring in total; V⁻ represents a counteranion; A⁻ represents an organic group containing an anion moiety; M^{m+} represents a m-valent organic cation; and m represents an integer of 1 to 3, provided that M^{m+} has one aromatic ring or no aromatic ring.

2. The resist composition for EUV or EB according to claim 1, wherein the polymeric compound (A1) comprises a structural unit (a1) having an acid decomposable group that exhibits increased polarity by the action of acid.

3. A resist composition comprising:
a base component (A) which generates acid upon exposure and exhibits changed solubility in a developing solution by the action of acid, wherein
the base component (A) contains a resin component (A1b) which contains a structural unit (a0) having a group represented by the general formula (a0-1) or (a0-2) shown below and a structural unit (a5) represented by general formula (a5-1) shown below: 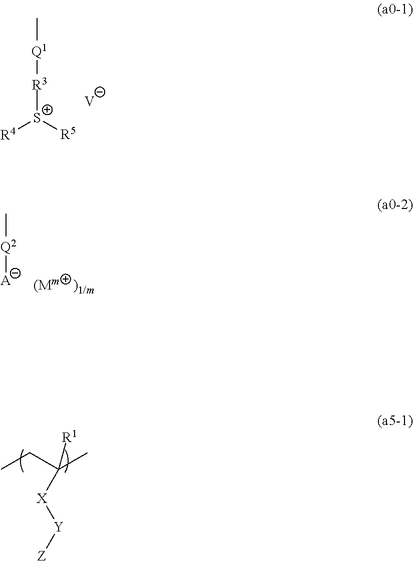
wherein each of Q¹ and Q² independently represent a single bond or a divalent linking group; each of R³, R⁴ and R⁵ independently represents an organic group, R⁴ and R⁵ may be mutually bonded to form a ring with the sulfur atom, provided that —R³—S⁺(R⁴)(R⁵) has one aromatic ring or no aromatic ring in total; V⁻ represents a counteranion; A⁻ represents an organic group containing an anion moiety; M^{m+} represents a m-valent organic cation; and m represents an integer of 1 to 3, provided that M^{m+} has one aromatic ring or no aromatic ring; R¹ represents a hydrogen atom, a methyl group or an alkyl group which has a substituent; X represents a divalent linking group; Y represents —O—, —COO—, —CON(R′)—, —OCO—, —CONHCO— or —CONHCS—, R′ represents a hydrogen atom or a methyl group, provided that when Y is —O—, X is a divalent linking group other than C(═O); and Z represents a group containing a lactone ring which may be either monocyclic or polycyclic and may have a substituent.

4. The resist composition according to claim 3, wherein the resin component (A1b) comprises a structural unit (a1) having an acid decomposable group that exhibits increased polarity by the action of acid.

5. A resist composition for EUV or EB comprising:
a base component (A) which generates acid upon exposure and exhibits changed solubility in a developing solution by the action of acid; and
a photoreactive quencher (C), wherein
the base component (A) contains a polymeric compound (A1) which contains a structural unit (a0) having a group represented by general formula (a0-1) or (a0-2) shown below: 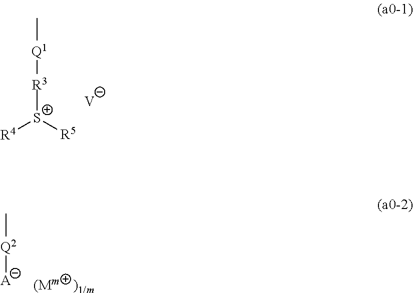
wherein each of Q¹ and Q² independently represent a single bond or a divalent linking group; each of R³, R⁴ and R⁵ independently represents an organic group, R⁴ and R⁵ may be mutually bonded to form a ring with the sulfur atom, provided that —R³—S⁺(R⁴)(R⁵) has one aromatic ring or no aromatic ring in total; V⁻ represents a counteranion; A⁻ represents an organic group containing an anion moiety; M^{m+} represents a m-valent organic cation; and m represents an integer of 1 to 3, provided that M^{m+} has one aromatic ring or no aromatic ring.

6. The resist composition for EUV or EB according to claim 5, wherein the structural unit (a0) is a structural unit represented by general formula (a0-21) shown below: 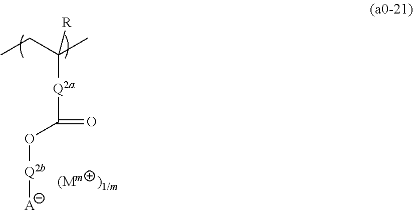
wherein R represents a hydrogen atom, an alkyl group of 1 to 5 carbon atoms or a halogenated alkyl group of 1 to 5 carbon atoms; Q^{2a} represents a single bond or a divalent linking group; Q^{2b} represents a single bond or a divalent linking group; A⁻ represents an organic group containing an anion moiety; M^{m+} represents a m-valent organic cation; and m represents an integer of 1 to 3, provided that M^{m+} has one aromatic ring or no aromatic ring.

7. The positive resist composition for EUV or EB according to claim 5, wherein the M^{m+} represents an organic cation having no aromatic ring.

8. The resist composition for EUV or EB according to claim 5, wherein the photoreactive quencher (C) comprises at least one compound selected from the group consisting of a compound (C1) represented by general formula (c1) shown below, a compound (C2) represented by general formula (c2) shown below and a compound (C3) represented by general formula (c3) shown below: 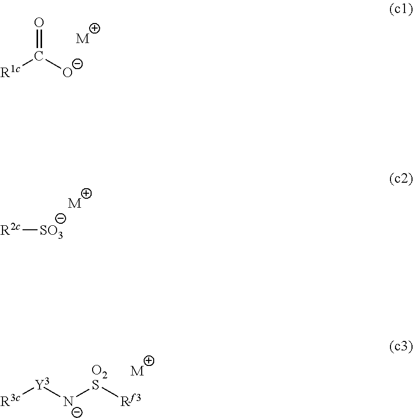
wherein R^{1c} represents a hydrocarbon group which may have a substituent; Z^{2c} represents a hydrocarbon group of 1 to 30 carbon atoms which may have a substituent, provided that the carbon atom adjacent to the sulfur atom has no fluorine atom; R^{3c} is an organic group; Y³ represents a linear, branched or cyclic alkylene group or arylene group; and R^{f3} represents a hydrocarbon group containing a fluorine atom; and each of M⁺ independently represents a sulfonium cation or a iodonium cation.

9. The resist composition for EUV or EB according to claim 5, wherein the polymeric compound (A1) comprises a structural unit (a1) having an acid decomposable group that exhibits increased polarity by the action of acid.

10. The resist composition for EUV or EB according to claim 9, wherein the polymeric compound (A1) further comprises a structural unit (a2) having an —SO₂— containing cyclic group or a lactone-containing cyclic group.
